(19) United States
(12) Patent Application Publication
(10) Pub. No.: US 2023/0001447 A1
(43) Pub. Date: Jan. 5, 2023

(54) MIXED POWDER, METHOD OF VAPOR-DEPOSITING ORGANIC COMPOUND, METHOD OF FABRICATING ORGANIC ELECTROLUMINESCENCE DEVICE, METHOD OF SELECTING ORGANIC COMPOUNDS, AND METHOD OF VAPOR-DEPOSITING

(71) Applicant: IDEMITSU KOSAN CO.,LTD., Tokyo (JP)

(72) Inventor: Hiroyuki IWABUCHI, Sodegaura-shi (JP)

(73) Assignee: IDEMITSU KOSAN CO.,LTD., Tokyo (JP)

(21) Appl. No.: 17/512,990

(22) Filed: Oct. 28, 2021

(30) Foreign Application Priority Data
May 21, 2021 (JP) 2021-086538

(51) Int. Cl. B05D 1/00; H01L 51/00

(52) U.S. Cl. CPC B05D 1/60; H01L 51/0072; H01L 51/0074; H01L 51/0073; H01L 51/56

(57) ABSTRACT

A mixed powder usable for a vapor deposition process, including a first organic compound and a second organic compound, wherein the following formula (1) is satisfied:

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source.

### TECHNICAL FIELD

The invention relates to a mixed powder, a method of vapor-depositing an organic compound, a method of fabricating an organic electroluminescence device, a method of selecting an organic compound, and a method of vapor-depositing.

### BACKGROUND ART

Vacuum vapor deposition process is generally used as a method of forming an organic layer in various fields including organic semiconductor devices such as organic electroluminescence devices (hereinafter, also referred to as organic EL devices), organic transistors, organic solar cells, and the like. In this process, an organic layer is formed by heating a target material in a vapor deposition source (a crucible) to allow the material to melt-evaporate or sublimate, and depositing the vaporized material on a substrate placed above. For example, Patent Documents 1 and 2 disclose formation of an organic layer of an organic EL device by a vacuum vapor deposition process.

### RELATED ART DOCUMENTS

### Patent Documents

### [Patent Document 1] JP 2015-018883 A

### [Patent Document 2] WO 2020/080416 A1

### SUMMARY OF THE INVENTION

However, there are cases where some organic materials do not deposit sufficiently on a substrate, since they falls into a vapor deposition source or a vapor deposition equipment to block the vapor deposition source, or they precipitate in the vapor deposition equipment before reaching the substrate. In a mass-production deposition apparatus, a cylindrical cavity with a large inner diameter is sometimes installed at the top of the crucible for pressure control, but in this case as well, material deposits near a nozzle installed at the top of the cavity and inside the cavity, to cause problems such as crucible blockage.

An object of the invention is to provide a method of vapor-depositing and a mixed powder enabling an efficient vapor deposition which is hardly causing a process trouble even when an organic compound which is unsuitable for a vapor deposition process is used.

As a result of studies, the inventor found that the above-mentioned problems at the time of vapor deposition have a large relationship with a degree of spread (diffusion) of an organic material at the time when it is vaporized from a vapor deposition source, that is, a degree of spread in the lateral direction (width direction), i.e., a spread of a vapor deposition trajectory. In other words, in the case of a material with a small degree of spread during a vapor deposition, it is conceivable that the vaporized material is converged in a part of a substrate due to its high straight traveling property, the supply rate becomes faster than the deposition rate in the part of the substrate, and as a result, deposition on the substrate may become difficult. Also, when using the cylindrical cavity as described above, the vaporized material is reflected by the upper wall inside the cavity to deposit at the bottom of the cavity. On the other hand, in the case of a material with a large degree of spread during a vapor deposition, it is conceivable that a proportion of precipitation in the vapor deposition equipment without reaching the substrate is increased, also, when using the cylindrical cavity, a turbulence is generated inside the cavity, a velocity difference between the inside and outside of the nozzle is generated, thereby facilitating crystal growth at the edge of the nozzle.

As a result of further studies to solve the above-mentioned problems, the inventor found that when vapor deposition is performed using a mixed material (powder) previously prepared by mixing a material with a large degree of spread of a vapor deposition trajectory with a material with a small degree of spread of a vapor deposition trajectory, a degree of spread of a vapor deposition trajectory becomes smaller than the former and larger than the latter. Namely, the inventor found that the vapor deposition characteristics (a spread of a vapor deposition trajectory) of an organic material can be adjusted by mixing another organic material having a different vapor deposition characteristics. The inventor found that, by this means, an efficient vapor deposition which is less likely to cause process troubles becomes possible even when using an organic material which unsuitable for a vapor deposition process because of its too wide or too narrow vapor deposition trajectory in the case where it is used alone, and the inventor has completed the invention.

According to the invention, the following mixed powder and so on are provided.

1. A mixed powder usable for a vapor deposition process, comprising a first organic compound and a second organic compound, wherein the following formula (1) is satisfied:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

2. A method of vapor-depositing an organic compound comprising:

vaporizing a mixed powder comprising a first organic compound and a second organic compound from a vapor deposition source, to form a film on a base material opposite to the vapor deposition source, wherein the following formula (1) is satisfied for the mixed powder:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

3. A method of fabricating an organic electroluminescence device comprising a cathode, an anode, and one or two or more organic layers disposed between the cathode and the anode, the organic layers comprising an emitting layer; comprising:

vaporizing a mixed powder from a vapor deposition source to deposit at least one layer of the one or two or more organic layers, wherein

the mixed powder comprises a first organic compound and a second organic compound, and the following formula (1) is satisfied for the mixed powder:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

4. A method of selecting a first organic compound and a second organic compound comprised in a mixed powder usable for a vapor deposition process, comprising:

selecting the first organic compound and the second organic compound so as to satisfy the following formula (1):

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

5. A method of vapor-depositing comprising:

when vapor-depositing a first organic compound from a vapor deposition source to a base material, adjusting a spread angle of a vapor deposition trajectory of the first organic compound by adding a second organic compound having a larger or smaller spread angle of a vapor deposition trajectory at the time of a vapor deposition than that of the first organic compound.

According to the invention, a method of vapor-depositing and a mixed powder enabling an efficient vapor deposition which is hardly causing a process trouble even when an organic compound which is unsuitable fora vapor deposition process is used can be provided.

### BRIEF DESCRIPTION OF THE DRAWINGS

FIGS. 1(a) and 1(b) are schematic diagrams showing a measurement apparatus used for measuring a spread of the vapor deposition trajectory.

FIGS. 2(a) and 2(b) are diagrams showing the relationship between a spread angle θ of a vapor deposition trajectory and a film thickness distribution.

FIG. 3 is a schematic diagram showing masks 201 placed on the deposition surface of the substrate 102 in Example.

### MODE FOR CARRYING OUT THE INVENTION

### [Method of Vapor-Depositing]

The method of vapor-depositing according to one aspect of the invention includes, when vapor-depositing a first organic compound (hereinafter, also referred to as a “first component”) from a vapor deposition source to a base material, adjusting a spread angle of a vapor deposition trajectory of the first organic compound by adding a second organic compound (hereinafter, also referred to as a “second component”) having a larger or smaller spread angle of a vapor deposition trajectory at the time of a vapor deposition than that of the first organic compound.

As described above, since the spread of a vapor deposition trajectory at the time of vapor deposition of the first organic compound can be changed by using another organic compound (a second organic compound) having different degree of spread of the a deposition trajectory in combination, the vapor deposition trajectory can be adjusted so as to have a desired degree of spread. Although the mechanism is not necessarily clear, it is considered to be due to intermolecular interactions of the first organic compound and the second organic compound.

For example, by mixing a first organic compound with a second organic compound having a smaller spread of a vapor deposition trajectory than that of the first organic compound, the spread of a vapor deposition trajectory when the mixture is used for a vapor deposition can be suppressed and narrowed compared with when the first organic compound is used alone for a vapor deposition. Also, by mixing a first organic compound with a second organic compound having a larger spread of a vapor deposition trajectory than that of the first organic compound, the vapor deposition trajectory when the mixture is used for vapor deposition can be widened compared when the first organic compound is used alone for a vapor deposition.

Thus, even when using a compound which is unsuitable for a vapor deposition process due to its too wide or too narrow vapor deposition trajectory in the case where it is used alone, blockage of crucible, undesired deposition, adhesion to a protective plate or the like can be prevented to reduce troubles in a vapor deposition process by adjusting (improving) the vapor deposition trajectory by combining another compound having different vapor deposition characteristics. In addition, a high-rate vapor deposition can be achieved while maintaining a balance between a vapor deposition rate and a precipitation rate, and mass production efficiency and a material usage efficiency can be increased.

Note that, as will be described below, in one embodiment, the first organic compound and the second organic compound are used in powder form.

### <Spread of Vapor Deposition Trajectory>

In the invention, the “spread of vapor deposition trajectory” refers to a degree to which a material vaporized with heating in a vapor deposition source spreads form the opening of the vapor deposition source when the vaporized material is ejected toward an opposite base material (e.g., a substrate) located above the vapor deposition source. Specifically, the degree is evaluated by the central angle θ of spread when the vapor deposition source is viewed from the horizontal direction. The method of measuring the central angle θ (spread angle θ of vapor deposition trajectory) is as follows.

### (Method of Measuring Spread Angle θ of Vapor Deposition Trajectory)

Hereinafter, a method of measuring a spread angle θ_{A} of a vapor deposition trajectory of an organic compound A to be measured will be described with reference to Drawings.

### (1) Measuring Apparatus

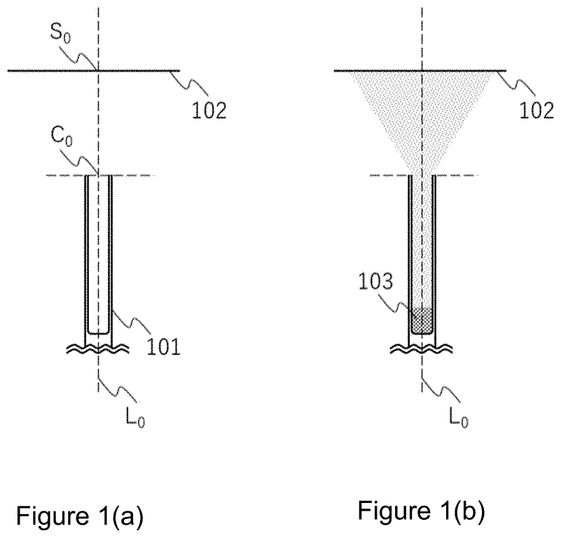

A crucible and a substrate to be vapor-deposited are placed inside a chamber of a vapor deposition equipment having a decompression function. At this time, as shown in FIG. 1(a), a crucible 101 is placed so that its longitudinal direction becomes vertical, and a substrate 102 is placed so that its surface to be vapor-deposited becomes perpendicular to the longitudinal direction of the crucible 101 (i.e., horizontal direction). When the central point of the crucible opening is defined as C₀, and the intersection point of the line L₀ extended from the central point C₀ in the longitudinal direction of the crucible and the surface of the substrate to be vapor-deposited is defined as S₀, the distance between C₀-S₀ is set to 50 mm.

As the vapor deposition source, a crucible made of aluminum nitride is used, the crucible has a cylindrical shape with one end closed (crucible having a cylindrical hollow part), an inner diameter of the hollow part of 10 mm, and a total length of the hollow part of 50 mm or more. The total length of the hollow part is set to be 100 mm or less.

Other conditions of the vapor deposition equipment are not particularly limited as long as the method of measuring can be performed. As the substrate, a glass substrate is generally used. The size and thickness of the substrate are not particularly limited as long as the method for measuring can be performed.

### (2) Method of Operation

As shown in FIG. 1(b), the crucible 101 is charged with a powder of an organic compound A (sample 103). The input amount of the powder is set to be 5% or more of the total length of the hollow part of the crucible, and is set not to exceed 20%. A bulky powder may be compressed.

The degree of vacuum in the chamber is set to be 1×10⁻³ Pa or less, and the crucible is heated to start evaporation of the organic compound A, so that the vapor pressure (saturated vapor pressure) P of the organic compound A obtained by the following formula (A1) becomes 1 Pa or more, and the film formation is continued while maintaining the above-mentioned conditions until the sample 103 is completely vaporized.

$$P = \frac{1}{A} \cdot \frac{d Δ W}{d T} \cdot \frac{d T}{d t} \cdot \sqrt{\frac{2 π R T}{M}} \qquad ( A 1 )$$

In the formula (A1), each symbol represents the followings:

P: Saturated vapor pressure [Pa]
A: Deposition area on the surface of the substrate [m²]
ΔW: Mass loss of the organic compound A in the vapor deposition source [kg]
T: Temperature of an evaporation surface at the vapor deposition source [K]
t: Time [sec]
M: Molecular weight of the organic compound A [kg/mol]
R: Gas constant [J/(mol·K)]

In the formula (A1), A (deposition area on the surface of the substrate [m²]) is an area of a circle having a radius of the minimum value of the distance between S₀ to Sᵣ, in which Sᵣ is the position where the film thickness becomes 0.05 T₀, wherein T₀ is the film thickness at S₀.

In the formula (A1), T (temperature of an evaporation surface in the vapor deposition source [K]) is the temperature of the crucible at the end of the vapor deposition.

Strictly theoretically, a condensation coefficient “a” may affect the saturated vapor pressure P, but in this operation, since the organic compound A is considered to be in a sufficiently spreaded state, the condensation coefficient “a” is deemed as 1. Therefore, the condensation coefficient “a” does not appear in the formula (A1).

When the heat of the heated crucible 101 is easily transmitted to the substrate 102, in order to prevent the negative effect of the heat, a reflector or the like may be placed around the opening of the crucible 101 for example so as to be parallel to the substrate 102 in a position that does not affect the vapor deposition trajectory.

### (3) Measurement of Film Thickness and Calculation of θ_{A}

For the film obtained on the substrate 102, the film thickness is measured along the vapor deposited surface of the substrate from S₀ to evaluate the film thickness distribution.

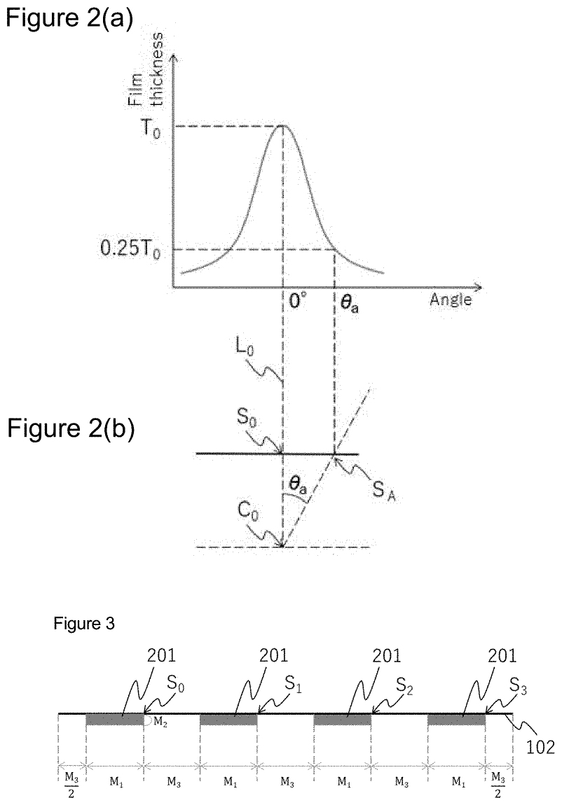

The film thickness distribution in this example is shown in FIG. 2(a) (schematic diagram). When vacuum vapor deposition of an organic compound is performed onto a fixed substrate, such a film thickness distribution is generally obtained. Horizontal axis in FIG. 2(a) indicates a tilt angle θ from the center-line L₀ around C₀. As shown in FIGS. 2(a) and (b), when the film thickness at the angle θ=0° (film thickness at S₀) is defined to be T₀, and the angle at the position S_{A} (∠S₀C₀S_{A}) where the film thickness decreases to 25% to become 0.25 T₀ is defined to be θₐ, the spread angle of the vapor deposition trajectory of the organic compound A is defined as θ_{A}=2θₐ in consideration of the spread in the lateral direction. Note that S_{A} is a position where the distance from S₀ is minimized.

The film thickness and the film thickness distribution can be measured by the method described in Example (a method by providing a mask on the substrate surface) and a method using an optical film thickness meter.

The above measurement can be carried out using a general vapor deposition equipment having a cylindrical crucible having one end closed (e.g., a film forming apparatus used in a fabrication of an organic EL device, etc.).

(Difference in spread angle θ)

In one embodiment, as the first organic compound and the second organic compound described above, organic compounds with a difference of 10° or more in a spread angle θ of a vapor deposition trajectory are used. This embodiment can be expressed as follows.

A method of vapor-depositing an organic compound comprising:

vaporizing a mixed powder comprising a first organic compound and a second organic compound from a vapor deposition source, to form a film on a base material opposite to the vapor deposition source, wherein the following formula (1) is satisfied for the mixed powder:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

If the difference between the spread angles θ of the vapor deposition trajectory of the two materials (|θ₁-θ2|) is 10° or more, the above-mentioned effect of adjusting a spread of a vapor deposition trajectory is sufficiently expected, and a desired vapor deposition trajectory (a spread angle θₘ of a vapor deposition trajectory of a mixed powder) can be realized depending upon a vapor deposition equipment and required conditions.

For example, in the case where θₘ is adjusted to become a° smaller than θ₁ to suppress a spread of a vapor deposition trajectory of a first organic compound, as a rough indication, a second organic compound having θ₂ of about (θ₁-2a)° can be combined to form a mixed powder having a desired θₘ with adjusting mixing ratio of the two compounds or the like.

The difference between the spread angles θ of the vapor deposition trajectory of two materials (|θ₁-θ₂|) is preferably 15° or more, and more preferably 20° or more. The larger the difference between θ₁ and θ₂ is, the wider the angle adjustment range becomes, and the desired θₘ can be easily obtained. The upper limit of the difference of the two θ's (|θ₁-θ₂|) is not particularly limited.

Although the actual values of θ₁ and θ₂ are not particularly limited, it is conceivable to combine, for example, a first organic compound having a θ₁ of 100° to 120° with a second organic compound having a θ₂ of 60° to 80° to form a mixed powder having a θₘ of 80° to 100°, by taking into consideration vapor deposition conditions in a conventional film forming apparatus.

### <Mixed Powder>

A mixed powder used in the method of vapor-depositing according to one aspect of the invention is not particularly limited as long as the mixed powder contains a powder of two kinds of organic compounds having different spread of a vapor deposition trajectory (preferably a powder of two kinds of organic compounds satisfying the formula (1)).

In one embodiment, it is preferred that the first organic compound and the second organic compound have compound characteristics similar to each other. The compound characteristics are, for example, a molecular weight, a sublimation temperature, a vapor deposition temperature, and the like.

A difference in molecular weight between the first organic compound and the second organic compound (|molecular weight of the first compound—molecular weight of the second compound|) is preferably 500 or less, more preferably 400 or less, and still more preferably 300 or less.

The evaporation temperature (sublimation temperature, vapor deposition temperature) of a compound is a temperature measured at a surface located a set distance away from the vapor deposition source of the material to be vapor deposited at a vapor deposition rate of 0.5 to 2 Å/sec in a vacuum deposition apparatus, at a constant pressure of 5 Pa or less, or in a vacuum vessel holding a pressure of 1 Pa to 1×10⁻⁷ Pa.

A difference between the evaporation temperature T1 [° C.] of the first organic compound, and the deposition temperature T2 [° C.] of the second organic compound (|T1-T2|) is, for example, 35° C. or lower, 30° C. or lower, 25° C. or lower, 20° C. or lower, or 15° C. or lower, and is preferably 20° C. or lower or 15° C. or lower.

In one embodiment, the difference between T1 and T2 (|T1-T2|) is 10° C. or higher and 30° C. or lower, 5° C. or higher and 25° C. or lower, or 0° C. or higher and 20° C. or lower.

### (Mixing Ratio)

Mixing ratio of the first organic compound and the second organic compound in the mixed powder is not particularly limited, and can be appropriately determined by taking into consideration a mixing ratio in a vapor deposited film and a spread angle θₘ of a vapor deposition trajectory. The mixing ratio (mass ratio) of the first organic compound and the second organic compound is usually 1:99 to 99:1, and for example, 10:90 to 90:10.

### (First Organic Compound and Second Organic Compound)

The compound structure of a first organic compound and a second organic compound is not particularly limited, and any organic compound can be used as long as satisfying the above-described vapor deposition characteristics.

In one embodiment, the first organic compound and the second organic compound are organic semiconductor materials, e.g., a material for an organic EL device, a material for an organic transistor, or a material for an organic solar cell.

As a material for an organic EL device, a material described below in [Method of fabricating organic EL device] can be used.

In one embodiment, at least one of the first organic compound and the second organic compound is a fluorescent emitting compound that emits fluorescence. Examples of the compound include a dopant material used in an emitting layer of an organic EL device, and a material described below in [Method of fabricating organic EL device] can be used.

In one embodiment, at least one of the first organic compound and the second organic compound is a fluorescent emitting compound that emits fluorescence with a main peak wavelength of 500 nm or less. As such compounds, a “blue fluorescent emitting material” described below in [Method of fabricating organic EL device] can be used.

The method for measuring the main peak wavelength of a compound is described as follows. A sample of 5 μmol/L toluene solution of the compound to be measured is prepared, placed in a quartz cell, and the emission spectrum (vertical axis: emission intensity, horizontal axis: wavelength) of this sample is measured at room temperature (300 K). The emission spectrum can be measured by a spectrofluorometer (Device name: F-7000) manufactured by Hitachi High-Technology Science Corporation. In the emission spectrum, the peak wavelength of the emission spectrum where the emission intensity is the maximum is defined as the main peak wavelength.

In one embodiment, neither the first organic compound nor the second organic compound is a phosphorescent compound that emits phosphorescence. Examples of the phosphorescent compound include materials described below in [Method of fabricating organic EL device].

In one embodiment, the first organic compound is a host material for the emitting layer and the second organic compound is a dopant material for the emitting layer. It is preferable that the triplet energy T₁ (H1) of the first organic compound and the triplet energy T₁ (D1) of the second organic compound satisfy the following relation (mathematical formula 1).

T₁(D1)>T₁(H1) (mathematical formula 1)

The method of measuring a triplet energy T₁ is described as follows.

A compound to be measured is dissolved in EPA (diethylether:isopentane:ethanol=5:5:2 (volume ratio)) in a concentration of 10⁻⁵ mol/L or higher and 10⁻⁴ mol/L or lower, and this solution is put in a quartz cell as a measurement sample. For this measurement sample, phosphorescent spectrum (the vertical axis: phosphorescence emission intensity, the horizontal axis: wavelength) is measured at a low temperature (77 [K]), a tangent line is drawn to the rising edge on the short wavelength side of this phosphorescence spectrum, and the energy quantity calculated through the following conversion expression (F1) based on the wavelength value λ_{edge} [nm] of the intersection point between the tangent line and the horizontal axis is defined as the triplet energy T₁.

Conversion expression (F1): T₁ [eV]=1239.85/λ_{edge}

The tangent to the rise of the phosphorescence spectrum close to the short-wavelength region is drawn as follows. While moving on a curve of the phosphorescence spectrum from the short-wavelength region to the maximum spectral value closest to the short-wavelength region among the maximum spectral values, a tangent is checked at each point on the curve toward the long-wavelength of the phosphorescence spectrum. An inclination of the tangent is increased along the rise of the curve (i.e., a value of the ordinate axis is increased). A tangent drawn at a point of the maximum inclination (i.e., a tangent at an inflection point) is defined as the tangent to the rise of the phosphorescence spectrum close to the short-wavelength region.

The maximum with peak intensity being 15% or less of the maximum peak intensity of the spectrum is not included in the above-mentioned maximum closest to the short-wavelength region. The tangent drawn at a point of the maximum spectral value being closest to the short-wavelength region and having the maximum inclination is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any device for phosphorescence measurement is usable. A combination of a cooling unit, a low temperature container, an excitation light source and a light-receiving unit may be used for phosphorescence measurement.

In one embodiment, the following compounds can be used as the first organic compound and the second organic compound, respectively.

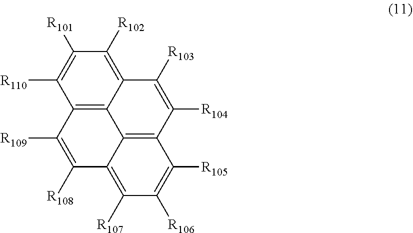

In the formula (11),

one or more sets of two or more adjacent groups of R₁₀₁ to R₁₁₀ form a substituted or unsubstituted, saturated or unsaturated ring by bonding with each other, or do not form a substituted or unsubstituted, saturated or unsaturated ring;

at least one of R₁₀₁ to R₁₁₀ is a monovalent group represented by the formula (12);

R₁₀₁ to R₁₁₀ that do not form the substituted or unsubstituted, saturated or unsaturated ring and that are not the monovalent group represented by the following formula (12) are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms, —Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
R₉₀₁ to R₉₀₇ are independently
   a hydrogen atom,
   a substituted or unsubstituted alkyl group including 1 to 50 carbon atoms,
   a substituted or unsubstituted cycloalkyl group including 3 to 50 ring carbon atoms,
   a substituted or unsubstituted aryl group including 6 to 50 ring carbon atoms, or
   a substituted or unsubstituted monovalent heterocyclic group including 5 to 50 ring atoms; and when two or more of each of R₉₀₁ to R₉₀₇ are present, the two or more of each of R₉₀₁ to R₉₀₇ are the same as or different from each other.

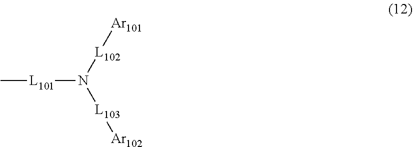

In the formula (12), Ar₁₀₁ and Ar₁₀₂ are independently

a substituted or unsubstituted aryl group including 6 to 50 ring carbon atoms, or
a substituted or unsubstituted monovalent heterocyclic group including 5 to 50 ring atoms;

L₁₀₁ to L₁₀₃ are independently

a single bond,
a substituted or unsubstituted arylene group including 6 to 30 ring carbon atoms, or
a substituted or unsubstituted divalent heterocyclic group including 5 to 30 ring atoms.

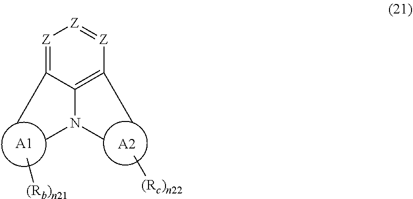

In the formula (21),

Z's are independently CRₐ or N;

ring A1 and ring A2 are independently a substituted or unsubstituted aromatic hydrocarbon ring including 6 to 50 ring carbon atoms, or a substituted or unsubstituted heterocycle including 5 to 50 ring atoms;

when a plurality of Rₐ's exist, one or more sets of two or more adjacent Rₐ's form a substituted or unsubstituted, saturated or unsaturated ring by bonding with each other, or do not form a substituted or unsubstituted, saturated or unsaturated ring;

when a plurality of R_{b}'s exist, one or more sets of two or more adjacent R_{b}'s form a substituted or unsubstituted, saturated or unsaturated ring by bonding with each other, or do not form a substituted or unsubstituted, saturated or unsaturated ring;

when a plurality of R_{c}'s exist, one or more sets of two or more adjacent R_{c}'s form a substituted or unsubstituted, saturated or unsaturated ring by bonding with each other, or do not form a substituted or unsubstituted, saturated or unsaturated ring;

n21 and n22 are independently an integer of 0 to 4;

Rₐ to R_{c} that do not form the substituted or unsubstituted, saturated or unsaturated ring are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₉₀₁ to R₉₀₇ are as defined in the formula (11).

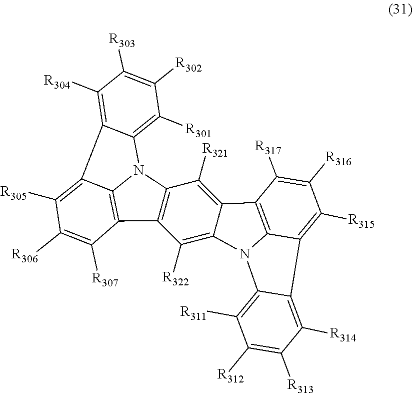

In the formula (31),

one or more sets of two or more adjacent groups of R₃₀₁ to R₃₀₇ and R₃₁₁ to R₃₁₇ form a substituted or unsubstituted, saturated or unsaturated ring by bonding with each other, or do not form a substituted or unsubstituted, saturated or unsaturated ring;

R₃₀₁ to R₃₀₇ and R₃₁₁ to R₃₁₇ that do not form the substituted or unsubstituted, saturated or unsaturated ring are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₃₂₁ and R₃₂₂ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms; and

R₉₀₁ to R₉₀₇ are as defined in the formula (11).

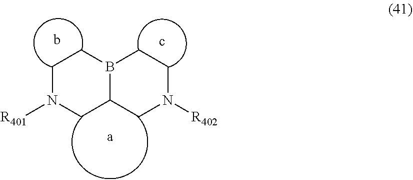

In the formula (41),

ring a, ring b and ring c are independently

a substituted or unsubstituted aromatic hydrocarbon ring including 6 to 50 ring carbon atoms, or
a substituted or unsubstituted heterocycle including 5 to 50 ring atoms;

R₄₀₁ and R₄₀₂ independently form a substituted or unsubstituted heterocycle by bonding to the ring a, the ring b or the ring c, or do not form a substituted or unsubstituted heterocycle;

R₄₀₁ and R₄₀₂ that do not form the substituted or unsubstituted heterocycle are independently

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms.

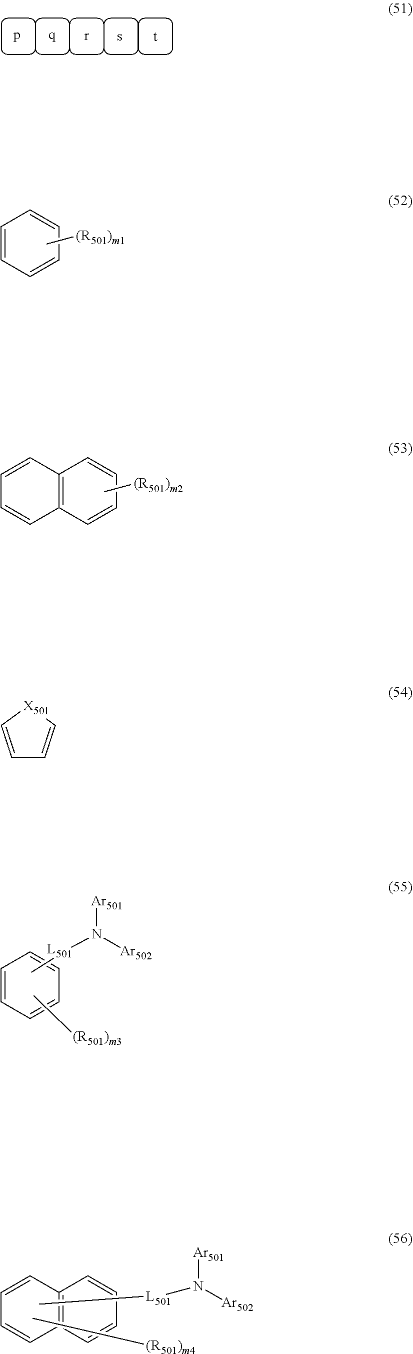

In the formula (51),

ring r is a ring represented by the formula (52) or the formula (53) which is fused to adjacent rings at respective arbitrary positions;

ring q and ring s are independently a ring represented by the formula (54) which is fused to adjacent rings at respective arbitrary positions;

ring p and ring t are independently a ring represented by the formula (55) or the formula (56) which is fused to an adjacent ring at an arbitrary position;

when a plurality of R₅₀₁'s exist, adjacent R₅₀₁'s form a substituted or unsubstituted, saturated or unsaturated ring by bonding with each other, or do not form a substituted or unsubstituted, saturated or unsaturated ring;

X₅₀₁ is an oxygen atom, a sulfur atom, or NR₅₀₂;

R₅₀₁ and R₅₀₂ that do not form the substituted or unsubstituted saturated or unsaturated ring, and R₅₀₂ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₉₀₁ to R₉₀₇ are as defined in the formula (11);

Ar₅₀₁ and Ar₅₀₂ are independently

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms;

L₅₀₁ is

a substituted or unsubstituted alkylene group including 1 to 50 carbon atoms,
a substituted or unsubstituted alkenylene group including 2 to 50 carbon atoms,
a substituted or unsubstituted alkynylene group including 2 to 50 carbon atoms,
a substituted or unsubstituted cycloalkylene group including 3 to 50 ring carbon atoms,
a substituted or unsubstituted arylene group including 6 to 50 ring carbon atoms, or
a substituted or unsubstituted divalent heterocyclic group including 5 to 50 ring atoms;

m1 is an integer of 0 to 2, m2 is an integer of 0 to 4, m3 is independently an integer of 0 to 3, and m4 is independently an integer of 0 to 5; and when a plurality of R₅₀₁'s exist, the plurality of R₅₀₁'s may be the same as or different from each other.

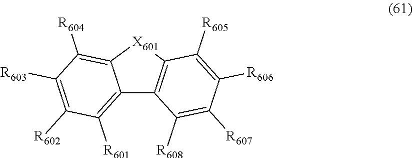

In the formula (61),

at least one set of R₆₀₁ and R₆₀₂, R₆₀₂ and R₆₀₃, and R₆₀₃ and R₆₀₄ form a divalent group represented by the following formula (62) by bonding with each other;

at least one set of R₆₀₅ and R₆₀₆, R₆₀₆ and R⁶⁰⁷, and R₆₀₇ and R₆₀₈ form a divalent group represented by the following formula (63) by bonding with each other.

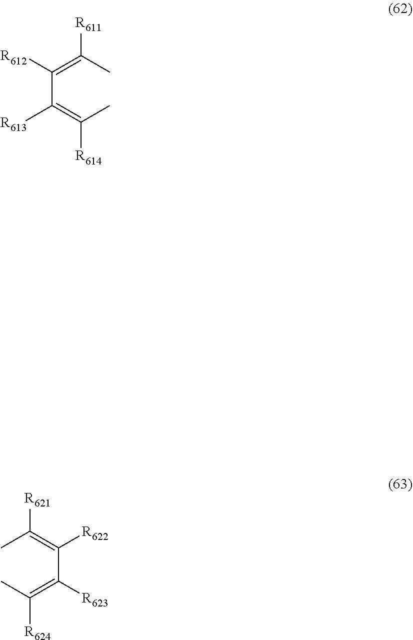

At least one of R₆₀₁ to R₆₀₄ that do not form the divalent group represented by the formula (62), and R₆₁₁ to R₆₁₄ is a monovalent group represented by the following formula (64);

at least one of R₆₀₅ to R₆₀₈ that do not form the divalent group represented by the formula (63), and R₆₂₁ to R₆₂₄ is a monovalent group represented by the following formula (64);

X₆₀₁ is an oxygen atom, a sulfur atom, or NR₆₀₉;

R₆₀₁ to R₆₀₈ that do not form the divalent group represented by any of the formulas (62) and (63) and that is not the monovalent group represented by the formula (64), R₆₁₁ to R₆₁₄ and R₆₂₁ to R₆₂₄ that are not the monovalent group represented by the formula (64), and R₆₀₉ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₉₀₁ to R₉₀₇ are as defined in the formula (11).

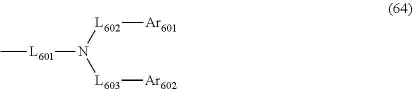

In the formula (64), Ar₆₀₁ and Aram are independently

a substituted or unsubstituted aryl group including 6 to 50 ring carbon atoms, or
a substituted or unsubstituted monovalent heterocyclic group including 5 to 50 ring atoms;

L₆₀₁ to L₆₀₃ are independently

a single bond,
a substituted or unsubstituted arylene group including 6 to 30 ring carbon atoms,
a substituted or unsubstituted divalent heterocyclic group including 5 to 30 ring atoms, or
a divalent group formed by linking 2 to 4 groups selected from the group consisting of the above-mentioned arylene group and divalent heterocyclic group.

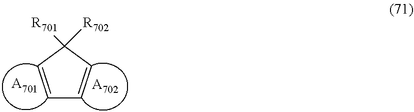

In the formula (71),

ring A₇₀₁ and ring A₇₀₂ are independently

a substituted or unsubstituted aromatic hydrocarbon ring including 6 to 50 ring carbon atoms, or
a substituted or unsubstituted heterocycle including 5 to 50 ring atoms;

one or both of the ring A701 and the ring A702 is bonded to a structure represented by the following formula (72) at arbitrary positions of the ring A701 or the ring A702 via *'s.

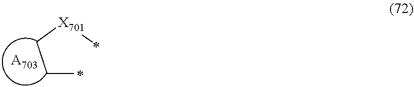

In the formula (72),

rings A₇₀₃'s are independently

a substituted or unsubstituted aromatic hydrocarbon ring including 6 to 50 ring carbon atoms, or
a substituted or unsubstituted heterocycle including 5 to 50 ring atoms;

X₇₀₁ is NR₇₀₃, C(R₇₀₄)(R₇₀₅), Si(R₇₀₆) (R₇₀₇), Ge(R₇₀₈) (R₇₀₉), O, S or Se;

R₇₀₁ and R₇₀₂ form a substituted or unsubstituted, saturated or unsaturated ring by bonding with each other, or do not form a substituted or unsubstituted saturated or unsaturated ring;

R₇₀₁ and R₇₀₂ that do not form the substituted or unsubstituted, saturated or unsaturated ring, and R₇₀₃ to R₇₀₉ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₉₀₁ to R₉₀₇ are as defined in the formula (11).

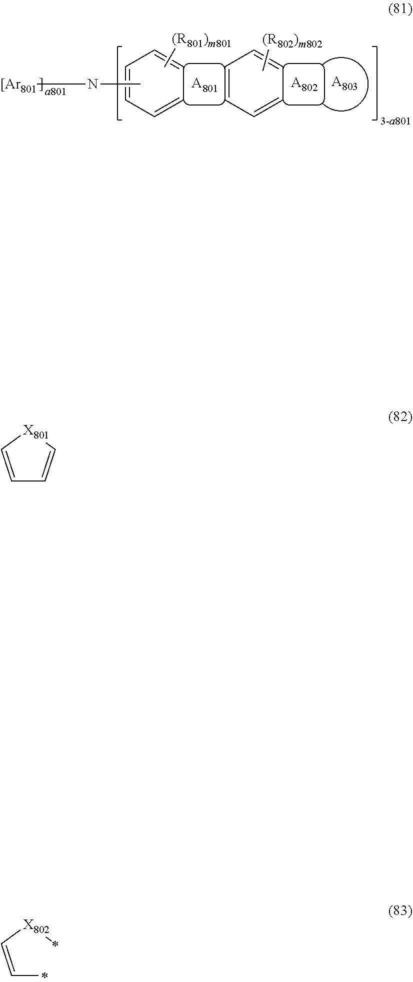

In the formula (81),

ring A₈₀₁ is a ring represented by the formula (82) which is fused to adjacent rings at respective arbitrary positions;

ring A₈₀₂ is a ring represented by the formula (83) which is fused to adjacent rings at respective arbitrary positions;

two *'s bond to A₈₀₃ ring at respective arbitrary positions;

X₈₀₁ and X₈₀₂ are independently C(R₈₀₃)(R₈₀₄), Si(R₈₀₅)(R₈₀₆), an oxygen atom, or a sulfur atom;

ring A₈₀₃ is a substituted or unsubstituted aromatic hydrocarbon ring including 6 to 50 ring carbon atoms, or a substituted or unsubstituted heterocycle including 5 to 50 ring atoms;

Ar₈₀₁ is a substituted or unsubstituted aryl group including 6 to 50 ring carbon atoms, or a substituted or unsubstituted monovalent heterocyclic group including 5 to 50 ring atoms;

R₈₀₁ to R₈₀₆ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—S(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

R₉₀₁ to R₉₀₇ are as defined in the formula (11);
m801 and m802 are independently an integer of 0 to 2; when they are 2, a plurality of R₈₀₁'s or R₈₀₂'s may be the same as or different from each other;

a801 is an integer of 0 to 2; when a801 is 0 or 1, “3-a801” structures in the parentheses may be the same as or different from each other; and when a801 is 2, Ar₈₀₁'s may be the same as or different from each other.

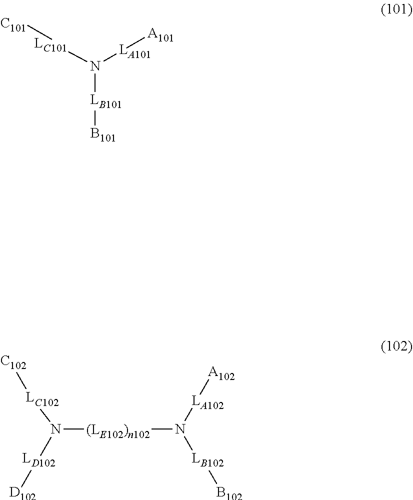

In the formulas (101) and (102),

L_{A101}, L_{B101}, L_{C101}, L_{A102}, L_{B102}, L_{C102}, and L_{D102} are independently

a single bond,
a substituted or unsubstituted arylene group including 6 to 50 ring carbon atoms, or
a substituted or unsubstituted divalent heterocyclic group including 5 to 50 ring atoms.

n102 is 1, 2, 3, or 4.

When n102 is 1, L_{E102} is

a substituted or unsubstituted arylene group including 6 to 50 ring carbon atoms, or
a substituted or unsubstituted divalent heterocyclic group including 5 to 50 ring atoms.

When n2 is 2, 3, or 4, the plurality of L_{E102}'s may be the same as or different from each other.

When n2 is 2, 3, or 4, the plurality of L_{E102}'s

form a substituted or unsubstituted monocyclic ring by bonding with each other,
form a substituted or unsubstituted fused ring by bonding with each other, or
do not bond with each other.

L_{E102} that do not form the monocyclic ring and do not form the fused ring is

a substituted or unsubstituted arylene group including 6 to 50 ring carbon atoms, or
a substituted or unsubstituted divalent heterocyclic group including 5 to 50 ring atoms.

A₁₀₁, B₁₀₁, C₁₀₁, A₁₀₂, B₁₀₂, C₁₀₂, and D₁₀₂ are independently

a substituted or unsubstituted aryl group including 6 to 50 ring carbon atoms,
a substituted or unsubstituted monovalent heterocyclic group including 5 to 50 ring atoms, or
—Si(R′₉₀₁) (R′₉₀₂) (R′₉₀₃).

R′₉₀₁, R′₉₀₂, and R′₉₀₃ are independently a substituted or unsubstituted aryl group including 6 to 50 ring carbon atoms.

When a plurality of R′₉₀₁'s are present, the plurality of R′₉₀₁'s may be the same as or different from each other.

When a plurality of R′₉₀₂'s are present, the plurality of R′₉₀₂'s may be the same as or different from each other.

When a plurality of R′₉₀₃'s are present, the plurality of R′₉₀₃'s may be the same as or different from each other.

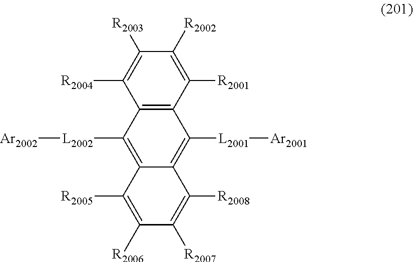

In the formula (201), R₂₀₀₁ to R₂₀₀₈ are independently selected from the group consisting of

a hydrogen atom,
a substituted or unsubstituted alkyl group including 1 to 50 carbon atoms,
—Si(R₉₀₁)(R₉₀₂)(R₉₀₃),

### —O—(R₉₀₄),

—N(R₉₀₆)(R₉₀₇),
a substituted or unsubstituted aryl group including 6 to 50 ring carbon atoms, and
a substituted or unsubstituted siloxane group.

R₉₀₁ to R₉₀₄ and R₉₀₆ to R₉₀₇ are as defined in the formula (11).

L₂₀₀₁ and L₂₀₀₂ are independently

a single bond, or
a substituted or unsubstituted arylene group including 6 to 50 ring carbon atoms.

Ar₂₀₀₁ and Ar₂₀₀₂ are independently

a substituted or unsubstituted aryl group including 6 to 50 ring carbon atoms.

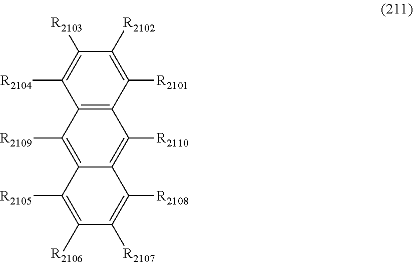

In the formula (211),

at least one of R₂₁₀₁ to R₂₁₀₈ is a group represented by the following formula (212).

R₂₁₀₁ to R₂₁₀₈ that is not a group represented by the formula (212) are independently a hydrogen atom,

a substituted or unsubstituted alkyl group including 1 to 50 carbon atoms,

### —O—(R₉₀₄),

a substituted or unsubstituted aryl group including 6 to 50 ring carbon atoms, or
a substituted or unsubstituted monovalent heterocyclic group including 5 to 50 ring atoms other than a dibenzofuranyl group and a dibenzothiophenyl group.

R₉₀₄ is as defined in the formula (11).

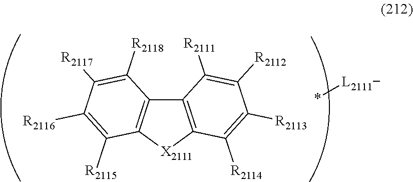

In the formula (212),

L₂₁₁₁ is

a substituted or unsubstituted arylene group including 6 to 50 ring carbon atoms, or
a substituted or unsubstituted divalent heterocyclic group including 5 to 50 ring atoms other than a dibenzofuranylene group and a dibenzothiophenylene group.

X₂₁₁₁ is an oxygen atom or a sulfur atom.

One of R₂₁₁₁ to R₂₁₁₈ is a single bond which bonds with L₂₁₁₁.

R₂₁₁₁ to R₂₁₁₈ that are not a single bond which is bonded with L₂₁₁₁ are independently

a hydrogen atom,
a substituted or unsubstituted alkyl group including 1 to 50 carbon atoms,
a substituted or unsubstituted cycloalkyl group including 3 to 50 ring carbon atoms,

### —O—(R₉₀₄),

a substituted or unsubstituted phenyl group,
a substituted or unsubstituted naphthyl group, or
a substituted or unsubstituted monovalent heterocyclic group including 5 to 50 ring atoms.

R₉₀₄ is as defined in the formula (11).

When a plurality of the groups represented by the formula (212) is present, the plurality of the groups represented by the formula (212) may be the same as or different from each other.

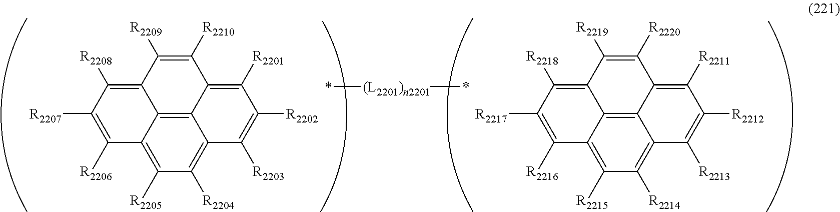

In the formula (221),

L₂₂₀₁ is

a single bond,
a substituted or unsubstituted arylene group including 6 to 24 ring carbon atoms, or
a substituted or unsubstituted divalent heterocyclic group including 5 to 24 ring atoms.

One of R₂₂₀₁ to R₂₂₁₀ and one of R₂₂₁₁ to R₂₂₂₀ are each a single bond which bonds with L₂₁₁₁. R₂₂₀₁ to R₂₂₂₀ that are not a single bond which bonds with L₂₁₁₁ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,

### —C(═O)(R₉₁₁), or

### —COO(R₉₁₂).

R₉₀₁ to R₉₀₇ are as defined in the formula (11).

R₉₁₁ and R₉₁₂ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms.

When two or more of each of R₉₁₁ and R₉₁₂ are present, the two or more of each of R₉₁₁ and R₉₁₂ may be the same as or different from each other.

n2201 is 1, 2, 3, 4, or 5.

When two or more L₂₂₀₁'s are present, the two or more L₂₂₀₁'s may be the same as or different from each other.

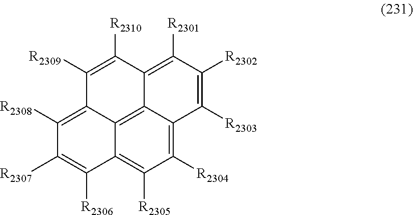

In the formula (231),

At least one of R₂₃₀₁ to R₂₃₁₀ is a group represented by the following formula (232).

R₂₃₀₁ to R₂₃₁₀ that are not the group represented by the formula (232) are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms other than a substituted or unsubstituted pyrenyl group,
a substituted or unsubstituted monovalent heterocyclic group including 5 to 50 ring atoms,

### —C(═O)(R₉₁₁), or

### —COO(R₉₁₂).

R₉₀₁ to R₉₀₇ are as defined in the formula (11).

R₉₁₁ to R₉₁₂ are as defined in the formula (221).

Ar₂₃₁₁-(L₂₃₁₁)ₙ₂₃₁₁- (232)

In the formula (232),

L₂₃₁₁ is a substituted or unsubstituted arylene group including 6 to 50 ring carbon atoms other than a substituted or unsubstituted pyrenylene group.

Ar₂₃₁₁ is a substituted or unsubstituted aryl group including 6 to 50 ring carbon atoms other than a substituted or unsubstituted pyrenyl group.

n2311 is 1, 2, 3, 4, or 5.

When two or more L₂₃₁₁'s are present, the two or more L₂₃₁₁'s may be the same as or different from each other.

When a plurality of the groups represented by the formula (232) is present, the plurality of the groups represented by the formula (232) may be the same as or different from each other.

### (Compound α Containing at Least One of a First Ring Structure Represented by the Following Formula (301) and a Second Ring Structure Represented by the Following Formula (302))

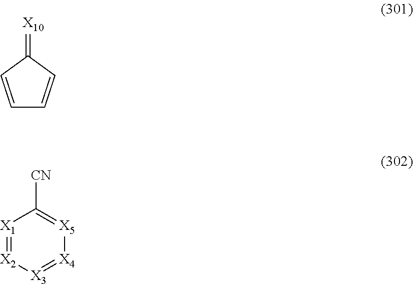

In the molecule of the compound α, a first ring structure represented by the formula (301) is fused with one or more ring structures selected from the group consisting of a substituted or unsubstituted aromatic hydrocarbon ring including 6 to 50 ring carbon atoms and a substituted or unsubstituted heterocycle including 5 to 50 ring atoms in a molecule of the compound α.

In the formula (301),

X₁₀ is a divalent group represented by the following formula (301a), (301b), (301c), (301d), (301e), (301f), (301g), (301h), (301i), (301j), (301k), or (301m).

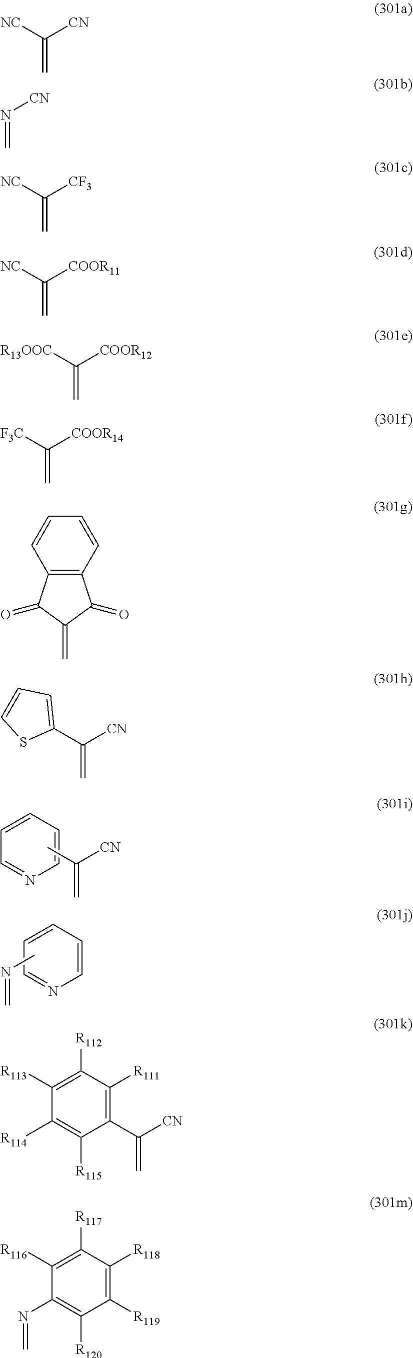

In the formulas (301a) to (301m),

R₁₁ to R₁₄ and R₁₁₁ to R₁₂₀ are independently a hydrogen atom or a substituent R.

The substituent R is a group selected from the group consisting of

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, and
a substituted or unsubstituted monovalent heterocyclic group including 5 to 50 ring atoms.

R₉₀₁ to R₉₀₇ are as defined in the formula (11).

When two or more substituents R's are present, the two or more substituents R's may be the same as or different from each other.

When two or more X₁₀'s are present, the two or more X₁₀'s may be the same as or different from each other.

In the formula (3θ₂),

X₁ to X₅ are independently N, CR₁₅, or a carbon atom which bonds with another atom in the molecule of the compound α. Provided that at least one of X₁ to X₅ is a carbon atom which bonds with another atom in the molecule of the compound α.

When two or more of each of X₁ to X₅ are present, the two or more of each of X₁ to X₅ may be the same as or different from each other.

R₁₅ is

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

When two or more R₁₅'s are present, the two or more R₁₅'s may be the same as or different from each other.

In one embodiment, the compound α is a compound formed by fusing two or three structures represented by the following formula (303) with a third ring structure selected from a substituted or unsubstituted aromatic hydrocarbon ring including 6 to 50 ring carbon atoms and a substituted or unsubstituted heterocycle including 5 to 50 ring atoms.

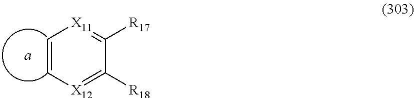

In the formula (303),

ring a is a ring structure which fuses to the third ring structure, and is represented by the formula (301).

X₁₁ and X₁₂ are independently C(R₁₆) or N.

R₁₆, R₁₇, and R₁₈ are independently a hydrogen atom or a substituent R.

The substituent R is as defined in the formula (301).

When two or more R₁₆'s are present, the two or more R₁₆'s may be the same as or different from each other.

In one embodiment, the compound α is a compound represented by the following formula (304) or (305).

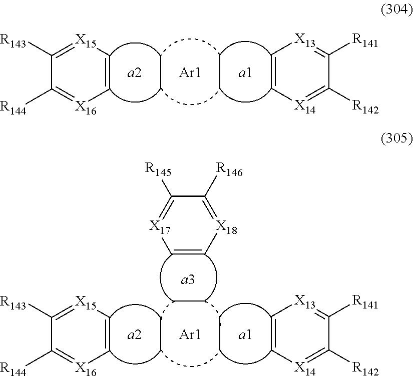

In the formulas (304) and (305),

ring Ar1 is

a substituted or unsubstituted aromatic hydrocarbon ring including 6 to 50 ring carbon atoms, or
a substituted or unsubstituted heterocycle including 5 to 50 ring atoms.

Rings a1, a2, and a3 are independently a ring structure represented by the formula (301).

X₁₃ to X₁₈ are independently C(R₁₆) or N.

R₁₄₁ to R₁₄₆ and R₁₆ are independently a hydrogen atom or a substituent R.

The substituent R is as defined in the formula (301).

When two or more R₁₆'s are present, the two or more R₁₆'s may be the same as or different from each other.

In one embodiment, the compound α is a compound represented by the following formula (304A) or (305A).

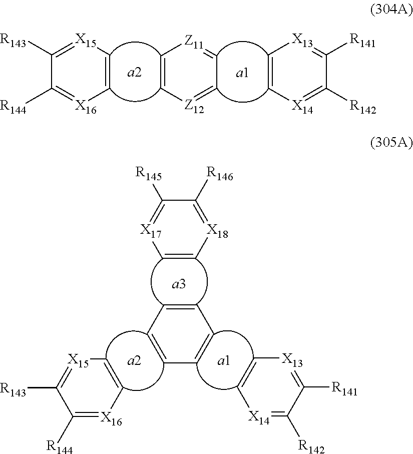

In the formulas (304A) and (305A),

rings a1, a2, and a3 are independently a ring structure represented by the formula (301).

X₁₃ to X₁₈ are independently C(R₁₆) or N.

R₁₄₁ to R₁₄₆ and R₁₆ are independently a hydrogen atom or a substituent R.

The substituent R is as defined in the formula (301).

When two or more R₁₆'s are present, the two or more R₁₆'s may be the same as or different from each other.

In the formula (304A),

Z₁₁ and Z₁₂ are independently CH or N.

In one embodiment, the second ring structure represented by the formula (302) is a ring structure represented by the following formula (321) or (322).

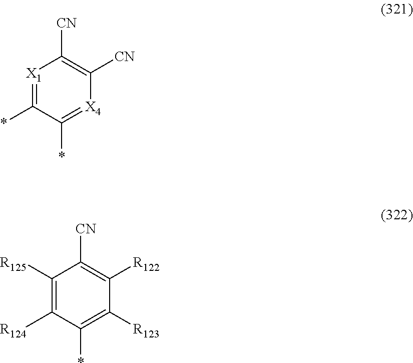

In the formulas (321) and (322),

X₁ and X₄ are independently N or C(R₁₂₁).

R₁₂₁ and R₁₂₂ to R₁₂₅ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

When two or more R₁₂₁'s are present, the two or more R₁₂₁'s may be the same as or different from each other.

*′s are independently a position which bonds with another atom in the molecule of the compound α.

In one embodiment, the compound α is a compound represented by the following formula (321A).

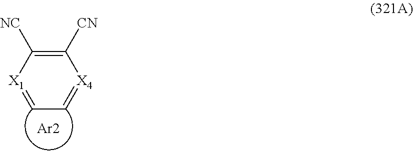

In the formula (321A),

ring Ar2 is

a substituted or unsubstituted aromatic hydrocarbon ring including 6 to 50 ring carbon atoms, or
a substituted or unsubstituted heterocycle including 5 to 50 ring atoms.

X₁ and X₄ are independently N or C(R₁₂₁).

R₁₂₁ is

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

When two or more R₁₂₁'s are present, the two or more R₁₂₁'s may be the same as or different from each other.

In one embodiment, the compound α is a compound represented by the following formula (321B).

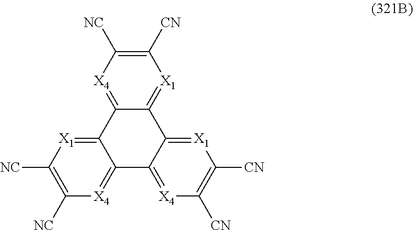

In the formula (321B),

X₁ and X₄ are independently N or C(R₁₂₁).

R₁₂₁ is

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

A plurality of each of X₁ and X₄ may be the same as or different from each other.

When two or more R₁₂₁'s are present, the two or more R₁₂₁'s may be the same as or different from each other.

In one embodiment, the second ring structure represented by the formula (302) is a ring structure represented by the following formula (322B).

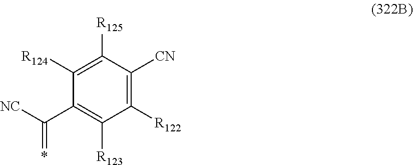

In the formula (322B),

R₁₂₂ to R₁₂₅ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

* indicates a position which bonds with another atom in the molecule of the compound α.

In one embodiment, the compound α is a compound represented by the following formula (322C).

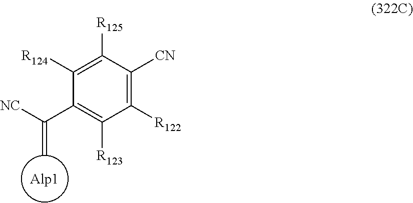

In the formula (322C),

R₁₂₂ to R₁₂₅ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

Ring Alp1 is a substituted or unsubstituted aliphatic ring including 3 to 6 ring carbon atoms.

In one embodiment, the compound α is a compound represented by the following formula (322D).

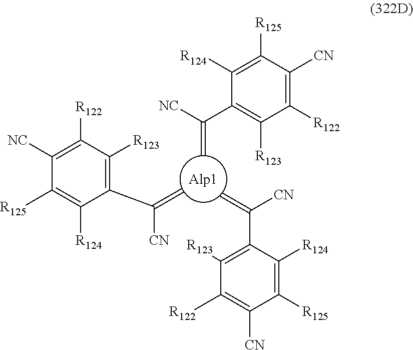

In the formula (322D),

R₁₂₂ to R₁₂₅ are independently

a hydrogen atom,
a substituted or unsubstituted alkyl group including 1 to 50 carbon atoms,
a substituted or unsubstituted alkenyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms,
a substituted or unsubstituted monovalent heterocyclic group including 5 to 50 ring atoms,
a carboxy group,
a substituted or unsubstituted ester group,
a substituted or unsubstituted carbamoyl group, or
a substituted or unsubstituted siloxanyl group.

R₉₀₁ to R₉₀₇ are as defined in the formula (11).

A plurality of each of R₁₂₂ to R₁₂₅ may be the same as or different from each other.

Ring Alp1 is a substituted or unsubstituted aliphatic ring including 3 to 6 ring carbon atoms.

In one embodiment, the compound α is a compound represented by the following formula (322E).

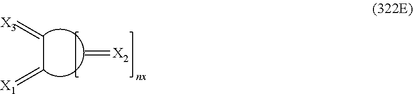

In the formula (322E),

nx is 1, 2, 3, or 4.

Structures represented by each of ═X₁, ═X₂, and ═X₃ are independently a structure represented by the following formula (E1), (E2), (E3), or (E4).

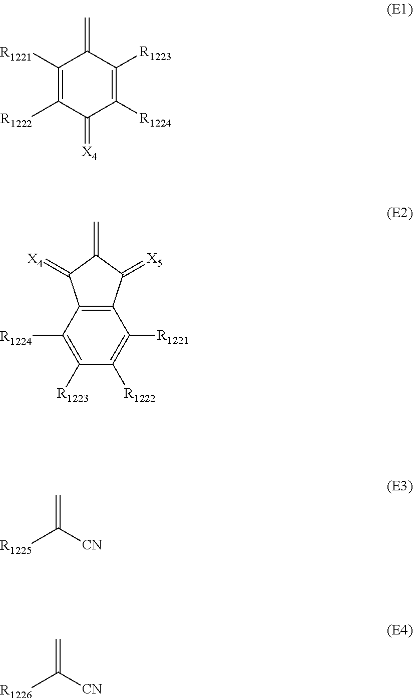

In the formulas (E1), (E2), (E3), and (E4),

═X₄ and ═X₅ are independently

### oxo (═O), or

dicyanometylidene (═C(CN)₂).

R₁₂₂₅ is a substituted or unsubstituted aryl group including 6 to 50 ring carbon atoms.

R₁₂₂₆ is a substituted or unsubstituted monovalent heterocyclic group including 5 to 50 ring atoms.

R₁₂₂₁ to R₁₂₂₄ are independently

a hydrogen atom,
a halogen atom,
a cyano group,
a substituted or unsubstituted alkyl group including 1 to 50 carbon atoms,
a substituted or unsubstituted aryl group including 6 to 50 ring carbon atoms, or
a substituted or unsubstituted monovalent heterocyclic group including 5 to 50 ring atoms.

When nx is 1, the formula (322E) is represented by the following formula (3221E); when nx is 2, the formula (322E) is represented by the following formula (3222E); when nx is 3, the formula (322E) is represented by the following formula (3223E); and when nx is 4, the formula (322E) is represented by the following formula (3224E).

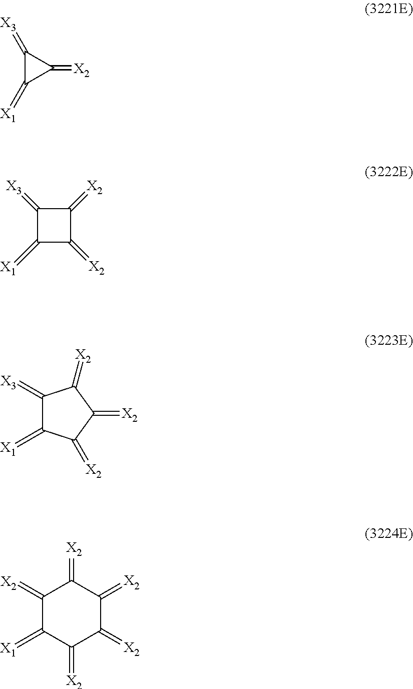

In the formulas (3221E), (3222E), (3223E), and (3224E),

structures represented by each of =X₁, ═X₂, and ═X₃ are independently a structure represented by the formula (E1), the formula (E2), the formula (E3), or the formula (E4).

A plurality of X₂'s may be the same as or different from each other.

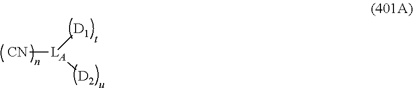

In the formula (401A),

n is an integer of 1 or more, t is an integer of 1 or more, and u is an integer of 0 or more.

L_{A} is

a substituted or unsubstituted aromatic hydrocarbon ring including 6 to 30 ring carbon atoms, or
a substituted or unsubstituted aromatic heterocycle including 6 to 30 ring atoms.

CN is a cyano group.

D₁ and D₂ are independently a group represented by the following formula (401Y).

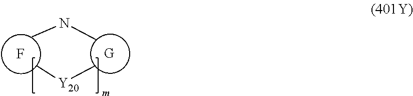

In the formula (401Y),

the nitrogen atom is bonded with L_{A} in the formula (401A).

F and G are independently represents a ring structure.

The ring structure F and the ring structure G may be unsubstituted or may have a substituent; m is 0 or 1; when m is 1, Y₂₀ represents a single bond, an oxygen atom, a sulfur atom, a selenium atom, a carbonyl group, CR₂₁R₂₂, SiR₂₃R₂₄, or GeR₂₅R₂₆; and R₂₁ to R₂₆ are substituents R.

When m is 1, the formula (401Y) is represented by any one of the formulas (422) to (428) described below and the following formulas (421Y) to (424Y).

D₁ and D₂ may be the same as or different from each other.

When t is 2 or more, a plurality of D₁'s may be the same as or different from each other.

When u is 2 or more, a plurality of D₂ may be the same as or different from each other.

The substituent R is as defined in the formula (301).

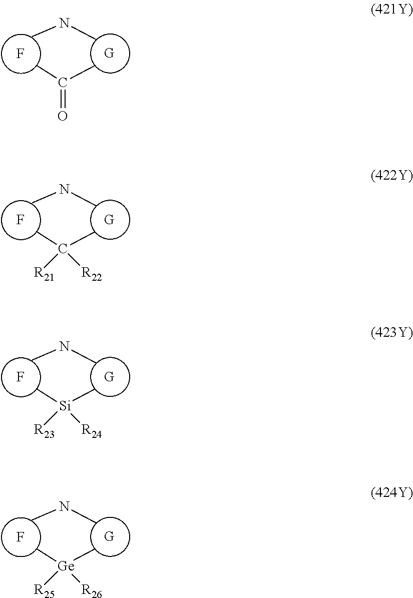

In the formulas (421Y) to (424Y),

the nitrogen atom is bonded with L_{A} in the formula (401A).

R₂₁ to R₂₆ are independently a hydrogen atom or a substituent R.

The substituent R is as defined in the formula (301).

In one embodiment, L_{A} is preferably a substituted or unsubstituted aromatic hydrocarbon ring including 6 to 14 ring carbon atoms. Examples of the aromatic hydrocarbon ring including 6 to 14 ring carbon atoms include benzene, naphthalene, fluorene, phenanthrene, and the like. L_{A} is more preferably an aromatic hydrocarbon ring including 6 to 10 ring carbon atoms.

Also, examples of the aromatic heterocycle including 6 to 30 ring atoms for L_{A} include pyridine, pyrimidine, pyrazine, quinoline, quinazoline, phenanthroline, benzofuran, dibenzofuran, and the like.

When m is 0 in the formula (401Y), the formula (401Y) is represented by the following formula (420Y).

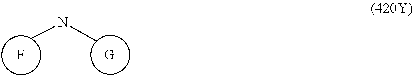

In the formula (420Y),

the nitrogen atom is bonded with L_{A} in the formula (401A).

Ring structures F and G are the same as the ring structures F and G in the formula (401Y), respectively.

In the formula (401Y), when m is 1, the formula (401Y) is represented by any one of the following formulas (422) to (428).

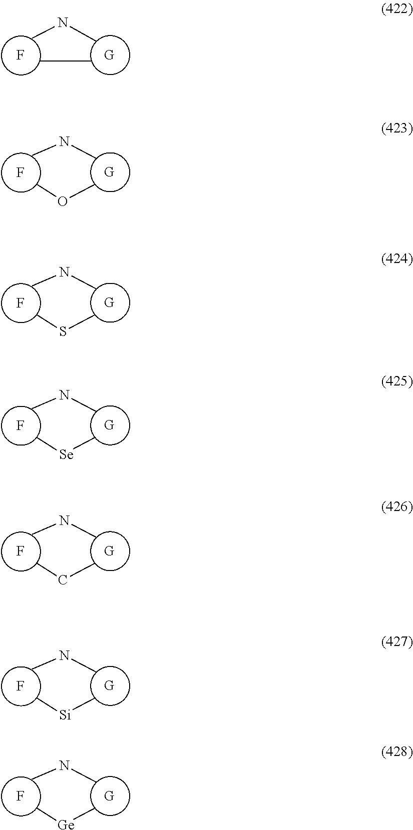

In the formulas (422) to (428),

the nitrogen atom is bonded with L_{A} in the formula (401A).

Ring structures F and G are the same as the ring structures F and G in the formula (401Y), respectively.

In one embodiment, the ring structure F and the ring structure G are preferably a five-membered ring or a six-membered ring, and the five-membered ring or the six-membered ring is preferably an unsaturated ring, and more preferably an unsaturated six-membered ring.

In one embodiment, it is preferable that the formula (401Y) be represented by at least one of the following formula (401a) and the following formula (401x).

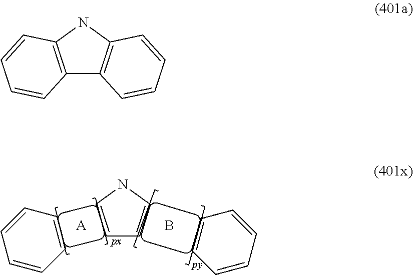

The benzene rings in the formulas (401a) and (401x) may be substituted by a substituent R. The substituent R is as defined in the formula (301).

In the formula (401a), the nitrogen atom is bonded with L_{A} in the formula (401A).

In the formula (401x),

the nitrogen atom is bonded with L_{A} in the formula (401A).

Rings A and B are independently

a ring structure represented by the following formula (401c), or
a ring structure represented by the following formula (401d).

The ring structure A and the ring structure B are fused with adjacent ring structures at respective arbitrary positions.

px and py are independently an integer of 0 or more and 4 or less, and represent the number of the ring structure A and the ring structure B, respectively.

When px is an integer of 2 or more and 4 or less, a plurality of the ring structures A may be the same as or different from each other.

When py is an integer of 2 or more and 4 or less, a plurality of the ring structures B may be the same as or different from each other.

Therefore, for example, when px is 2, the ring structure A may be composed of two ring structures represented by the following formula (401c), or may be composed of two ring structures represented by the following formula (401d), or may be composed of one ring structure represented by the following formula (401c) and one ring structure represented by the following formula (401d) in combination.

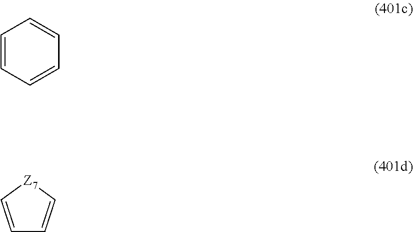

The carbon atoms in the formulas (401c) and (401d) may be substituted by a substituent R. The substituent R is as defined in the formula (301). In the formula (401d), Z₇ represents a carbon atom, a nitrogen atom, a sulfur atom, or an oxygen atom.

In the formula (401x), when px is 0 and py is c, the formula (401x) is represented by the following formula (401b).

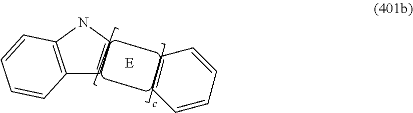 [SMILES: c1ccc2[nH]ccc2c1 ; c1ccccc1]

In the formula (401b),

the nitrogen atom is bonded with L_{A} in the formula (401A).

The benzene ring may be substituted by a substituent R. The substituent R is as defined in the formula (301).

c is an integer of 1 or more and 4 or less.

When c is an integer of 2 or more and 4 or less, a plurality of ring structures E may be the same as or different each other.

The ring structure E is a ring structure represented by the formula (401c) or a ring structure represented by the formula (401d), and the ring structure E is fused with adjacent ring structures at respective arbitrary positions.

Therefore, for example, when c is 2, the two ring structures E may be composed of two ring structures represented by the formula (401c), or may be composed of two ring structures represented by the formula (401d), or may be composed of one ring structure represented by the formula (401c) and one ring structure represented by the formula (401d) in combination.

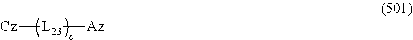

In the formula (501),

Az is a ring structure selected from the group consisting of

a substituted or unsubstituted pyridine ring,
a substituted or unsubstituted pyrimidine ring,
a substituted or unsubstituted triazine ring, and
a substituted or unsubstituted pyrazine ring.

c is 0, 1, 2, 3, 4, or 5.

When c is 0, Cz and Az are bonded via a single bond.

When c is 1, 2, 3, 4, or 5, L₂₃ is a linking group selected from the group consisting of

a substituted or unsubstituted arylene group including 6 to 30 ring carbon atoms, and
a substituted or unsubstituted heteroarylene group including 5 to 30 ring atoms.

When c is 2, 3, 4, or 5, a plurality of L₂₃'s form a ring by bonding with each other, or do not form a ring.

A plurality of L₂₃'s that do not form the ring may be the same as or different from each other.

Cz is a group represented by the following formula (501a).

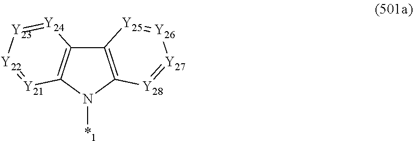

In the formula (501a),

Y₂₁ to Y₂₈ are independently N or C(R_{A3}).

When a plurality of Ray's are present, one or more sets of adjacent two or more Ray's form a ring by bonding with each other, or do not form a ring.

R_{A3}'s that do not form the ring are independently a group selected from the group consisting of

a hydrogen atom,
a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group,
a substituted silyl group,
a cyano group,
a nitro group, and
a carboxy group.

A plurality of R_{A3}'s may be the same as or different from each other.

*1 is a single bond which bonds with a carbon atom in a structure of a linking group represented by L₂₃, or a single bond which bonds with a carbon atom in a ring structure represented by Az.

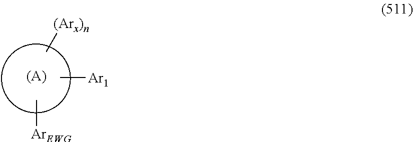

In the formula (511),

Ar₁ is a group selected from the group consisting of

a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group,
a substituted silyl group,
a cyano group,
a nitro group,
a carboxy group, and
groups represented by each of the following formulas (511a) to (511j).

Ar_{EWG} is

a substituted or unsubstituted heteroaryl group including 5 to 30 ring atoms containing one or more nitrogen atoms in the ring, or
an aryl group including 6 to 30 ring carbon atoms substituted with one or more cyano groups.

Ar_{X}'s are independently a group selected from the group consisting of

a hydrogen atom,
a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group,
a substituted silyl group,
a cyano group,
a nitro group,
a carboxy group, and
groups represented by each of the following formulas (511a) to (511j).

n is 0, 1, 2, 3, 4, or 5.

When n is 2, 3, 4, or 5, a plurality of Ar_{X}'s may be the same as or different from each other.

In the formula (511), ring (A) is a substituted or unsubstituted aromatic hydrocarbon ring or a substituted or unsubstituted five-membered, six-membered or seven-membered heterocycle. The ring (A) may be an aromatic hydrocarbon ring or a heterocycle. Ar₁ and Ar_{X} are bonded with elements which constitute the ring (A), respectively.

In the formula (511), at least one of Ar₁ and Ar_{X} is a group selected from the group consisting of groups represented by each of the following formulas (511a) to (511j).

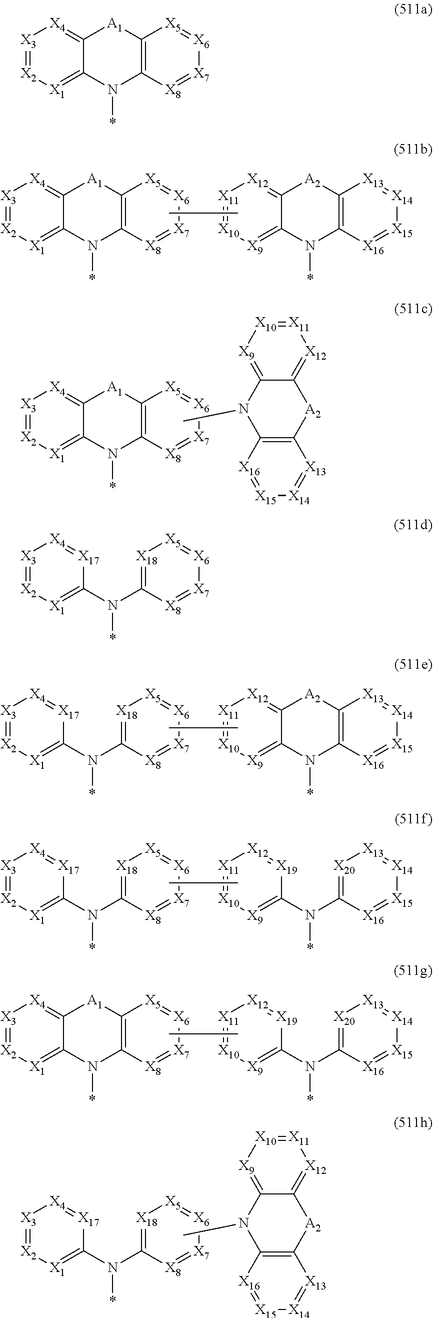

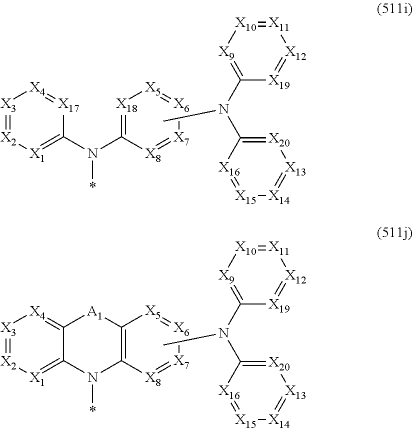

In the formulas (511a) to (511j), X₁ to X₂₀ are independently N or C(R_{A1}).

In the formula (511b), one of X₅ to X₈ is a carbon atom which bonds with one of X₉ to X₁₂, and one of X₉ to X₁₂ is a carbon atom which bonds with one of X₅ to X₈.

In the formula (511c), one of X₅ to X₈ is a carbon atom which bonds with the nitrogen atom in the ring containing A2.

In the formula (511e), one of X₅ to X₈ and X₁₈ is a carbon atom which bonds with one of X₉ to X₁₂, and one of X₉ to X₁₂ is a carbon atom which bonds with one of X₅ to X₈ and X₁₈.

In the formula (511f), one of X₅ to X₈ and X₁₈ is a carbon atom which bonds with one of X₉ to X₁₂ and X₁₈, and one of X₉ to X₁₂ and X₁₈ is a carbon atom which bonds with one of X₅ to X₈ and X₁₈.

In the formula (511g), one of X₅ to X₈ is a carbon atom which bonds with one of X₉ to X₁₂ and X₁₈, and one of X₉ to X₁₂ and X₁₈ is a carbon atom which bonds with one of X₅ to X₈.

In the formula (511h), one of X₅ to X₈ and X₁₈ is a carbon atom which bonds with the nitrogen atom in the ring containing A₂.

In the formula (511i), one of X₅ to X₈ and X₁₈ is a carbon atom which bonds with the nitrogen atom which links the ring composed of X₉ to X₁₂ and X₁₈ and the ring composed of X₁₃ to X₁₈ and X₂₀.

In the formula (511j), one of X₅ to X₈ is a carbon atom which bonds with the nitrogen atom linking the ring composed of X₉ to X₁₂ and X₁₈ and the ring composed of X₁₃ to X₁₈ and X₂₀.

When a plurality of R_{A1}'s are present, one or more sets of adjacent two or more R_{A1}'s form a ring by directly bonding with each other, or form a ring via a hetero atom.

R_{A1}'s that do not form the ring are independently a hydrogen atom, or a group selected from the group consisting of

a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group,
a substituted silyl group,
a cyano group,
a nitro group, and
a carboxy group.

A plurality of R_{A1}'s may be the same as or different from each other.

In the formula (511a), when X₁ to X₈ are C(R_{A1})'s, it is preferable that the plurality of R_{A1}'s do not form the ring.

In the formulas (511a) to (511j), * represents a single bond which bonds with the ring (A).

In the formulas (511a) to (511j), A₁ and A₂ are independently a single bond, an oxygen atom (O), a sulfur atom (S), C(R₂₀₂₁)(R₂₀₂₂), Si(R₂₀₂₃)(R₂₀₂₄), C(═O), S(═O), SO₂, or N(R₂₀₂₅).

R₂₀₂₁ to R₂₀₂₅ are independently a hydrogen atom, or a group selected from the group consisting of

a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group,
a substituted silyl group,
a cyano group,
a nitro group, and
a carboxy group.

In the formulas (511a) to (511j),

Ara is a group selected from the group consisting of

a substituted or unsubstituted aryl group including 6 to 30 ring carbon atoms,
a substituted or unsubstituted heteroaryl group including 5 to 30 ring atoms,
a substituted or unsubstituted alkyl group including 1 to 30 carbon atoms,
a substituted or unsubstituted fluoroalkyl group including 1 to 30 carbon atoms,
a substituted or unsubstituted cycloalkyl group including 3 to 30 ring carbon atoms,
a substituted or unsubstituted aralkyl group including 7 to 30 carbon atoms,
a substituted phosphoryl group, and
a substituted silyl group,

Ara is preferably

a substituted or unsubstituted aryl group including 6 to 30 ring carbon atoms, or
a substituted or unsubstituted heteroaryl group including 5 to 30 ring atoms.

When A₁ is a single bond, the formula (511a) is represented by the following formula (511aa), when A₁ is O, the formula (511a) is represented by the following formula (511ab); when A₁ is S, the formula (511a) is represented by the following formula (511ac); when A₁ is C(R₂₀₂₁)(R₂₀₂₂), the formula (511a) is represented by the following formula (511ad); when A₁ is Si(R₂₀₂₃)(R₂₀₂₄), the formula (511a) is represented by the following formula (511ae); when A₁ is C(═O), the formula (511a) is represented by the following formula (511af); when A₁ is S(═O), the formula (511a) is represented by the following formula (511ag); when A₁ is SO₂, the formula (511a) is represented by the following formula (511ah); and when A₁ is N(R₂₀₂₅), the formula (511a) is represented by the following formula (511ai). In the following formulas (511aa) to (511ai), X₁ to X₈ and R₂₀₂₁ to R₂₀₂₅ are as defined above. The linking mode between the rings by each of A₁ and A₂ in the formulas (511b), (511c), (511e), and (511g) to (511j) are also the same as that in the following formulas (511aa) to (511ai). In the following formula (511aa), when X₁ to X₈ are C(R_{A1})'s, it is preferable that a plurality of R_{A1}'s do not form the ring.

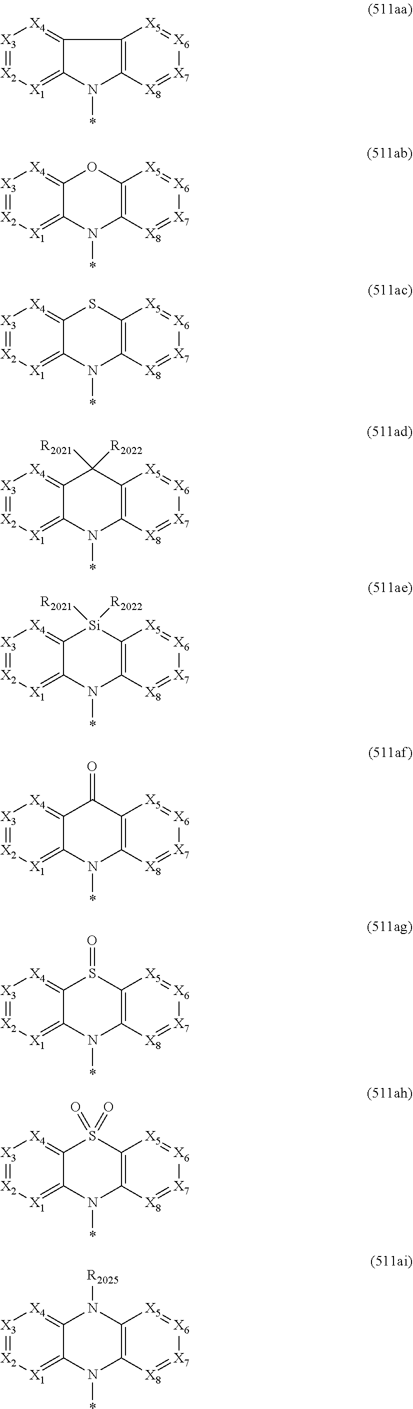

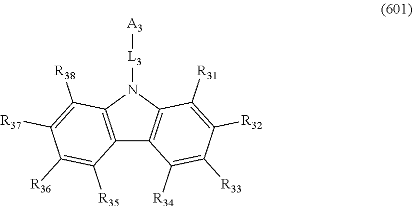

In the formula (601),

A₃ is

a substituted or unsubstituted aryl group including 6 to 50 ring carbon atoms, or
a substituted or unsubstituted monovalent heterocyclic group including 5 to 50 ring atoms.

L₃ is

a single bond,
a substituted or unsubstituted arylene group including 6 to 50 ring carbon atoms,
a substituted or unsubstituted divalent heterocyclic group including 5 to 50 ring atoms,
a divalent group formed by bonding two groups selected from the group consisting of a substituted or
unsubstituted arylene group including 6 to 50 ring carbon atoms and a substituted or unsubstituted divalent heterocyclic group including 5 to 50 ring atoms, or
a divalent group formed by bonding three groups selected from the group consisting of a substituted or unsubstituted arylene group including 6 to 30 ring carbon atoms and a substituted or unsubstituted divalent heterocyclic group including 5 to 30 ring atoms.

One or more sets of adjacent two or more of R₃₁ to R₃₈

form a substituted or unsubstituted monocyclic ring by bonding with each other,
form a substituted or unsubstituted fused ring by bonding with each other, or
do not bond with each other.

R₃₁ to R₃₃ that do not form the substituted or unsubstituted monocyclic ring and do not form the substituted or unsubstituted fused ring are independently

a hydrogen atom,
a substituted or unsubstituted alkyl group including 1 to 50 carbon atoms,
a substituted or unsubstituted haloalkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a group represented by —Si(R₉₀₁)(R₉₀₂)(R₉₀₃),
a group represented by —O—(R₉₀₄),
a group represented by —S—(R₉₀₅),
a group represented by —N(R₉₀₆)(R₉₀₇),
a substituted or unsubstituted aralkyl group including 7 to 50 carbon atoms,
a group represented by —C(═O)R₉₀₈,
a group represented by —COOR₉₀₉,
a halogen atom,
a cyano group,
a nitro group,
a group represented by —P(═O)(R₉₃₁)(R₉₃₂),
a group represented by —Ge(R₉₃₃)(R₉₃₄)(R₉₃₅),
a group represented by —B(R₉₃₆)(R₉₃₇),
a substituted or unsubstituted aryl group including 6 to 50 ring carbon atoms,
a substituted or unsubstituted heterocyclic group including 5 to 50 ring atoms, or
a group represented by the following formula (601A).

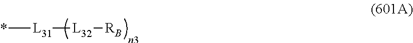

In the formula (601A),

R_{B} is

a substituted or unsubstituted alkyl group including 1 to 50 carbon atoms,
a substituted or unsubstituted haloalkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a group represented by —Si(R₉₀₁)(R₉₀₂)(R₉₀₃),
a group represented by —O—(R₉₀₄),
a group represented by —S—(R₉₀₅),
a group represented by —N(R₉₀₆)(R₉₀₇),
a substituted or unsubstituted aralkyl group including 7 to 50 carbon atoms,
a group represented by —C(═O)R₉₀₈,
a group represented by —COOR₉₀₉,
a halogen atom,
a cyano group,
a nitro group,
a group represented by —P(═O)(R₉₃₁)(R₉₃₂),
a group represented by —Ge(R₉₃₃)(R₉₃₄)(R₉₃₅),
a group represented by —B(R₉₃₆)(R₉₃₇),
a substituted or unsubstituted aryl group including 6 to 50 ring carbon atoms, or
a substituted or unsubstituted heterocyclic group including 5 to 50 ring atoms.

When a plurality of R_{B}'s are present, the plurality of R_{B}'s may be the same as or different from each other.

L₃₁ is

a single bond,
a substituted or unsubstituted arylene group including 6 to 50 ring carbon atoms,
a trivalent group, a tetravalent group, a pentavalent group, or a hexavalent group derived from the arylene group,
a substituted or unsubstituted divalent heterocyclic group including 5 to 50 ring atoms,
a trivalent group, a tetravalent group, a pentavalent group, or a hexavalent group derived from the heterocyclic group,
a divalent group formed by bonding two groups selected from the group consisting of a substituted or unsubstituted arylene group including 6 to 50 ring carbon atoms and a substituted or unsubstituted divalent heterocyclic group including 5 to 50 ring atoms, or
a trivalent group, a tetravalent group, a pentavalent group, or a hexavalent group derived from the divalent group.

L₃₂ is

a single bond,
a substituted or unsubstituted arylene group including 6 to 50 ring carbon atoms, or
a substituted or unsubstituted divalent heterocyclic group including 5 to 50 ring atoms.

n3 is 1, 2, 3, 4, or 5.

When L₃₁ is a single bond, n3 is 1, and L₃₂ is bonded with a carbon atom constituting the six-member ring in the formula (601).

When a plurality of L₃₂'s are present, the plurality of L₃₂'s may be the same as or different from each other.

* represents a single bond which bonds with a carbon atom constituting the six-membered ring in the formula (601).

In the formulas (601) and (601A), R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted heterocyclic group including 5 to 50 ring atoms.

When a plurality of R₉₀₁'s are present, the plurality of R₉₀₁'s may be the same as or different from each other. When a plurality of R₉₀₂'s are present, the plurality of R₉₀₂'s may be the same as or different from each other. When a plurality of R₉₀₃'s are present, the plurality of R₉₀₃'s may be the same as or different from each other. When a plurality of R₉₀₄'s are present, the plurality of R₉₀₄'s may be the same as or different from each other. When a plurality of R₉₀₅'s are present, the plurality of R₉₀₅'s may be the same as or different from each other. When a plurality of R₉₀₆'s are present, the plurality of R₉₀₆'s may be the same as or different from each other. When a plurality of R₉₀₇'s are present, the plurality of R₉₀₇'s may be the same as or different from each other. When a plurality of R₉₀₈'s are present, the plurality of R₉₀₈'s may be the same as or different from each other. When a plurality of R₉₀₉'s are present, the plurality of R₉₀₉'s may be the same as or different from each other. When a plurality of R₉₃₁'s are present, the plurality of R₉₃₁'s may be the same as or different from each other. When a plurality of R₉₃₂'s are present, the plurality of R₉₃₂'s may be the same as or different from each other. When a plurality of R₉₃₃'s are present, the plurality of R₉₃₃'s may be the same as or different from each other. When a plurality of R₉₃₄'s are present, the plurality of R₉₃₄'s may be the same as or different from each other. When a plurality of R₉₃₅'s are present, the plurality of R₉₃₅'s may be the same as or different from each other. When a plurality of R₉₃₆'s are present, the plurality of R₉₃₆'s may be the same as or different from each other. When a plurality of R₉₃₇'s are present, the plurality of R₉₃₇'s may be the same as or different from each other.

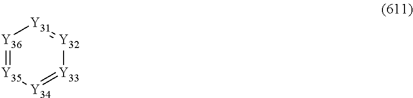

In the formula (611),

Y₃₁ to Y₃₆ are independently CR₃ or a nitrogen atom.

Provided that one or more of Y₃₁ to Y₃₆ are nitrogen atoms.

When a plurality of R₃'s are present, one or more sets of adjacent two or more R₃'s form a substituted or unsubstituted monocyclic ring by bonding with each other,

form a substituted or unsubstituted fused ring by bonding with each other, or
do not bond with each other.

R₃'s that do not form the substituted or unsubstituted monocyclic ring and do not form the substituted or unsubstituted fused ring are independently

a hydrogen atom,
a substituted or unsubstituted alkyl group including 1 to 50 carbon atoms,
a substituted or unsubstituted haloalkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a group represented by —Si(R₉₀₁)(R₉₀₂)(R₉₀₃),
a group represented by —O—(R₉₀₄),
a group represented by —S—(R₉₀₅),
a group represented by —N(R₉₀₆)(R₉₀₇),
a substituted or unsubstituted aralkyl group including 7 to 50 carbon atoms,
a group represented by —C(═O)R₉₀₈,
a group represented by —COOR₉₀₉,
a halogen atom,
a cyano group,
a nitro group,
a group represented by —P(═O)(R₉₃₁)(R₉₃₂),
a group represented by —Ge(R₉₃₃)(R₉₃₄)(R₉₃₅),
a group represented by —B(R₉₃₆)(R₉₃₇),
a substituted or unsubstituted aryl group including 6 to 50 ring carbon atoms,
a substituted or unsubstituted heterocyclic group including 5 to 50 ring atoms, or
a group represented by the following formula (611A).

R₉₀₁ to R₉₀₇ are as defined in the formula (11).

R₉₀₈, R₉₀₉, and R₉₃₁ to R₉₃₇ are as defined in the formula (601).

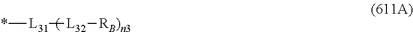

In the formula (611A),

R_{B} is

a substituted or unsubstituted alkyl group including 1 to 50 carbon atoms,
a substituted or unsubstituted haloalkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
a group represented by —Si(R₉₀₁)(R₉₀₂)(R₉₀₃),
a group represented by —O—(R₉₀₄),
a group represented by —S—(R₉₀₅),
a group represented by —N(R₉₀₆)(R₉₀₇),
a substituted or unsubstituted aralkyl group including 7 to 50 carbon atoms,
a group represented by —C(═O)R₉₀₈,
a group represented by —COOR₉₀₉,
a halogen atom,
a cyano group,
a nitro group,
a group represented by —P(═O)(R₉₃₁)(R₉₃₂),
a group represented by —Ge(R₉₃₃)(R₉₃₄)(R₉₃₅),
a group represented by —B(R₉₃₆)(R₉₃₇),
a substituted or unsubstituted aryl group including 6 to 50 ring carbon atoms, or
a substituted or unsubstituted heterocyclic group including 5 to 50 ring atoms.

When a plurality of R_{B}'s are present, the plurality of R_{B}'s may be the same as or different from each other.

R₉₀₁ to R₉₀₇ are as defined in the formula (11).

R₀₀₈, R₉₀₉, and R₉₃₁ to R₉₃₇ are as defined in the formula (601).

L₃₁ is

a single bond,
a substituted or unsubstituted arylene group including 6 to 50 ring carbon atoms, or a trivalent group, a tetravalent group, a pentavalent group, or a hexavalent group derived from the arylene group,
a substituted or unsubstituted divalent heterocyclic group including 5 to 50 ring atoms,
a trivalent group, a tetravalent group, a pentavalent group, or a hexavalent group derived from the heterocyclic group,
a divalent group formed by bonding two groups selected from the group consisting of a substituted or unsubstituted arylene group including 6 to 50 ring carbon atoms and a substituted or unsubstituted divalent heterocyclic group including 5 to 50 ring atoms, or
a trivalent group, a tetravalent group, a pentavalent group, or a hexavalent group derived from the divalent group.

L₃₂ is

a single bond,
a substituted or unsubstituted arylene group including 6 to 50 ring carbon atoms, or
a substituted or unsubstituted divalent heterocyclic group including 5 to 50 ring atoms.

n 3 is 1, 2, 3, 4, or 5.

When L₃₁ is a single bond, n3 is 1 and L₃₂ is bonded with a carbon atom constituting the six-member ring in the formula (611).

When a plurality of L₃₂'s are present, the plurality of L₃₂'s may be the same as or different from each other.

* represents a single bond which bonds with a carbon atom constituting the six-membered ring in the formula (611).

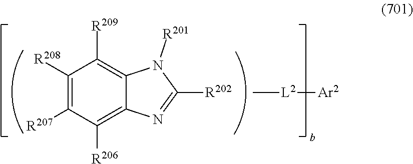

In the formula (701),

b is an integer of 1 to 3.

One of R²⁰¹, R²⁰², and R²⁰⁶ to R²⁰⁹ is a single bond which bonds with L².

One or more sets of adjacent two or more of R²⁰¹, R₂₀₂, and R²⁰⁶ to R²⁰⁹ that are not a single bond which bonds with L² form a substituted or unsubstituted, saturated or unsaturated ring by bonding with each other, or do not form a substituted or unsubstituted, saturated or unsaturated ring.

R²⁰¹, R²⁰², and R²⁰⁶ to R²⁰⁹ that are not a single bond which bonds with L² and do not form the substituted or unsubstituted, saturated or unsaturated ring are independently a hydrogen atom or a substituent R.

When b is 1, L² is

a single bond,
a substituted or unsubstituted linear, branched, or cyclic divalent aliphatic hydrocarbon group including 1 to 30 carbon atoms,
a substituted or unsubstituted divalent aromatic hydrocarbon ring group including 6 to 40 ring carbon atoms,
a substituted or unsubstituted divalent heterocyclic group including 5 to 40 ring atoms,
a divalent multiple linking group formed by bonding two to three groups selected from the aromatic hydrocarbon ring group,
a divalent multiple linking group formed by bonding two to three groups selected from the heterocyclic group, or
a divalent multiple linking group formed by bonding two to three groups selected from the aromatic hydrocarbon ring group and the aromatic hydrocarbon ring group.

When b is 2 or 3, L² is

a substituted or unsubstituted linear, branched, or cyclic aliphatic hydrocarbon group including 1 to 30 carbon atoms,
a substituted or unsubstituted aromatic hydrocarbon ring group including 6 to 40 ring carbon atoms,
a substituted or unsubstituted heterocyclic group including 5 to 40 ring atoms,
a multiple linking group formed by bonding two to three groups selected from the aromatic hydrocarbon ring group,
a multiple linking group formed by bonding two to three groups selected from the heterocyclic group, or
a multiple linking group formed by bonding two to three groups selected from the aromatic hydrocarbon ring group and the aromatic hydrocarbon ring group.

Each of the aromatic hydrocarbon ring group and the heterocyclic group constituting the multiple linking group may be the same as or different from each other.

One or more sets of adjacent two or more of the aromatic hydrocarbon ring group and the heterocyclic group constituting the multiple linking group form a substituted or unsubstituted, saturated or unsaturated ring by bonding with each other, or do not form a substituted or unsubstituted, saturated or unsaturated ring.

Ar² is

a substituted or unsubstituted aromatic hydrocarbon group including 6 to 40 ring carbon atoms, or
a substituted or unsubstituted heterocyclic group including 5 to 40 ring atoms.

Ar² and L² form a substituted or unsubstituted, saturated or unsaturated ring by bonding with each other, or do not form a substituted or unsubstituted, saturated or unsaturated ring.

The substituent R is as defined in the formula (301).

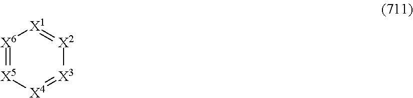

In the formula (711),

X¹ is a nitrogen atom or CR¹.

X² is a nitrogen atom or CR².

X³ is a nitrogen atom or CR³.

X⁴ is a nitrogen atom or CR⁴.

X⁵ is a nitrogen atom or CR⁵.

X⁶ is a nitrogen atom or CR⁶.

Provided that at least one of X¹ to X⁶ is a nitrogen atom.

One to three of R¹ to R⁶ are independently a group represented by any of the following formulas (712) to (715).

R¹ to R⁶ that are not the group represented by any of the following formulas (712) to (715) are independently a hydrogen atom or a substituent R.

One or more sets of adjacent two or more of R¹ to R⁶ form

a substituted or unsubstituted fused aromatic hydrocarbon ring including 10 to 30 ring carbon atoms,
a substituted or unsubstituted non-fused aromatic hydrocarbon ring,
a substituted or unsubstituted fused aromatic heterocycle including 9 to 30 ring atoms, or
a substituted or unsubstituted non-fused aromatic heterocycle including 5 or 6 ring atoms by bonding with each other, or do not form the ring.

The substituent R is as defined in the formula (301).

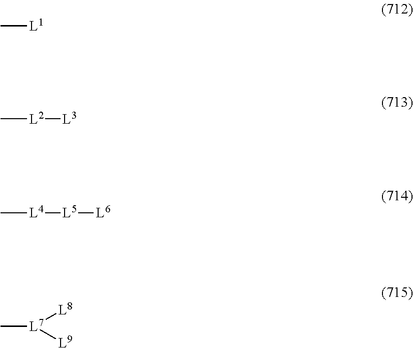

In the formulas (712) to (715),

L¹, L³, L⁶, L⁸, and L⁹ are independently

a substituted or unsubstituted fused aryl group including 10 to 30 ring carbon atoms,
a substituted or unsubstituted non-fused aryl group including 6 to 30 ring carbon atoms,
a substituted or unsubstituted fused heteroaryl group including 9 to 32 ring atoms, or
a substituted or unsubstituted non-fused heteroaryl group including 5 to 30 ring atoms.

L², L⁴, and L⁵ are independently

a substituted or unsubstituted fused arylene group including 10 to 30 ring carbon atoms,
a substituted or unsubstituted non-fused arylene group including 6 to 30 ring carbon atoms,
a substituted or unsubstituted fused heteroarylene group including 9 to 30 ring atoms, or
a substituted or unsubstituted non-fused heteroarylene group including 5 to 30 ring atoms.

L⁷ is

a substituted or unsubstituted fused aromatic hydrocarbon ring including 10 to 30 ring carbon atoms,
a substituted or unsubstituted non-fused aromatic hydrocarbon ring including 10 to 30 ring carbon atoms,
a substituted or unsubstituted fused aromatic heterocycle including 9 to 30 ring atoms, or
a substituted or unsubstituted trivalent non-fused aromatic heterocycle including 5 or 6 ring atoms.

A-(L)ₙ-Ar—CN (721)

In the formula (721),

A is

a substituted or unsubstituted fused aryl group including 10 to 30 ring carbon atoms,
a substituted or unsubstituted non-fused aryl group including 6 to 30 ring carbon atoms,
a substituted or unsubstituted fused heteroaryl group including 9 to 30 ring atoms, or
a substituted or unsubstituted non-fused heteroaryl group including 5 to 30 ring atoms.

L is

a substituted or unsubstituted fused arylene group including 10 to 30 ring carbon atoms,
a substituted or unsubstituted non-fused arylene group including 6 to 30 ring carbon atoms,
a substituted or unsubstituted fused heteroarylene group including 9 to 30 ring atoms, or
a substituted or unsubstituted non-fused heteroarylene group including 5 to 30 ring atoms.

n is an integer of 0 to 2.

When n is 0, L is a single bond.

When n is 2, two L's may be the same as or different from each other.

Ar is

a substituted or unsubstituted fused arylene group including 10 to 30 ring carbon atoms,
a substituted or unsubstituted non-fused arylene group including 6 to 30 ring carbon atoms,
a substituted or unsubstituted fused heteroarylene group including 9 to 30 ring atoms, or
a substituted or unsubstituted non-fused heteroarylene group including 5 to 30 ring atoms.

In one embodiment, one or more compounds selected from each of the following groups (Group 2A) to (Group 33A) may also be independently used as the first organic compound and the second organic compound. Note that the first organic compound and the second organic compound in this specification are not limited to one or more compounds independently selected from each of the following groups (Group 2A) to (Group 33A), and may not be one or more compounds independently selected from each of the following groups (Group 2A) to (Group 33A).

### (Group 2A)

bis(phenylamino)biphenyl; rubrene; bis(phenylamino)biphenyl; TBP; OP31; tris(quinolinato)aluminum; coumarin 545T

### (Group 4A)

Alq3; NPB; TBADN; DCJTP; rubrene; OP31; DPQA; DBzR

### (Group 5A)

tris(methylphenylphenylamino)triphenylamine; tetrafluorotetracyanoquinodimethane; bathophenanthroline; tris(carbazolyl)triphenylamine; factris(phenylpyridine)iridium; zinc phthalocyanine; fullerene C60

### (Group 6A)

tris(methylphenylphenylamino)triphenylamine; tetrafluorotetracyanoquinodimethane; bathophenanthroline; tris(carbazolyl)triphenylamine; factris(phenylpyridine)iridium; zinc phthalocyanine; fullerene C60

### (Group 9A)

quaternaphthalene; binaphthalenyl(naphthyl)benzene; temaphthalene; binaphthalenyl(naphthyl)benzene; binaphthalenyl(naphthyl)benzene; quaternaphthalene; quaternaphthalene; quatemaphthalene; quaternaphthalene; ternaphthaleyl(naphthyl)benzene; [bis(isopropylnaphthaleyl)]biphenyl; (ternaphthaleyl)biphenyl; ternaphthaleyl(naphthyl)benzene; temaphthaleyl(naphthyl)benzene; diphenylphenanthrene; tetraphenylphenanthrene; dimethylbis(methylphenyl)phenanthrene; bis(trifluoromethyl)bis(trifluoromethylphenyl)phenanthrene; dimethoxybis(methoxyphenyl)phenanthrene; diphenylbis(biphenylyl)phenanthrene; diphenylbis(methylphenyl)phenanthrene; dimethyl(biphenylyl)phenanthrene; methylphenylmethylphenyl(biphenylyl)phenanthrene; di(naphthyl)phenanthrene; di(pyridyl)phenanthrene; di(tert-butyldiphenylphenanthrene; distyrylphenanthrene; cyanophenanthrene; bis(diphenylvinyl)phenanthrene; binaphthalenyl(phenanthrenyl)benzene; di(phenanthrenyl)naphthalene; bis(diphenylphenanthrenyl)naphthalene; [di(phenanthrenyl)]binaphthalene; (binaphthalenyl)phenanthrene; di(phenanthrenyl)benzene; di(phenanthrenyl)naphthalene; naphthyl(phenanthrenyl)phenanthrene; naphthyl(phenanthrenyl)phenanthrene; diphenyl(naphthyl(phenanthrenyl))phenanthrene; naphthyl(phenanthrenyldiphenyl)phenanthrene; phenyl(phenanthrenyl)naphthalene; (diphenyl)[di(phenanthrenyl)]naphthalene; naphthyl(phenanthrenylphenyl)phenanthrene; [di(phenanthrenyl)]biphenyl; (naphthyl)[di(phenanthrenyl)]benzene; (naphthyl)[di(phenanthrenyl)]benzene; tris(phenanthrenyl)naphthalene; [(phenyl)naphthaleyl]phenylphenanthrene; [(phenyl)naphthaleyl](naphthyl)phenanthrene; (binaphthalenyl(naphthyl)phenanthrene; (binaphthalenyl)(phenanthrenyl)phenanthrene; [di(naphthyl)]biphenanthrene; [(naphthyl)]terphenanthrene; [(phenyl)phenanthrenyl](phenanthrenyl)benzene; (diphenylbinaphthalenyl)(naphthyl)phenanthrene; [di(naphthyl)diphenyl]biphenanthrene; [di(naphthyl)diphenyl]biphenanthrene; (binaphthalenyl)(naphthyl)phenanthrene; [(naphthyl)phenyl](naphthyl)phenanthrene; [(binaphthalenyl)(phenanthrenyl)biphenyl; [(phenanthrenyl)phenyl](naphthylphenylphenanthrene; bis[(phenanthrenyl)phenyl]naphthalene; bis[(phenanthrenyl)phenyl]naphthalene; bis[(phenanthrenyl)phenyl]naphthalene; bis[(phenanthrenyl)phenyl]naphthalene; bis[(phenanthrenyl)phenyl]phenanthrene; bis[(phenanthrenyl)phenyl]naphthalene; bis[(phenanthrenyl)phenyl]naphthalene; bis[(phenanthrenyl)phenyl]naphthalene; (binaphthalenyl)[(biphenylyl)phenanthrenyl]benzene; (naphthyl)[(phenanthrenyl)naphthaleyl]benzene; [(phenanthrenyl)naphthaleyl](phenanthrenyl)benzene; (binaphthalenyl)(phenanthrenyl)benzene; (binaphthalenyl)(phenanthrenyl)benzene; [(phenanthrenyl)naphthaleyl](phenanthrenyl)benzene; (binaphthalenyl)(phenanthrenyl)benzene; (binaphthalenyl)(phenanthrenyl)benzene; [(phenanthrenyl)naphthaleyl](phenanthrenyl)benzene; (binaphthalenyl)(phenanthrenyl)benzene; (binaphthalenyl)(phenanthrenyl)benzene; (binaphthalenyl)(phenanthrenyl)benzene; [(phenanthrenyl)naphthaleyl](phenanthrenyl)benzene; [(phenyl)naphthaleyl](phenanthrenyl)benzene; ethyl[ethyl(binaphthalenyl)](phenanthrenyl)benzene; [(phenyl)binaphthalenyl]phenanthrene; [bis(phenanthrenyl)]binaphthalene; [(benzophenanthrenyl)(phenanthrenyl)binaphthalene; (benzochrysenyl){[(tert-butyldimethylsilyl)phenanthrenyl]naphthaleyl}benzene; [phenyl(phenanthrenyl)]binaphthalene; [(phenanthrenyl)phenyl]binaphthalene; (ternaphthaleyl)phenanthrene; [bis(phenanthrenyl)]binaphthalene; [bis(phenanthrenyl)]binaphthalene; [phenanthrenyl(phenanthrenyl)]binaphthalene; [bis(phenanthrenyl)]binaphthalene; (temaphthaleyl)phenanthrene; (temaphthaleyl)phenanthrene; (ternaphthaleyl)phenanthrene; [bis(phenanthrenyl)]binaphthalene; {bis[(trimethylsilyl)phenanthrenyl]}binaphthalene; [bis(phenanthrenyl)]biphenyl; [naphthyl(phenanthrenyl)]biphenyl; [phenanthrenyl(phenanthrenyl)]biphenyl; [bis(phenanthrenyl)]biphenyl; [bis(phenanthrenyl)]biphenyl; [(phenanthrenyl(naphthyl)]biphenyl; [dimethylbis(phenanthrenyl)]biphenyl; [dimethylphenanthrenyl(methylphenanthrenyl)]biphenyl; [bis(diisopropylphenanthrenyl)]biphenyl; [phenanthrenyl(trimethylsilylnaphthaleyl)]biphenyl; [difluorobis(phenanthrenyl)]biphenyl; [dicyanobis(phenanthrenyl)]biphenyl; [(phenanthrenyl)[(naphthyl)phenyl]]binaphthalene; [biphenylyl(phenanthrenyl)]binaphthalene; [(phenanthrenyl)phenyl](phenanthrenyl)binaphthalene; [(phenanthrenyl)phenyl](phenanthrenyl)binaphthalene; [[(phenanthrenyl)phenyl]phenyl]binaphthalene; di(naphthyl)chrysene; di(naphthyl)chrysene; (naphthyl(naphthyl)chrysene; di(phenanthrenyl)chrysene; (naphthyl)(phenanthrenyl)chrysene; (naphthyl)(phenanthrenyl)chrysene; bis[(naphthyl)phenyl]chrysene; bis[(naphthyl)phenyl]chrysene; [(naphthyl)phenyl][(naphthyl)phenyl]chrysene; (naphthyl)[(naphthyl)phenyl]chrysene; [(naphthyl)phenyl](phenylnaphthaleyl)chrysene; [(naphthyl)phenyl](naphthyl)chrysene; bis(phenylnaphthaleyl)chrysene; bis[(biphenylyl)phenyl]chrysene; bis(phenylnaphthaleyl)chrysene; (phenylnaphthaleyl)[(phenylnaphthaleyl)phenyl]chrysene; bis[(benzophenanthrenyl)phenyl]chrysene; [(naphthyl)phenyl][(naphthyl)phenyl]chrysene; bis[(naphthyl)phenyl]chrysene; bis[(naphthyl)phenyl]chrysene; phenyl[(phenanthrenyl)naphthaleyl]chrysene; bis(phenylchrysenyl)naphthalene; di(naphthyl)chrysene; (naphthyl)(naphthyl)chrysene; di(naphthyl)chrysene; (naphthyl)(phenanthrenyl)chrysene; di(phenanthrenyl)chrysene; (naphthyl)(phenanthrenyl)chrycene; diphenyldi(naphthyl)chrysene; phenyl(naphthyl(naphthyl)chrysene; phenyldi(naphthyl)chrysene; phenyl(phenanthrenyl)(naphthyl)chrysene; (isopropyl)di(phenanthrenyl)chrysene; di(naphthyl(phenanthrenyl))chrysene; phenyldi(phenanthrenyl)chrysene; (phenanthrenyl)(naphthyl)picene; [(biphenylyl)naphthaleyl]chrysene; (chrysenyl)[(phenanthrenyl)naphthaleyl]benzene; [chrysenyl(phenanthrenyl)]binaphthalene; bis(chrysenyl)biphenyl; (phenyl)[(cyclohexylchrysenyl)phenyl]binaphthalene; (phenyl)[(chrysenyl)phenyl]binaphthalene; (picenyl){(phenanthrenyl)phenyl}naphthalene; diphenylbenzophenanthrene; di(naphthyl)benzophenanthrene; bis(phenylnaphthaleyl)benzophenanthrene; bis(phenylnaphthaleyl)benzophenanthrene; (phenylnaphthaleyl)(naphthyl)benzophenanthrene; [(naphthyl)phenyl](naphthyl)benzophenanthrene; bis[(naphthyl)phenyl]benzophenanthrene; bis[(naphthyl)phenyl]benzophenanthrene; (benzophenanthrenyl)(phenanthrenyl)benzene; [(naphthyl)phenyl][(naphthyl)phenyl]benzophenanthrene; (benzophenanthrenyl)(phenanthrenyl)benzene; diphenylbenzophenanthrene; di(naphthyl)benzophenanthrene; (benzophenanthrenyl)(phenanthrenyl)biphenyl; di(naphthyl)benzophenanthrene; (naphthylphenyl)(phenanthrenyl)benzophenanthrene; di(naphthyl)benzochrysene; di(naphthyl)benzochrysene; (benzophenanthrenyl)(naphthylphenanthrenyl)benzene; (benzochrysenyl)(phenylnaphthaleyl)benzene; [benzochrysenyl(benzophenanthrenyl)]binaphthalene; [benzophenanthrenyl(naphthyl)]biphenyl; [benzophenanthrenyl(benzophenanthrenyl)]biphenyl; [(phenanthrenyl)phenyl](benzophenanthrenyl)naphthalene; [phenanthrenyl(benzochrysenyl)]binaphthalene; [di(benzochrysenyl)]biphenyl; diphenylbenzochrysene; bis[(naphthyl)phenyl]benzochrysene; bis[(naphthyl)phenyl]benzochrysene; di(naphthyl)benzochrysene; bis(phenylnaphthaleyl)benzochrysene; diphenylhelicene; di(naphthyl)helicene; di(naphthyl)helicene; di(naphthyl)(fluoranthenyl)benzene; diphenyl[(naphthyl)phenyl]fluoranthene; bis[(naphthyl)phenyl]fluoranthene; phenyl(phenanthrenyl)fluoranthene; naphthyltetraphenylfluoranthene; phenanthrenyltetraphenylfluoranthene; diphenyl[(naphthyl)phenyl]fluoranthene; diisopropyldiphenyl[(naphthyl)phenyl]fluoranthene; diphenyl[(phenanthrenyl)phenyl]fluoranthene; di(naphthyl)fluoranthene; (naphthyl)((naphthyl)phenyl)fluoranthene; (naphthyl)bis[(naphthyl)phenyl]fluoranthene; (naphthyl)(phenanthrenyl)fluoranthene; (naphthyl)(naphthyl)fluoranthene; (biphenylyl)(naphthyl)fluoranthene; [(phenyl)biphenylyl](naphthyl)fluoranthene; [(phenyl)biphenylyl](naphthyl)fluoranthene; (biphenylyl)(terbenzenyl)fluoranthene; di(fluoranthenyl)naphthalene; [(benzofluoranthenyl)naphthaleyl][(naphthyl)phenyl]phenanthrene; diphenyldi(fluoranthenyl)naphthalene; {[(benzofluoranthenyl)biphenylyl]}[(benzofluoranthenyl)phenyl]naphthalene; [benzofluoranthenyl(phenanthrenyl)]biphenyl; [di(fluoranthenyl)]binaphthalene; [(fluoranthenyl)phenyl](phenanthrenyl)naphthalene; [(phenanthrenyl)phenyl](fluoranthenyl)naphthalene; [di(fluoranthenyl)]biphenyl; {[(phenanthrenyl)phenyl](fluoranthenyl)}binaphthalene; (benzofluoranthenyl)(phenanthrenyl)benzene; (benzofluoranthenyl)(phenanthrenyl)triphenylene; di(naphthyl)(benzofluoranthenyl)benzene; (benzofluoranthenyl)(naphthyl)benzene; bis[(naphthyl)phenyl]benzofluoranthene; (phenanthrenyl)benzofluoranthene; tetraphenylbenzofluoranthene; tetraphenyldibenzofluoranthene; diphenyl[(naphthyl)phenyl]benzofluoranthene; diphenyl[(naphthyl)phenyl]benzofluoranthene; diphenyl[(phenanthrenyl)phenyl]benzofluoranthene; diphenylbenzofluoranthene; bis[(phenyl)biphenylyl]diphenylbenzofluoranthene; (phenyldiphenyl)benzofluoranthene; (diphenyl)benzofluoranthenylphenylnaphthalene; di(naphthyl)diphenylbenzofluoranthene; (biphenylyl)(diphenyl)[(naphthyl)phenyl]benzofluoranthene; bis(biphenylyl)(diphenyl)benzofluoranthene; di(methylstyryl)triphenylene; distyryltriphenylene; tri(methylstyryl)triphenylene; tristyryltriphenylene; diphenyltriphenylene; (naphthylphenyl)triphenylene; diphenyltriphenylene; hexaphenyltriphenylene; triphenyltriphenylene; tris(biphenylyl)triphenylene; tetraphenyltriphenylene; (triphenylenyl(phenanthrenyl)diphenylphenanthrene; naphthyl(phenanthrenyl)triphenylene; (biphenanthrenyl)triphenylene; bis(triphenylenyl)binaphthalene; [(triphenylenyl)phenyl](phenanthrenyl)naphthalene; [bis(triphenylenyl)]biphenyl; [bis(triphenylenyl)]biphenyl; {[(triphenylenyl)]phenylphenyl}binaphthalene; [(naphthyl)phenyl][(naphthyl)phenyl]naphthoquinoline; bis(naphthyl)azabenzochrysene; diphenyldiazodibenzophenanthrene; bis(phenylnaphthaleyl)acenaphthopyrazine; bis(phenylnaphthaleyldiazabenzofluoranthene; diphenylazabenzofluoranthene; iridium(III)bis(phenylquinolyl)acetylacetonate; iridium(III)tris(phenylisoquinolyl); iridium(III)bis((tert-butylphenyl)isoquinolyl)acetylacetonate; iridium(III)bis(diphenylquinoxalyl)acetylacetonate; iridium(III)bis(diphenyltetrahydroquinoxalyl)acetylacetonate; iridium(III)bis(diphenylpyrazine)acetylacetonate; osmium(IV)bis[(triphenylmethyltriazolylmethylpyridyl]bis(methyldiphenylphosphonate); ruthenium(V)bis[dipyridyl](phenylpyridyl); platinum(II)bis[(thienyl)pyridyl]; iridium(III)bis[(benzothiophenyl]pyridine]acetylacetonate; iridium(III)bis(phenylbenzothiazole)acetylacetonate; iridium(III)tris(diphenylquinoxalyl); iridium(III)bis(phenylphenanthrydiyl)acetylacetonate; iridium(III)bis((biphenylyl)pyridine)acetylacetonate; iridium(III)bis(phenylisoquinolyl)(acetylhydroxycyclohexenone); platinum(II)bis[phenylenebis(ditert-butylsalicylideneimine]; iridium(III)tris(difluorodibenzoquinolyl)acetylacetonate; platinum(II)(octaethylporphyrin); iridium(III)tris[(fluoro)phenylpyridyl]; iridium(III)bis[(fluoro)phenylpyridyl]acetylacetonate; iridium(III)tris[(difluorophenyl)pyridyl]; iridium(III)tris[(fluorophenylmethoxypyridyl]; iridium(III)bis[(fluorophenyl)pyridyl][(difluorophenyl)pyridyl]; iridium(III)tris[(difluorophenylmethoxypyridyl]; iridium(III)tris[(fluorophenyldiphenylaminopyridyl]; iridium(III)tris[(fluorophenyldimethylaminopyridyl]acetylacetonate; iridium(III)tris[(difluorophenylmethylpyridyl]; platinum(II)[di(pyridyl)benzil](biphenylone]; iridium(III)tris[(methylphenylpyridyl]; iridium(III)tris[(methylphenylpyridyl]; iridium(III)bis[phenylisoquinolyl]acetylacetonate; iridium(III)bis[phenylpyridyl]acetylacetonate; iridium(III)bis[(bis(trifluoromethyl)phenyl)pyridyl](carboxylatepyridinium); iridium(III)bis[(difluorophenyl)pyridyl](carboxylatepyridinium); iridium(III)bis[(difluorophenyl)pyridyl][(trifluoromethyl(pyridinyltriazole); iridium(III)tris[phenylpyridyl]; iridium(III)bis[phenylisoquinolyl]acetylacetonate; iridium(III)bis[(difluorophenyl)pyridyl][tetrakis(pyrazolyl)boron]; iridium(III)tris[phenylmethyldihydrobenzoimidazole]; iridium(III)tris[(dibenzofuranylmethylimidazoline]; iridium(III)tris[(dimethylfluorenylpyrazole]; platinum(II)bis(phenylpyridine); iridium(III)tris[(trifluorophenyl)pyridyl]; iridium(III)bis[(thienyl)pyridyl]acetylacetonate; iridium(III)bis(phenylbenzooxazole)acetylacetonate; iridium(III)bis[(naphthyl)benzooxazole]acetylacetonate; iridium(III)bis[(benzothiazolyldimethylaminocoumaryl]acetylacetonate; iridium(III)bis[(naphthyl)isoquinolyl]acetylacetonate; iridium(III)bis[(naphthyl)isoquinolyl]acetylacetonate; iridium(III)bis[(pyridyl)isoquinolyl]acetylacetonate; iridium(III)bis(phenylisoquinolyl)(phenylpyridyl); iridium(III)tris[(thienyl)isoquinolyl]

### (Group 10A)

[di(carbazolyl)]biphenyl; [dimethyldi(carbazolyl)]biphenyl; [diphenyldi(carbazolyl)]biphenyl; di(carbazolyl)benzene; tri(carbazolyl)benzene; di(carbazolyl)triphenylsilylbenzene; tris[(carbazolyl)phenyl]amine; tris[(carbazolyl)phenyl]benzene; tris{[methylphenyl(phenyl)amino]phenyl}amine; tris{[naphthyl(phenyl)amino]phenyl}amine; [bis(tribenzoazepinyl)]biphenyl; [dimethylbis(tribenzoazepinyl)]biphenyl; bis(tribenzoazepinyl)benzene; tris(tribenzoazepinyl)benzene; tris[(tribenzoazepinyl)phenyl]amine; tris[(tribenzoazepinyl)phenyl]benzene; diphenylbis[(carbazolyl)phenyl]silane; diphenylbis[(carbazolyl)phenyl]methane; di(carbazolyl)quaterbenzene; di(carbazolyl)quaterbenzene; di(carbazolyl)quaterbenzene; bis[(carbazolyl)phenyl]tetraphenylbenzene; bis[(carbazolyl)phenyl]tetraphenylbenzene; [di(carbazolyl)]biphenyl; bis(tert-butylindole-d₅)benzene-d₄; di(carbazolyl-d₈)benzene-d₄; [di(carbazolyl-da)]biphenyl; diphenylbis{[bis(methylphenyl)amino]phenyl}biphenyldiamine; tris[(naphthylphenylamino)phenyl]amine; diphenyldi(naphthyl)biphenyldiamine; tris(phenylbenzoimidazolyl)benzene; tris(phenylimidazopyridinyl)benzene; tris((methylphenyl)imidazopyridinyl)benzene; tris((biphenylyl)imidazopyridinyl)benzene; tris(methylbenzoimidazolyl)triazine; tris(phenylbenzoimidazolyl)triazine; aluminum(III)tris(quinolinolato); aluminum(III)bis(methylquinolinolato)(biphenylol); aluminum(III)bis(methylquinolinolato)(phenylnaphthalenol); aluminum(III)bis(methylquinolinolato)(triphenylsilanol); aluminum(III)tris[(hydroxyphenyl)phenylimidazopyridinol]; gallium(III)tris[(hydroxyphenyl)phenylimidazopyridinol]; aluminum(III)tris[(triphenylimidazolyl)phenol]; palladium(II)bis(phenylpyridyl); platinum(II)bis(phenylpyridyl); iridium(III)tris(phenylpyrazolyl); iridium(III)bis(phenylpyrazolyl)(phenylpyridyl); palladium(II)bis(phenylpyrazolyl); platinum(II)[diphenylbis(phenylpyridinyl)methane]; platinum(II){diphenylbis[(difluorophenyl)pyridinyl)methane]; palladium(II)[bis(phenylpyridinyl)propane]; palladium(II)[diphenylbis(phenylpyridinyl)methane]; platinum(II)[bis(phenylpyridinyl)methane]; platinum(II){bis[(isoquinolinyl)naphthaleyl)]methane}; platinum(II){bis[(isoquinolinyl)benzene]one}; platinum(II)[bis(phenylpyridinyl)methane]; platinum(II)[bis(bipyridinyl)one}; platinum(II)(diphenylquinoquinoline)}; platinum(II)[phenyl(phenylpyridinyl)quinoline]; platinum(II){bis[(benzothiophenyl)pyridinyl]methylene]; platinum(II){{bis[(methyl)indolyl]pyridinyl}methane]; platinum(II)[bis(phenylisoquinolinyl)methane]; platinum(II){bis[(methoxyphenyl)isoquinolinyl]methane]; platinum(II)[bis(phenacylpyridine)]platinum(II)[bis((hydroxyphenyl)pyridine)]platinum(II){bis[(hydroxybenzylidene)]benzene}; platinum(II)[(diphenylphenanthrolinediyl)bis(phenol)]; platinum(II)[[(phenylpropanyl)isoquinolinediyl](phenylpropanyl)isoquinoline]; platinum(II)[[(phenylpropanyl)isoquinolinediyl](phenylpropanyl)isoquinoline]; platinum(II)[(methylenebispyridinediyl)methylenebispyridine]; platinum(II)[[(pyridylpropanyl)pyridine)diyl](phenylpropanyl)benzene]; platinum(II)[[(isoquinolylpropanyl)isoquinoline)diyl]((naphthalene)propanyl)naphthalene]; platinum(II)[(quinoquinolinediyl)(phenylpropanyl)benzene]; platinum(II)[tetrazahexacyclodotriacontapentadecaene]; platinum(II)[[((pyrazyl)propanyl)pyrazine)diyl](phenylpropanyl)benzene]; platinum(II)[bis(phenylpyridinyl)aniline]; platinum(II){[(naphthyl)pyridinyl](phenylpyridinyl)propane}; platinum(II){(phenylpyridinyl)[(benzoimidazolyl)pyridinyl]propane}; platinum(II)[bis(phenylisoquinolinyl)aniline]; platinum(II)[bis(phenylbiisoquinolinyl)aniline]; platinum(II)[bis((naphthyl)pyridinyl)aniline]; platinum(II)[bis((thienyl)pyridinyl)aniline]; platinum(II)[bis(phenylpyridinyl)ethene]; platinum(II)[bis(phenylpyridinyl)one]; platinum(II)[bis((pyridyl)phenyl)aniline]; platinum(II)[bis(difluorobipyridinatoyl)propane]; platinum(II)[(difluorobipyridinatoyl){(trifluoromethylpyrazolyl)pyridinatoyl}propane]platinum(II){bis[(cyanophenyl)pyri dinyl]propane]; platinum(II)[(difluorobipyridinatoyl)(pyridinecarboxylateyl)propane]; platinum(II){[(phenylpyrazolyl)[(dibenzofuranyl)pyrazolyl]propane]; platinum(II)[bis(phenylpyridinyl)propane]; platinum(II){[bis(biphenylyl)pyridinyl]propane}; iridium(III)bis[(dimethylphenyl)isobutylquinoline]acetylacetonate; iridium(III)bis[(quinolyl)isobutylbenzene]acetylacetonate; iridium(III)bis[(quinolyl)diisobutylbenzene]acetylacetonate; iridium(III)bis[(quinolyl)dimethylbenzene]acetylacetonate; iridium(III)tris[phenylisoquinoline]; iridium(III)bis[phenylisoquinoline]acetylacetonate; iridium(III)bis[(naphthyl)quinoline](tetramethyloxalatoheptenone); iridium(III)bis[(naphthyl)quinoline](phenylpyridine); iridium(III)bis(phenylpyridine) [(naphthyl)quinoline]; iridium(III)bis((thienyl)quinoline) (phenyloxalatobutenone); iridium(III)bis[(pyridinyl)quinoline](phenylpyrazine); iridium(III)bis(biquinoline)acetylacetonate; iridium(III)bis(phenylbenzoquinoline)acetylacetonate; iridium(III)bis[(naphthyl)quinoline](phenylbenzooxazole); iridium(III)bis(phenylquinoline)acetylacetonate; iridium(III)bis[(methylphenyl)quinoline]acetylacetonate; iridium(III)bis(benzoacridine)acetylacetonate; iridium(III)bis[(naphthyl)quinoline)acetylacetonate; iridium(III)bis[(pyrenyl)quinoline]acetylacetonate; iridium(III)bis[(biphenylyl)quinoline]acetylacetonate; iridium(III)bis[(phenanthrenyl)quinoline]acetylacetonate; iridium(III)bis[(methylphenyl)quinoline]acetylacetonate; iridium(III)bis[phenylquinoline]acetylacetonate; iridium(III)tris(phenylquinoline); iridium(III)bis(phenylisoquinoline)acetylacetonate; iridium(III)bis[(naphthyl)isoquinoline]acetylacetonate; iridium(III)tris{[(trifluoromethyl)phenyl]pyrazole}; iridium(III)tris[(difluorophenyl)pyridine]; iridium(III)tris[(tert-butylphenyl)pyridine]; iridium(III)tris[(thienyl)pyridine]; iridium(III)tris[(pyridyl)benzothiophene]; iridium(III)tris[(tert-butylphenyl)isoquinoline]; iridium(III)tris[(thienyl)isoquinoline]; iridium(III)tris[(dimethylfluorenyl)isoquinoline]; iridium(III)bis[(difluorophenyl)pyridine][tetra(pyrazolyl)borane]; iridium(III)bis[(difluorotrifluoromethylphenyl)pyridine](pyridinecarboxylate); iridium(III)bis(phenylpyridine)acetylacetonate; iridium(III)tris(phenylbenzooxazole); iridium(III)bis(phenylquinoline)acetylacetonate; iridium(III)bis[(pyridyl)benzothiophene]acetylacetonate; iridium(III)bis(phenylisoquinoline)acetylacetonate; iridium(III)bis[(pyridyl)naphthalene]acetylacetonate; europium(IV)tris[(thienyl)trifluoroxylatobutenone](phenanthroline); iridium(III)tris[(naphthyl)isoquinoline]; terbium(IV)trisacetylacetonate(phenanthroline); dysprosium(IV)tris[trifluoroxylatophenylbutenone](benzo[h]quinoline); platinum(II)[bis(phenylpyridinyl)propane]; platinum(II){bis[(difluorophenyl)pyridinyl]propane}; platinum(II){bis[(trifluoromethylpyrazolyl)pyridinyl]propane}; platinum(II){bis[(trifluoromethylpyrazolyl)pyridinyl]fluorene}; bis(diphenylethenyl)biphenyl; diphenylanthracene; di(naphthyl)anthracene; tetrakis(biphenylyl)pyrene; octakis(methylphenyl)pyrenetetraamine; dimethylquinacridone; rubrene; coumarin; {[(tetrahydrobenzoquinolizine)yl]ethenylmethylpyranylidene}propanedinitrile

### (Group 12A)

diphenyl(triphenylenyl)triazine; diphenyl(triphenylenyl)pyridine; (triphenylenyl)diphenylpyrimidine; (pyridinyl)(triphenylenyl)biphenyl; di(pyridinyl)(triphenylenyl)benzene; (pyridinyl)(pyridinyl)(triphenylenyl)benzene; di(pyridinyl)(triphenylenyl)benzene; (pyridinyl)phenyl(triphenylenyl)triazine; (pyridinyl)(triphenylenyl)pyrimidine; phenyl(triphenylenyl)pyrimidine; (pyridinyl)(triphenylenyl)benzene; phenyl(triphenylenyl)triazine; (diphenylpyridinyl)(triphenylenyl)benzene; (diphenylpyridinyl)(triphenylenyl)benzene; (diphenyltriazinyl)(triphenylenyl)benzene; di(pyridinyl)(triphenylenyl)biphenyl; di(pyridinyl)(triphenylenyl)biphenyl; (pyridinyl)(pyridinyl)(triphenylenyl)biphenyl; [di(pyridinyl)triazinyl](triphenylenyl)benzene; phenyl[(triphenylenyl)phenyl]pyrimidine; phenyl[(triphenylenyl)phenyl]triazine; (diphenylpyridinyl)(triphenylenyl)benzene; [(triphenylenyl)phenyl]diphenylpyrimidine; [(triphenylenyl)phenyl]diphenyltriazine; di(pyridinyl)(triphenylenyl)biphenyl; di(pyridinyl)(triphenylenyl)biphenyl; (pyridinyl)(pyridinyl)(triphenylenyl)biphenyl; [di(pyridinyl)triazinyl](triphenylenyl)benzene; phenyl[(triphenylenyl)phenyl]pyrimidine; phenyl[(triphenylenyl)phenyl]triazine; (triphenylenyl)(diphenylpyridinyl)biphenyl; (triphenylenyl)(diphenylpyrimidineyl)biphenyl; (triphenylenyl)(diphenyltriazinyl)biphenyl; (triphenylenyl)(pyridinyl)terbenzene; (triphenylenyl)(pyridinyl)terbenzene; (triphenylenyl)(pyridinyl)(pyridinyl)terbenzene; (triphenylenyl)[di(pyridinyl)triazinyl]biphenyl; (triphenylenyl)(phenylpyrimidineyl)biphenyl; (triphenylenyl)(phenyltriazinyl)biphenyl; (triphenylenyl)(diphenylpyridinyl)biphenyl; (triphenylenyl)(diphenylpyrimidineyl)biphenyl; (triphenylenyl)(diphenyltriazinyl)biphenyl; (triphenylenyl)di(pyridinyl)terbenzene; (triphenylenyl)di(pyridinyl)terbenzene; (triphenylenyl)(pyridinyl)(pyridinyl)terbenzene; (triphenylenyl)[di(pyridinyl)triazinyl]biphenyl; (triphenylenyl)(phenylpyrimidineyl)biphenyl; (triphenylenyl)(phenyltriazinyl)biphenyl; (diphenylpyridinyl)(triphenylenyl)biphenyl; (diphenylpyrimidineyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; [di(pyridinyl)triazinyl](triphenylenyl)biphenyl; (phenylpyrimidineyl)(triphenylenyl)biphenyl; (phenyltriazinyl)(triphenylenyl)biphenyl; (diphenylpyridinyl)(triphenylenyl)biphenyl; (diphenylpyrimidineyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; (di(pyridinyl)triazinyl)(triphenylenyl)biphenyl; (phenylpyrimidineyl)(triphenylenyl)biphenyl; (phenyltriazinyl)(triphenylenyl)biphenyl; (diphenylpyridinyl)(triphenylenyl)biphenyl; (diphenylpyrimidineyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; [di(pyridinyl)triazinyl](triphenylenyl)biphenyl; (phenylpyrimidineyl)(triphenylenyl)biphenyl; (phenyltriazinyl)(triphenylenyl)biphenyl; (diphenylpyridinyl)(triphenylenyl)terbenzene; (diphenylpyrimidineyl)(triphenylenyl)terbenzene; (diphenyltriazinyl)(triphenylenyl)terbenzene; di(pyridinyl)(triphenylenyl)quaterbenzene; di(pyridinyl)(triphenylenyl)quaterbenzene; (pyridinyl)(pyridinyl)(triphenylenyl)quaterbenzene; [di(pyridinyl)triazinyl](triphenylenyl)terbenzene; (phenylpyrimidineyl)(triphenylenyl)terbenzene; (phenyltriazinyl)(triphenylenyl)terbenzene; (diphenylpyridinyl)(triphenylenyl)terbenzene; (diphenylpyrimidineyl)(triphenylenyl)terbenzene; (diphenyltriazinyl)(triphenylenyl)terbenzene; di(pyridinyl)(triphenylenyl)quaterbenzene; di(pyridinyl)(triphenylenyl)quaterbenzene; (pyridinyl)(pyridinyl)(triphenylenyl)quaterbenzene; [di(pyridinyl)triazinyl](triphenylenyl)terbenzene; (phenylpyrimidineyl)(triphenylenyl)terbenzene; (phenyltriazinyl)(triphenylenyl)terbenzene; (diphenylpyridinyl)(phenyltriphenylenyl)biphenyl; (diphenylpyrimidineyl)(triphenylenyl)terbenzene; (triphenylenyl)(diphenyltriazinyl)terbenzene; [di(pyridinyl)triazinyl](triphenylenyl)terbenzene; [(triphenylenyl)biphenylyl)terpyridine; [(triphenylenyl)biphenylyl)terpyridine; (phenyltriphenylenyl)diphenyltriazine; (methyltriphenylenyl)diphenyltriazine; (phenyltriphenylenyl)(pyridinyl)biphenyl; (phenyltriphenylenyl)di(pyridinyl)benzene; (methyltriphenylenyl)(pyridinyl)(pyridinyl)benzene; (diphenyltriphenylenyl)(pyridinyl)phenyltriazine; (pyridinyl)(phenyltriphenylenyl)pyrimidine; phenyl(phenyltriphenylenyl)pyrimidine; (diphenylpyridinyl)(methyltriphenylenyl)benzene; (diphenylpyrimidineyl)(diphenyltriphenylenyl)benzene; di(pyridinyl)(phenyltriphenylenyl)biphenyl; (pyridinyl)(pyridinyl)(methyltriphenylenyl)biphenyl; (diphenylpyridinyl)(phenyltriphenylenyl)benzene; di(pyridinyl)(triphenylenyl)biphenyl; [di(pyridinyl)triazinyl](phenyltriphenylenyl)benzene; di(pyridinyl)(phenyltriphenylenyl)terbenzene; [di(pyridinyl)triazinyl](phenyltriphenylenyl)biphenyl; (phenyltriphenylenyl)di(pyridinyl)terbenzene; [di(pyridinyl)triazinyl](dimethyltriphenylenyl)biphenyl; (diphenylpyridinyl)(phenyltriphenylenyl)biphenyl; (diphenylpyrimidineyl)(methyltriphenylenyl)biphenyl; (diphenyltriazinyl)(phenyltriphenylenyl)biphenyl; (diphenyltriazinyl)(dimethyltriphenylenyl)terbenzene; (diphenyltriazinyl)(methyltriphenylenyl)terbenzene; di(pyridinyl)(phenyltriphenylenyl)terbenzene; (diphenyltriazinyl)(phenyltriphenylenyl)biphenyl; (diphenyltriazinyl)(phenyltriphenylenyl)biphenyl; phenyl(diphenylpyridinyl)bi(carbazole); phenyl(diphenylpyridinyl)bi(carbazole); (biphenylyl)(diphenylpyridinyl)bi(carbazole); (terphenylyl)(diphenylpyridinyl)bi(carbazole); (terphenylyl)(diphenylpyridinyl)bi(carbazole); (naphthaleyl)(diphenylpyridinyl)bi(carbazole); (naphthaleyl)(diphenylpyridinyl)bi(carbazole); (triphenylenyl)(diphenylpyridinyl)bi(carbazole); (triphenylenyl)(diphenylpyridinyl)bi(carbazole); bi[(diphenylpyridinyl)carbazole]; (diphenylpyridinyl)(diphenylpyridinyl)bi(carbazole); bi[(diphenylpyridinyl)carbazole]; (dimethylfluorenyl)phenylbi(carbazole); (dimethylfluorenyl)(biphenylyl)bi(carbazole); (dimethylfluorenyl)(terphenylyl)bi(carbazole); (dibenzofuranyl)phenylbi(carbazole); (dibenzofuranyl)(biphenylyl)bi(carbazole); (dibenzofuranyl)(terphenylyl)bi(carbazole); (dibenzothiophenyl)phenylbi(carbazole); (dibenzothiophenyl)(biphenylyl)bi(carbazole); (dibenzothiophenyl)(terphenylyl)bi(carbazole); bi[phenylcarbazole]; bi[(pyridinyl)carbazole]; bi[(pyrimidineyl)carbazole]; (triphenylenyl)phenylbi(carbazole); (triphenylenyl)(pyridinyl)bi(carbazole); (triphenylenyl)phenylbi(carbazole); (triphenylenyl)(pyridinyl)bi(carbazole); phenyl(triphenylenyl)bi(carbazole); (pyridinyl)(triphenylenyl)bi(carbazole); (biphenylyl)(biphenylyl)bi(carbazole); (biphenylyl)(terphenylyl)bi(carbazole); (biphenylyl)(terphenylyl)bi(carbazole); (dimethylfluorenyl)phenylbi(carbazole); (dimethylfluorenyl)(biphenylyl)bi(carbazole); (dimethylfluorenyl)(biphenylyl)bi(carbazole); (dimethylfluorenyl)(terphenylyl)bi(carbazole); (dibenzofuranyl)(biphenylyl)bi(carbazole); (dibenzothiophenyl)(biphenylyl)bi(carbazole); (phenylcarbazolyl)phenylbi(carbazole); (dibenzofuranyl)phenylbi(carbazole); (dibenzofuranyl)(biphenylyl)bi(carbazole); (dibenzofuranyl)(terphenylyl)bi(carbazole); (dibenzofuranyl)(biphenylyl)bi(carbazole); (dibenzothiophenyl)phenylbi(carbazole); (dibenzothiophenyl)(biphenylyl)bi(carbazole); (dibenzothiophenyl)(terphenylyl)bi(carbazole); (dibenzothiophenyl)(biphenylyl)bi(carbazole); (diphenylpyridinyl)(dimethylfluorenyl)bi(carbazole); (diphenylpyridinyl)(dimethylfluorenyl)bi(carbazole); [(pyridinyl)biphenylyl](dimethylfluorenyl)bi(carbazole); [(pyridinyl)biphenylyl](dimethylfluorenyl)bi(carbazole); [(pyridinyl)biphenylyl](dimethylfluorenyl)bi(carbazole); (diphenylpyridinyl)(dibenzofuranyl)bi(carbazole); (dibenzofuranyl)[(pyridinyl)biphenylyl]bi(carbazole); (dibenzofuranyl)[(pyridinyl)biphenylyl]bi(carbazole); (dibenzofuranyl)[(pyridinyl)biphenylyl]bi(carbazole); (dibenzothiophenyl)(diphenylpyridinyl)bi(carbazole); (dibenzothiophenyl)[(pyridinyl)biphenylyl]bi(carbazole); (dibenzothiophenyl)[(pyridinyl)biphenylyl]bi(carbazole); (dibenzothiophenyl)[(pyridinyl)biphenylyl]bi(carbazole); phenyl(diphenylpyridinyl)bi(carbazole); phenyl[(pyridinyl)biphenylyl]bi(carbazole); phenyl(diphenylpyridinyl)bi(carbazole); (biphenylyl)(diphenylpyridinyl)bi(carbazole); (biphenylyl)[(pyridinyl)biphenylyl]bi(carbazole); (biphenylyl)(diphenylpyridinyl)bi(carbazole); (biphenylyl)(diphenylpyridinyl)bi(carbazole); (biphenylyl)(diphenylpyridinyl)bi(carbazole); (biphenylyl)[(pyridinyl)biphenylyl]bi(carbazole); (diphenylpyridinyl)phenylbi(carbazole); (diphenylpyridinyl)phenylbi(carbazole); [(pyridinyl)biphenylyl]phenylbi(carbazole); (diphenylpyridinyl)(biphenylyl)bi(carbazole); (diphenylpyridinyl)(biphenylyl)bi(carbazole); [(pyridinyl)biphenylyl](biphenylyl)bi(carbazole); (diphenylpyridinyl)(biphenylyl)bi(carbazole); (diphenylpyridinyl)(biphenylyl)bi(carbazole); [(pyridinyl)biphenylyl](biphenylyl)bi(carbazole); (dibenzofuranyl)(terphenylyl)bi(carbazole); (dibenzofuranyl)(biphenylyl)bi(carbazole); (dibenzofuranyl)phenylbi(carbazole); (dibenzofuranyl)(biphenylyl)bi(carbazole); (dibenzothiophenyl)(terphenylyl)bi(carbazole); (dibenzothiophenyl)(biphenylyl)bi(carbazole); (dibenzothiophenyl)phenylbi(carbazole); (dibenzothiophenyl)(biphenylyl)bi(carbazole); (biphenylyl)(diphenylpyridinyl)bi(carbazole); (diphenylpyridinyl)(biphenylyl)bi(carbazole); phenyl(diphenylpyridinyl)bi(carbazole); (diphenylpyridinyl)phenylbi(carbazole); phenyl(diphenylpyridinyl)bi(carbazole); phenyl(diphenylpyridinyl)bi(carbazole); phenyl(diphenylpyridinyl)bi(carbazole); (diphenylpyridinyl)phenylbi(carbazole); (diphenylpyridinyl)phenylbi(carbazole); (biphenylyl)(diphenylpyridinyl)bi(carbazole); phenyl(diphenylpyridinyl)bi(carbazole); bi[(biphenylyl)carbazole]; bi[(biphenylyl)carbazole]; (biphenylyl)phenylbi(carbazole)

### (Group 13A)

(carbazolyl)(triphenylenyl)biphenyl; (carbazolyl)(triphenylenyl)biphenyl; (carbazolyl)(triphenylenyl)biphenyl; (carbazolyl)(triphenylenyl)biphenyl; (carbazolyl)(triphenylenyl)terbenzene; (carbazolyl)(triphenylenyl)terbenzene; (carbazolyl)(triphenylenyl)terbenzene; (carbazolyl)(triphenylenyl)terbenzene; (carbazolyl)(triphenylenyl)quaterbenzene; (triphenylenyl)(carbazolyl)terbenzene; (phenylcarbazolyl)(triphenylenyl)biphenyl; (diphenylcarbazolyl)(triphenylenyl)biphenyl; (carbazolyl)(phenyltriphenylenyl)biphenyl; (carbazolyl)(triphenylenyl)terbenzene; (triphenylenyl)(carbazolyl)terbenzene; (carbazolyl)[(triphenylenyl)phenyl]terbenzene; (phenylcarbazolyl)(triphenylenyl)terbenzene; (diphenylcarbazolyl)(triphenylenyl)terbenzene; (carbazolyl)[(triphenylenyl)phenyl]pyridine; (carbazolyl)[(triphenylenyl)phenyl]pyridine; (carbazolyl)[(triphenylenyl)phenyl]pyridine; (carbazolyl)[(triphenylenyl)phenyl]pyridine; [(carbazolyl)pyridinyl](triphenylenyl)biphenyl; [(carbazolyl)pyridinyl](triphenylenyl)biphenyl; [(carbazolyl)pyridinyl](triphenylenyl)biphenyl; [(carbazolyl)pyridinyl](triphenylenyl)biphenyl; [(carbazolyl)pyridinyl](triphenylenyl)terbenzene; (carbazolyl)phenyl[(triphenylenyl)phenyl]pyridine; (phenylcarbazolyl)[(triphenylenyl)phenyl]pyridine; (diphenylcarbazolyl)[(triphenylenyl)phenyl]pyridine; (carbazolyl)[(phenyltriphenylenyl)phenyl]pyridine; [(carbazolyl)pyridinyl](triphenylenyl)biphenyl; (carbazolyl)phenyl[(triphenylenyl)phenyl]pyridine; (triphenylenyl)[(carbazolyl)pyridinyl]terbenzene; [(phenylcarbazolyl)pyridinyl](triphenylenyl)biphenyl; [(diphenylcarbazolyl)pyridinyl](triphenylenyl)biphenyl; [(carbazolyl)phenyl][(triphenylenyl)phenyl]pyridine; [(carbazolyl)phenyl][(triphenylenyl)biphenylyl]pyridine; (carbazolyl)[(triphenylenyl)phenyl]pyrimidine; (carbazolyl)[(triphenylenyl)phenyl]pyrimidine; (carbazolyl)[(triphenylenyl)phenyl]pyrimidine; (carbazolyl)[(triphenylenyl)phenyl]pyridine; [(triphenylenyl)phenyl](carbazolyl)pyridine; [(triphenylenyl)phenyl](carbazolyl)pyridine; (carbazolyl)[(triphenylenyl)phenyl]pyridine; [(carbazolyl)pyridinyl](triphenylenyl)biphenyl; (carbazolyl)(phenyltriphenylenyl)biphenyl; (carbazolyl)(diphenyltriphenylenyl)biphenyl; [(carbazolyl)biphenylyl][(carbazolyl)phenyl]triphenylene; bis[(carbazolyl)biphenylyl]triphenylene; bis[(carbazolyl)biphenylyl]triphenylene; [(carbazolyl)biphenylyl][(carbazolyl)phenyl]triphenylene; (carbazolyl)[(triphenylenyl)phenyl]pyridine; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [di(biphenylyl)triazinyl]phenylindolocarbazole; [(biphenylyl)phenyltriazinyl](biphenylyl)indolocarbazole; [di(biphenylyl)triazinyl](biphenylyl)indolocarbazole; [(biphenylyl)phenyltriazinyl](terphenylyl)indolocarbazole; [di(biphenylyl)triazinyl](terphenylyl)indolocarbazole; [(biphenylyl)phenyltriazinyl]thiaazaindenofluorene; [di(biphenylyl)triazinyl]thiaazaindenofluorene; [bis(dimethylfluorenyl)triazinyl]phenylindolocarbazole; [(biphenylyl)phenyltriazinyl]oxaazaindenofluorene; [di(biphenylyl)triazinyl]oxaazaindenofluorene; [bis(dimethylfluorenyl)triazinyl]thiaazaindenofluorene; (diphenyltriazinyl)phenylindolocarbazole; (diphenyltriazinyl)(biphenylyl)indolocarbazole; [phenyl(biphenylyl)triazinyl]phenylindolocarbazole; [di(biphenylyl)triazinyl]phenylindolocarbazole; [phenyl(biphenylyl)triazinyl]thiaazaindenofluorene; [di(biphenylyl)triazinyl]thiaazaindenofluorene; [phenyl(biphenylyl)triazinyl]azaoxaindenofluorene; [di(biphenylyl)triazinyl]azaoxaindenofluorene; [bis(dimethylfluorenyl)triazinyl]thiaazaindenofluorene; [bis(dimethylfluorenyl)triazinyl]azaoxaindenofluorene; [bis(dimethylfluorenyl)triazinyl]phenylindolocarbazole; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [di(biphenylyl)triazinyl]phenylindolocarbazole; [di(biphenylyl)triazinyl](biphenylyl)indolocarbazole; [di(dimethylfluorenyl)triazinyl]phenylindolocarbazole; [(biphenylyl)phenyltriazinyl]thiaazaindenofluorene; [di(biphenylyl)triazinyl]thiaazaindenofluorene; [bis(dimethylfluorenyl)triazinyl]thiaazaindenofluorene; [(biphenylyl)phenyltriazinyl]oxaindenofluorene; [di(biphenylyl)triazinyl]azaoxaindenofluorene; [bis(dimethylfluorenyl)triazinyl]azaoxaindenofluorene; [(biphenylyl)phenyltriazinyl]dimethylindenocarbazole; [di(biphenylyl)triazinyl]dimethylindenocarbazole; [bis(dimethylfluorenyl)triazinyl]dimethylindenocarbazole; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [bis(dimethylfluorenyl)triazinyl]phenylindolocarbazole; [bis(dimethylfluorenyl)triazinyl](biphenylyl)indolocarbazole; [(biphenylyl)phenyltriazinyl]azathiaindenofluorene; [di(biphenylyl)triazinyl]azathiaindenofluorene; [bis(dimethylfluorenyl)triazinyl]azathiaindenofluorene; [(biphenylyl)phenyltriazinyl]azaoxaindenofluorene; [di(biphenylyl)triazinyl]azaoxaindenofluorene; [bis(dimethylfluorenyl)triazinyl]azaoxaindenofluorene; (biphenylyl)[(diphenyltriazinyl)phenyl]indolocarbazole; (terphenylyl)[(diphenyltriazinyl)phenyl]indolocarbazole; phenyl{[phenyl(biphenylyl)triazinyl]phenyl}indolocarbazole; phenyl{[di(biphenylyl)triazinyl]phenyl}indolocarbazole; phenyl{[bis(dimethylfluorenyl)triazinyl]phenyl}indolocarbazole; (biphenylyl){[(biphenylyl)phenyltriazinyl]phenyl}indolocarbazole; (biphenylyl){[di(biphenylyl)triazinyl]phenyl}indolocarbazole; (terphenylyl){[(biphenylyl)phenyltriazinyl]phenyl}indolocarbazole; [(diphenyltriazinyl)phenyl]thiaazaindenofluorene; {[phenyl(biphenylyl)triazinyl]phenyl}thiaazaindenofluorene; {[di(biphenylyl)triazinyl]phenyl}thiaazaindenofluorene; {[bis(dimethylfluorenyl)triazinyl]phenyl}thiaazaindenofluorene; [(diphenyltriazinyl)phenyl]oxaazaindenofluorene; {[phenyl(biphenylyl)triazinyl]phenyl}oxaazaindenofluorene; {[di(biphenylyl)triazinyl]phenyl}oxaazaindenofluorene; {[bis(dimethylfluorenyl)triazinyl]phenyl}oxaazaindenofluorene; [(phenylpyridinyl)phenyl](diphenyltriazinyl)indolocarbazole; (terphenylyl)(diphenyltriazinyl)indolocarbazole; (terphenylyl)[(biphenylyl)phenyltriazinyl]indolocarbazole; phenyl(diphenyltriazinyl)dimethyldiazadiindenofluorene; (biphenylyl)(diphenyltriazinyl)dimethyldiazaindenofluorene; (biphenylyl)[(biphenylyl)phenyltriazinyl]dimethyldiazaindenofluorene; tetramethyl[(biphenylyl)phenyltriazinyl]azadiindenofluorene; tetramethyl[di(biphenylyl)triazinyl]azadiindenofluorene; [(biphenylyl)phenyltriazinyl]azadithiadiindenofluorene; [di(biphenylyl)triazinyl]azadithiadiindenofluorene; [(biphenylyl)phenyltriazinyl]azadithiadiindenofluorene; [(biphenylyl)phenyltriazinyl]azadioxydiindenofluorene; [di(biphenylyl)triazinyl]azadithiadiindenofluorene; [di(biphenylyl)triazinyl]azadioxydiindenofluorene

### (Group 14A)

(biphenylyl)(diphenyltriazinyl)carbazole; iridium(III)bis[(dimethylphenyl)isobutylquinoline](acetylacetonate); phenyl(diphenyltriazinyl)indolocarbazole; iridium(III)bis(phenylmethyl-d₃pyridine)((diphenylmethyl-d₃)pyridine); (biphenylyl)(diphenyltriazinyl)carbazole; (terphenylyl)(diphenyltriazinyl)carbazole; triphenyl(diphenyltriazinyl)carbazole; (biphenylyl)[phenyl(biphenylyl)triazinyl]carbazole; diphenyl[phenyl(biphenylyl)triazinyl]carbazole; (biphenylyl)[(diphenyltriazinyl)phenyl]carbazole; phenyl[di(biphenylyl)triazinyl]carbazole; diphenyl[(diphenyltriazinyl)phenyl]carbazole; diphenyl[di(biphenylyl)triazinyl]carbazole; phenyl{[di(biphenylyl)triazinyl]phenyl}carbazole; di(biphenylyl)(diphenyltriazinyl)carbazole; (dimethylfluorenyl)(diphenyltriazinyl)carbazole; [(dimethylfluorenyl)phenyl](diphenyltriazinyl)carbazole; (dimethylfluorenyl)[phenyl(biphenylyl)triazinyl]carbazole; [(dimethylfluorenyl)phenyl][phenyl(biphenylyl)triazinyl]carbazole; (dimethylfluorenyl)[di(biphenylyl)triazinyl]carbazole; (phenylcarbazolyl)(diphenyltriazinyl)carbazole; (triphenylenyl)[phenyl(biphenylyl)triazinyl]carbazole; (phenylcarbazolyl)[phenyl(biphenylyl)triazinyl]carbazole; phenyl[phenyl(dimethylfluorenyl)triazinyl]carbazole; (triphenylenyl)(diphenyltriazinyl)carbazole; (biphenylyl)[phenyl(dimethylfluorenyl)triazinyl]carbazole; (terphenylyl)[phenyl(dimethylfluorenyl)triazinyl]carbazole; (quaterphenylyl)[phenyl(biphenylyl)triazinyl]carbazole; phenyl[(biphenylyl)(dimethylfluorenyl)triazinyl]carbazole; [(terphenylyl)phenyl](diphenyltriazinyl)carbazole; phenyl[bis(dimethylfluorenyl)triazinyl]carbazole; [(terphenylyl)phenyl][phenyl(biphenylyl)triazinyl]carbazole; (terphenylyl)(diphenyltriazinyl)carbazole; (biphenylyl)(diphenyltriazinyl)carbazole; (biphenylyl)[phenyl(biphenylyl)triazinyl]carbazole; (biphenylyl)[di(biphenylyl)triazinyl]carbazole; (terphenylyl)(diphenyltriazinyl)carbazole; (terphenylyl)(diphenyltriazinyl)carbazole; (biphenylyl)(diphenyltriazinyl)carbazole; (terphenylyl)[phenyl(biphenylyl)triazinyl]carbazole; (biphenylyl)[phenyl(biphenylyl)triazinyl]carbazole; (terphenylyl)[di(biphenylyl)triazinyl]carbazole; (terphenylyl)(diphenyltriazinyl)carbazole; (terphenylyl)[phenyl(biphenylyl)triazinyl]carbazole; (terphenylyl)[phenyl(biphenylyl)triazinyl]carbazole; phenyl[(biphenylyl)(biphenylyl)triazinyl]carbazole; phenyl[(biphenylyl)phenyltriazinyl]carbazole; (biphenylyl)[phenyl(biphenylyl)triazinyl]carbazole; (biphenylyl)[(biphenylyl)(biphenylyl)triazinyl]carbazole; phenyl[di(biphenylyl)triazinyl]carbazole; (biphenylyl)[phenyl(dimethylfluorenyl)triazinyl]carbazole; (dimethylfluorenyl)[(biphenylyl)phenyltriazinyl]carbazole; (biphenylyl){phenyl[(dimethylfluorenyl)phenyl]triazinyl}carbazole; [(dimethylfluorenyl)phenyl][phenyl(biphenylyl)triazinyl]carbazole; iridium(III)bis[(dimethylphenyl)quinoline](acetylacetonate); iridium(III)bis[(dimethylphenyl)quinoline](diethylnonanedionate); iridium(III)bis[(dimethylphenyl)quinoline](dimethylheptanedionate); iridium(III)bis[(dimethylphenyl)isobutylquinoline](dimethylheptanedionate); iridium(III)bis[(dimethylphenyl)quinoline](dimethylnonanedionate); iridium(III)bis[(dimethylphenyl)isobutylquinoline](dimethylnonanedionate); iridium(III)bis[(dimethylphenyl)isobutylquinoline](acetylacetonate); iridium(III)bis[(dimethylphenyl)isobutylquinoline](acetylacetonate); iridium(III)bis[(dimethylphenyl)isobutylquinoline](diethylnonanedionate); iridium(III)bis[(dimethylphenyl)isobutylquinoline](diethylnonanedionate); iridium(III)bis[(dimethylphenyl)isobutylquinoline](dimethylheptanedionate); iridium(III)bis[(dimethylphenyl)isobutylquinoline](diethylnonanedionate); iridium(III)bis[(dimethylphenyl)isobutylquinoline](dimethylnonanedionate); iridium(III)bis[(dimethylphenyl)isobutylquinoline](dimethylheptanedionate); iridium(III)bis[(dimethylphenyl)isobutylquinoline](acetylacetonate); iridium(III)bis[(dimethylphenyl)isobutylquinoline](dimethylnonanedionate); iridium(III)bis[(dimethylphenyl)cyclopentylquinoline](acetylacetonate); iridium(III)bis[(dimethylphenyl)cyclopentylquinoline](acetylacetonate); iridium(III)bis[(dimethylphenyl)cyclopentylquinoline](diethylnonanedionate); iridium(III)bis[(dimethylphenyl)cyclopentylquinoline](diethylnonanedionate); iridium(III)bis[(dimethylphenyl)cyclopentylquinoline](dimethylheptanedionate); iridium(III)bis[(dimethylphenyl)cyclopentylquinoline](dimethylheptanedionate); iridium(III)bis[(dimethylphenyl)cyclopentylquinoline](dimethylnonanedionate); iridium(III)bis[(dimethylphenyl)cyclopentylquinoline](dimethylnonanedionate); iridium(III)bis[(dimethylphenyl)cyclopentylquinoline](acetylacetonate); iridium(III)bis[(dimethylphenyl)cyclopentylquinoline](dimethylnonanedionate); iridium(III)bis[(dimethylphenyl)cyclopentylquinoline](diethylnonanedionate); iridium(III)bis[(dimethylphenyl)isopropylquinoline](acetylacetonate); iridium(III)bis[(dimethylphenyl)isopropylquinoline](diethylnonanedionate); iridium(III)bis[(dimethylphenyl)cyclopentylquinoline](dimethylheptanedionate); iridium(III)bis[(dimethylphenyl)isopropylquinoline](dimethylheptanedionate); iridium(III)bis[(dimethylphenyl)isopropylquinoline](dimethylnonanedionate); iridium(III)bis[(dimethylphenyl)isopropylquinoline](dimethylnonanedionate); iridium(III)bis[(dimethylphenyl)isopropylquinoline](acetylacetonate); iridium(III)bis[(dimethylphenyl)isopropylquinoline](acetylacetonate); iridium(III)bis[(dimethylphenyl)isopropylquinoline](diethylnonanedionate); iridium(III)bis[(dimethylphenyl)isopropylquinoline](diethylnonanedionate); iridium(III)bis[(dimethylphenyl)isopropylquinoline](diethylpentanedionate); iridium(III)bis[(dimethylphenyl)isopropylquinoline](diethylpentanedionate); iridium(III)bis[(dimethylphenyl)isopropylquinoline](diethylnonanedionate); iridium(III)bis(phenylpyridine)(diphenylpyridine); iridium(III)bis(phenylpyridine)[phenyl(methylphenyl)pyridine); iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(ethylfluorophenyl)pyridine]; iridium(III)bis(phenylpyridine)[phenyl(fluorophenyl)pyridine]; iridium(III)bis(phenylpyridine)[phenyl(isopropylfluorophenyl)pyridine]; iridium(III)bis(phenylpyridine)[phenyl(methylfluorophenyl)pyridine]; iridium(III)bis(phenylpyridine)[phenyl(isobutylfluorophenyl)pyridine]; iridium(III)bis(phenylpyridine)(diphenylpyridine); iridium(III)bis(phenylpyridine)[phenyl(isobutylphenyl)pyridine]; iridium(III)bis(phenylpyridine)[phenyl(methylphenyl)pyridine]; iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(isobutylphenyl)pyridine]; iridium(III)bis(phenylpyridine)[phenyl(isopropylfluorophenyl)pyridine]; iridium(III)bis(phenylpyridine)[phenyl(fluorophenyl)pyridine]; iridium(III)bis(phenylpyridine)[phenyl(isobutylfluorophenyl)pyridine]; iridium(III)bis(phenylpyridine)[phenyl(methylfluorophenyl)pyridine]; iridium(III)bis(phenylpyridine)[diphenylpyridine]; iridium(III)bis(phenylpyridine)[phenyl(ethylfluorophenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(methylfluorophenyl)pyridine]; iridium(III)bis(phenylmethylpyridine)[phenyl(isopropylphenyl)pyridine]; iridium(III)bis(phenylmethylpyridine)[phenyl(ethylfluorophenyl)pyridine]; iridium(III)bis(phenylmethylpyridine)[phenyl(fluorophenyl)pyridine]; iridium(III)bis(phenylmethylpyridine)[phenyl(isopropylfluorophenyl)pyridine]; iridium(III)bis(phenylmethylpyridine)[phenyl(isobutylfluorophenyl)pyridine]; iridium(III)bis(phenylmethylpyridine)[phenyl(isopropylphenyl)pyridine]; iridium(III)bis(phenylmethylpyridine)[diphenylpyridine]; iridium(III)bis(phenylmethylpyridine)[phenyl(isobutylphenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(isopropylphenyl)pyridine]; iridium(III)bis(phenylmethylpyridine)[phenyl(ethylfluorophenyl)pyridine]; iridium(III)bis(phenylmethylpyridine)[phenyl(isobutylphenyl)pyridine]; iridium(III)bis(phenylmethylpyridine)[phenyl(isopropylfluorophenyl)pyridine]; iridium(III)bis(phenylmethylpyridine)[phenyl(fluorophenyl)pyridine]; iridium(III)bis(phenylmethylpyridine)[phenyl(isobutylfluorophenyl)pyridine]; iridium(III)bis(phenylmethylpyridine)[phenyl(methylfluorophenyl)pyridine]; iridium(III)bis(phenylpyridine)[phenyl((methyl-d₃)phenyl)pyridine]; iridium(III)bis(phenylpyridine)[phenyl((ethyl-d₅)phenyl)pyridine]; iridium(III)bis(phenylpyridine)[phenyl((ethyl-d₅)fluorophenyl)pyridine]; iridium(III)bis(phenylpyridine)[phenyl((isopropyl-d₇)phenyl)pyridine]; iridium(III)bis(phenylpyridine)[phenyl((isopropyl-d₇)fluorophenyl)pyridine]; iridium(III)bis(phenylpyridine)[phenyl((methyl-d₃)fluorophenyl)pyridine]; iridium(III)bis(phenylpyridine)[phenyl((isobutyl-d₉)fluorophenyl)pyridine]; iridium(III)bis(phenylpyridine)[phenyl(dimethyl-d₆)phenyl)pyridine]; iridium(III)bis(phenylpyridine)[phenyl((isobutyl-d₉)phenyl)pyridine]; iridium(III)bis(phenylpyridine)[phenyl((methyl-d₃)phenyl)pyridine]; iridium(III)bis(phenylpyridine)[phenyl((ethyl-d₆)phenyl)pyridine]; iridium(III)bis(phenylpyridine)[phenyl((isopropyl-d₇)phenyl)pyridine]; iridium(III)bis(phenylpyridine)[phenyl((isobutyl-d₉)phenyl)pyridine]; iridium(III)bis(phenylpyridine)[phenyl((isobutyl-d₉)fluorophenyl)pyridine]; iridium(III)bis(phenylpyridine)[phenyl((methyl-d₃)fluorophenyl)pyridine]; iridium(III)bis(phenyl(methyl-d₃)pyridine)[diphenylpyridine]; iridium(III)bis(phenylpyridine)[phenyl((ethyl-d₅)fluorophenyl)pyridine]; iridium(III)bis(phenyl(methyl-d₃)pyridine)[phenyl((methyl-d₃)phenyl)pyridine]; iridium(III)bis(phenylpyridine)[phenyl((isopropyl-d₇)fluorophenyl)pyridine]; iridium(III)bis(phenyl(methyl-d₃)pyridine)[phenyl((ethyl-d₅)phenyl)pyridine]; iridium(III)bis(phenyl(methyl-d₃)pyridine)[phenyl((isopropyl-d₇)phenyl)pyridine]; iridium(III)bis(phenyl(methyl-d₃)pyridine)[phenyl((isopropyl-d₇)fluorophenyl)pyridine]; iridium(III)bis(phenyl(methyl-d₃)pyridine)[phenyl((methyl-d₃)fluorophenyl)pyridine]; iridium(III)bis(phenyl(methyl-d₃)pyridine)[phenyl((isobutyl-d₉)fluorophenyl)pyridine]; iridium(III)bis(phenyl(methyl-d₃)pyridine)[phenyl((ethyl-d₅)fluorophenyl)pyridine]; iridium(III)bis(phenyl(methyl-d₃)pyridine)[phenyl(fluorophenyl)pyridine]; iridium(III)bis(phenyl(methyl-d₃)pyridine)[diphenylpyridine]; iridium(III)bis(phenyl(methyl-d₃)pyridine)[phenyl((isobutyl-d₉)phenyl)pyridine]; iridium(III)bis(phenyl(methyl-d₃)pyridine)[phenyl((methyl-d₃)phenyl)pyridine]; iridium(III)bis(phenyl(methyl-d₃)pyridine)[phenyl((ethyl-d₅)phenyl)pyridine]; iridium(III)bis(phenyl(methyl-d₃)pyridine)[phenyl((isopropyl-d₇)phenyl)pyridine]; iridium(III)bis(phenyl(methyl-d₃)pyridine)[phenyl((isobutyl-d₉)phenyl)pyridine]; iridium(III)bis(phenyl(methyl-d₃)pyridine)[phenyl((isopropyl-d₇)fluorophenyl)pyridine]; iridium(III)bis(phenyl(methyl-d₃)pyridine)[phenyl(fluorophenyl)pyridine]; iridium(III)bis(phenyl(methyl-d₃)pyridine)[phenyl((isobutyl-d₉)fluorophenyl)pyridine]; iridium(III)bis(phenyl(methyl-d₃)pyridine)[phenyl((methyl-d₃)fluorophenyl)pyridine]; iridium(III)bis(phenylpyridine)[phenylbipyridine]; iridium(III)bis(phenyl(methyl-d₃)pyridine)[phenyl((ethyl-d₅)fluorophenyl)pyridine]; iridium(III)bis(phenylpyridine)[phenylbipyridine]; iridium(III)bis(phenylpyridine)[phenylbipyridine]; iridium(III)bis(phenylpyridine)[isobutylphenylbipyridine]; iridium(III)bis(phenylpyridine)[methylphenylbipyridine]; iridium(III)bis(phenylpyridine)[(phenylpyridinyl)pyrimidine]; iridium(III)bis(phenylpyridine)[ethylphenylbipyrdine]; iridium(III)bis(phenylpyridine)[(phenylpyridinyl)pyrazine]; iridium(III)bis(phenylpyridine)[isopropylphenylbipyridine]; iridium(III)bis(phenylpyridine)[(phenylpyridinyl)pyrimidine]; iridium(III)bis(phenylpyridine)[(phenylpyridinyl)pyrimidine]; iridium(III)bis(phenylpyridine)[(phenylpyridinyl)dimethyltriazine]; iridium(III)bis(phenylpyridine)[(phenylpyridinyl)triazine]; iridium(III)bis(phenylpyridine)[phenylbipyridine]; iridium(III)bis(phenylpyridine)[methyl(phenylpyridinyl)pyrimidine]; iridium(III)bis(phenylpyridine)[phenylbipyridine]; iridium(III)bis(phenylpyridine)[methyl(phenylpyridinyl)pyrimidine]; iridium(III)bis(phenylpyridine)[phenylbipyridine]; iridium(III)bis(phenylpyridine)[methylphenylbipyridine]; iridium(III)bis(phenylpyridine)[(phenylpyridinyl)pyrimidine]; iridium(III)bis(phenylpyridine)[ethylphenylbipyridine]; iridium(III)bis(phenylpyridine)[(phenylpyridinyl)pyrazine]; iridium(III)bis(phenylpyridine)[isopropylphenylbipyridine]; iridium(III)bis(phenylpyridine)[(phenylpyridinyl)pyrimidine]; iridium(III)bis(phenylpyridine)[isobutylphenylbipyridine]; iridium(III)bis(phenylpyridine)[(phenylpyridinyl)pyrimidine]; iridium(III)bis(phenylpyridine)[(phenylpyridinyl)triazine]; iridium(III)bis(phenylpyridine)[(methyl-d₃)phenylbipyridine]; iridium(III)bis(phenylpyridine)[methyl(phenylpyridinyl)pyrimidine]; iridium(III)bis(phenylpyridine)[(ethyl-d₅)phenylbipyridine]; iridium(III)bis(phenylpyridine)[methyl(phenylpyridinyl)pyrimidine]; iridium(III)bis(phenylpyridine)[dimethyl(phenylpyridinyl)triazine]; iridium(III)bis(phenylpyridine)[(isopropyl-d₇)phenylbipyridine]; iridium(III)bis(phenylpyridine)[(isobutyl-d₉)phenylbipyridine]; iridium(III)bis(phenylpyridine)[(dimethyl-d₆)(phenylpyridinyl)triazine]; iridium(III)bis(phenylpyridine)[(methyl-d₃)(phenylpyridinyl)pyrimidine]; iridium(III)bis(phenylpyridine)[(methyl-d₃)phenylbipyridine]; iridium(III)bis(phenylpyridine)[(ethyl-d₅)phenylbipyridine]; iridium(III)bis(phenylpyridine)[(methyl-d₃)(phenylpyridinyl)pyrimidine]; iridium(III)bis(phenylpyridine)[(isopropyl-d₇)phenylbipyridine]; iridium(III)bis(phenylpyridine)[(isobutyl-d₅)phenylbipyridine]; iridium(III)bis(phenylmethylpyridine)(phenylbipyridine); iridium(III)bis(phenylpyridine)[(methyl-d₃)(phenylpyridinyl)pyrimidine]; iridium(III)bis(phenylmethylpyridine)(phenylbipyridine); iridium(III)bis(phenylpyridine)[(methyl-d₃)(phenylpyridinyl)pyrimidine]; iridium(III)bis(phenylmethylpyridine)(phenylbipyridine); iridium(III)bis(phenylpyridine)[(dimethyl-d₆)(phenylpyridinyl)triazine]; iridium(III)bis(phenylmethylpyridine)(methylphenylbipyridine); iridium(III)bis(phenylmethylpyridine)(ethylphenylbipyridine); iridium(III)bis(phenylmethylpyridine)[(phenylpyridinyl)pyrimidine]; iridium(III)bis(phenylmethylpyridine)(isopropylphenylbipyridine); iridium(III)bis(phenylmethylpyridine)[(phenylpyridinyl)pyrazine]; iridium(III)bis(phenylmethylpyridine)[(phenylpyridinyl)pyrimidine]; iridium(III)bis(phenylmethylpyridine)(isobutylphenylbipyridine); iridium(III)bis(phenylmethylpyridine)[(phenylpyridinyl)pyrimidine]; iridium(III)bis(phenylmethylpyridine)[(phenylpyridinyl)triazine]; iridium(III)bis(phenylmethylpyridine)(phenylbipyridine); iridium(III)bis(phenylmethylpyridine)[methyl(phenylpyridinyl)pyrimidine]; iridium(III)bis(phenylmethylpyridine)(phenylbipyridine); iridium(III)bis(phenylmethylpyridine)[methyl(phenylpyridinyl)pyrimidine]; iridium(III)bis(phenylmethylpyridine)(phenylbipyridine); iridium(III)bis(phenylpyridine)[dimethyl(phenylpyridinyl)triazine]; iridium(III)bis(phenylmethylpyridine)(methylphenylbipyridine); iridium(III)bis(phenylmethylpyridine)(ethylphenylbipyridine); iridium(III)bis(phenylmethylpyridine)[(phenylpyridinyl)pyrazine]; iridium(III)bis(phenylmethylpyridine)(isopropylphenylbipyridine); iridium(III)bis(phenylmethylpyridine)[(phenylpyridinyl)pyrimidine]; iridium(III)bis(phenylmethylpyridine)(isobutylphenylbipyridine); iridium(III)bis(phenylmethylpyridine)[(phenylpyridinyl)pyrimidine]; iridium(III)bis(phenylmethylpyridine)[(phenylpyridinyl)pyrimidine]; iridium(III)bis(phenylmethylpyridine)[(phenylpyridinyl)triazine]; iridium(III)bis(phenylmethylpyridine)[methyl(phenylpyridinyl)pyrimidine]; iridium(III)bis(phenylmethylpyridine)[(methyl-d₃)phenylbipyridine]; iridium(III)bis(phenylmethylpyridine)[methyl(phenylpyridinyl)pyrimidine]; iridium(III)bis(phenyl(methyl-d₃)pyridine)[(ethyl-d₅)phenylbipyridine]; iridium(III)bis(phenylmethylpyridine)[dimethyl(phenylpyridinyl)triazine]; iridium(III)bis[phenyl(methyl-d₃)pyridine][phenylbipyridine]; iridium(III)bis[phenyl(methyl-d₃)pyridine][(isopropyl-d₇)phenylbipyridine]; iridium(III)bis[phenyl(methyl-d₃)pyridine][(isobutyl-d₉)phenylbipyridine]; iridium(III)bis(phenyl(methyl-d₃)pyridine)[(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(phenylpyridinyl)triazine]; iridium(III)bis(phenyl(methyl-d₃)pyridine)[(phenylpyridinyl)pyrazine]; iridium(III)bis(phenyl(methyl-d₃)pyridine)[(methyl-d₃)(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(methyl-d₃)(phenylpyridinyl)pyrimidine]; iridium(III)bis(phenyl(methyl-d₃)pyridine)[(dimethyl-d₆)(phenylpyridinyl)triazine]; iridium(III)bis[phenyl(methyl-d₃)pyridine][(isopropyl-d₉)phenylbipyridine]; iridium(III)bis[phenyl(methyl-d₃)pyridine][phenylbipyridine]; iridium(III)bis[phenyl(methyl-d₃)pyridine][(isobutyl-d₉)phenylbipyridine]; iridium(III)bis[phenyl(methyl-d₃)pyridine][(methyl-d₃)phenylbipyridine]; iridium(III)bis(phenyl(methyl-d₃)pyridine)[(phenylpyridinyl)pyrimidine]; iridium(III)bis[phenyl(methyl-d₃)pyridine][(ethyl-d₇)phenylbipyridine]; iridium(III)bis(phenyl(methyl-d₃)pyridine)[(phenylpyridinyl)pyrazine]; iridium(III)bis(phenyl(methyl-d₃)pyridine)[(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(phenylpyridinyl)triazine]; iridium(III)bis(phenyl(methyl-d₃)pyridine)[(methyl-d₃)(phenylpyridinyl)pyrimidine]; iridium(III)bis(phenyl(methyl-d₃)pyridine)[(methyl-d₃)(phenylpyridinyl)pyrimidine]; iridium(III)bis(phenyl(methyl-d₃)pyridine)[(dimethyl-d₆)(phenylpyridinyl)triazine]; (biphenylyl)(diphenyltriazinyl)indolocarbazole; phenyl[(biphenylyl)phenyltriazinyl]indolocarbazole; [(biphenylyl)phenyltriazinyl]oxaazaindenofluorene; [(biphenylyl)phenyltriazinyl]thiaazaindenofluorene; [(dimethylfluorenyl)phenyltriazinyl]thiaazaindenofluorene; [diphenyltriazinyl]thiaazaindenofluorene; phenyl[(dimethylfluorenyl)phenyltriazinyl]indolocarbazole; phenyl(dimethyltriazinyl)indolocarbazole; phenyl[phenyl(terphenylyl)triazinyl]indolocarbazole; (diphenyltriazinyl)azaoxaindenofluorene; [(biphenylyl)phenyltriazinyl)azaoxaindenofluorene; (diphenyltriazinyl)thiaazaindenofluorene; [(dimethylfluorenyl)phenyltriazinyl]thiaazaindenofluorene; [(biphenylyl)phenyltriazinyl]thiaazaindenofluorene; [(dimethylfluorenyl)phenyltriazinyl]azaoxaindenofluorene; phenyl[(dimethylfluorenyl)phenyltriazinyl]indolocarbazole; phenyl[(biphenylyl)phenyltriazinyl]indolocarbazole; phenyl(diphenyltriazinyl)indolocarbazole; phenyl[(dimethylfluorenyl)phenyltriazinyl]indolocarbazole; (biphenylyl)(diphenyltriazinyl)indolocarbazole; (diphenyltriazinyl)thiaazaindenofluorene; [(biphenylyl)phenyltriazinyl]thiaazaindenofluorene; [(biphenylyl)phenyltriazinyl]azaoxaindenofluorene; [(dimethylfluorenyl)phenyltriazinyl]thiaazaindenofluorene; [(dimethylfluorenyl)phenyltriazinyl]azaoxaindenofluorene; (diphenyltriazinyl)azaoxaindenofluorene; (diphenyltriazinyl)dimethylazaindenofluorene; [(biphenylyl)phenyltriazinyl]dimethylazaindenofluorene; (diphenyltriazinyl)phenylindolocarbazole; [(dimethylfluorenyl)phenyltriazinyl]dimethylazaindenofluorene; [(biphenylyl)phenyltriazinyl]phenylindolocarbazole; (diphenyltriazinyl)phenylindolocarbazole; (dimethylfluorenyl)phenylindolocarbazole; (diphenyltriazinyl)azathiaindenofluorene; (diphenyltriazinyl)azaoxaindenofluorene; [(biphenylyl)phenyltriazinyl]azathiaindenofluorene; [(biphenylyl)phenyltriazinyl]azaoxaindenofluorene; [(dimethylfluorenyl)phenyltriazinyl]azathiaindenofluorene; [(dimethylfluorenyl)phenyltriazinyl]azaoxaindenofluorene; phenyl(diphenyltriazinyl)indolocarbazole; [(biphenylyl)phenyltriazinyl]azathiaindenofluorene; phenyl[(biphenylyl)phenyltriazinyl]indolocarbazole; [(dimethylfluorenyl)phenyltriazinyl]azathiaindenofluorene; phenyl[(dimethylfluorenyl)phenyltriazinyl]indolocarbazole; (diphenyltriazinyl)azathiaindenofluorene; (diphenyltriazinyl)azathiaindenofluorene; [(biphenylyl)phenyltriazinyl]azaoxaindenofluorene; [(dimethylfluorenyl)phenyltriazinyl]azaoxaindenofluorene; [(diphenyltriazinyl)phenyl]thiaazaindenofluorene; phenyl[(diphenyltriazinyl)phenyl]indolocarbazole; [(diphenyltriazinyl)phenyl]oxaazaindenofluorene; phenyl{[(dimethylfluorenyl)phenyltriazinyl]phenyl}indolocarbazole; phenyl[(diphenyltriazinyl)phenyl]dimethyldiazaindenofluorene; iridium(III)bis(phenylpyridine)(diphenylmethylpyridine); iridium(III)bis(phenylpyridine)(diphenylethylpyridine); iridium(III)bis(phenylpyridine)(diphenylisopropylpyridine); iridium(III)bis(phenylpyridine)[phenylmethyl(fluorophenyl)pyridine]; iridium(III)bis(phenylpyridine)[phenylethyl(fluorophenyl)pyridine]; iridium(III)bis(phenylpyridine)[phenylisopropyl(fluorophenyl)pyridine]; iridium(III)bis(phenylpyridine)[phenyl(methylphenyl)pyridine]; iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(methylfluorophenyl)pyridine]; iridium(III)bis(phenylmethylpyridine)(diphenylmethylpyridine); iridium(III)bis(phenylmethylpyridine)(diphenylethylpyridine); iridium(III)bis(phenylmethylpyridine)(diphenylisopropylpyridine); iridium(III)bis(phenylmethylpyridine)[phenylmethyl(fluorophenyl)pyridine]; iridium(III)bis(phenylmethylpyridine)[phenylethyl(fluorophenyl)pyridine]; iridium(III)bis(phenylmethylpyridine)[phenylisopropyl(fluorophenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(isopropylphenyl)pyridine]; iridium(III)bis(phenylmethylpyridine)[phenyl(methylfluorophenyl)pyridine]; iridium(III)bis(phenylmethylpyridine)[diphenyl(methyl-d₃)pyridine]; iridium(III)bis(phenylpyridine)[diphenyl(ethyl-d₅)pyridine]; iridium(III)bis(phenylpyridine)[diphenyl(isopropyl-d₇)pyridine]; iridium(III)bis(phenylpyridine)[phenyl(methyl-d₃)(fluorophenyl)pyridine]; iridium(III)bis(phenylpyridine)[phenyl(ethyl-d₅)(fluorophenyl)pyridine]; iridium(III)bis(phenylpyridine)[phenyl(isopropyl-d₇)(fluorophenyl)pyridine]; iridium(III)bis(phenylpyridine){phenyl[(methyl-d₃)phenyl]pyridine}; iridium(III)bis(phenylpyridine){phenyl[(ethyl-d₅)phenyl]pyridine}; iridium(III)bis(phenylpyridine){phenyl[(isopropyl-d₇)phenyl]pyridine}; iridium(III)bis(phenylpyridine){phenyl[(methyl-d₃)fluorophenyl]pyridine}; iridium(III)bis[phenyl(methyl-d₃)pyridine][diphenyl(methyl-d₃)pyridine]; iridium(III)bis[phenyl(methyl-d₃)pyridine][diphenyl(ethyl-d₅)pyridine]; iridium(III)bis[phenyl(methyl-d₃)pyridine][diphenyl(isopropyl-d₇)pyridine]; iridium(III)bis[phenyl(methyl-d₃)pyridine][phenyl(methyl-d₃)(fluorophenyl)pyridine]; iridium(III)bis[phenyl(methyl-d₃)pyridine][phenyl(ethyl-d₅)(fluorophenyl)pyridine]; iridium(III)bis[phenyl(methyl-d₃)pyridine][phenyl(isopropyl-d₇)(fluorophenyl)pyridine]; iridium(III)bis[phenyl(methyl-d₃)pyridine]{phenyl[(methyl-d₃)phenyl]pyridine}; iridium(III)bis[phenyl(methyl-d₃)pyridine]{phenyl[(ethyl-d₅)phenyl]pyridine}; iridium(III)bis[phenyl(methyl-d₃)pyridine]{phenyl[(isopropyl-d₇)phenyl]pyridine}; iridium(III)bis[phenyl(methyl-d₃)pyridine]{phenyl[(methyl-d₃)fluorophenyl]pyridine}

### (Group 15A)

(diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (diphenyltriazinyl)[(biphenylyl)dibenzofuranyl]biphenyl; (diphenyltriazinyl)[(biphenylyl)dibenzoselenophenyl]biphenyl; (diphenyltriazinyl)[(biphenylyl)dibenzoselenophenyl]biphenyl; (diphenyltriazinyl)(phenyldibenzofuranyl)terbenzene; (diphenyltriazinyl)(phenyldibenzothiophenyl)terbenzene; (diphenyltriazinyl)(phenyldibenzoselenophenyl)terbenzene; (diphenyltriazinyl)(phenyldibenzofuranyl)terbenzene; (diphenyltriazinyl)(phenyldibenzothiophenyl)terbenzene; (diphenyltriazinyl)(phenyldibenzoselenophenyl)terbenzene; (diphenyltriazinyl)[(biphenylyl)dibenzofuranyl]terbenzene; (diphenyltriazinyl)[(biphenylyl)dibenzothiophenyl]terbenzene; (diphenyltriazinyl)[(biphenylyl)dibenzoselenophenyl]terbenzene; [(biphenylyl)phenyltriazinyl](dibenzofuranyl)biphenyl; [(biphenylyl)phenyltriazinyl](dibenzothiophenyl)biphenyl; [(biphenylyl)phenyltriazinyl](dibenzoselenophenyl)biphenyl; [(biphenylyl)phenyltriazinyl](dibenzofuranyl)biphenyl; [(biphenylyl)phenyltriazinyl](dibenzothiophenyl)biphenyl; [(biphenylyl)phenyltriazinyl](dibenzoselenophenyl)biphenyl; [di(biphenylyl)triazinyl](dibenzofuranyl)biphenyl; [di(biphenylyl)triazinyl](dibenzothiophenyl)biphenyl; [di(biphenylyl)triazinyl](dibenzoselenophenyl)biphenyl; [(dimethylfluorenyl)phenyltriazinyl](dibenzofuranyl)biphenyl; [(dimethylfluorenyl)phenyltriazinyl](dibenzothiophenyl)biphenyl; [(dimethylfluorenyl)phenyltriazinyl](dibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(dimethylfluorenyl)phenyltriazinyl](phenyldibenzofuranyl)biphenyl; [(dimethylfluorenyl)phenyltriazinyl](phenyldibenzofuranyl)biphenyl; [(dimethylfluorenyl)phenyltriazinyl](phenyldibenzofuranyl)biphenyl; [(biphenylyl)phenyltriazinyl](dibenzofuranyl)terbenzene; [(biphenylyl)phenyltriazinyl](dibenzothiophenyl)terbenzene; [(biphenylyl)phenyltriazinyl](dibenzoselenophenyl)terbenzene; [(biphenylyl)phenyltriazinyl](dibenzofuranyl)terbenzene; [(biphenylyl)phenyltriazinyl](dibenzothiophenyl)terbenzene; [(biphenylyl)phenyltriazinyl](dibenzoselenophenyl)terbenzene; [(dimethylfluorenyl)phenyltriazinyl](dibenzofuranyl)terbenzene; [(dimethylfluorenyl)phenyltriazinyl](dibenzofuranyl)terbenzene; [(dimethylfluorenyl)phenyltriazinyl](dibenzofuranyl)terbenzene; [(biphenylyl)phenyltriazinyl][(biphenylyl)dibenzofuranyl]biphenyl; [(biphenylyl)phenyltriazinyl][(biphenylyl)dibenzothiophenyl]biphenyl; [(biphenylyl)phenyltriazinyl][(biphenylyl)dibenzoselenophenyl]biphenyl; [(biphenylyl)phenyltriazinyl][(biphenylyl)dibenzofuranyl]biphenyl; [(biphenylyl)phenyltriazinyl][(biphenylyl)dibenzothiophenyl]biphenyl; [(biphenylyl)phenyltriazinyl][(biphenylyl)dibenzoselenophenyl]biphenyl; [(dimethylfluorenyl)phenyltriazinyl][(biphenylyl)dibenzofuranyl]biphenyl; [(dimethylfluorenyl)phenyltriazinyl][(biphenylyl)dibenzothiophenyl]biphenyl; [(dimethylfluorenyl)phenyltriazinyl][(biphenylyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (diphenyltriazinyl)(dibenzoselenophenyl)terbenzene; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(diphenyldibenzofuranyl)biphenyl; (diphenyltriazinyl)(diphenyldibenzothiopheny)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(pyridinyl)(phenyldibenzofuranyl)benzene; (diphenyltriazinyl)(pyridinyl)(phenyldibenzothiophenyl)benzene; (diphenyltriazinyl)(pyridinyl)(phenyldibenzoselenophenyl)benzene; (diphenyltriazinyl)(pyridinyl)(phenyldibenzofuranyl)benzene; (diphenyltriazinyl)(pyridinyl)(phenyldibenzothiophenyl)benzene; (diphenyltriazinyl)(pyridinyl)(phenyldibenzoselenophenyl)benzene; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)[spiro(cyclopentanefluorenyl)]biphenyl; (diphenyltriazinyl)(dimethylfluorenyl)terbenzene; (diphenyltriazinyl)(diphenylfluorenyl)biphenyl; [(diphenylyl)phenyltriazinyl](dimethylfluorenyl)biphenyl; [(dimethylfluorenyl)phenyltriazinyl](dimethylfluorenyl)terbenzene; (diphenyltriazinyl)di(dimethylfluorenyl)benzene; (diphenyltriazinyl)(dimethylfluorenyl)terbenzene; (diphenyltriazinyl)phenyldibenzofuran; (diphenyltriazinyl)phenyldibenzothiophene; (diphenyltriazinyl)phenyldibenzoselenophene; [(biphenylyl)phenyltriazinyl]phenyldibenzofuran; [(biphenylyl)phenyltriazinyl]phenyldibenzothiophene; [(biphenylyl)phenyltriazinyl]phenyldibenzoselenophene; [(biphenylyl)phenyltriazinyl]phenyldibenzofuran; [(biphenylyl)phenyltriazinyl]phenyldibenzothiophene; [(biphenylyl)phenyltriazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [(biphenylyl)phenyltriazinyl](phenyldibenzofuranyl)benzene; [(biphenylyl)phenyltriazinyl](phenyldibenzothiophenyl)benzene; [(biphenylyl)phenyltriazinyl](phenyldibenzoselenophenyl)benzene; [(biphenylyl)phenyltriazinyl](phenyldibenzofuranyl)benzene; [(biphenylyl)phenyltriazinyl](phenyldibenzothiophenyl)benzene; [(biphenylyl)phenyltriazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; (biphenylyl)(dimethylfluorenyl)(phenyldibenzofuranyl)triazine; (biphenylyl)(dimethylfluorenyl)(phenyldibenzothiophenyl)triazine; (biphenylyl)(dimethylfluorenyl)(phenyldibenzoselenophenyl)triazine; (biphenylyl)(dimethylfluorenyl)(phenyldibenzofuranyl)triazine; (biphenylyl)(dimethylfluorenyl)(phenyldibenzothiophenyl)triazine; (biphenylyl)(dimethylfluorenyl)(phenyldibenzoselenophenyl)triazine; phenyl(dimethylfluorenyl)[(phenyldibenzofuranyl)phenyl]triazine; phenyl(dimethylfluorenyl)[(phenyldibenzothiophenyl)phenyl]triazine; phenyl(dimethylfluorenyl)[(phenyldibenzoselenophenyl)phenyl]triazine; bis(dimethylfluorenyl)[(phenyldibenzofuranyl)phenyl]triazine; bis(dimethylfluorenyl)[(phenyldibenzothiophenyl)phenyl]triazine; bis(dimethylfluorenyl)[(phenyldibenzoselenophenyl)phenyl]triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzoselenophenyl](dimethylfluorenyl)triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzoselenophenyl](dimethylfluorenyl)triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl[(dimethylfluorenyl)phenyl](phenyldibenzofuranyl)triazine; phenyl[(dimethylfluorenyl)phenyl](phenyldibenzothiophenyl)triazine; phenyl[(dimethylfluorenyl)phenyl](phenyldibenzoselenophenyl)triazine; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzofuranyl](dimethylfluorenyl)triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl[(dimethylfluorenyl)phenyl](phenyldibenzofuranyl)triazine; phenyl[(dimethylfluorenyl)phenyl](phenyldibenzothiophenyl)triazine; phenyl[(dimethylfluorenyl)phenyl](phenyldibenzoselenophenyl)triazine; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (diphenyltriazinyl)phenyldibenzofuran; (diphenyltriazinyl)phenyldibenzothiophene; (diphenyltriazinyl)phenyldibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; [(diphenyltriazinyl)phenyl](biphenylyl)dibenzofuran; [(diphenyltriazinyl)phenyl](biphenylyl)dibenzothiophene; [(diphenyltriazinyl)phenyl](biphenylyl)dibenzoselenophene; [(diphenyltriazinyl)phenyl](biphenylyl)dibenzofuran; [(diphenyltriazinyl)phenyl](biphenylyl)dibenzothiophene; [(diphenyltriazinyl)phenyl](biphenylyl)dibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; {[phenyl(phenylpyridinyl)triazinyl]phenyl}phenyldibenzofuran; {[phenyl(phenylpyridinyl)triazinyl]phenyl}phenyldibenzothiophene; {[phenyl(phenylpyridinyl)triazinyl]phenyl}phenyldibenzoselenophene; (diphenyltriazinyl)[(biphenylyl)dibenzofuranyl]pyridine; (diphenyltriazinyl)[(biphenylyl)dibenzothiophenyl]pyridine; (diphenyltriazinyl)[(biphenylyl)dibenzoselenophenyl]pyridine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenyldibenzoselenophenyl)triazine; (biphenylyl)(dimethylindenopyridinyl)(phenyldibenzofuranyl)triazine; (biphenylyl)(dimethylindenopyridinyl)(phenyldibenzothiophenyl)triazine; (biphenylyl)(dimethylindenopyridinyl)(phenyldibenzoselenophenyl)triazine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenyldibenzoselenophenyl)triazine; phenyl(spiro[cyclohexanefluorene]yl)(phenyldibenzofuranyl)triazine; phenyl(spiro[cyclohexanefluorene]yl)(phenyldibenzothiophenyl)triazine; phenyl(spiro[cyclohexanefluorene]yl)(phenyldibenzoselenophenyl)triazine; phenyl(spirobi[fluorene]yl)(phenyldibenzofuranyl)triazine; phenyl(spirobi[fluorene]yl)(phenyldibenzothiophenyl)triazine; phenyl(spirobi[fluorene]yl)(phenyldibenzoselenophenyl)triazine; (diphenyl-d₁₀)[(phenyldibenzofuranyl)phenyl-d₁₄]triazine; (diphenyl-d₁₀)[(phenyldibenzothiophenyl)phenyl-d₁₄]triazine; (diphenyl-d₁₀)[(phenyldibenzoselenophenyl)phenyl-d₁₄]triazine(diphenyl-d₁₀){[(biphenylyl)dibenzofuranyl]phenyl-d₁₈}triazine; (diphenyl-d₁₀){[(biphenylyl)dibenzothiophenyl]phenyl-d₁₈}triazine; (diphenyl-d₁₀){[(biphenylyl)dibenzoselenophenyl]phenyl-d₁₈}triazinephenyl[(dimethyl-d₆)fluorenyl](phenyldibenzofuranyl)triazine; phenyl[(dimethyl-d₆)fluorenyl](phenyldibenzothiophenyl)triazine; phenyl[(dimethyl-d₆)fluorenyl](phenyldibenzoselenophenyl)triazine; (diphenyl-d₁₀){[(biphenylyl)dibenzofuranyl]phenyl-d₁₈}triazine; (diphenyl-d₁₀){[(biphenylyl)dibenzothiophenyl]phenyl-d₁₈}triazine; (diphenyl-d₁₀){[(biphenylyl)dibenzoselenophenyl]phenyl-d₁₈}triazine(diphenyl-d₁₀){[(biphenylyl)dibenzofuranyl]phenyl}triazine; (diphenyl-d₁₀){[(biphenylyl)dibenzothiophenyl]phenyl}triazine; (diphenyl-d₁₀){[(biphenylyl)dibenzoselenophenyl]phenyl}triazine; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; [di(fluorophenyl)triazinyl][(biphenylyl)dibenzofuranyl]phenyl; [di(fluorophenyl)triazinyl][(biphenylyl)dibenzothiophenyl]phenyl; [di(fluorophenyl)triazinyl][(biphenylyl)dibenzoselenophenyl]phenyl; (dibenzothiophenyl)(diphenyltriazinyl)biphenyl; (diphenyltriazinyl)(dibenzothiophenyl)biphenyl; (diphenyltriazinyl)(dibenzothiophenyl)biphenyl; (dibenzofuranyl)triphenylene; (dibenzothiophenyl)triphenylene; (dibenzoselenophenyl)triphenylene; (dibenzofuranyl)(triphenylenyl)benzene; (dibenzothiophenyl)(triphenylenyl)benzene; (dibenzoselenophenyl)(triphenylenyl)benzene; (phenyldibenzofuranyl)(triphenylenyl)benzene; (phenyldibenzothiophenyl)(triphenylenyl)benzene; (phenyldibenzoselenophenyl)(triphenylenyl)benzene; (dibenzofuranyl)(triphenylenyl)biphenyl; (dibenzothiophenyl)(triphenylenyl)biphenyl; (dibenzoselenophenyl)(triphenylenyl)biphenyl; phenyl(triphenylenyl)dibenzofuran; phenyl(triphenylenyl)dibenzothiophene; phenyl(triphenylenyl)dibenzoselenophene; (biphenylyl)(triphenylenyl)dibenzofuran; (biphenylyl)(triphenylenyl)dibenzothiophene; (biphenylyl)(triphenylenyl)dibenzoselenophene; (terbenzenyl)(triphenylenyl)dibenzofuran; (terbenzenyl)(triphenylenyl)dibenzothiophene; (terbenzenyl)(triphenylenyl)dibenzoselenophene; (biphenylyl)[(triphenylenyl)phenyl]dibenzofuran; (biphenylyl)[(triphenylenyl)phenyl]dibenzothiophene; (biphenylyl)[(triphenylenyl)phenyl]dibenzoselenophene; (carbazolyl)(triphenylenyl)dibenzofuran; (carbazolyl)(triphenylenyl)dibenzothiophene; (carbazolyl)(triphenylenyl)dibenzoselenophene; (carbazolyl)(triphenylenyl)biphenyl; (triphenylenyl)(carbazolyl)biphenyl; (carbazolyl)[(triphenylenyl)phenyl]pyridine; tri(terbenzenyl)triazine; di(terbenzenyl)(biphenylyl)triazine; di(terbenzenyl)(biphenylyl)triazine; di(terbenzenyl)(dimethylfluorenyl)triazine; (dimethylfluorenyl)(terbenzenyl)(biphenylyl)triazine; phenyl(dibenzofuranyl)(terbenzenyl)triazine; phenyl(dibenzothiophenyl)(terbenzenyl)triazine; phenyl(dibenzoselenophenyl)(terbenzenyl)triazine; (biphenylyl)(dibenzofuranyl)(terbenzenyl)triazine; (biphenylyl)(dibenzothiophenyl)(terbenzenyl)triazine; (biphenylyl)(dibenzoselenophenyl)(terbenzenyl)triazine; (dibenzofuranyl)(dimethylfluorenyl)(terbenzenyl)triazine; (dibenzothiophenyl)(dimethylfluorenyl)(terbenzenyl)triazine; (dibenzoselenophenyl)(dimethylfluorenyl)(terbenzenyl)triazine; [(carbazolyl)phenyl](terphenylyl)carbazole; [(carbazolyl)phenyl](terphenylyl)carbazole; [(carbazolyl)pyridinyl](terphenylyl)carbazole; [(carbazolyl)pyridinyl](terphenylyl)carbazole; [(carbazolyl)pyridinyl](terphenylyl)carbazole; (terphenylyl)bicarbazole; (terphenylyl)bicarbazole; [(carbazolyl)phenyl](triphenylenyl)carbazole; [(carbazolyl)phenyl](triphenylenyl)carbazole; [(carbazolyl)pyridinyl](triphenylenyl)carbazole; [(carbazolyl)pyridinyl](triphenylenyl)carbazole; [(carbazolyl)phenyl](triphenylenyl)carbazole; (triphenylenyl)bicarbazole; (triphenylenyl)bicarbazole; [(triphenylenyl)phenyl]bicarbazole; [(triphenylenyl)phenyl]bicarbazole; [(carbazolyl)phenyl](dimethylfluorenyl)carbazole; [(carbazolyl)phenyl](dimethylfluorenyl)carbazole; [(carbazolyl)pyridinyl](dimethylfluorenyl)carbazole; [(carbazolyl)pyridinyl](dimethylfluorenyl)carbazole; (dimethylfluorenyl)bicarbazole; (dimethylfluorenyl)bicarbazole; [c-(dimethylfluorenyl)phenyl]bicarbazole; [c-(dimethylfluorenyl)phenyl]bicarbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)phenylbicarbazole; (dibenzothiophenyl)phenylbicarbazole; (dibenzoselenophenyl)phenylbicarbazole; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)phenylbicarbazole; (dibenzothiophenyl)phenylbicarbazole; (dibenzoselenophenyl)phenylbicarbazole; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)(bicarbazolyl)biphenyl; (dibenzothiophenyl)(bicarbazolyl)biphenyl; (dibenzoselenophenyl)(bicarbazolyl)biphenyl

### (Group 16A)

diphenylindolocarbazole; phenyl(biphenylyl)indolocarbazole; di(biphenylyl)indolocarbazole; phenyl(terphenylyl)indolocarbazole; phenyl(quaterphenylyl)indolocarbazole; phenyl(quinquephenylyl)indolocarbazole; phenyl(naphthaleyl)indolocarbazole; phenyl(binaphthalenyl)indolocarbazole; phenyl(acenaphthenyl)indolocarbazole; phenyl(acenaphthenyl)indolocarbazole; phenyl(azulenylphenyl)indolocarbazole; phenyl[(phenylanthraceneyl)phenyl]indolocarbazole; phenyl(methylphenyl)indolocarbazole; phenyl[(diphenylamino)phenyl]indolocarbazole; phenyl[[bis(trimethylphenyl)borane]phenyl]indolocarbazole; di(biphenylyl)indolocarbazole; biphenylyl(pyridinylphenyl)indolocarbazole; phenyl(triphenylenyl)indolocarbazole; phenyl(terphenylyl)indolocarbazole; phenyl(chrysenyl)indolocarbazole; phenyl(pyrenyl)indolocarbazole; phenyl(phenanthrenyl)indolocarbazole; phenyl(coronenyl)indolocarbazole; phenyl[(diphenylpyrimidineyl)phenyl]indolocarbazole; phenyl[(diphenyltriazinyl)phenyl]indolocarbazole; phenyl[(bithiophenyl)phenyl]indolocarbazole; phenyl[(isothiazolyl)phenyl]indolocarbazole; phenyl(dicyanophenyl)indolocarbazole; phenyl(dicyanophenyl)indolocarbazole; bis(ethylphenyl)indolocarbazole; bis(isopropylphenyl)indolocarbazole; bis(tert-butylphenyl)indolocarbazole; phenyl[[phenyl(naphthaleyl)amino]phenyl]indolocarbazole; phenyl[[di(naphthaleyl)amino]phenyl]indolocarbazole phenyl[[di(naphthaleyl)borane]phenyl]indolocarbazole; phenyl(terphenylyl)indolocarbazole; di(naphthaleyl)indolocarbazole; phenyl(anthraceneyl)indolocarbazole; phenyl(tetracenyl)indolocarbazole; phenyl(perylenyl)indolocarbazole; phenyl(fluorenyl)indolocarbazole; phenyl[(n-butyl)phenyl]indolocarbazole; [(n-octyl)phenyl][(n-butyl)phenyl]indolocarbazole; phenyl[[phenyl(anthraceneyl)amino]phenyl]indolocarbazole; phenyl[[di(anthraceneyl)borane]phenyl]indolocarbazole; naphthalene(biphenylyl)indolocarbazole; phenyl[(phenylcarbazolyl)phenyl]indolocarbazole; phenyl[(carbazolyl)phenyl]indolocarbazole; phenyl[(dibenzothiophenyl)phenyl]indolocarbazole; phenyl[(phenylphenazinyl)phenyl]indolocarbazole; tetraphenylindolocarbazole; (dipyridine)(diphenyl)indolocarbazole; diphenyl(carbazolyl)indolocarbazole; phenyl(biphenylyl)indolocarbazole; tetraphenylindolocarbazole; di(naphthaleyl)indolocarbazole; phenyl[(phenyldibenzofuranyl)phenyl]indolocarbazole; phenyl(dibenzothiophenyl)indolocarbazole; phenyl(dibenzofuranyl)indolocarbazole; dimethyl(diphenyl)indolocarbazole; diphenyl[bis(diphenylamino)]indolocarbazole; diphenyl[bis(trimethylphenyl)boraneyl]indolocarbazole; diphenyldicyanoindolocarbazole; dipyridinylindolocarbazole; bis(phenylcarbazolyl)indolocarbazole; bis[phenylindolocarbazolyl]benzene; bis[phenylindolocarbazolyl]benzene; bis[phenylindolocarbazolyl]biphenyl; bis[phenylindolocarbazolyl]naphthalene; bis[phenylindolocarbazolyl]anthracene; bis[phenylindolocarbazolyl]pyrene; bis[phenylindolocarbazolyl](cyano)benzene; (phenylindolocarbazolyl)[(carbazolyl)indolocarbazolyl]benzene; (phenylindolocarbazolyl)[(dibenzoselenophenyl)indolocarbazolyl]benzene; phenyl(phenylpyridinyl)indolocarbazole; phenyl(diphenylpyrimidineyl)indolocarbazole; phenyl(diphenyltriazinyl)indolocarbazole; phenyl(phenylpyrazinyl)indolocarbazole; phenyl(quinolinyl)indolocarbazole; phenyl(quinazolinyl)indolocarbazole; phenyl(phenylbenzoimidazolyl)indolocarbazole; phenyl(cinnolinyl)indolocarbazole; phenyl(phenylcarbazolyl)indolocarbazole; methylbiphenylyl(phenylpyridinyl)indolocarbazole; phenyl(carbazolylpyridinyl)indolocarbazole; phenyl[phenyl(carbazolyl)pyrimidineyl]indolocarbazole; phenyl[phenyl(biphenylyl)triazinyl]indolocarbazole; biphenylyl(diphenyltriazinyl)indolocarbazole; phenyl[phenyl(biphenylyl)triazinyl]indolocarbazole; phenyl[di(biphenylyl)triazinyl]indolocarbazole; naphthaleyl(quinolinyl)indolocarbazole; phenyl(biphenylylquinazolinyl)indolocarbazole; phenyl(biphenylylindolyl)indolocarbazole; terphenylyl(phenylpyridinyl)indolocarbazole; phenyl[di(biphenylyl)triazinyl]indolocarbazole; tetraphenyl(quinolinyl)indolocarbazole; phenyl(carbazolyl)(phenylcarbazolyl)indolocarbazole; diphenylaminophenyl(phenylquinazolinyl)indolocarbazole; phenyl{phenyl[(carbazolyl)methylphenyl]triazinyl}indolocarbazole; phenyl(naphthaleylcarbazolyl)indolocarbazole phenyl(quinolinylcarbazolyl)indolocarbazole; phenyl(phenylpyridinyl)indolocarbazole; phenyl(phenylpyridinyl)indolocarbazole; biphenylyl(phenylpyridinyl)indolocarbazole; terphenylyl(phenylpyridinyl)indolocarbazole; phenyl(diphenylpyrimidineyl)indolocarbazole; (dibenzothiophenylphenyl)(diphenylpyrimidineyl)indolocarbazole; phenyl(diphenyltriazinyl)indolocarbazole; phenyl[phenyl(biphenylyl)triazinyl]indolocarbazole; biphenylyl[phenyl(biphenylyl)triazinyl]indolocarbazole; phenyl[biphenylyl(naphthaleyl)triazinyl]indolocarbazole; dibenzothiophenyl(diphenyltriazinyl)indolocarbazole; phenyl(quinolinyl)indolocarbazole; biphenylyl(quinazolinyl)indolocarbazole; phenyl(quinoxalinyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; phenyl(dibenzothiophenylcarbazolyl)indolocarbazole; phenyl(phenylpyridoindolyl)indolocarbazole; phenyl(phenylpyridinyl)indolocarbazole; phenyl(phenylpyridinyl)indolocarbazole; phenyl(diphenylpyrimidineyl)indolocarbazole; phenyl(diphenyltriazinyl)indolocarbazole; naphthalene(diphenyltriazinyl)indolocarbazole; phenyl(diphenyltriazinyl)indolocarbazole; phenyl[di(cyanophenyl)triazinyl]indolocarbazole; phenyl(phenylbipyridinyl)indolocarbazole; tert-butylphenyl(quinolinyl)indolocarbazole; phenyl(phenylquinazolinyl)indolocarbazole; phenyl(quinoxalinyl)indolocarbazole; phenyl(carbazolepyridinyl)indolocarbazole; phenyl(phenylcarbazolylpyridinyl)indolocarbazole; phenyl(phenylcarbazolylpyridinyl)indolocarbazole; phenyl(triphenylenylpyridinyl)indolocarbazole; methylpyridinyl(triphenylenyl)indolocarbazole; phenylpyridinyl(phenanthrenyl)indolocarbazole; phenylpyridinyl(pyrenyl)indolocarbazole; phenylpyridinyl(terphenylyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; biphenylyl(phenylcarbazolyl)indolocarbazole; phenyl(biphenylylcarbazolyl)indolocarbazole; phenyl(phenylpyridoindolyl)indolocarbazole; phenyl(phenylpyridinyl)indolocarbazole; phenyl(diphenylpyrimidineyl)indolocarbazole; phenyl(diphenyltriazinyl)indolocarbazole; phenyl(quinolinyl)indolocarbazole; phenyl(phenylquinazolinyl)indolocarbazole; phenyl(phenylindolyl)indolocarbazole; phenyl(phenylbenzoindolyl)indolocarbazole; phenyl[phenyl(naphthaleyl)triazinyl]indolocarbazole; phenyl[phenyl(phenanthrenyl)triazinyl]indolocarbazole; phenyl[phenyl(fluorenyl)triazinyl]indolocarbazole; phenylpyridinyl(triphenylenyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; benzothiophenyl(phenylcarbazolyl)indolocarbazole; phenyl(naphthaleylcarbazolyl)indolocarbazole; phenyl(phenylazaoxaindenofluorenyl)indolocarbazole; phenyl(pyridinyl)indolocarbazole; phenyl(diphenylpyridinyl)indolocarbazole; phenyl(diphenylpyrimidineyl)indolocarbazole; phenyl[phenyl(dibenzofuranyl)pyrimidineyl]indolocarbazole; phenyl(diphenyltriazinyl)indolocarbazole; phenyl[phenyl(phenylanthraceneyl)triazinyl]indolocarbazole; phenylpyridinyl(anthraceneyl)indolocarbazole; phenyl(quinolinyl)indolocarbazole; phenyl(isoquinolinyl)indolocarbazole; phenyl(acridineyl)indolocarbazole; phenyl[(phenylanthraceneyl)pyridinyl]indolocarbazole; phenyl(naphthaleylpyridinyl)indolocarbazole; phenyl(isoquinolinylpyridinyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; phenyl(methylphenylcarbazolyl)indolocarbazole; phenyl(terphenylylcarbazolyl)indolocarbazole; bis[phenylindolocarbazolyl]pyridazine; bis[phenylindolocarbazolyl]pyridine; bis[phenylindolocarbazolyl]cyanopyridine; bis[phenylindolocarbazolyl]pyrazine; bis[phenylindolocarbazolyl]phenylpyrimidine; bis[phenylindolocarbazolyl]phenylcarbazole; tris[phenylindolocarbazolyl]triazine

### (Group 17A)

(diphenyl-d₁₀)[(biphenylyldibenzothiophenyl)phenyl]triazine; (phenyl-d₅)(triphenylenylphenyl)dibenzothiophene; (dicarbazolyl-d₁₆)dibenzothiophene-d₆; [(dimethyl-d₆)fluorenyl][(diphenyltriazinyl)phenyl]dibenzothiophene

### (Group 18A)

phenyl(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; bis(terphenylyl)indolocarbazole; bis(terphenylyl)indolocarbazole; bis(terphenylyl)indolocarbazole; (terphenylyl)(triphenylenyl)indolocarbazole; (terphenyl)(dimethylfluorenyl)indolocarbazole; (terphenylyl)(spiro[cyclopentanefluorene]yl)indolocarbazole; (terphenylyl)(spiro[cyclohexanefluorene]yl)indolocarbazole; (terphenylyl)(dimethylfluorenyl)indolocarbazole; (terphenylyl)(spirobi[fluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(dibenzoselenophenyl)indolocarbazole; (terphenylyl)(dibenzoselenophenyl)indolocarbazole; (terphenylyl)dibenzoselenophene-indolocarbazole; (terphenylyl)phenylcarbazole-indolocarbazole; (terphenylyl)(carbazolylphenyl)indolocarbazole; (terphenylyl)(benzothienopyridinyl)indolocarbazole; (terphenylyl)(benzothienopyrimidineyl)indolocarbazole; (terphenylyl)(benzothienopyrimidineyl)indolocarbazole; (terphenylyl)phenylbenzothienopyrimidineyl)indolocarbazole; (terphenylyl)(diphenyltriazinyl)indolocarbazole; (terphenylyl)(phenylquinazolinyl)indolocarbazole; (terphenylyl)(dibenzoquinazolinyl)indolocarbazole; (terphenylyl)(dibenzoquinoxalinyl)indolocarbazole; [(phenyl-d₅)biphenylyl](biphenylyl)indolocarbazole; [(phenyl-d₅)biphenylyl](phenyl-d₅)indolocarbazole; (terphenylyl)[(dimethyl-d₆)fluorene]indolocarbazole; (terphenylyl)(dibenzofuranylphenyl)indolocarbazole; (terphenylyl)(dibenzothiophenylphenyl)indolocarbazole; (terphenylyl)(triphenylenylphenyl)indolocarbazole; (terphenylyl)[(diphenyltriazinyl)phenyl]-indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(triphenylenyl)indolocarbazole; (terphenylyl)(dimethylfluorenyl)indolocarbazole; (terphenylyl)(spiro[cyclohexanefluorene]yl)indolocarbazole; (terphenylyl)(spiro[cyclopentanefluorene]yl)indolocarbazole; (terphenylyl)(spirobi[fluorene]yl)indolocarbazole; (terphenylyl)(dimethylfluorenyl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(dibenzoselenophenyl)indolocarbazole; (terphenylyl)(dibenzoselenophenyl)indolocarbazole; (terphenylyl)(dibenzoselenophenyl)indolocarbazole; (terphenylyl)(phenylcarbazolyl)indolocarbazole; (terphenylyl)[(carbazolyl)phenyl]indolocarbazole; (terphenylyl)(benzothienopyridinyl)indolocarbazole; (terphenylyl)(benzothienopyrimidineyl)indolocarbazole; (terphenylyl)(benzothienopyrimidineyl)indolocarbazole; (terphenylyl)(phenylbenzothienopyrimidineyl)indolocarbazole; (terphenylyl)(diphenylbenzothienopyrimidineyl)indolocarbazole; (terphenylyl)(diphenylbenzothienopyrimidineyl)indolocarbazole; (terphenylyl)(diphenyltriazinyl)indolocarbazole; (terphenylyl)(phenylquinazolinyl)indolocarbazole; (terphenylyl)(dibenzoquinazolinyl)indolocarbazole; (terphenylyl)(dibenzoquinoxalinyl)indolocarbazole; (terphenylyl)[(dimethyl-d₆)fluorenyl]indolocarbazole; (terphenylyl)[(diphenyltriazinyl)phenyl]indolocarbazole; [(phenyl-d₅)biphenylyl](biphenylyl)indolocarbazole; [(phenyl-d₅)biphenylyl](phenyl-d₅)indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole di(terphenylyl)indolocarbazole; (terphenylyl)(triphenylenyl)indolocarbazole; (terphenylyl)(dimethylfluorenyl)indolocarbazole; (terphenylyl)(spirobi[fluorene]yl)-indolocarbazole; (terphenylyl)(spiro[cyclopentanefluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(diphenyltriazinyl)indolocarbazole; (terphenylyl)(phenylquinazolinyl)indolocarbazole; (terphenylyl)(benzothienopyrimidineyl)indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(triphenylenyl)indolocarbazole; (terphenylyl)(dimethylfluorenyl)indolocarbazole; (terphenylyl)(spirobi[fluorene]yl)-indolocarbazole; (terphenylyl)(spiro[cyclopentanefluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(diphenyltriazinyl)indolocarbazole; (terphenylyl)(phenylquinazolinyl)indolocarbazole; (terphenylyl)(benzothienopyrimidineyl)indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(dimethylfluorenyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(benzothienopyridinyl)indolocarbazole; (terphenylyl)(benzothienopyrimidineyl)indolocarbazole; (terphenylyl)(diphenyltriazinyl)indolocarbazole; (terphenylyl)(phenylquinazolinyl)indolocarbazole; [(phenyl-d₅)biphenylyl](biphenylyl)indolocarbazole; [(phenyl-d₅)biphenylyl](phenyl-d₅)indolocarbazole; (terphenylyl)(phenyl)indolocarbazole; (terphenylyl)(biphenylyl)indolocarbazole; (terphenylyl)(biphenylyl)indolocarbazole; (terphenylyl)(dibenzothiophenyl)indolocarbazole; (terphenylyl)(dibenzothiophenyl)indolocarbazole; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)phenyldibenzothiophenyl](diphenyltriazinyl)biphenyl; [(biphenylyl)phenyldibenzoselenophenyl](diphenyltriazinyl)biphenyl; [(biphenylyl)dibenzofuranyl](diphenyltriazinyl)biphenyl; [(biphenylyl)phenyldibenzothiophenyl](diphenyltriazinyl)biphenyl; [(biphenylyl)phenyldibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [biphenylyl(dibenzofuranyl)](diphenyltriazinyl)terbenzene; [biphenylyl(dibenzothiophenyl)](diphenyltriazinyl)terbenzene; [biphenylyl(dibenzoselenophenyl)](diphenyltriazinyl)terbenzene; dibenzofuranyl[phenyl(biphenylyl)triazinyl]biphenyl; dibenzothiophenyl[phenyl(biphenylyl)triazinyl]biphenyl; dibenzoselenophenyl[phenyl(biphenylyl)triazinyl]biphenyl; dibenzofuranyl[phenyl(biphenylyl)triazinyl]biphenyl; dibenzothiophenyl[phenyl(biphenylyl)triazinyl]biphenyl; dibenzoselenophenyl[phenyl(biphenylyl)triazinyl]biphenyl; dibenzofuranyl[bis(biphenylyl)triazinyl]biphenyl; dibenzothiophenyl[bis(biphenylyl)triazinyl]biphenyl; dibenzoselenophenyl[bis(biphenylyl)triazinyl]biphenyl; dibenzofuranyl[dimethylfluorenyl(biphenylyl)triazinyl]biphenyl; dibenzothiophenyl[dimethylfluorenyl(biphenylyl)triazinyl]biphenyl; dibenzoselenophenyl[dimethylfluorenyl(biphenylyl)triazinyl]biphenyl; phenyldibenzofuranyl[phenyl(biphenylyl)triazinyl]biphenyl; phenyldibenzothiophenyl[phenyl(biphenylyl)triazinyl]biphenyl; phenyldibenzoselenophenyl[phenyl(biphenylyl)triazinyl]biphenyl; phenyldibenzofuranyl[phenyl(biphenylyl)triazinyl]biphenyl; phenyldibenzothiophenyl[phenyl(biphenylyl)triazinyl]biphenyl; phenyldibenzoselenophenyl[phenyl(biphenylyl)triazinyl]biphenyl; phenyldibenzofuranyl[dimethylfluorenyl(biphenylyl)triazinyl]biphenyl; phenyldibenzothiophenyl[dimethylfluorenyl(biphenylyl)triazinyl]biphenyl; phenyldibenzoselenophenyl[dimethylfluorenyl(biphenylyl)triazinyl]biphenyl; dibenzofuranyl[phenyl(biphenylyl)triazinyl]terbenzene; dibenzothiophenyl[phenyl(biphenylyl)triazinyl]terbenzene; dibenzoselenophenyl[phenyl(biphenylyl)triazinyl]terbenzene; dibenzofuranyl[phenyl(biphenylyl)triazinyl]terbenzene; dibenzothiophenyl[phenyl(biphenylyl)triazinyl]terbenzene; dibenzoselenophenyl[phenyl(biphenylyl)triazinyl]terbenzene; dibenzofuranyl[dimethylfluorenyl(biphenylyl)triazinyl]terbenzene; dibenzothiophenyl[dimethylfluorenyl(biphenylyl)triazinyl]terbenzene; dibenzoselenophenyl[dimethylfluorenyl(biphenylyl)triazinyl]terbenzene; (biphenylyl)dibenzofuranyl[phenyl(biphenylyl)triazinyl]biphenyl; (biphenylyl)dibenzothiophenyl[phenyl(biphenylyl)triazinyl]biphenyl; (biphenylyl)dibenzoselenophenyl[phenyl(biphenylyl)triazinyl]biphenyl; (biphenylyl)dibenzofuranyl[phenyl(biphenylyl)triazinyl]biphenyl; (biphenylyl)dibenzothiophenyl[phenyl(biphenylyl)triazinyl]biphenyl; (biphenylyl)dibenzoselenophenyl[phenyl(biphenylyl)triazinyl]biphenyl; (biphenylyl)dibenzofuranyl[dimethylfluorenyl(biphenylyl)triazinyl]biphenyl; (biphenylyl)dibenzothiophenyl[dimethylfluorenyl(biphenylyl)triazinyl]biphenyl; (biphenylyl)dibenzoselenophenyl[dimethylfluorenyl(biphenylyl)triazinyl]biphenyl; diphenyltriazinyl(dibenzofuranyl)terbenzene; diphenyltriazinyl(dibenzothiophenyl)]terbenzene; diphenyltriazinyl(dibenzoselenophenyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; diphenyldibenzofuranyl(diphenyltriazinyl)biphenyl; diphenyldibenzothiophenyl(diphenyltriazinyl)biphenyl; diphenyldibenzoselenophenyl(diphenyltriazinyl)biphenyl; diphenyldibenzofuranyl(diphenyltriazinyl)biphenyl; diphenyldibenzothiophenyl(diphenyltriazinyl)biphenyl; diphenyldibenzoselenophenyl(diphenyltriazinyl)biphenyl; phenyldibenzofuranyl(diphenyltriazinyl)biphenyl; phenyldibenzothiophenyl(diphenyltriazinyl)biphenyl; phenyldibenzoselenophenyl(diphenyltriazinyl)biphenyl; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; [(pyridinyl)dibenzofuranyl](diphenyltriazinyl)biphenyl; [(pyridinyl)dibenzothiophenyl](diphenyltriazinyl)biphenyl; [(pyridinyl)phenyldibenzoselenophenyl](diphenyltriazinyl)biphenyl; diphenyltriazinyl(dibenzofuranyl)terbenzene; diphenyltriazinyl(dibenzothiophenyl)terbenzene; diphenyltriazinyl(dibenzoselenophenyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; (dibenzofuranyl)(dimethylfluorenyl)(diphenyltriazinyl)benzene; (dibenzothiophenyl)(dimethylfluorenyl)(diphenyltriazinyl)benzene; (dibenzoselenophenyl)(dimethylfluorenyl)(diphenyltriazinyl)benzene; diphenyltriazinyl(dimethylfluorenyl)biphenyl; diphenyltriazinyl(spiro[cyclopentanefluorene]yl)biphenyl; diphenyltriazinyl(dimethylfluorenyl)terbenzene; diphenylfluorenyl(diphenyltriazinyl)biphenyl; dimethylfluorenyl[phenyl(biphenylyl)triazinyl]biphenyl; dimethylfluorenyl[phenyl(biphenylyl)triazinyl]biphenyl; dimethylfluorenyl[phenyl(dimethylfluorenyl)triazinyl]terbenzene; diphenyl[bis(dimethylfluorenyl)phenyl]triazine; phenyl(diphenyltriazinyl)dibenzofuran; phenyl(diphenyltriazinyl)dibenzothiophene; phenyl(diphenyltriazinyl)dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]benzoselenophene; phenyl[bis(biphenylyl)triazinyl]dibenzofuran; phenyl[bis(biphenylyl)triazinyl]dibenzothiophene; phenyl[bis(biphenylyl)triazinyl]benzoselenophene; phenyl[bis(biphenylyl)triazinyl]dibenzofuran; phenyl[bis(biphenylyl)triazinyl]dibenzothiophene; phenyl[bis(biphenylyl)triazinyl]benzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]benzoselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzoselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]benzoselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzoselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzoselenophene; phenyldibenzofuran(diphenyltriazinyl)biphenyl; phenyldibenzothiophene(diphenyltriazinyl)biphenyl; phenylbenzoselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; phenyldibenzofuran(diphenyltriazinyl)biphenyl; phenyldibenzothiophene(diphenyltriazinyl)biphenyl; phenylbenzoselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; phenyldibenzofuran(diphenyltriazinyl)biphenyl; phenyldibenzothiophene(diphenyltriazinyl)biphenyl; phenylbenzoselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzoselenophene[phenyl(biphenylyl)triazinyl]biphenyl; biphenylyl(diphenyltriazinyl)dibenzofuran; biphenylyl(diphenyltriazinyl)dibenzothiophene; biphenylyl(diphenyltriazinyl)benzoselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzoselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzoselenophene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzoselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzoselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; biphenylyl(diphenyltriazinyl)dibenzofuran; biphenylyl(diphenyltriazinyl)dibenzothiophene; biphenylyl(diphenyltriazinyl)benzoselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzoselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzoselenophene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzoselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzoselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzoselenophenyl][phenyl(biphenylyl)triazinyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]benzoselenophene; phenyl[biphenylyl(dimethylfluorenyl)triazinyl]dibenzofuran; phenyl[biphenylyl(dimethylfluorenyl)triazinyl]dibenzothiophene; phenyl[biphenylyl(dimethylfluorenyl)triazinyl]benzoselenophene; phenyl[biphenylyl(dimethylfluorenyl)triazinyl]dibenzofuran; phenyl[biphenylyl(dimethylfluorenyl)triazinyl]dibenzothiophene; phenyl[biphenylyl(dimethylfluorenyl)triazinyl]benzoselenophene; phenyldibenzofuranyl[phenyl(dimethylfluorenyl)triazinyl]benzene; phenyldibenzothiophenyl[phenyl(dimethylfluorenyl)triazinyl]benzene; phenylbenzoselenophenyl[phenyl(dimethylfluorenyl)triazinyl]benzene; phenyldibenzofuranyl[bis(dimethylfluorenyl)triazinyl]benzene; phenyldibenzothiophenyl[bis(dimethylfluorenyl)triazinyl]benzene; phenylbenzoselenophenyl[bis(dimethylfluorenyl)triazinyl]benzene; biphenylyl[phenyl(dimethylfluorenyl)triazinyl]dibenzofuran; biphenylyl[phenyl(dimethylfluorenyl)triazinyl]dibenzothiophene; biphenylyl[phenyl(dimethylfluorenyl)triazinyl]benzoselenophene; biphenylyl[phenyl(dimethylfluorenyl)triazinyl]dibenzofuran; biphenylyl[phenyl(dimethylfluorenyl)triazinyl]dibenzothiophene; biphenylyl[phenyl(dimethylfluorenyl)triazinyl]benzoselenophene; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzoselenophenyl][phenyl(dimethylfluorenyl)triazinyl]benzene; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzoselenophenyl][phenyl(dimethylfluorenyl)triazinyl]benzene; phenyl[phenyl(dimethylfluorenylphenyl)triazinyl]dibenzofuran; phenyl[phenyl(dimethylfluorenylphenyl)triazinyl]dibenzothiophene; phenyl[phenyl(dimethylfluorenylphenyl)triazinyl]benzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]benzoselenophene; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)benzoselenophenyl](dimethylfluorenyl)triazine; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzoselenophenyl][phenyl(dimethylfluorenyl)triazinyl]benzene; phenyl(phenyldibenzofuranyl)(phenyldimethylfluorenyl)triazine; phenyl(phenyldibenzothiophenyl)(phenyldimethylfluorenyl)triazine; phenyl(phenylbenzoselenophenyl)(phenyldimethylfluorenyl)triazine; phenyl(phenyldibenzofuranyl)(dimethylfluorenyl)triazine; phenyl(phenyldibenzothiophenyl)(dimethylfluorenyl)triazine; phenyl(phenylbenzoselenophenyl)(dimethylfluorenyl)triazine; diphenyl(phenyldibenzofuranyl)triazine; diphenyl(phenyldibenzothiophenyl)triazine; diphenyl(phenylbenzoselenophenyl)triazine; diphenyltriazinyl(phenyldibenzofuranyl)benzene; diphenyltriazinyl(phenyldibenzothiophenyl)benzene; diphenyltriazinyl(phenylbenzoselenophenyl)benzene; diphenyltriazinyl[(biphenylyl)dibenzofuranyl]benzene; diphenyltriazinyl[(biphenylyl)dibenzothiophenyl]benzene; diphenyltriazinyl[(biphenylyl)benzoselenophenyl]benzene; diphenyltriazinyl(diphenyldibenzofuranyl)benzene; diphenyltriazinyl(diphenyldibenzothiophenyl)benzene; diphenyltriazinyl(diphenylbenzoselenophenyl)benzene; diphenyl(phenyldibenzofuranyl)triazine; diphenyl(phenyldibenzothiophenyl)triazine; diphenyl(phenylbenzoselenophenyl)triazine; diphenyl[(biphenylyl)dibenzofuranyl]triazine; diphenyl[(biphenylyl)dibenzothiophenyl]triazine; diphenyl[(biphenylyl)benzoselenophenyl]triazine; diphenyl[(biphenylyl)dibenzofuranyl]triazine; diphenyl[(biphenylyl)dibenzothiophenyl]triazine; diphenyl[(biphenylyl)benzoselenophenyl]triazine; diphenyltriazinyl(diphenyldibenzofuranyl)benzene; diphenyltriazinyl(diphenyldibenzothiophenyl)benzene; diphenyltriazinyl(diphenylbenzoselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzoselenophenyl)benzene; diphenyl[phenyldibenzofuranyl]triazine; diphenyl[phenyldibenzothiophenyl]triazine; diphenyl[phenylbenzoselenophenyl]triazine; diphenyltriazinyl(phenyldibenzofuranyl)benzene; diphenyltriazinyl(phenyldibenzothiophenyl)benzene; diphenyltriazinyl(phenylbenzoselenophenyl)benzene; diphenyltriazinyl(phenyldibenzofuranyl)benzene; diphenyltriazinyl(phenyldibenzothiophenyl)benzene; diphenyltriazinyl(phenylbenzoselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzoselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzoselenophenyl)benzene; diphenyltriazinyl(phenyldibenzofuranyl)benzene; diphenyltriazinyl(phenyldibenzothiophenyl)benzene; diphenyltriazinyl(phenylbenzoselenophenyl)benzene; diphenyltriazinyl(phenyldibenzofuranyl)pyridine; diphenyltriazinyl(phenyldibenzothiophenyl)pyridine; diphenyltriazinyl(phenylbenzoselenophenyl)pyridine; phenyl(phenylpyridinyl)triazinyl(phenyldibenzofuranyl)pyridine; phenyl(phenylpyridinyl)triazinyl(phenyldibenzothiophenyl)pyridine; phenyl(phenylpyridinyl)triazinyl(phenylbenzoselenophenyl)pyridine; phenyl(phenylpyridinyl)triazinyl(phenyldibenzofuranyl)benzene; phenyl(phenylpyridinyl)triazinyl(phenyldibenzothiophenyl)benzene; phenyl(phenylpyridinyl)triazinyl(phenylbenzoselenophenyl)benzene; diphenyltriazinyl(biphenylyldibenzofuranyl)pyridine; diphenyltriazinyl(biphenylyldibenzothiophenyl)pyridine; diphenyltriazinyl(biphenylylbenzoselenophenyl)pyridine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenylbenzoselenophenyl)triazine; (biphenylyl)(dimethylindenopyridinyl)(phenyldibenzofuranyl)triazine; (biphenylyl)(dimethylindenopyridinyl)(phenyldibenzothiophenyl)triazine; (biphenylyl)(dimethylindenopyridinyl)(phenylbenzoselenophenyl)triazine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenylbenzoselenophenyl)triazine; phenyl(spiro[cyclohexaneindenopyridine]yl)(phenyldibenzofuranyl)triazine; phenyl(spiro[cyclohexaneindenopyridine]yl)(phenyldibenzothiophenyl)triazine; phenyl(spiro[cyclohexaneindenopyridine]yl)(phenylbenzoselenophenyl)triazine; phenyl(spirobi[fluorene]yl)(phenyldibenzofuranyl)triazine; phenyl(spirobi[fluorene]yl)(phenyldibenzothiophenyl)triazine; phenyl(spirobi[fluorene]yl)(phenylbenzoselenophenyl)triazine; benzened₃[(diphenyl-d₁₀)triazinyl][(phenyl-d₅)dibenzofuranyl-d₆]; benzened₃[(diphenyl-d₁₀)triazinyl][(phenyl-d₅)dibenzothiophenyl-d₆]; benzened₃[(diphenyl-d₁₀)triazinyl][(phenyl-d₅)benzoselenophenyl-d₆]; benzened₃[(diphenyl-d₁₀)triazinyl][(biphenylyl-d₈)dibenzofuranyl-d₆]; benzened₃[(diphenyl-d₁₀)triazinyl][(biphenylyl-d₈)dibenzothiophenyl-d₆]; benzened₃[(diphenyl-d₁₀)triazinyl][(biphenylyl-d₈)benzoselenophenyl-d₆]; phenyl[(dimethyl-d₆)fluorene][phenyldibenzofuranyl]triazine; phenyl[(dimethyl-d₆)fluorene][phenyldibenzothiophenyl]triazine; phenyl[(dimethyl-d₆)fluorene][phenylbenzoselenophenyl]triazine; benzened₃[(diphenyl-d₁₀)triazinyl][(biphenylyl-d₈)dibenzofuranyl-d₆]; benzened₃[(diphenyl-d₁₀)triazinyl][(biphenylyl-d₈)dibenzothiophenyl-d₆]; benzened₃[(diphenyl-d₁₀)triazinyl][(biphenylyl-d₈)benzoselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)benzoselenophenyl]benzene; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)benzoselenophenyl]biphenyl; [bis(fluorophenyl)triazinyl][(biphenylyl)dibenzofuranyl]benzene; [bis(fluorophenyl)triazinyl][(biphenylyl)dibenzothiophenyl]benzene; [bis(fluorophenyl)triazinyl][(biphenylyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzoselenophenyl]biphenyl; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzoselenophenyl]biphenyl; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzoselenophenyl]biphenyl; diphenyltriazinyl[(dimethylfluorenyl)dibenzofuranyl]pyridine; diphenyltriazinyl[(dimethylfluorenyl)dibenzothiophenyl]pyridine; diphenyltriazinyl[(dimethylfluorenyl)benzoselenophenyl]pyridine; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzoselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)benzoselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)benzoselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[bis(dimethylfluorenyl)dibenzofuranyl]benzene; diphenyltriazinyl[bis(dimethylfluorenyl)dibenzothiophenyl]benzene; diphenyltriazinyl[bis(dimethylfluorenyl)benzoselenophenyl]benzene; [phenyl(terphenylyl)triazinyl][(dimethylfluorenyl)dibenzofuranyl]benzene; [phenyl(terphenylyl)triazinyl]triazinyl[(dimethylfluorenyl)dibenzothiophenyl]benzene; [phenyl(terphenylyl)triazinyl][(dimethylfluorenyl)benzoselenophenyl]benzene; diphenyltriazinyl[(spiro[cyclopentanefluorene]yl)dibenzofuranyl]benzene; diphenyltriazinyl[(spiro[cyclopentanefluorene]yl)dibenzothiophenyl]benzene; diphenyltriazinyl[(spiro[cyclopentanefluorene]yl)benzoselenophenyl]benzene; diphenyltriazinyl[(diphenylfluorenyl)dibenzofuranyl]benzene; diphenyltriazinyl[(diphenylfluorenyl)dibenzothiophenyl]benzene; diphenyltriazinyl[(diphenylfluorenyl)benzoselenophenyl]benzene; diphenyltriazinyl[(spirobi[fluorene]yl)dibenzofuranyl]benzene; diphenyltriazinyl[(spirobi[fluorene]yl)dibenzothiophenyl]benzene; diphenyltriazinyl[(spirobi[fluorene]yl)benzoselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzoselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzoselenophenyl]benzene; [(diphenyltriazinyl)phenyl](phenyldimethylfluorenyl)dibenzofuran; [(diphenyltriazinyl)phenyl](phenyldimethylfluorenyl)dibenzothiophene; [(diphenyltriazinyl)phenyl](phenyldimethylfluorenyl)benzoselenophene; diphenyltriazinyl{[(dimethyl-d₆)fluorenyl]dibenzofuranyl}benzene; diphenyltriazinyl{[(dimethyl-d₉)fluorenyl]dibenzothiophenyl}benzene; diphenyltriazinyl{[(dimethyl-d₆)fluorenyl]benzoselenophenyl}benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzoselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzoselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzoselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)benzoselenophenyl]benzene; benzened₄[(diphenyl-d₁₀)triazinyl][(dimethylfluorenyl)dibenzofuranyl]; benzened₄[(diphenyl-d₁₀)triazinyl][(dimethylfluorenyl)dibenzothiophenyl]; benzened₄[(diphenyl-d₁₀)triazinyl][(dimethylfluorenyl)benzoselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]benzoselenophenyl}benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)benzoselenophenyl]

### (Group 19A)

phenyl[phenyl(biphenylyl)triazinyl]indenocarbazole; biphenylyl[phenyl(biphenylyl)triazinyl]indenocarbazole; biphenylyl[phenyl(biphenylyl)triazinyl]indenocarbazole; (dimethyl)(phenyl)[phenyl(biphenylyl)triazinyl]indenocarbazole; triphenyl[phenyl(biphenylyl)triazinyl]indenocarbazole; phenyl(dipyridinyl)[phenyl(biphenylyl)triazinyl]indenocarbazole; biphenylyl[phenyl(biphenylyl)triazinyl]indenocarbazole; phenyl[phenyl(biphenylyl)triazinyl]indenocarbazole; biphenylyl[phenyl(biphenylyl)triazinyl]indenocarbazole; terphenylyl[phenyl(biphenylyl)triazinyl]indenocarbazole; terphenylyl[phenyl(biphenylyl)triazinyl]indenocarbazole; [di(n-hexyl)](phenyl)[phenyl(biphenylyl)triazinyl]indenocarbazole; (dinaphthaleyl)(phenyl)[phenyl(biphenylyl)triazinyl]indenocarbazole; (diquinolinyl)(phenyl)[phenyl(biphenylyl)triazinyl]indenocarbazole; phenyl[phenyl(biphenylyl)triazinyl]indenocarbazole; biphenylyl[phenyl(biphenylyl)triazinyl]indenocarbazole; biphenylyl[phenyl(biphenylyl)triazinyl]indenocarbazole; phenyl[bis(dibenzofuranyl)][phenyl(biphenylyl)triazinyl]indenocarbazole; phenyl[bis(carbazolyl)][phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[bis(biphenylyl)triazinyl]indenocarbazole; phenyl[phenyl(terphenylyl)triazinyl]indenocarbazole; phenyl[bis(terphenylyl)triazinyl]indenocarbazole; phenyl[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; (dimethyl)(phenyl)[phenyl(biphenylyl)triazinyl]indenocarbazole; phenyl[phenyl(biphenylyl)triazinyl]indenocarbazole; phenyl[bis(biphenylyl)triazinyl]indenocarbazole; (biphenylyl)[phenyl(biphenylyl)triazinyl]indenocarbazole; (terphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; (terphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[phenyl(terphenylyl)triazinyl]indenocarbazole; (biphenylyl)[phenyl(biphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[(biphenylyl)(terphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; phenyl(naphthaleyl)bi(carbazole); bi[(naphthaleyl)carbazole]; (biphenylyl)(naphthaleyl)bi(carbazole); (biphenylyl)(naphthaleyl)bi(carbazole); (terphenylyl)(naphthaleyl)bi(carbazole); [(naphthaleyl)phenyl](naphthaleyl)bi(carbazole); bi[(naphthaleyl)carbazole]; (phenanthrenyl)(naphthaleyl)bi(carbazole); (phenylanthraceneyl)(naphthaleyl)bi(carbazole); phenyl(naphthaleyl)bi(carbazole); bi[(naphthaleyl)carbazole]; (biphenylyl)(naphthaleyl)bi(carbazole); (biphenylyl)(naphthaleyl)bi(carbazole); (terphenylyl)(naphthaleyl)bi(carbazole); [(naphthaleyl)phenyl](naphthaleyl)bi(carbazole); bi[(naphthaleyl)carbazole]; (phenanthrenyl)(naphthaleyl)bi(carbazole); (phenylanthraceneyl)(naphthaleyl)bi(carbazole); phenyl(phenanthrenyl)bi(carbazole); (phenanthrenyl)(biphenylyl)bi(carbazole); (phenanthrenyl)(biphenylyl)bi(carbazole); (terphenylyl)(phenanthrenyl)bi(carbazole); (phenanthrenyl)[(naphthaleyl)phenyl]bi(carbazole); bi[(phenanthrenyl)carbazole]; (phenylanthraceneyl)(phenanthrenyl)bi(carbazole); phenyl(naphthaleyl)bi(carbazole); bi[(naphthaleyl)carbazole]; phenyl(naphthaleyl)bi(carbazole); bi[(naphthaleyl)carbazole]; phenyl(phenanthrenyl)bi(carbazole); bi[(phenanthrenyl)carbazole]; phenyl(anthraceneyl)bi(carbazole); bi[(anthraceneyl)carbazole]; phenyl(naphthaleyl)bi(carbazole); bi[(naphthaleyl)carbazole]; phenyl(naphthaleyl)bi(carbazole); bi[(naphthaleyl)carbazole]; phenyl(phenanthrenyl)bi(carbazole); bi[(phenanthrenyl)carbazole]; phenyl(anthraceneyl)bi(carbazole); bi[(anthraceneyl)carbazole]; phenyl(naphthaleyl)bi(carbazole); bi[(naphthaleyl)carbazole]; phenyl(naphthaleyl)bi(carbazole); bi[(naphthaleyl)carbazole]; phenyl(phenanthrenyl)bi(carbazole); bi[(phenanthrenyl)carbazole]; phenyl(naphthaleyl)bi(carbazole); bi[(naphthaleyl)carbazole]; phenyl(naphthaleyl)bi(carbazole); phenyl(naphthaleyl)bi(carbazole); bi[(naphthaleyl)carbazole]; phenyl(naphthaleyl)bi(carbazole); phenyl(phenanthrenyl)bi(carbazole); bi[(phenanthrenyl)carbazole]; phenyl(phenanthrenyl)bi(carbazole); phenyl(anthraceneyl)bi(carbazole); phenyl(naphthaleyl)bi(carbazole); phenyl(naphthaleyl)bi(carbazole); bi[(naphthaleyl)carbazole]; phenyl(naphthaleyl)bi(carbazole); phenyl(phenanthrenyl)bi(carbazole); phenyl(anthraceneyl)bi(carbazole); phenyl(naphthaleyl)bi(carbazole); phenyl(naphthaleyl)bi(carbazole); bi[(naphthaleyl)carbazole]; phenyl(naphthaleyl)bi(carbazole); phenyl(naphthaleyl)bi(carbazole); bi[(naphthaleyl)carbazole]; phenyl(phenanthrenyl)bi(carbazole); phenyl(phenanthrenyl)bi(carbazole); bi[(phenanthrenyl)carbazole]; phenyl(anthraceneyl)bi(carbazole); phenyl(anthraceneyl)bi(carbazole); bi[(anthraceneyl)carbazole]

### (Group 20A)

(dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [(biphenylyl)dibenzofuranyl](diphenyltriazinyl)terbenzene; [(biphenylyl)dibenzothiophenyl](diphenyltriazinyl)terbenzene; [(biphenylyl)dibenzoselenophenyl](diphenyltriazinyl)terbenzene; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[bis(biphenylyl)triazinyl]biphenyl; (dibenzothiophenyl)[bis(biphenylyl)triazinyl]biphenyl; (dibenzoselenophenyl)[bis(biphenylyl)triazinyl]biphenyl; (dibenzofuranyl)[phenyl(dimethylfluorenyl)triazinyl]biphenyl; (dibenzothiophenyl)[phenyl(dimethylfluorenyl)triazinyl]biphenyl; (dibenzoselenophenyl)[phenyl(dimethylfluorenyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(dimethylfluorenyl)triazinyl]biphenyl; (phenyldibenzothiophenyl)[phenyl(dimethylfluorenyl)triazinyl]biphenyl; (phenyldibenzoselenophenyl)[phenyl(dimethylfluorenyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]terbenzene; (dibenzothiophenyl)[phenyl(biphenylyl)triazinyl]terbenzene; (dibenzoselenophenyl)[phenyl(biphenylyl)triazinyl]terbenzene; (dibenzofuranyl)[phenyl(dimethylfluorenyl)triazinyl]terbenzene; (dibenzothiophenyl)[phenyl(dimethylfluorenyl)triazinyl]terbenzene; (dibenzoselenophenyl)[phenyl(dimethylfluorenyl)triazinyl]terbenzene; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(dimethylfluorenyl)triazinyl]biphenyl; [(biphenylyl)dibenzothiophenyl][phenyl(dimethylfluorenyl)triazinyl]biphenyl; [(biphenylyl)dibenzoselenophenyl][phenyl(dimethylfluorenyl)triazinyl]biphenyl; (diphenyltriazinyl)[(biphenylyl)dibenzofuranyl]terbenzene; (diphenyltriazinyl)[(biphenylyl)dibenzothiophenyl]terbenzene; (diphenyltriazinyl)[(biphenylyl)dibenzoselenophenyl]terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyldibenzofuranyl)(diphenyltriazinyl)biphenyl; (diphenyldibenzothiophenyl)(diphenyltriazinyl)biphenyl; (diphenyldibenzoselenophenyl)(diphenyltriazinyl)biphenyl; (diphenyldibenzofuranyl)(diphenyltriazinyl)biphenyl; (diphenyldibenzothiophenyl)(diphenyltriazinyl)biphenyl; (diphenyldibenzoselenophenyl)(diphenyltriazinyl)biphenyl; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; [(pyridinyl)dibenzofuranyl](diphenyltriazinyl)biphenyl; [(pyridinyl)dibenzothiophenyl](diphenyltriazinyl)biphenyl; [(pyridinyl)dibenzoselenophenyl](diphenyltriazinyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)(dimethylfluorenyl)benzene; (dibenzothiophenyl)(diphenyltriazinyl)(dimethylfluorenyl)benzene; (dibenzoselenophenyl)(diphenyltriazinyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terbenzene; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terbenzene; (diphenyltriazinyl)[bis(dimethylfluorenyl)]benzene; (diphenyltriazinyl)(dimethylfluorenyl)terbenzene; (diphenyltriazinyl)phenyldibenzofuran; (diphenyltriazinyl)phenyldibenzothiophene; (diphenyltriazinyl)phenyldibenzoselenophene; [phenyl(biphenylyl)triazinyl]phenyldibenzofuran; [phenyl(biphenylyl)triazinyl]phenyldibenzothiophene; [phenyl(biphenylyl)triazinyl]phenyldibenzoselenophene; [phenyl(biphenylyl)triazinyl]phenyldibenzofuran; [phenyl(biphenylyl)triazinyl]phenyldibenzothiophene; [phenyl(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophene]benzene; [phenyl(biphenylyl)triazinyl][(biphenylyl)dibenzoselenophene]benzene; [phenyl(biphenylyl)triazinyl][(biphenylyl)dibenzofuranyl]benzene; [phenyl(biphenylyl)triazinyl][(biphenylyl)dibenzothiophene]benzene; [phenyl(biphenylyl)triazinyl][(biphenylyl)dibenzoselenophene]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(dimethylfluorenyl)triazinyl](phenyldibenzofuran); [phenyl(dimethylfluorenyl)triazinyl](phenyldibenzothiophene); [phenyl(dimethylfluorenyl)triazinyl](phenyldibenzoselenophene); [(biphenylyl)(dimethylfluorenyl)triazinyl](phenyldibenzofuran); [(biphenylyl)(dimethylfluorenyl)triazinyl](phenyldibenzothiophene); [(biphenylyl)(dimethylfluorenyl)triazinyl](phenyldibenzoselenophene); [(biphenylyl)(dimethylfluorenyl)triazinyl](phenyldibenzofuran); [(biphenylyl)(dimethylfluorenyl)triazinyl](phenyldibenzothiophene); [(biphenylyl)(dimethylfluorenyl)triazinyl](phenyldibenzoselenophene); [phenyl(dimethylfluorenyl)triazinyl](phenyldibenzofuranyl)benzene; [phenyl(dimethylfluorenyl)triazinyl](phenyldibenzothiophenyl)benzene; [phenyl(dimethylfluorenyl)triazinyl](phenyldibenzoselenophenyl)benzene; [bis(dimethylfluorenyl)triazinyl](phenyldibenzofuranyl)benzene; [bis(dimethylfluorenyl)triazinyl](phenyldibenzothiophenyl)benzene; [bis(dimethylfluorenyl)triazinyl](phenyldibenzoselenophenyl)benzene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenylphenyl)triazinyl](phenyldibenzofuranyl)benzene; [phenyl(dimethylfluorenylphenyl)triazinyl](phenyldibenzothiophenyl)benzene; [phenyl(dimethylfluorenylphenyl)triazinyl](phenyldibenzoselenophenyl)benzene; [phenyl(dimethylfluorenyl)triazinyl]phenyldibenzofuran; [phenyl(dimethylfluorenyl)triazinyl]phenyldibenzothiophene; [phenyl(dimethylfluorenyl)triazinyl]phenyldibenzoselenophene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenylphenyl)triazinyl](phenyldibenzofuranyl)benzene; [phenyl(dimethylfluorenylphenyl)triazinyl](phenyldibenzothiophenyl)benzene; [phenyl(dimethylfluorenylphenyl)triazinyl](phenyldibenzoselenophenyl)benzene; [phenyl(dimethylfluorenyl)triazinyl](phenyldibenzofuran); [phenyl(dimethylfluorenyl)triazinyl](phenyldibenzothiophene); [phenyl(dimethylfluorenyl)triazinyl](phenyldibenzoselenophene); phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; [phenyl(phenylpyridinyl)triazinyl](phenyldibenzofuranyl)benzene; [phenyl(phenylpyridinyl)triazinyl](phenyldibenzothiophenyl)benzene; [phenyl(phenylpyridinyl)triazinyl](phenyldibenzoselenophenyl)benzene; (diphenyltriazinyl)[(biphenylyl)dibenzofuranyl)]pyridine; (diphenyltriazinyl)[(biphenylyl)dibenzothiophenyl)]pyridine; (diphenyltriazinyl)[(biphenylyl)dibenzoselenophenyl)]pyridine; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[phenyl(spiro[cyclohexanefluorene]yl)triazinyl]dibenzofuran; phenyl[phenyl(spiro[cyclohexanefluorene]yl)triazinyl]dibenzothiophene; phenyl[phenyl(spiro[cyclohexanefluorene]yl)triazinyl]dibenzoselenophene; phenyl[phenyl(spirobi[9H-fluorene]yl)triazinyl]dibenzofuran; phenyl[phenyl(spirobi[9H-fluorene]yl)triazinyl]dibenzothiophene; phenyl[phenyl(spirobi[9H-fluorene]yl)triazinyl]dibenzoselenophene; benzene-d₃[(diphenyl-d₁₀)triazinyl][(phenyl-d₅)dibenzofuranyl-d₆]; benzene-d₃[(diphenyl-d₁₀)triazinyl][(phenyl-d₅)dibenzothiophenyl-d₆]; benzene-d₃[(diphenyl-d₁₀)triazinyl][(phenyl-d₅)dibenzoselenophenyl-d₆]; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-d₉)dibenzoselenophenyl-d₆]; phenyl{phenyl[(dimethyl-d₆)fluorenyl]triazinyl}dibenzofuran; phenyl{phenyl[(dimethyl-d₆)fluorenyl]triazinyl}dibenzothiophene; phenyl{phenyl[(dimethyl-d₆)fluorenyl]triazinyl}dibenzoselenophene; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-d₉)dibenzoselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (difluorophenyltriazinyl)[(biphenylyl)dibenzofuranyl]benzene; (difluorophenyltriazinyl)[(biphenylyl)dibenzothiophenyl]benzene; (difluorophenyltriazinyl)[(biphenylyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]pyridine; (diphenyltriazinyl)[(dimethylfluorenyl)dibenzothiophenyl]pyridine; (diphenyltriazinyl)[(dimethylfluorenyl)dibenzoselenophenyl]pyridine; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[bis(dimethylfluorenyl)dibenzofuranyl]benzene; (diphenyltriazinyl)[bis(dimethylfluorenyl)dibenzothiophenyl]benzene; (diphenyltriazinyl)[bis(dimethylfluorenyl)dibenzoselenophenyl]benzene; [phenyl(terphenyl)triazinyl][(dimethylfluorenyl)dibenzofuranyl]benzene; [phenyl(terphenyl)triazinyl][(dimethylfluorenyl)dibenzothiophenyl]benzene; [phenyl(terphenyl)triazinyl][(dimethylfluorenyl)dibenzoselenophenyl]benzene; (diphenyltriazinyl)[(spiro[cyclopentanefluorene]yl)dibenzofuranyl]benzene; (diphenyltriazinyl)[(spiro[cyclopentanefluorene]yl)dibenzothiophenyl]benzene; (diphenyltriazinyl)[(spiro[cyclopentanefluorene]yl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(phenyldimethylfluorenyl)dibenzofuranyl]benzene; (diphenyltriazinyl)[(phenyldimethylfluorenyl)dibenzothiophenyl]benzene; (diphenyltriazinyl)[(phenyldimethylfluorenyl)dibenzoselenophenyl]benzene; (diphenyltriazinyl){[(dimethyl-d₆)fluorenyl]dibenzofuranyl}benzene; (diphenyltriazinyl){[(dimethyl-d₆)fluorenyl]dibenzothiophenyl}benzene; (diphenyltriazinyl){[(dimethyl-d₆)fluorenyl]benzoselenophenyl}benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)dibenzoselenophenyl]benzene; benzene-d₃[(diphenyl-d₁₀)triazinyl][(dimethylfluorenyl)dibenzofuranyl]; benzene-d₃[(diphenyl-d₁₀)triazinyl][(dimethylfluorenyl)dibenzothiophenyl]; benzene-d₃[(diphenyl-d₁₀)triazinyl][(dimethylfluorenyl)dibenzoselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]dibenzoselenophenyl}benzene; benzened₄[(diphenyl-d₁₀)triazinyl][(dimethylfluorenyl)dibenzofuranyl]; benzened₄(diphenyl-d₁₀)triazinyl][(dimethylfluorenyl)dibenzothiophenyl]; benzened₄[(diphenyl-d₁₀)triazinyl][(dimethylfluorenyl)dibenzoselenophenyl]; phenyl(triphenylenyl)bi[carbazole]; phenyl(triphenylenyl)bi[carbazole]; phenyl(triphenylenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; (biphenylyl)(dimethylfluorenyl)bi[carbazole]; (biphenylyl)(dimethylfluorenyl)bi[carbazole]; (terphenylyl)(dimethylfluorenyl)bi[carbazole]; diphenylter[carbazole]; diphenylter[carbazole]diphenylter[carbazole]phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; phenyl(phenyldibenzofuranyl)bi[carbazole]; phenyl(phenyldibenzothiophenyl)bi[carbazole]; phenyl(phenyldibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(benzofuropyridinyl)bi[carbazole]; phenyl(benzothienopyridinyl)bi[carbazole]; phenyl(benzoselenopyridinyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; bi[phenylcarbazole]; phenyl(biphenylyl)bi[carbazole]; phenyl(biphenylyl)bi[carbazole]; bi[(biphenylyl)carbazole]; bi[(biphenylyl)carbazole]; triphenylbi[carbazole]; bi[diphenylcarbazole]; phenyl[phenyl(biphenylyl)]bi[carbazole]; bi[phenylcarbazole]; phenyl(biphenylyl)bi[carbazole]; phenyl(biphenylyl)bi[carbazole]; bi[(biphenylyl)carbazole]; bi[(biphenylyl)carbazole]; bi[(biphenylyl)carbazole]; triphenylbi[carbazole]; bi[diphenylcarbazole]; phenyl[phenyl(biphenylyl)]bi[carbazole]; phenyl(terphenylyl)bi[carbazole]; phenyl(terphenylyl)bi[carbazole]; phenyl(terphenylyl)bi[carbazole]; phenyl(diphenylpyridinyl)bi[carbazole]

### (Group 21A)

(dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [(biphenylyl)dibenzofuranyl](diphenyltriazinyl)terbenzene; [(biphenylyl)dibenzothiophenyl](diphenyltriazinyl)terbenzene; [(biphenylyl)dibenzoselenophenyl](diphenyltriazinyl)terbenzene; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[bis(biphenylyl)triazinyl]biphenyl; (dibenzothiophenyl)[bis(biphenylyl)triazinyl]biphenyl; (dibenzoselenophenyl)[bis(biphenylyl)triazinyl]biphenyl; (dibenzofuranyl)[phenyl(dimethylfluorenyl)triazinyl]biphenyl; (dibenzothiophenyl)[phenyl(dimethylfluorenyl)triazinyl]biphenyl; (dibenzoselenophenyl)[phenyl(dimethylfluorenyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(dimethylfluorenyl)triazinyl]biphenyl; (phenyldibenzothiophenyl)[phenyl(dimethylfluorenyl)triazinyl]biphenyl; (phenyldibenzoselenophenyl)[phenyl(dimethylfluorenyl)triazinyl]biphenyl; (phenyldibenzofuranyl)[phenyl(biphenylyl)triazinyl]terbenzene; (phenyldibenzothiophenyl)[phenyl(biphenylyl)triazinyl]terbenzene; (phenyldibenzoselenophenyl)[phenyl(biphenylyl)triazinyl]terbenzene; (phenyldibenzofuranyl)[phenyl(biphenylyl)triazinyl]terbenzene; (phenyldibenzothiophenyl)[phenyl(biphenylyl)triazinyl]terbenzene; (phenyldibenzoselenophenyl)[phenyl(biphenylyl)triazinyl]terbenzene; (phenyldibenzofuranyl)[phenyl(dimethylfluorenyl)triazinyl]terbenzene; (phenyldibenzothiophenyl)[phenyl(dimethylfluorenyl)triazinyl]terbenzene; (phenyldibenzoselenophenyl)[phenyl(dimethylfluorenyl)triazinyl]terbenzene; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(dimethylfluorenyl)triazinyl]biphenyl; [(biphenylyl)dibenzothiophenyl][phenyl(dimethylfluorenyl)triazinyl]biphenyl; [(biphenylyl)dibenzoselenophenyl][phenyl(dimethylfluorenyl)triazinyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(phenyldibenzofuranyl)(pyridinyl)benzene; (diphenyltriazinyl)(phenyldibenzothiophenyl)(pyridinyl)benzene; (diphenyltriazinyl)(phenyldibenzoselenophenyl)(pyridinyl)benzene; (diphenyltriazinyl)(phenyldibenzofuranyl)(pyridinyl)benzene; (diphenyltriazinyl)(phenyldibenzothiophenyl)(pyridinyl)benzene; (diphenyltriazinyl)(phenyldibenzoselenophenyl)(pyridinyl)benzene; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terbenzene; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terbenzene; (diphenyltriazinyl)[bis(dimethylfluorenyl)]benzene; (diphenyltriazinyl)(dimethylfluorenyl)terbenzene; phenyl(diphenyltriazinyl)dibenzofuran; phenyl(diphenyltriazinyl)dibenzothiophene; phenyl(diphenyltriazinyl)dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl][(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl][(biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; [phenyl(dimethylfluorenyl)triazinyl](phenyldibenzofuranyl)benzene; [phenyl(dimethylfluorenyl)triazinyl](phenyldibenzothiophenyl)benzene; [phenyl(dimethylfluorenyl)triazinyl](phenyldibenzoselenophenyl)benzene; [bis(dimethylfluorenyl)triazinyl](phenyldibenzofuranyl)benzene; [bis(dimethylfluorenyl)triazinyl](phenyldibenzothiophenyl)benzene; [bis(dimethylfluorenyl)triazinyl](phenyldibenzoselenophenyl)benzene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; phenyl[phenyl(phenyldimethylfluorenyl)triazinyl]dibenzofuran; phenyl[phenyl(phenyldimethylfluorenyl)triazinyl]dibenzothiophene; phenyl[phenyl(phenyldimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl(diphenyltriazinyl)dibenzofuran; phenyl(diphenyltriazinyl)dibenzothiophene; phenyl(diphenyltriazinyl)dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)(diphenyldibenzofuranyl)benzene; (diphenyltriazinyl)(diphenyldibenzothiophenyl)benzene; (diphenyltriazinyl)(diphenyldibenzoselenophenyl)benzene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (diphenyltriazinyl)(diphenyldibenzofuranyl)benzene; (diphenyltriazinyl)(diphenyldibenzothiophenyl)benzene; (diphenyltriazinyl)(diphenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; phenyl(diphenyltriazinyl)dibenzofuran; phenyl(diphenyltriazinyl)dibenzothiophene; phenyl(diphenyltriazinyl)dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; [phenyl(phenylpyridinyl)triazinyl](phenyldibenzofuranyl)benzene; [phenyl(phenylpyridinyl)triazinyl](phenyldibenzothiophenyl)benzene; [phenyl(phenylpyridinyl)triazinyl](phenyldibenzoselenophenyl)benzene; (diphenyltriazinyl)[(biphenylyl)dibenzofuranyl]pyridine; (diphenyltriazinyl)[(biphenylyl)dibenzothiophenyl]pyridine; (diphenyltriazinyl)[(biphenylyl)dibenzoselenophenyl]pyridine; phenyl[phenyl(dimethylbenzofuropyridine)triazinyl]dibenzofuran; phenyl[phenyl(dimethylbenzothienopyridine)triazinyl]dibenzothiophene; phenyl[phenyl(dimethylbenzoselenopyridine)triazinyl]dibenzoselenophene; [(biphenylyl)(dimethylbenzofuropyridine)triazinyl]dibenzofuran; [(biphenylyl)(dimethylbenzothienopyridine)triazinyl]dibenzothiophene; [(biphenylyl)(dimethylbenzoselenopyridine)triazinyl]dibenzoselenophene; phenyl[phenyl(dimethylbenzofuropyridine)triazinyl]dibenzofuran; phenyl[phenyl(dimethylbenzothienopyridine)triazinyl]dibenzothiophene; phenyl[phenyl(dimethylbenzoselenopyridine)triazinyl]dibenzoselenophene; phenyl[phenyl(spiro[cyclohexanefluorene]yl)triazinyl]dibenzofuran; phenyl[phenyl(spiro[cyclohexanefluorene]yl)triazinyl]dibenzothiophene; phenyl[phenyl(spiro[cyclohexanefluorene]yl)triazinyl]dibenzoselenophene; phenyl[phenyl(spirobi[fluorene]yl)triazinyl]dibenzofuran; phenyl[phenyl(spirobi[fluorene]yl)triazinyl]dibenzothiophene; phenyl[phenyl(spirobi[fluorene]yl)triazinyl]dibenzoselenophene; benzene-d₃[(diphenyl-d₁₀)triazinyl][(phenyl-d₅)dibenzofuranyl-d₆]; benzene-d₃[(diphenyl-d₁₀)triazinyl][(phenyl-d₅)dibenzothiophenyl-d₆]; benzene-d₃[(diphenyl-d₁₀)triazinyl][(phenyl-d₅)dibenzoselenophenyl-d₆]; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-d₉)dibenzoselenophenyl-d₆]; phenyl{phenyl[(dimethyl-d₆)fluorenyl]triazinyl}dibenzofuran; phenyl{phenyl[(dimethyl-d₆)fluorenyl]triazinyl}dibenzothiophene; phenyl{phenyl[(dimethyl-d₆)fluorenyl]triazinyl}dibenzoselenophene; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-d₉)dibenzoselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)dibenzoselenophenyl]benzene; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (difluorophenyltriazinyl)[(biphenylyl)dibenzofuranyl]benzene; (difluorophenyltriazinyl)[(biphenylyl)dibenzothiophenyl]benzene; (difluorophenyltriazinyl)[(biphenylyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]pyridine; (diphenyltriazinyl)[(dimethylfluorenyl)dibenzothiophenyl]pyridine; (diphenyltriazinyl)[(dimethylfluorenyl)dibenzoselenophenyl]pyridine; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[bis(dimethylfluorenyl)dibenzofuranyl]benzene; (diphenyltriazinyl)[bis(dimethylfluorenyl)dibenzothiophenyl]benzene; (diphenyltriazinyl)[bis(dimethylfluorenyl)dibenzoselenophenyl]benzene; [phenyl(terphenylyl)triazinyl][(dimethylfluorenyl)dibenzofuranyl]benzene; [phenyl(terphenylyl)triazinyl][(dimethylfluorenyl)dibenzothiophenyl]benzene; [phenyl(terphenylyl)triazinyl][(dimethylfluorenyl)dibenzoselenophenyl]benzene; (diphenyltriazinyl)[(spiro[cyclopentanefluorene]yl)dibenzofuranyl]benzene; (diphenyltriazinyl)[(spiro[cyclopentanefluorene]yl)dibenzothiophenyl]benzene; (diphenyltriazinyl)[(spiro[cyclopentanefluorene]yl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[(spirobi[fluorene]yl)dibenzofuranyl]benzene; (diphenyltriazinyl)[(spirobi[fluorene]yl)dibenzothiophenyl]benzene; (diphenyltriazinyl)[(spirobi[fluorene]yl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(phenyldimethylfluorenyl)dibenzofuranyl]benzene; (diphenyltriazinyl)[(phenyldimethylfluorenyl)dibenzothiophenyl]benzene; (diphenyltriazinyl)[(phenyldimethylfluorenyl)dibenzoselenophenyl]benzene; (diphenyltriazinyl){[(dimethyl-d₆)fluorenyl]dibenzofuranyl}benzene; (diphenyltriazinyl){[(dimethyl-d₆)fluorenyl]dibenzothiophenyl}benzene; (diphenyltriazinyl){[(dimethyl-d₆)fluorenyl]dibenzoselenophenyl}benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)dibenzoselenophenyl]benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)dibenzoselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]dibenzoselenophenyl}benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)dibenzoselenophenyl]; [bis(carbazole)yl]benzofuropyridine; [bis(carbazole)yl]benzothienopyridine; [bis(carbazole)yl]benzoselenopyridine; [bis(carbazole)yl]benzofuropyridine; [bis(carbazole)yl]benzothienopyridine; [bis(carbazole)yl]benzoselenopyridine; [bis(carbazole)yl]benzofuropyridine; [bis(carbazole)yl]benzothienopyridine; [bis(carbazole)yl]benzoselenopyridine; [bis(carbazole)yl]benzofuropyridine; [bis(carbazole)yl]benzothienopyridine; [bis(carbazole)yl]benzoselenopyridine; (triphenylenyl)(carbazolyl)benzofuropyridine; (triphenylenyl)(carbazoly)benzothienopyridine; (triphenylenyl)(carbazolyl)benzoselenopyridine; (dibenzothiophenyl)(carbazolyl)benzofuropyridine; (dibenzothiophenyl)(carbazolyl)benzothienopyridine; (dibenzothiophenyl)(carbazolyl)benzoselenopyridine; phenyl(triphenylenyl)benzofuropyridine; phenyl(triphenylenyl)benzothienopyridine; phenyl(triphenylenyl)benzoselenopyridine; phenyl(triphenylenyl)benzofuropyridine; phenyl(triphenylenyl)benzothienopyridine; phenyl(triphenylenyl)benzoselenopyridine; phenyl(triphenylenyl)bi[carbazole]; phenyl(triphenylenyl)bi[carbazole]; phenyl(triphenylenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; (biphenylyl)(dimethylfluorenyl)bi[carbazole]; (biphenylyl)(dimethylfluorenyl)bi[carbazole]; (terphenylyl)(dimethylfluorenyl)bi[carbazole]; diphenyl(ter[carbazole]); diphenyl(ter[carbazole]); diphenyl(ter[carbazole]); bi(phenylcarbazole); phenyl(biphenylyl)bi[carbazole]; phenyl(biphenylyl)bi[carbazole]; bi[(biphenylyl)carbazole]; bi[(biphenylyl)carbazole]; triphenylbi[carbazole]; bi[diphenylcarbazole]; diphenyl(biphenylyl)bi[carbazole]:bi[phenylcarbazole]; phenyl(biphenylyl)bi[carbazole]; phenyl(biphenylyl)bi[carbazole]; bi[(biphenylyl)carbazole]; bi[(biphenylyl)carbazole]; triphenylbi[carbazole]; bi[diphenylcarbazole]; diphenyl(biphenylyl)bi[carbazole]:phenyl(terphenylyl)bi[carbazole]; phenyl(terphenylyl)bi[carbazole]; phenyl(terphenylyl)bi[carbazole]; phenyl(diphenylpyridinyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (phenylcarbazolyl)(dibenzofuranyl)fluorene; (phenylcarbazolyl)(dibenzothiophenyl)fluorene; (phenylcarbazolyl)(dibenzoselenophenyl)fluorene; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; phenyl(phenyldibenzofuranyl)bi[carbazole]; phenyl(phenyldibenzothiophenyl)bi[carbazole]; phenyl(phenyldibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (naphthaleyl)(dibenzofuranyl)bi[carbazole]; (naphthaleyl)(dibenzothiophenyl)bi[carbazole]; (naphthaleyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (triphenylenyl)dibenzofuran; (triphenylenyl)dibenzothiophene; (triphenylenyl)dibenzoselenophene; (triphenylenyl)(dibenzofuranyl)benzene; (triphenylenyl)(dibenzothiophenyl)benzene; (triphenylenyl)(dibenzoselenophenyl)benzene; (triphenylenyl)(phenyldibenzofuranyl)benzene; (triphenylenyl)(phenyldibenzothiophenyl)benzene; (triphenylenyl)(phenyldibenzoselenophenyl)benzene; (triphenylenyl)(dibenzofuranyl)biphenyl; (triphenylenyl)(dibenzothiophenyl)biphenyl; (triphenylenyl)(dibenzoselenophenyl)biphenyl; phenyl(triphenylenyl)dibenzofuran; phenyl(triphenylenyl)dibenzothiophene; phenyl(triphenylenyl)dibenzoselenophene; (biphenylyl)(triphenylenyl)dibenzofuran; (biphenylyl)(triphenylenyl)dibenzothiophene; (biphenylyl)(triphenylenyl)dibenzoselenophene; (terphenylyl)(triphenylenyl)dibenzofuran; (terphenylyl)(triphenylenyl)dibenzothiophene; (terphenylyl)(triphenylenyl)dibenzoselenophene; (biphenylyl)[(triphenylenyl)phenyl]dibenzofuran; (biphenylyl)[(triphenylenyl)phenyl]dibenzothiophene; (biphenylyl)[(triphenylenyl)phenyl]dibenzoselenophene; (carbazolyl)(triphenylenyl)dibenzofuran; (carbazolyl)(triphenylenyl)dibenzothiophene; (carbazolyl)(triphenylenyl)dibenzoselenophene; (carbazolyl)(triphenylenyl)biphenyl; (carbazolyl)(triphenylenyl)biphenyl; iridium(III)tris[phenylpyridine-N,C′]; iridium(III)tris[methyl(phenyl)pyridine-N,C′]; iridium(III)tris[(methyl-d₃)(phenyl)pyridine-N,C′]; iridium(III)tris[(dimethyl-d₆)(phenyl)pyridine-N,C′]; iridium(III)tris[(methyl-d₆)(diphenyl)pyridine-N,C′]; iridium(III)tris[(pyridinyl)biphenyl-N,C′]; iridium(III)tris[(methylpyridinyl)biphenyl-N,C′]; iridium(III)bis(phenylpyridine-N,C′[(pyridinyl)biphenyl-N,C′]; iridium(III)bis(phenylpyridine-N,C′[(pyridinyl)biphenyl-N,C′]; iridium(III)bis(phenylpyridine-N,C′[(methylpyridinyl)biphenyl-N,C′]; iridium(III)bis(phenylpyridine-N,C′[(methylpyridinyl)biphenyl-N,C′]; iridium(III)bis(phenylpyridine-N,C′{[(methyl-d₃)pyridinyl]biphenyl-N,C′}; iridium(III)bis(phenylpyridine-N,C′[(methyl)(diphenyl)pyridine-N,C′]; iridium(III)bis(phenylpyridine-N,C′[(methyl-d₃)(diphenyl)pyridine-N,C′]; iridium(III)bis(phenylpyridine-N,C′[ethane-d₃-(diphenyl)pyridine-N,C′]; iridium(III)bis(phenylpyridine-N,C′[(methyl)(diphenyl)pyridine-N,C′]; iridium(III)bis[(methyl)(phenyl)pyridine-N,C′][(methyl)(phenyl)(naphthaleyl)pyridine-N,C′]; iridium(III)bis[(methyl)(phenyl)pyridine-N,C′][(methyl)(diphenyl)pyridine-N,C′]; iridium(III)bis[(methy)(phenyl)pyridine-N,C′][diphenylpyridine-N,C′]; iridium(III)bis{[(methylphenyl-d₃)pyridined₄]-N,C′}{[(diphenyl-d)pyridined₄]-N,C′}; iridium(III)bis[(methyl)(phenyl)pyridine-N,C′][diphenylpyridine-N,C′]; iridium(III)bis[(methyl-d₃)(phenyl)pyridine-N,C′][diphenylpyridine-N,C′]; iridium(III)bis[phenylpyridine-N,C′][(methyl)(diphenyl)pyridine-N,C′]; iridium(III)bis[phenylpyridine-N,C′][(methyl-d₃)(diphenyl)pyridine-N,C′]; iridium(III)bis[phenylpyridine-N,C′][(ethyl)(diphenyl)pyridine-N,C′]; iridium(III)bis[phenylpyridine-N,C′][(methyl)(phenyl)(fluorophenyl)pyridine-N,C′]; iridium(III)bis[phenylpyridine-N,C′][(dibenzofuranyl)pyridine-N,C′]; iridium(III)bis[phenylpyridine-N,C′][(isopropyl)(dibenzofuranyl)pyridine-N,C′]; iridium(III)bis[(methyl)(phenyl)pyridine-N,C′][(isopropyl)(dibenzofuranyl)pyridine-N,C′]; iridium(III)bis[phenylpyridine-N,C′][(isopropyl-d₇)(dibenzofuranyl)pyridine-N,C′]; iridium(III)bis[(methyl-d₃)(phenyl)pyridine-N,C′][(isopropyl-d₇)(dibenzofuranyl)pyridine-N,C′]; iridium(III)bis[(methyl-d₃)(phenyl)pyridine-N,C′][(methyl-d₃)(diphenyl)pyridine-N,C′]; iridium(III)bis[phenylpyridine-N,C′][(isopropyl)(isopropylbenzofuropyridinyl)pyridine-N,C′]; iridium(III)bis[phenylpyridine-N,C′][(benzofuropyridinyl)pyridine-N,C′]; iridium(III)bis[phenylpyridine-N,C′][(benzofuropyridinyl)pyridine-N,C′]; iridium(III)bis[phenylpyridine-N,C′][(methylbenzofuropyridinyl)pyridine-N,C′]; iridium(III)bis[phenylpyridine-N,C′]{[(methyl-d₃)benzofuropyridinyl]pyridine-N,C′}; iridium(III)bis[phenylpyridine-N,C′][(methylbenzofuropyridinyl)pyridine-N,C′]; iridium(III)bis[phenylpyridine-N,C′]{[(methyl-d₃)benzofuropyridinyl]pyridine-N,C′}; iridium(III)bis[(methyl-d₃)(phenyl)pyridine-N,C′]{[(methyl-d₃)benzofuropyridinyl]pyridine-N,C′}; iridium(III)bis[(methyl-d₃)(phenyl)pyridine-N,C′][(isopropyl-d₇)(benzofuropyridinyl)pyridine-N,C′]; iridium(III)bis[(methyl-d₃)(phenyl)pyridine-N,C′]{(isopropyl-d₇)[(methyl-d₃)benzofuropyridinyl]pyridine-N,C′}; iridium(III)bis[(isopropyl-d₇)(phenyl)pyridine-N,C′]{(isopropyl-d₇)[(methyl-d₃)benzofuropyridinyl]pyridine-N,C′}; iridium(III)bis[(methyl-d₃)(phenyl)pyridine-N,C′][(isopropyl-d₁)(benzofuropyridinyl)pyridine-N,C′]; iridium(III)bis[(methyl-d₃)(phenyl)pyridine-N,C′]{(isopropyl-d₁)[(methyl-d₃)benzofuropyridinyl]pyridine-N,C′}; iridium(III)bis[(methyl-d₃)(phenyl)pyridine-N,C′][(isopropyl)(methyl-d₃)(benzofuropyridinyl)pyridine-N,C′]; iridium(III)bis[(methyl-d₃)(phenyl)pyridine-N,C′][(isopropyl-d₁)(methyl-d₃)(benzofuropyridinyl)pyridine-N,C′]; iridium(III)bis[(dimethyl-d₆)(phenyl)pyridine-N,C′]{(isopropyl-d₇)[(methyl-d₃)benzofuropyridinyl]pyridine-N,C′}; iridium(III)bis[(dimethyl-de)(phenyl)pyridine-N,C′]{(isopropyl)(methyl-d₃)[(methyl-d₃)benzofuropyridinyl]pyridine-N,C′}; iridium(III)bis[(dimethyl-de)(phenyl)pyridine-N,C′]{(isopropyl-d₇)(methyl-d₃)[(methyl-d₃)benzofuropyridinyl]pyridine-N,C′}; iridium(III)bis[(dimethyl-d₆)(phenyl)pyridine-N,C′]{(isopropyl-d₇)(methyl-d₃)[(methyl-d₃)benzofuropyridinyl]pyridine-N,C′}; iridium(III)bis[(methyl-d₃)(phenyl)pyridine-N,C′]{(isopropyl-d₇)(methyl-d₃)[(methyl-d₃)benzofuropyridinyl]pyridine-N,C′}; iridium(III)bis(phenylpyridine-N,C′{[(dimethyl-de)benzofuropyridinyl]pyridine-N,C′}; iridium(III)bis[(dimethyl-d₆)(phenyl)pyridine-N,C′]{(isopropyl)[(isopropyl)benzofuropyridinyl]pyridine-N,C′}; iridium(III)bis[(dimethyl-d₆)(phenyl)pyridine-N,C′]{(isopropyl-d₁)[(isopropyl-d₁)benzofuropyridinyl]pyridine-N,C′}; iridium(III)bis[(methyl-d₃)(phenyl)pyridine-N,C′]{(isopropyl-d₁)[(isopropyl-d₁)benzofuropyridinyl]pyridine-N,C′}; iridium(III)bis[(phenyl)pyridine-N,C′]{[(dimethyl-de)benzofuropyridinyl]pyridine-N,C′}; iridium(III)bis[(phenyl)pyridine-N,C′]{[(dimethyl-de)benzofuropyridinyl]pyridine-N,C′}; iridium(III)bis[(methyl-d₃)(phenyl)pyridine-N,C′][diphenylpyridine-N,C′]; iridium(III)bis[phenylpyridine-N,C′][diphenylpyridine-N,C′]; iridium(III)bis{[methyl(phenyl-d₃)](pyridined₄)-N,C′]{[(diphenyl-d)(pyridined₃)]-N,C′}; iridium(III)bis[phenylpyridine-N,C′]{phenyl[(methyl-d₃)phenyl]pyridine-N,C′]; iridium(III)bis[(methyl)(phenyl)pyridine-N,C′][diphenylpyridine-N,C′]; iridium(III)bis[(dimethyl)(phenyl)pyridine-N,C′][diphenylpyridine-N,C′]; iridium(III)bis[(dimethyl)(phenyl)pyridine-N,C′]{phenyl[(methyl-d₃)phenyl]pyridine-N,C′]; iridium(III)bis[(dimethyl-de)(phenyl)pyridine-N,C′][diphenylpyridine-N,C′]; iridium(III)bis[(methyl)(phenyl)pyridine-N,C′][diphenylpyridine-N,C′]; iridium(III)bis[(phenyl)pyridine-N,C′][(fluorophenyl)(methylbenzofuropyridinyl)pyridine-N,C′]; iridium(III)bis[(phenyl)pyridine-N,C′][(fluorophenyl)(methylbenzofuropyridinyl)pyridine-N,C′]; iridium(III)bis[(phenyl)pyridine-N,C′]{(fluorophenyl)[(methyl-d₃)benzofuropyridinyl]pyridine-N,C′}; iridium(III)bis[(phenyl)pyridine-N,C′]{(fluorophenyl)[(methyl-d₃)benzofuropyridinyl]pyridine-N,C′}; iridium(III)bis[(phenyl)pyridine-N,C′]{(phenyl)[(methyl-d₃)benzofuropyridinyl]pyridine-N,C′}; iridium(III)bis[(phenyl)pyridine-N,C′][phenylbipyridine-N,C′]; iridium(III)bis[(isopropylphenyl)pyridine-N,C′][(fluorophenyl)(methylbenzofuropyridinyl)pyridine-N,C′]; iridium(III)bis{[(isopropyl-d₇)phenyl]pyridine-N,C′}{(fluorophenyl)[(methyl-d₃)benzofuropyridinyl]pyridine-N,C′}; iridium(III)bis{[(isopropyl-d₇)phenyl]pyridine-N,C′}{(fluorophenyl)[(methyl-d₃)benzofuropyridinyl]pyridine-N,C′}; iridium(III)bis{[(methylphenyltriazinyl)phenyl]pyridine-N,C′}iridium(III)bis[phenylquinoline-N,C′](acetylacetonate); iridium(III)bis[(methyl)(methylphenyl)quinoline-N,C′](acetylacetonate); iridium(III)bis[(methyl)(methylphenyl)quinoline-N,C′](diethylnonanedionate); iridium(III)bis[(methyl)(methylphenyl)quinoline-N,C′](methyldiethylnonanedionate); iridium(III)bis[(dimethylphenyl)quinoline-N,C′](acetylacetonate); iridium(III)bis[(isobutyl)(dimethylphenyl)quinoline-N,C′](acetylacetonate); iridium(III)bis[(isobutyl)(methylphenyl)quinoline-N,C′](dimethylnonanedionate); iridium(III)bis[(isobutyl)(methylphenyl)quinoline-N,C′](dimethylheptanedionate); iridium(III)bis[(isobutyl)(dimethylphenyl)quinoline-N,C′](acetylacetonate); iridium(III)bis[(isobutyl)(dimethylphenyl)quinoline-N,C′](dimethylnonanedionate); iridium(III)bis[(phenyl)quinoline-N,C′](diethylnonanedionate); iridium(III)bis[(isopentyl)(dimethylphenyl)quinoline-N,C′](diethylnonanedionate); iridium(III)bis[(isobutyl)(dimethylphenyl)quinoline-N,C′](diethylnonanedionate); iridium(III)bis[(isobutyl)(dimethylphenyl)quinoline-N,C′](bis[cyclopentyl]acetylacetonate); iridium(III)bis[(isobutyl)(dimethylphenyl)quinoline-N,C′](bis[cyclohexyl]acetylacetonate); iridium(III)bis[(diisobutyl)(dimethylphenyl)quinoline-N,C′](acetylacetonate); iridium(III)bis[(dimethyl)(dimethylphenyl)quinoline-N,C′](ethylmethyldecanedionate); iridium(III)bis[(dimethyl)(dimethylphenyl)quinoline-N,C′](dimethylnonanedionate); iridium(III)bis[(dimethyl)[(dimethyl-de)phenyl]quinoline-N,C′](acetylacetonate); iridium(III)bis[methyl(diphenyl)dibenzoquinoxaline-N,C′](acetylacetonate); iridium(III)bis[(phenyl)quinoline-N,C′](acetylacetonate); iridium(III)bis[(phenyl)isoquinoline-N,C′](acetylacetonate); iridium(III)bis[(cyclobutyl)(dimethylphenyl)quinoline-N,C′](diethylnonanedionate); iridium(III)bis[(cyclopentyl)(dimethylphenyl)quinoline-N,C′](diethylnonanedionate); iridium(III)bis[(cyclobutyl)(dimethylphenyl)quinoline-N,C′](methyldiethylnonanedionate); iridium(III)bis[(cyclopentyl)(dimethylphenyl)quinoline-N,C′](methyldiethylnonanedionate); iridium(III)bis[(cyclohexyl)(methylphenyl)quinoline-N,C′](acetylacetonate); iridium(III)bis[(methylphenyl)(dimethylphenyl)quinoline-N,C′](diethylnonanedionate); iridium(III)bis[(trifluoropropyl)(dimethylphenyl)quinoline-N,C′](diethylnonanedionate); iridium(III)bis[(trifluoropropyl)(dimethylphenyl)quinoline-N,C′](acetylacetonate); iridium(III)bis[(trifluoropropyl)(dimethylphenyl)quinoline-N,C′][bis(cyclopentyl)acetylacetonate]; iridium(III)bis[(trifluoropropyl)(dimethylphenyl)quinoline-N,C′][bis(cyclohexyl)acetylacetonate]; iridium(III)bis[(trifluoropropyl)(dimethylphenyl)quinoline-N,C′](diethylnonanedionate); iridium(III)bis[(trifluoropropyl)(dimethylphenyl)quinoline-N,C′](acetylacetonate); iridium(III)bis[(trifluoropropyl)(dimethylphenyl)quinoline-N,C′][bis(cyclopentyl)acetylacetonate]; iridium(III)bis[(trifluoropropyl)(dimethylphenyl)quinoline-N,C′][bis(cyclohexyl)acetylacetonate]; iridium(III)bis[(trifluorodimethylbutyl)(dimethylphenyl)quinoline-N,C′](diethylnonanedionate); iridium(III)bis[(trifluorodimethylbutyl)(dimethylphenyl)quinoline-N,C′](acetylacetonate); iridium(III)bis[(trifluorodimethylbutyl)(dimethylphenyl)quinoline-N,C′][bis(cyclohexyl)acetylacetonate]; iridium(III)bis[(trifluorodimethylbutyl)(dimethylphenyl)quinoline-N,C′][bis(cyclopentyl)acetylacetonate]; iridium(III)bis[(trifluorodimethylbutyl)(dimethylphenyl)quinoline-N,C′][diethylnonanedionate]; iridium(III)bis[(trifluorodimethylbutyl)(dimethylphenyl)quinoline-N,C′][acetylacetonate]; iridium(III)bis[(trifluorodimethylbutyl)(dimethylphenyl)quinoline-N,C′][bis(cyclopentyl)acetylacetonate]; iridium(III)bis[(trifluorodimethylbutyl)(dimethylphenyl)quinoline-N,C′][bis(cyclohexyl)acetylacetonate]; iridium(III)bis[(trifluoropropyl)(dimethylphenyl)quinoline-N,C′][bis(ethylmethylisopropylnonanedionate]; iridium(III)bis[(tifluorodimethylbutyl(dimethylphenyl)quinoline-N,C′][dimethyldiisopropylnonanedionate]; iridium(III)bis[(tisfluorodimethylbutyl(dimethylphenyl)quinoline-N,C′][dimethyldiisopropylnonanedionate]; iridium(III)bis[(isobutyl)(dimethylbenzofuropyridinyl)quinoline-N,C′][dimethyldiisopropylnonanedionate]; iridium(III)bis[(isobutyl)(dimethylbenzofuropyridinyl)quinoline-N,C′][diethylnonanedionate]; iridium(III)bis[(tifluorodimethylbutyl(dimethylbenzofuropyriinyl)quinoline-N,C′][diethylmethylnonanedionate]; iridium(III)bis[(isobutyl)(dimethylphenyl)quinoline-N,C′][dimethyldiisopropylnonanedionate]; iridium(III)bis[(isopropylphenyl)quinoline-N,C′]{[di(isopropyl)triazinyl](methylbenzofuropyidinyl)pyridine-N,C′}; iridium(III)bis[(isopropyl)(dimethylphenyl)isoquinoline-N,C′][diethylnonanedionate]; iridium(III)bis[(isopropyl)(dimethylphenyl)isoquinoline-N,C′][diethylnonanedionate]; iridium(III)bis[di(isopropyl)(dimethylphenyl)isoquinoline-N,C′][acetylacetonate]; iridium(III)tris[dimethyldibenzoquinoline-N,C′]; iridium(III)bis[(tert-butylphenyl)thienoisoquinoline-N,C′][acetylacetonate]; iridium(III)bis[(phenyl)thienopyridine-N,C′][acetylacetonate]; iridium(III)bis[(dimethylfluorenyl)quinoline-N,C′][acetylacetonate]; iridium(III)bis[(methylnaphthaleyl)pyridine-N,C′][acetylacetonate]; iridium(III)bis{[(methyl)(fluoro)phenyl]isoquinoline-N,C′}[acetylacetonate]; iridium(III)bis[(methyl)(fluoro)(dimethylphenyl)quinoline-N,C′][acetylacetonate]

### (Group 22A)

phenyl(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; bis(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spiro[cyclopentanefluorene]yl)(terphenylyl)indolocarbazole; (spiro[cyclohexanefluorene]yl)(terphenylyl)indolocarbazole; (dimethylfluorenyl)(terphenylyl)indolocarbazole; (spirobi[fluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (phenylcarbazolyl)(terphenylyl)indolocarbazole; [(carbazolyl)phenyl](terphenylyl)indolocarbazole; (benzothienopyridinyl)(terphenylyl)indolocarbazole; (benzothienopyrimidineyl)(terphenylyl)indolocarbazole; (benzothienopyrimidineyl)(terphenylyl)indolocarbazole; (phenylbenzothienopyrimidineyl)(terphenylyl)indolocarbazole; (diphenyltriazinyl)(terphenylyl)indolocarbazole; (phenylquinazolinyl)(terphenylyl)indolocarbazole; (dibenzoquinazolinyl)(terphenylyl)indolocarbazole; (dibenzoquinoxalinyl)(terphenylyl)indolocarbazole; [(phenyl-d₅)biphenylyl](biphenylyl)indolocarbazole; [(phenyl-d₅)biphenylyl](phenyl-d₅)indolocarbazole; [(dimethyl-d₆)fluorenyl](terphenylyl)indolocarbazole; [(dibenzofuranyl)phenyl](terphenylyl)indolocarbazole; [(dibenzothiophenyl)phenyl](terphenylyl)indolocarbazole; [(triphenylenyl)phenyl](terphenylyl)indolocarbazole; [(diphenyltriazinyl)phenyl](terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spiro[cyclohexanefluorene]yl)(terphenylyl)indolocarbazole; (spiro[cyclopentanefluorene]y)(terphenylyl)indolocarbazole; (spirobi[fluorene]yl)(terphenylyl)indolocarbazole; (dimethylfluorenyl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (phenylcarbazolyl)(terphenylyl)indolocarbazole; [(carbazolyl)phenyl](terphenylyl)indolocarbazole; (benzothienopyridinyl)(terphenylyl)indolocarbazole; (benzothienopyrimidineyl)(terphenylyl)indolocarbazole; (benzothienopyrimidineyl)(terphenylyl)indolocarbazole; (phenylbenzothienopyrimidineyl)(terphenylyl)indolocarbazole; (diphenylbenzothienopyrimidineyl)(terphenylyl)indolocarbazole; (diphenylbenzothienopyrimidineyl)(terphenylyl)indolocarbazole; (diphenyltriazinyl)(terphenylyl)indolocarbazole; (phenylpyridotriazinyl)(terphenylyl)indolocarbazole; (dibenzopyrimidineyl)(terphenylyl)indolocarbazole; (dibenzoquinoxalinyl)(terphenylyl)indolocarbazole; [(dimethyl-d₆)fluorenyl](terphenylyl)indolocarbazole; [(diphenyltriazinyl)phenyl](terphenylyl)indolocarbazole; [(phenyl-d₅)biphenylyl](biphenylyl)indolocarbazole; [(phenyl-d₅)biphenylyl](phenyl-d₅)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spirobi[fluorene]yl)(terphenylyl)indolocarbazole; (spiro[cyclopentanefluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (diphenyltriazinyl)(terphenylyl)indolocarbazole; (phenylquinazolinyl)(terphenylyl)indolocarbazole; (benzothienopyrimidineyl)(terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spirobi[fluorene]yl)(terphenylyl)indolocarbazole; (spiro[cyclopentanefluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (diphenyltriazinyl)(terphenylyl)indolocarbazole; (phenylquinazolinyl)(terphenylyl)indolocarbazole; (benzothienopyrimidineyl)(terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; (dimethylfluorenyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (benzothienopyridinyl)(terphenylyl)indolocarbazole; (benzothienopyrimidineyl)(terphenylyl)indolocarbazole; (diphenyltriazinyl)(terphenylyl)indolocarbazole; (phenylquinazolinyl)(terphenylyl)indolocarbazole; [(phenyl-d₅)biphenylyl](biphenylyl)indolocarbazole; [(cyclohexyl-d₅)biphenylyl](phenyl-d₅)indolocarbazole; (phenyl)(terphenylyl)indolocarbazole; (biphenylyl)(terphenylyl)indolocarbazole; (biphenylyl)(terphenylyl)indolocarbazole; (dibenzothiophenyl)(terphenylyl)indolocarbazole; (dibenzothiophenyl)(terphenylyl)indolocarbazole; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terphenyl; (phenyldibenzothiophenyl)(diphenyltriazinyl)terphenyl; (phenyldibenzoselenophenyl)(diphenyltriazinyl)terphenyl; (phenyldibenzofuranyl)(diphenyltriazinyl)terphenyl; (phenyldibenzothiophenyl)(diphenyltriazinyl)terphenyl; (phenyldibenzoselenophenyl)(diphenyltriazinyl)terphenyl; [(biphenylyl)dibenzofuranyl](diphenyltriazinyl)terphenyl; [(biphenylyl)dibenzothiophenyl](diphenyltriazinyl)terphenyl; [(biphenylyl)dibenzoselenophenyl](diphenyltriazinyl)terphenyl; [phenyl(biphenylyl)triazinyl](dibenzofuranyl)biphenyl; [phenyl(biphenylyl)triazinyl](dibenzothiophenyl)biphenyl; [phenyl(biphenylyl)triazinyl](dibenzoselenophenyl)biphenyl; [phenyl(biphenylyl)triazinyl](dibenzofuranyl)biphenyl; [phenyl(biphenylyl)triazinyl](dibenzothiophenyl)biphenyl; [phenyl(biphenylyl)triazinyl](dibenzoselenophenyl)biphenyl; [bis(biphenylyl)triazinyl](dibenzofuranyl)biphenyl; [bis(biphenylyl)triazinyl](dibenzothiophenyl)biphenyl; [bis(biphenylyl)triazinyl](dibenzoselenophenyl)biphenyl; [phenyl(dimethylfluorenyl)triazinyl](dibenzofuranyl)biphenyl; [phenyl(dimethylfluorenyl)triazinyl](dibenzothiophenyl)biphenyl; [phenyl(dimethylfluorenyl)triazinyl](dibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(dimethylfluorenyl)triazinyl](phenyldibenzofuranyl)biphenyl; [phenyl(dimethylfluorenyl)triazinyl](phenyldibenzothiophenyl)biphenyl; [phenyl(dimethylfluorenyl)triazinyl](phenyldibenzoselenophenyl)biphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; [phenyl(dimethylfluorenyl)triazinyl](dibenzofuranyl)terphenyl; [phenyl(dimethylfluorenyl)triazinyl](dibenzothiophenyl)terphenyl; [phenyl(dimethylfluorenyl)triazinyl](dibenzoselenophenyl)terphenyl; [phenyl(biphenylyl)triazinyl][(biphenylyl)dibenzofuranyl)]biphenyl; [phenyl(biphenylyl)triazinyl][(biphenylyl)dibenzothiophenyl)]biphenyl; [phenyl(biphenylyl)triazinyl][(biphenylyl)dibenzoselenophenyl)]biphenyl; [phenyl(biphenylyl)triazinyl][(biphenylyl)dibenzofuranyl)]biphenyl; [phenyl(biphenylyl)triazinyl][(biphenylyl)dibenzothiophenyl)]biphenyl; [phenyl(biphenylyl)triazinyl][(biphenylyl)dibenzoselenophenyl)]biphenyl; [phenyl(dimethylfluorenyl)triazinyl][(biphenylyl)dibenzofuranyl)]biphenyl; [phenyl(dimethylfluorenyl)triazinyl][(biphenylyl)dibenzothiophenyl]biphenyl; [phenyl(dimethylfluorenyl)triazinyl][(biphenylyl)dibenzoselenophenyl]biphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; (dibenzofuranyl)[phenyl(biphenylyl)triazinyl]terphenyl; (dibenzothiophenyl)[phenyl(biphenylyl)triazinyl]terphenyl; (dibenzoselenophenyl)[phenyl(biphenylyl)triazinyl]terphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiopheny)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(phenyldibenzofuranyl)(pyridinyl)phenyl; (diphenyltriazinyl)(phenyldibenzothiophenyl)(pyridinyl)phenyl; (diphenyltriazinyl)(phenyldibenzoselenophenyl)(pyridinyl)phenyl; (diphenyltriazinyl)(phenyldibenzofuranyl)(pyridinyl)phenyl; (diphenyltriazinyl)(phenyldibenzothiophenyl)(pyridinyl)phenyl; (diphenyltriazinyl)(phenyldibenzoselenophenyl)(pyridinyl)phenyl; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (dibenzofuranyl)(diphenyltriazinyl)terphenyl; (dibenzothiophenyl)(diphenyltriazinyl)terphenyl; (dibenzoselenophenyl)(diphenyltriazinyl)terphenyl; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terphenyl; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terphenyl; (diphenyltriazinyl)[bis(diphenylfluorenyl)]benzene; (diphenyltriazinyl)(diphenylfluorenyl)terbenzene; (diphenyltriazinyl)(triphenylenyl)biphenyl; phenyl[(diphenyltriazinyl)phenyl]indolocarbazole; (biphenylyl)[(diphenyltriazinyl)phenyl]indolocarbazole; (biphenylyl)[(diphenyltriazinyl)phenyl]indolocarbazole; (dimethylfluorenyl)[(diphenyltriazinyl)phenyl]indolocarbazole; (dibenzothiophenyl)[(diphenyltriazinyl)phenyl]indolocarbazole; (dibenzofuranyl)[(diphenyltriazinyl)phenyl]indolocarbazole; (dibenzothiophenyl)[(diphenyltriazinyl)phenyl]indolocarbazole; (phenyl)[(diphenyltriazinyl)biphenylyl]indolocarbazole; (phenyl)[(diphenyltriazinyl)terphenyl]indolocarbazole; (phenyl)[(diphenyltriazinyl)terphenylyl]indolocarbazole; (phenyl)[((phenyl)(biphenylyl)triazinyl)phenyl]indolocarbazole; (phenyl)[(di(biphenylyl)triazinyl)phenyl]indolocarbazole; (phenyl)[((phenyl)(biphenylyl)triazinyl)phenyl]indolocarbazole; (phenyl)[((phenyl)(naphthyl)triazinyl)phenyl]indolocarbazole; (phenylcarbazolyl)[(diphenyltriazinyl)phenyl]indolocarbazole; (phenylcarbazolyl)[(diphenyltriazinyl)phenyl]indolocarbazole; (phenylcarbazolyl)[(diphenyltriazinyl)phenyl]indolocarbazole; di(phenyl)(triphenylenylbiphenylyl)triazine; (phenyl)(biphenylyl)(triphenylenylphenyl)triazine; (phenyl)(biphenylyl)(triphenylenylphenyl)triazine; di(biphenylyl)(triphenylenylphenyl)triazine; di(phenyl)(triphenylenylbiphenylyl)triazine; di(biphenylyl)(triphenylenyl)triazine; di(biphenylyl)(triphenylenyl)triazine; (phenyl)(biphenylyl)(triphenylenyl)triazine; (phenyl)(biphenylyl)(triphenylenyl)triazine; (naphthyl)[(diphenyltriazinyl)phenyl]indolocarbazole; (phenyl)(diphenyltriazinyl)dibenzofuran; (phenyl)(diphenyltriazinyl)dibenzothiophene; (phenyl)(diphenyltriazinyl)dibenzoselenophene; (phenyl)[(phenyl)(biphenylyl)triazinyl]dibenzofuran; (phenyl)[(phenyl)(biphenylyl)triazinyl]dibenzothiophene; (phenyl)[(phenyl)(biphenylyl)triazinyl]dibenzoselenophene; (phenyl)[(phenyl)(biphenylyl)triazinyl]dibenzofuran; (phenyl)[(phenyl)(biphenylyl)triazinyl]dibenzothiophene; (phenyl)[(phenyl)(biphenylyl)triazinyl]dibenzoselenophene; (phenyl)[di(biphenylyl)triazinyl]dibenzofuran; (phenyl)[di(biphenylyl)triazinyl]dibenzothiophene; (phenyl)[di(biphenylyl)triazinyl]dibenzoselenophene; (phenyl)[di(biphenylyl)triazinyl]dibenzofuran; (phenyl)[di(biphenylyl)triazinyl]dibenzothiophene; (phenyl)[di(biphenylyl)triazinyl]dibenzoselenophene; (phenyl)[di(biphenylyl)triazinyl]dibenzofuran; (phenyl)[di(biphenylyl)triazinyl]dibenzothiophene; (phenyl)[di(biphenylyl)triazinyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (phenyl)[(phenyl)(biphenylyl)triazinylphenyl]dibenzofuran; (phenyl)[(phenyl)(biphenylyl)triazinylphenyl]dibenzothiophene; (phenyl)[(phenyl)(biphenylyl)triazinylphenyl]dibenzoselenophene; (phenyl)[(phenyl)(biphenylyl)triazinylphenyl]dibenzofuran; (phenyl)[(phenyl)(biphenylyl)triazinylphenyl]dibenzothiophene; (phenyl)[(phenyl)(biphenylyl)triazinylphenyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (phenyl)[(phenyl)(biphenylyl)triazinylphenyl]dibenzofuran; (phenyl)[(phenyl)(biphenylyl)triazinylphenyl]dibenzothiophene; (phenyl)[(phenyl)(biphenylyl)triazinylphenyl]dibenzoselenophene; (phenyl)[(phenyl)(biphenylyl)triazinylphenyl]dibenzofuran; (phenyl)[(phenyl)(biphenylyl)triazinylphenyl]dibenzothiophene; (phenyl)[(phenyl)(biphenylyl)triazinylphenyl]dibenzoselenophene; (phenyl)[(diphenyltriazinyl)biphenylyl]dibenzofuran; (phenyl)[(diphenyltriazinyl)biphenylyl]dibenzothiophene; (phenyl)[(diphenyltriazinyl)biphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (phenyl)[(diphenyltriazinyl)biphenylyl]dibenzofuran; (phenyl)[(diphenyltriazinyl)biphenylyl]dibenzothiophene; (phenyl)[(diphenyltriazinyl)biphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (phenyl)[(diphenyltriazinyl)biphenylyl]dibenzofuran; (phenyl)[(diphenyltriazinyl)biphenylyl]dibenzothiophene; (phenyl)[(diphenyltriazinyl)biphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (phenyl)[(phenyl)(biphenylyl)triazinylbiphenylyl]dibenzofuran; (phenyl)[(phenyl)(biphenylyl)triazinylbiphenylyl]dibenzothiophene; (phenyl)[(phenyl)(biphenylyl)triazinylbiphenylyl]dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)[(phenyl)(biphenylyl)triazinyl]dibenzofuran; (biphenylyl)[(phenyl)(biphenylyl)triazinyl]dibenzothiophene; (biphenylyl)[(phenyl)(biphenylyl)triazinyl]dibenzoselenophene; (biphenylyl)[(phenyl)(biphenylyl)triazinyl]dibenzofuran; (biphenylyl)[(phenyl)(biphenylyl)triazinyl]dibenzothiophene; (biphenylyl)[(phenyl)(biphenylyl)triazinyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[di(phenyl)triazinyl]dibenzofuran; (biphenylyl)[di(phenyl)triazinyl]dibenzothiophene; (biphenylyl)[di(phenyl)triazinyl]dibenzoselenophene; (biphenylyl)[(phenyl)(biphenylyl)triazinyl]dibenzofuran; (biphenylyl)[(phenyl)(biphenylyl)triazinyl]dibenzothiophene; (biphenylyl)[(phenyl)(biphenylyl)triazinyl]dibenzoselenophene; (biphenylyl)[(phenyl)(biphenylyl)triazinyl]dibenzofuran; (biphenylyl)[(phenyl)(biphenylyl)triazinyl]dibenzothiophene; (biphenylyl)[(phenyl)(biphenylyl)triazinyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (biphenylyl)[(phenyl)(biphenylyl)triazinylphenyl]dibenzofuran; (biphenylyl)[(phenyl)(biphenylyl)triazinylphenyl]dibenzothiophene; (biphenylyl)[(phenyl)(biphenylyl)triazinylphenyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (phenyl)[(biphenylyl)(dimethylfluorenyl)triazinyl]dibenzofuran; (phenyl)[(biphenylyl)(dimethylfluorenyl)triazinyl]dibenzothiophene; (phenyl)[(biphenylyl)(dimethylfluorenyl)triazinyl]dibenzoselenophene; (phenyl)[(biphenylyl)(dimethylfluorenyl)triazinyl]dibenzofuran; (phenyl)[(biphenylyl)(dimethylfluorenyl)triazinyl]dibenzothiophene; (phenyl)[(biphenylyl)(dimethylfluorenyl)triazinyl]dibenzoselenophene; (phenyl)[(phenyl)(dimethylfluorenyl)triazinylphenyl]dibenzofuran; (phenyl)[(phenyl)(dimethylfluorenyl)triazinylphenyl]dibenzothiophene; (phenyl)[(phenyl)(dimethylfluorenyl)triazinylphenyl]dibenzoselenophene; (phenyl)[bis(dimethylfluorenyl)triazinylphenyl]dibenzofuran; (phenyl)[bis(dimethylfluorenyl)triazinylphenyl]dibenzothiophene; (phenyl)[bis(dimethylfluorenyl)triazinylphenyl]dibenzoselenophene; (biphenylyl)[(phenyl)(dimethylfluorenyl)triazinyl]dibenzofuran; (biphenylyl)[(phenyl)(dimethylfluorenyl)triazinyl]dibenzothiophene; (biphenylyl)[(phenyl)(dimethylfluorenyl)triazinyl]dibenzoselenophene; (biphenylyl)[(phenyl)(dimethylfluorenyl)triazinyl]dibenzofuran; (biphenylyl)[(phenyl)(dimethylfluorenyl)triazinyl]dibenzothiophene; (biphenylyl)[(phenyl)(dimethylfluorenyl)triazinyl]dibenzoselenophene; (biphenylyl)[(phenyl)(dimethylfluorenyl)triazinylphenyl]dibenzofuran; (biphenylyl)[(phenyl)(dimethylfluorenyl)triazinylphenyl]dibenzothiophene; (biphenylyl)[(phenyl)(dimethylfluorenyl)triazinylphenyl]dibenzoselenophene; (biphenylyl)[(phenyl)(dimethylfluorenyl)triazinylphenyl]dibenzofuran; (biphenylyl)[(phenyl)(dimethylfluorenyl)triazinylphenyl]dibenzothiophene; (biphenylyl)[(phenyl)(dimethylfluorenyl)triazinylphenyl]dibenzoselenophene; (phenyl)[(phenyl)(dimethylfluorenylphenyl)triazinyl]dibenzofuran; (phenyl)[(phenyl)(dimethylfluorenylphenyl)triazinyl]dibenzothiophene; (phenyl)[(phenyl)(dimethylfluorenylphenyl)triazinyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (biphenylyl)[(phenyl)(dimethylfluorenyl)triazinyl]dibenzofuran; (biphenylyl)[(phenyl)(dimethylfluorenyl)triazinyl]dibenzothiophene; (biphenylyl)[(phenyl)(dimethylfluorenyl)triazinyl]dibenzoselenophene; (biphenylyl)[(phenyl)(dimethylfluorenyl)triazinylphenyl]dibenzofuran; (biphenylyl)[(phenyl)(dimethylfluorenyl)triazinylphenyl]dibenzothiophene; (biphenylyl)[(phenyl)(dimethylfluorenyl)triazinylphenyl]dibenzoselenophene; (phenyl)[(dimethylfluorenyl)terphenylyl]dibenzofuran; (phenyl)[(dimethylfluorenyl)terphenylyl]dibenzothiophene; (phenyl)[(dimethylfluorenyl)terphenylyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; di(phenyl)[di(phenyl)triazinylphenyl]dibenzofuran; di(phenyl)[di(phenyl)triazinylphenyl]dibenzothiophene; di(phenyl)[di(phenyl)triazinylphenyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (biphenylyl)[di(phenyl)triazinyl]dibenzofuran; (biphenylyl)[di(phenyl)triazinyl]dibenzothiophene; (biphenylyl)[di(phenyl)triazinyl]dibenzoselenophene; (biphenylyl)[di(phenyl)triazinyl]dibenzofuran; (biphenylyl)[di(phenyl)triazinyl]dibenzothiophene; (biphenylyl)[di(phenyl)triazinyl]dibenzoselenophene; di(phenyl)[di(phenyl)triazinylphenyl]dibenzofuran; di(phenyl)[di(phenyl)triazinylphenyl]dibenzothiophene; di(phenyl)[di(phenyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (biphenylyl)[di(phenyl)triazinylphenyl]dibenzofuran; (biphenylyl)[di(phenyl)triazinylphenyl]dibenzothiophene; (biphenylyl)[di(phenyl)triazinylphenyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (phenyl)[di(phenyl)triazinylpyridyl]dibenzofuran; (phenyl)[di(phenyl)triazinylpyridyl]dibenzothiophene; (phenyl)[di(phenyl)triazinylpyridyl]dibenzoselenophene; (phenyl)[(phenyl)(phenylpyridyl)triazinylpyridyl]dibenzofuran; (phenyl)[(phenyl)(phenylpyridyl)triazinylpyridyl]dibenzothiophene; (phenyl)[(phenyl)(phenylpyridyl)triazinylpyridyl]dibenzoselenophene; (phenyl)[(phenyl)(phenylpyridyl)triazinylpyridyl]dibenzofuran; (phenyl)[(phenyl)(phenylpyridyl)triazinylpyridyl]dibenzothiophene; (phenyl)[(phenyl)(phenylpyridyl)triazinylpyridyl]dibenzoselenophene; (biphenylyl)[(phenyl)(pyridyl)triazinylpyridyl]dibenzofuran; (biphenylyl)[(phenyl)(pyridyl)triazinylpyridyl]dibenzothiophene; (biphenylyl)[(phenyl)(pyridyl)triazinylpyridyl]dibenzoselenophene; (phenyl)[(phenyl)(dimethylindenopyridyl)triazinyl]dibenzofuran; (phenyl)[(phenyl)(dimethylindenopyridyl)triazinyl]dibenzothiophene; (phenyl)[(phenyl)(dimethylindenopyridyl)triazinyl]dibenzoselenophene; (phenyl)[(biphenylyl)(dimethylindenopyridyl)triazinyl]dibenzofuran; (phenyl)[(biphenylyl)(dimethylindenopyridyl)triazinyl]dibenzothiophene; (phenyl)[(biphenylyl)(dimethylindenopyridyl)triazinyl]dibenzoselenophene; (phenyl)[(phenyl)(dimethylindenopyridyl)triazinyl]dibenzofuran; (phenyl)[(phenyl)(dimethylindenopyridyl)triazinyl]dibenzothiophene; (phenyl)[(phenyl)(dimethylindenopyridyl)triazinyl]dibenzoselenophene; (phenyl)[(phenyl)(spirocyclohexanefluorenyl)triazinyl]dibenzofuran; (phenyl)[(phenyl)(spirocyclohexanefluorenyl)triazinyl]dibenzothiophene; (phenyl)[(phenyl)(spirocyclohexanefluorenyl)triazinyl]dibenzoselenophene; (phenyl)[(phenyl)(spirobifluorenyl)triazinyl]dibenzofuran; (phenyl)[(phenyl)(spirobifluorenyl)triazinyl]dibenzothiophene; (phenyl)[(phenyl)(spirobifluorenyl)triazinyl]dibenzoselenophene; (phenyl-d₅)[(diphenyl-d₁₀)triazinylphenyl-d₉]dibenzofuran; (phenyl-d₅)[(diphenyl-d₁₀)triazinylphenyl-d₉]dibenzothiophene; (phenyl-d₅)[(diphenyl-d₁₀)triazinylphenyl-d₅]dibenzoselenophene; (biphenyl-d₉)[(diphenyl-d₁₀)triazinylphenyl-d₉]dibenzofuran; (biphenyl-d₉)[(diphenyl-d₁₀)triazinylphenyl-d₉]dibenzothiophene; (biphenyl-d₉)[(diphenyl-d₁₀)triazinylphenyl-d₉]dibenzoselenophene; (phenyl)[(phenyl)(dimethyl-d₆)fluorenyl)triazinyl]dibenzofuran; (phenyl)[(phenyl)(dimethyl-d₆)fluorenyl)triazinyl]dibenzothiophene; (phenyl)[(phenyl)(dimethyl-d₆)fluorenyl)triazinyl]dibenzoselenophene; (biphenyl-d₉)[(diphenyl-d₁₀)triazinylphenyl-d₉]dibenzofuran; (biphenyl-d₉)[(diphenyl-d₁₀)triazinylphenyl-d₉]dibenzothiophene; (biphenyl-d₉)[(diphenyl-d₁₀)triazinylphenyl-d₉]dibenzoselenophene; (biphenylyl)[(diphenyl-d₁₀)triazinylphenyl]dibenzofuran; (biphenylyl)[(diphenyl-d₁₀)triazinylphenyl]dibenzothiophene; (biphenylyl)[(diphenyl-d₁₀)triazinylphenyl]dibenzoselenophene; (biphenylyl)[di(phenyl)triazinylbiphenylyl]dibenzofuran; (biphenylyl)[di(phenyl)triazinylbiphenylyl]dibenzothiophene; (biphenylyl)[di(phenyl)triazinylbiphenylyl]dibenzoselenophene; (biphenylyl)[bis(fluorophenyl)triazinylphenyl]dibenzofuran; (biphenylyl)[bis(fluorophenyl)triazinylphenyl]dibenzothiophene; (biphenylyl)[bis(fluorophenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylbiphenylyl]dibenzofuran; (dimethylfluorenyl)[di(phenyl)triazinylbiphenylyl]dibenzothiophene; (dimethylfluorenyl)[di(phenyl)triazinylbiphenylyl]dibenzoselenophene; (dimethylfluorenyl)[di(phenyl)triazinylbiphenylyl]dibenzofuran; (dimethylfluorenyl)[di(phenyl)triazinylbiphenylyl]dibenzothiophene; (dimethylfluorenyl)[di(phenyl)triazinylbiphenylyl]dibenzoselenophene; (dimethylfluorenyl)[di(phenyl)triazinylbiphenylyl]dibenzofuran; (dimethylfluorenyl)[di(phenyl)triazinylbiphenylyl]dibenzothiophene; (dimethylfluorenyl)[di(phenyl)triazinylbiphenylyl]dibenzoselenophene; (dimethylfluorenyl)[di(phenyl)triazinylpyridyl]dibenzofuran; (dimethylfluorenyl)[di(phenyl)triazinylpyridyl]dibenzothiophene; (dimethylfluorenyl)[di(phenyl)triazinylpyridyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylbiphenylyl]dibenzofuran; (dimethylfluorenyl)[di(phenyl)triazinylbiphenylyl]dibenzothiophene; (dimethylfluorenyl)[di(phenyl)triazinylbiphenylyl]dibenzoselenophene; (dimethylfluorenyl)[(phenyl)(biphenylyl)triazinylphenyl]dibenzofuran; (dimethylfluorenyl)[(phenyl)(biphenylyl)triazinylphenyl]dibenzothiophene; (dimethylfluorenyl)[(phenyl)(biphenylyl)triazinylphenyl]dibenzoselenophene; (dimethylfluorenyl)[(phenyl)(dimethylfluorenyl)triazinylphenyl]dibenzofuran; (dimethylfluorenyl)[(phenyl)(dimethylfluorenyl)triazinylphenyl]dibenzothiophene; (dimethylfluorenyl)[(phenyl)(dimethylfluorenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; bis(dimethylfluorenyl)[di(phenyl)triazinylphenyl]dibenzofuran; bis(dimethylfluorenyl)[di(phenyl)triazinylphenyl]dibenzothiophene; bis(dimethylfluorenyl)[di(phenyl)triazinylphenyl]dibenzoselenophene; (dimethylfluorenyl)[(phenyl)(terphenylyl)triazinylphenyl]dibenzofuran; (dimethylfluorenyl)[(phenyl)(terphenylyl)triazinylphenyl]dibenzothiophene; (dimethylfluorenyl)[(phenyl)(terphenylyl)triazinylphenyl]dibenzoselenophene; (spirocyclopentanefluorenyl)[di(phenyl)triazinylphenyl]dibenzofuran; (spirocyclopentanefluorenyl)[di(phenyl)triazinylphenyl]dibenzothiophene; (spirocyclopentanefluorenyl)[di(phenyl)triazinylphenyl]dibenzoselenophene; (diphenylfluorenyl)[di(phenyl)triazinylphenyl]dibenzofuran; (diphenylfluorenyl)[di(phenyl)triazinylphenyl]dibenzothiophene; (diphenylfluorenyl)[di(phenyl)triazinylphenyl]dibenzoselenophene; (spirobifluorenyl)[di(phenyl)triazinylphenyl]dibenzofuran; (spirobifluorenyl)[di(phenyl)triazinylphenyl]dibenzothiophene; (spirobifluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; [di(methyl)(phenyl)fluorenyl][di(phenyl)triazinylphenyl]dibenzofuran; [di(methyl)(phenyl)fluorenyl][di(phenyl)triazinylphenyl]dibenzothiophene; [di(methyl)(phenyl)fluorenyl][di(phenyl)triazinylphenyl]dibenzoselenophene; [(dimethyl-d₆)fluorenyl][di(phenyl)triazinylphenyl]dibenzofuran; [(dimethyl-d₆)fluorenyl][di(phenyl)triazinylphenyl]dibenzothiophene; [(dimethyl-d₆)fluorenyl][di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[(diphenyl-d₁₀)triazinylphenyl]dibenzofuran; (dimethylfluorenyl)[(diphenyl-d₁₀)triazinylphenyl]dibenzothiophene; (dimethylfluorenyl)[(diphenyl-d₁₀)triazinylphenyl]dibenzoselenophene; (dimethylfluorenyl)[(diphenyl-d₁₀)triazinylphenyl-d₄]dibenzofuran; (dimethylfluorenyl)[(diphenyl-d₁₀)triazinylphenyl-d₄]dibenzothiophene; (dimethylfluorenyl)[(diphenyl-d₁₀)triazinylphenyl-d₄]dibenzoselenophene; [(dimethyl-d₆)fluorenyl][(diphenyl-d₁₀)triazinylphenyl]dibenzofuran; [(dimethyl-d₆)fluorenyl][(diphenyl-d₁₀)triazinylphenyl]dibenzothiophene; [(dimethyl-d₆)fluorenyl][(diphenyl-d₁₀)triazinylphenyl]dibenzoselenophene; (dimethylfluorenyl)[(diphenyl-d₁₀)triazinylphenyl-d₄]dibenzofuran; (dimethylfluorenyl)[(diphenyl-d₁₀)triazinylphenyl-d₄]dibenzothiophene; (dimethylfluorenyl)[(diphenyl-d₁₀)triazinylphenyl-d₄]dibenzoselenophene; (terphenylyl)[(phenyl)(biphenylyl)triazinyl]dibenzofuran; (terphenylyl)[(phenyl)(biphenylyl)triazinyl]dibenzothiophene; (terphenylyl)[(phenyl)(biphenylyl)triazinyl]dibenzoselenophene; (terphenylyl)[(phenyl)(biphenylyl)triazinyl]dibenzofuran; (terphenylyl)[(phenyl)(biphenylyl)triazinyl]dibenzothiophene; (terphenylyl)[(phenyl)(biphenylyl)triazinyl]dibenzoselenophene; (terphenylyl)[di(phenyl)triazinyl]dibenzofuran; (terphenylyl)[di(phenyl)triazinyl]dibenzothiophene; (terphenylyl)[di(phenyl)triazinyl]dibenzoselenophene; (terphenylyl)[di(biphenylyl)triazinyl]dibenzofuran; (terphenylyl)[di(biphenylyl)triazinyl]dibenzothiophene; (terphenylyl)[di(biphenylyl)triazinyl]dibenzoselenophene; (terphenylyl)[(phenyl)(biphenylyl)triazinyl]dibenzofuran; (terphenylyl)[(phenyl)(biphenylyl)triazinyl]dibenzothiophene; (terphenylyl)[(phenyl)(biphenylyl)triazinyl]dibenzoselenophene; (terphenylyl)[(phenyl)(biphenylyl)triazinyl]dibenzofuran; (terphenylyl)[(phenyl)(biphenylyl)triazinyl]dibenzothiophene; (terphenylyl)[(phenyl)(biphenylyl)triazinyl]dibenzoselenophene; (terphenylyl)[di(phenyl)triazinyl]dibenzofuran; (terphenylyl)[di(phenyl)triazinyl]dibenzothiophene; (terphenylyl)[di(phenyl)triazinyl]dibenzoselenophene; (terphenylyl)[(phenyl)(dibenzothiophenyl)triazinyl]dibenzofuran; (terphenylyl)[(phenyl)(dibenzothiophenyl)triazinyl]dibenzothiophene; (terphenylyl)[(phenyl)(dibenzothiophenyl)triazinyl]dibenzoselenophene; (terphenylyl)[(phenyl)(dibenzofuranyl)triazinyl]dibenzofuran; (terphenylyl)[(phenyl)(dibenzofuranyl)triazinyl]dibenzothiophene; (terphenylyl)[(phenyl)(dibenzofuranyl)triazinyl]dibenzoselenophene; (terphenylyl)[(phenyl)(dimethylfluorenyl)triazinyl]dibenzofuran; (terphenylyl)[(phenyl)(dimethylfluorenyl)triazinyl]dibenzothiophene; (terphenylyl)[(phenyl)(dimethylfluorenyl)triazinyl]dibenzoselenophene; (terphenylyl)[(phenyl)(dibenzothiophenyl)triazinyl]dibenzofuran; (terphenylyl)[(phenyl)(dibenzothiophenyl)triazinyl]dibenzothiophene; (terphenylyl)[(phenyl)(dibenzothiophenyl)triazinyl]dibenzoselenophene; (terphenylyl)[(phenyl)(dibenzofuranyl)triazinyl]dibenzofuran; (terphenylyl)[(phenyl)(dibenzofuranyl)triazinyl]dibenzothiophene; (terphenylyl)[(phenyl)(dibenzofuranyl)triazinyl]dibenzoselenophene; (terphenylyl)[(phenyl)(dimethylfluorenyl)triazinyl]dibenzofuran; (terphenylyl)[(phenyl)(dimethylfluorenyl)triazinyl]dibenzothiophene; (terphenylyl)[(phenyl)(dimethylfluorenyl)triazinyl]dibenzoselenophene; (terphenylyl)[di(phenyl)triazinylphenyl]dibenzofuran; (terphenylyl)[di(phenyl)triazinylphenyl]dibenzothiophene; (terphenylyl)[di(phenyl)triazinylphenyl]dibenzoselenophene; (terphenylyl)[di(phenyl)triazinylphenyl]dibenzofuran; (terphenylyl)[di(phenyl)triazinylphenyl]dibenzothiophene; (terphenylyl)[di(phenyl)triazinylphenyl]dibenzoselenophene; (terphenyl-d₁₃)[(diphenyl-d₁₀)triazinylphenyl-d₃]dibenzofuran-d₆; (terphenyl-d₁₃)[(diphenyl-d₁₀)triazinylphenyl-d₃]dibenzothiophene-d₆; (terphenyl-d₁₃)[(diphenyl-d₁₀)triazinylphenyl-d₃]dibenzoselenophene-d₆; (terphenylyl)[(diphenyl-d₁₀)triazinylphenyl]dibenzofuran; (terphenylyl)[(diphenyl-d₁₀)triazinylphenyl]dibenzothiophene; (terphenylyl)[(diphenyl-d₁₀)triazinylphenyl]dibenzoselenophene; (terphenylyl)[(diphenyl-d₁₀)triazinylphenyl]dibenzofuran; (terphenylyl)[(diphenyl-d₁₀)triazinylphenyl]dibenzothiophene; (terphenylyl)[(diphenyl-d₁₀)triazinylphenyl]dibenzoselenophene

### (Group 23A)

di(phenyl)[(phenyl)indoloindolyl]triazine; di(phenyl)[(phenyl)indoloindolyl]pyridine; di(phenyl)[(phenyl)indoloindolyl]pyrimidine; di(phenyl)[(phenyl)indoloindolyl]pyrimidine; di(biphenylyl)[(phenyl)indoloindolyl]triazine; di(phenyl)[(diphenyltriazinyl)indoloindolyl]triazine; di(phenyl)[(phenyl)indoloindolylphenyl]triazine; (phenyl)[(phenyl)indoloindolyl]quinazoline; bis(phenylcarbazolyl)indoloindole; (phenyl)(phenylcarbazolyl)indoloindole; (phenyl)(dibenzofuranyl)indoloindole; (phenyl)(dibenzothiophenyl)indoloindole; (phenyl)(carbazolylphenyl)indoloindole; di(phenyl)(benzothienoindolyl)triazine; (phenyl)(biphenylyl)(benzothienoindolyl)triazine; di(biphenylyl)(benzothienoindolyl)triazine; (phenyl)(carbazolylphenyl)(benzothienoindolyl)triazine; (phenylquinazolyl)benzothienoindole; (phenylcarbazolyl)benzothienoindole; (naphthylcarbazolyl)benzothienoindole; (triphenylenylcarbazolyl)benzothienoindole; (biphenylylcarbazolyl)benzothienoindole; (terphenylylcarbazolyl)benzothienoindole; (diphenylpyridyl)benzofuroindole; (diphenylpyrimidinyl)benzofuroindole; di(phenyl)(benzofuroindolyl)triazine; (phenyl)(biphenylyl)(benzofuroindolyl)triazine; di(biphenylyl)(benzofuroindolyl)triazine; (biphenylyl)(benzofuroindolyl)quinazoline; (carbazolyl)(benzofuroindolyl)dibenzofuran; (phenylcarbazolyl)benzofuroindole; (naphthylcarbazolyl)benzofuroindole; (terphenylylcarbazolyl)benzofuroindole; di(phenyl)(phenylbenzofuroindolyl)triazine; di(phenyl)(carbazolylbenzofuroindolyl)triazine; di(phenyl)bicarbazole; di(biphenylyl)bicarbazole; (phenyl)(biphenylyl)bicarbazole; di(biphenylyl)bicarbazole; (phenyl)(biphenylyl)bicarbazole; di(biphenylyl)bicarbazole; (phenyl)(naphthylphenyl)bicarbazole; (phenyl)(naphthylphenyl)bicarbazole; (phenyl)(naphthyl)bicarbazole; di(naphthyl)bicarbazole; (naphthyl)(biphenylyl)bicarbazole; (naphthyl)(biphenylyl)bicarbazole; (naphthyl)(terphenylyl)bicarbazole; (naphthyl)(naphthylphenyl)bicarbazole; di(naphthyl)bicarbazole; (naphthyl)(phenanthryl)bicarbazole; (naphthyl)(phenylanthryl)bicarbazole; (phenyl)(naphthyl)bicarbazole; di(naphthyl)bicarbazole; (naphthyl)(biphenylyl)bicarbazole; (naphthyl)(biphenylyl)bicarbazole; (naphthyl)(terphenylyl)bicarbazole; (naphthyl)(naphthylphenyl)bicarbazole; di(naphthyl)bicarbazole; (naphthyl)(phenanthryl)bicarbazole; (naphthyl)(phenylanthryl)bicarbazole; (phenyl)(phenanthryl)bicarbazole; (biphenylyl)(phenanthryl)bicarbazole; (biphenylyl)(phenanthryl)bicarbazole; (terphenylyl)(phenanthryl)bicarbazole; (naphthylphenyl)(phenanthryl)bicarbazole; di(phenanthryl)bicarbazole; (phenylanthryl)(phenanthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(anthryl)bicarbazole; di(anthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(anthryl)bicarbazole; di(anthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(naphthyl)bicarbazole; di(naphthyl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(phenanthryl)bicarbazole; di(phenanthryl)bicarbazole; (phenyl)(phenanthryl)bicarbazole; (phenyl)(anthryl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(phenanthryl)bicarbazole; (phenyl)(anthryl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(naphthyl)bicarbazole; di(naphthyl)bicarbazole; (phenyl)(phenanthryl)bicarbazole; (phenyl)(phenanthryl)bicarbazole; di(phenanthryl)bicarbazole; (phenyl)(anthryl)bicarbazole; (phenyl)(anthryl)bicarbazole; di(anthryl)bicarbazole; (phenyl)(pyrenyl)bicarbazole; (phenyl)(triphenylenyl)bicarbazole; (biphenylyl)(dibenzofuranyl)carbazole; (biphenylyl)(dibenzofuranyl)carbazole; (terphenylyl)(dibenzofuranyl)carbazole; (naphthylphenyl)(dibenzofuranyl)carbazole; (naphthylphenyl)(dibenzofuranyl)carbazole; (naphthyl)(dibenzofuranyl)carbazole; (phenanthryl)(dibenzofuranyl)carbazole; (triphenylenyl)(dibenzofuranyl)carbazole; (naphthyl)(dibenzofuranyl)carbazole; (biphenylyl)(dibenzothiophenyl)carbazole; (terphenylyl)(dibenzothiophenyl)carbazole; (naphthylphenyl)(dibenzothiophenyl)carbazole; (naphthylphenyl)(dibenzothiophenyl)carbazole; (naphthyl)(dibenzothiophenyl)carbazole; (phenanthryl)(dibenzothiophenyl)carbazole; (triphenylenyl)(dibenzothiophenyl)carbazole; (naphthyl)(dibenzothiophenyl)carbazole; (phenyl)(phenylpyridyl)bicarbazole; (phenylpyridyl)(dibenzofuranyl)carbazole; (phenylpyridyl)(dibenzothiophenyl)carbazole; (phenyl)(diphenylpyrimidinyl)bicarbazole; (diphenylpyrimidinyl)(dibenzofuranyl)carbazole; (diphenylpyrimidinyl)(dibenzothiophenyl)carbazole; (phenyl)(diphenyltriazinyl)bicarbazole; (diphenyltriazinyl)(dibenzofuranyl)carbazole; (diphenyltriazinyl)(dibenzothiophenyl)carbazole; (phenyl)(phenylquinazolyl)bicarbazole; (phenylquinazolyl)(dibenzofuranyl)carbazole; (phenylquinazolyl)(dibenzothiophenyl)carbazole

### (Group 24A)

(phenyl)(biphenylyl)[(phenyl)indolocarbazolyl]triazine; (phenyl)(biphenylyl)[(phenyl)indolocarbazolyl]triazine; di(phenyl)[(biphenylyl)indolocarbazolyl]triazine; di(phenyl)[(biphenylyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(phenyl)[(terphenylyl)indolocarbazolyl]triazine; di(phenyl)[(terphenylyl)indolocarbazolyl]triazine; di(phenyl)[(terphenylyl)indolocarbazolyl]triazine; di(phenyl)[(terphenylyl)indolocarbazolyl]triazine; di(biphenylyl)[(phenyl)indolocarbazolyl]triazine; di(biphenylyl)[(phenyl)indolocarbazolyl]triazine; di(biphenylyl)[(phenyl)indolocarbazolyl]triazine; di(phenyl)[(phenyl)(biphenylyl)indolocarbazolyl]triazine; di(phenyl)[(phenyl)(biphenylyl)indolocarbazolyl]triazine; di(phenyl)[tri(phenyl)indolocarbazolyl]triazine; di(phenyl)[tri(phenyl)indolocarbazolyl]triazine; di(phenyl)[(phenyl)(biphenylyl)indolocarbazolyl]triazine; di(phenyl)[(phenyl)(biphenylyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(butyl)indolocarbazolyl]triazine; (phenyl)(terphenylyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(tert-butyl)indolocarbazolyl]triazine; (phenyl)(terphenylyl)[(phenyl)di(butyl)indolocarbazolyl]triazine; (biphenylyl)(terphenylyl)[(phenyl)di(butyl)indolocarbazolyl]triazine; (phenyl)(biphenylyl)[(phenyl)indolocarbazolyl]triazine; (phenyl)(biphenylyl)[(phenyl)indolocarbazolyl]triazine; di(phenyl)[(biphenylyl)indolocarbazolyl]triazine; di(phenyl)[(biphenylyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(phenyl)[(terphenylyl)indolocarbazolyl]triazine; di(phenyl)[(terphenylyl)indolocarbazolyl]triazine; di(phenyl)[(terphenylyl)indolocarbazolyl]triazine; di(biphenylyl)[(phenyl)indolocarbazolyl]triazine; di(biphenylyl)[(phenyl)indolocarbazolyl]triazine; di(biphenylyl)[(phenyl)indolocarbazolyl]triazine; di(biphenylyl)[(phenyl)indolocarbazolyl]triazine; di(phenyl)[(phenyl)(biphenylyl)indolocarbazolyl]triazine; di(phenyl)[(phenyl)(biphenylyl)indolocarbazolyl]triazine; di(phenyl)[tri(phenyl)indolocarbazolyl]triazine; di(phenyl)[tri(phenyl)indolocarbazolyl]triazine; di(phenyl)[di(phenyl)(biphenylyl)indolocarbazolyl]triazine; di(phenyl)[di(phenyl)(biphenylyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(butyl)indolocarbazolyl]triazine; (phenyl)(terphenylyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(tert-butyl)indolocarbazolyl]triazine; (phenyl)(terphenylyl)[(phenyl)di(butyl)indolocarbazolyl]triazine; (biphenylyl)(terphenylyl)[(phenyl)di(butyl)indolocarbazolyl]triazine; (phenyl)(biphenylyl)[(phenyl)indolocarbazolyl]triazine; (phenyl)(biphenylyl)[(phenyl)indolocarbazolyl]triazine; di(phenyl)[(biphenylyl)indolocarbazolyl]triazine; di(phenyl)[(biphenylyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(phenyl)[(terphenylyl)indolocarbazolyl]triazine; di(phenyl)[(terphenylyl)indolocarbazolyl]triazine; di(phenyl)[(terphenylyl)indolocarbazolyl]triazine; di(phenyl)[(terphenylyl)indolocarbazolyl]triazine; di(biphenylyl)[(phenyl)indolocarbazolyl]triazine; di(biphenylyl)[(phenyl)indolocarbazolyl]triazine; di(biphenylyl)[(phenyl)indolocarbazolyl]triazine; di(phenyl)[(phenyl)(biphenylyl)indolocarbazolyl]triazine; di(phenyl)[(phenyl)(biphenylyl)indolocarbazolyl]triazine; di(phenyl)[tri(phenyl)indolocarbazolyl]triazine; di(phenyl)[tri(phenyl)indolocarbazolyl]triazine; di(phenyl)[di(phenyl)(biphenylyl)indolocarbazolyl]triazine; di(phenyl)[di(phenyl)(biphenylyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(butyl)indolocarbazolyl]triazine; (phenyl)(terphenylyl)[(phenyl)di(tert-butyl)indolocarbazolyl]triazine; (phenyl)(biphenylyl)[(phenyl)di(butyl)indolocarbazolyl]triazine; (phenyl)(biphenylyl)[(phenyl)di(tert-butyl)indolocarbazolyl]triazine; (phenyl)(terphenylyl)[(phenyl)di(butyl)indolocarbazolyl]triazine; (phenyl)(terphenylyl)[(phenyl)di(tert-butyl)indolocarbazolyl]triazine; (biphenylyl)(terphenylyl)[(phenyl)di(tert-butyl)indolocarbazolyl]triazine; (phenyl)(biphenylyl)[(phenyl)indolocarbazolyl]triazine; (phenyl)(biphenylyl)[(phenyl)indolocarbazolyl]triazine; di(phenyl)[(biphenylyl)indolocarbazolyl]triazine; di(phenyl)[(biphenylyl)indolocarbazolyl]triazine; di(phenyl)[tri(phenyl)indolocarbazolyl]triazine; di(phenyl)[(phenyl)di(butyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(biphenylyl)[(phenyl)indolocarbazolyl]triazine; di(biphenylyl)[(phenyl)indolocarbazolyl]triazine; (phenyl)(biphenylyl)[(phenyl)indolocarbazolyl]triazine; (phenyl)(biphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(biphenylyl)[(phenyl)indolocarbazolyl]triazine; di(biphenylyl)[(phenyl)indolocarbazolyl]triazine; (phenyl)(biphenylyl)[(phenyl)indolocarbazolyl]triazine; (phenyl)(biphenylyl)[(phenyl)indolocarbazolyl]triazine; di(phenyl)[(biphenylyl)indolocarbazolyl]triazine; di(phenyl)[(biphenylyl)indolocarbazolyl]triazine; di(phenyl)[tri(phenyl)indolocarbazolyl]triazine; di(phenyl)[(phenyl)di(butyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; (phenyl)(terphenylyl)[(phenyl)indolocarbazolyl]triazine; di(biphenylyl)[(phenyl)indolocarbazolyl]triazine; di(biphenylyl)[(phenyl)indolocarbazolyl]triazine; di(terphenylyl)[(phenyl)indolocarbazolyl]triazine; di(terphenylyl)[(phenyl)indolocarbazolyl]triazine; di(terphenylyl)[(phenyl)indolocarbazolyl]triazine; di(terphenylyl)[(phenyl)indolocarbazolyl]triazine; (phenyl)(biphenylyl)[(phenyl)(dibenzofuranyl)indolocarbazolyl]triazine; (phenyl)(biphenylyl)[(phenyl)(dibenzothiophenyl)indolocarbazolyl]triazine; (phenyl)(terphenylyl)[(phenyl)(dibenzofuranyl)indolocarbazolyl]triazine; (phenyl)(terphenylyl)[(phenyl)(dibenzothiophenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; (naphthyl)(biphenylyl)bicarbazole; di(biphenylyl)bicarbazole; di(biphenylyl)bicarbazole; di(biphenylyl)bicarbazole; (biphenylyl)(phenanthryl)bicarbazole; (biphenylyl)(anthryl)bicarbazole; (biphenylyl)(naphthylphenyl)bicarbazole; (biphenylyl)(naphthylphenyl)bicarbazole; (biphenylyl)(terphenylyl)bicarbazole; (biphenylyl)(anthrylphenyl)bicarbazole; (biphenylyl)(naphthylphenyl)bicarbazole; (biphenylyl)(anthrylphenyl)bicarbazole; (biphenylyl)(naphthylphenyl)bicarbazole; (biphenylyl)(terphenylyl)bicarbazole; (biphenylyl)(terphenylyl)bicarbazole; (biphenylyl)(terphenylyl)bicarbazole; (biphenylyl)(terphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylpheny)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (phenyl)(biphenylyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenylyl)bicarbazole; (phenyl)(terphenylyl)bicarbazole; (phenyl)(terphenylyl)bicarbazole; (phenyl)(naphthylbiphenylyl)bicarbazole; (phenyl)(naphthylbiphenylyl)bicarbazole; (naphthyl)(biphenylyl)bicarbazole; di(biphenylyl)bicarbazole; di(biphenylyl)bicarbazole; di(biphenylyl)bicarbazole; (biphenylyl)(phenanthryl)bicarbazole; (biphenylyl)(anthryl)bicarbazole; (biphenylyl)(naphthylphenyl)bicarbazole; (biphenylyl)(naphthylphenyl)bicarbazole; (biphenylyl)(terphenylyl)bicarbazole; (biphenylyl)(anthrylphenyl)bicarbazole; (biphenylyl)(naphthylphenyl)bicarbazole; (biphenylyl)(anthrylphenyl)bicarbazole; (biphenylyl)(naphthylphenyl)bicarbazole; (biphenylyl)(terphenylyl)bicarbazole; (biphenylyl)(terphenylyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylpheny)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (phenyl)(biphenylyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenylyl)bicarbazole; (phenyl)(terphenylyl)bicarbazole; (phenyl)(terphenylyl)bicarbazole; (phenyl)(naphthylbiphenylyl)bicarbazole; (phenyl)(naphthylbiphenylyl)bicarbazole; (naphthyl)(biphenylyl)bicarbazole; di(biphenylyl)bicarbazole; di(biphenylyl)bicarbazole; di(biphenylyl)bicarbazole; (biphenylyl)(phenanthryl)bicarbazole; (biphenylyl)(anthryl)bicarbazole; (biphenylyl)(naphthylphenyl)bicarbazole; (biphenylyl)(naphthylphenyl)bicarbazole; (biphenylyl)(terphenylyl)bicarbazole; (biphenylyl)(anthrylphenyl)bicarbazole; (biphenylyl)(naphthylphenyl)bicarbazole; (biphenylyl)(anthrylphenyl)bicarbazole; (biphenylyl)(naphthylphenyl)bicarbazole; (biphenylyl)(terphenylyl)bicarbazole; (biphenylyl)(terphenylyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (naphthyl)(biphenylyl)bicarbazole; di(biphenylyl)bicarbazole; di(biphenylyl)bicarbazole; di(biphenylyl)bicarbazole; (biphenylyl)(phenanthryl)bicarbazole; (biphenylyl)(anthryl)bicarbazole; (biphenylyl)(naphthylphenyl)bicarbazole; (biphenylyl)(naphthylphenyl)bicarbazole; (biphenylyl)(terphenylyl)bicarbazole; (biphenylyl)(anthrylphenyl)bicarbazole; (biphenylyl)(naphthylphenyl)bicarbazole; (biphenylyl)(anthrylphenyl)bicarbazole; (biphenylyl)(naphthylphenyl)bicarbazole; (biphenylyl)(terphenylyl)bicarbazole; (biphenylyl)(terphenylyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylpheny)bicarbazole; (biphenylyl)(terphenylyl)bicarbazole; (biphenylyl)(naphthylbiphenylyl)bicarbazole; (biphenylyl)(naphthylphenyl)bicarbazole; (biphenylyl)(naphthylphenyl)bicarbazole; (biphenylyl)(phenanthrylphenyl)bicarbazole; (phenyl)(biphenylyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenylyl)bicarbazole; (phenyl)(terphenylyl)bicarbazole; (phenyl)(terphenylyl)bicarbazole; (phenyl)(naphthylbiphenylyl)bicarbazole; (phenyl)(naphthylbiphenylyl)bicarbazole

### (Group 25A)

di(bipyridinyl)triphenylene; di(bipyridinyl)triphenylene; bis(dipyridinylphenyl)phenylpyrimidine; (phenylquinquephenylyl)diphenylpyrimidine; (phenylquarterphenylyl)diphenylpyrimidine; bis[(biphenylylpyrimidinyl)phenyl]ether; di(terphenylyl)sulfone; bis(diphenylterphenylyl)sulfone; phenyl(diphenylquinquephenylyl)sulfone; di(spirobifluorenyl)ketone; bis(diphenylfluorenyl)ketone; bis(dimethylfluorenyl)naphthyltriazine; bis(dimethylfluorenyl)biphenylyltriazine; bis(dimethylfluorenyl)terphenylyltriazine; biphenylyl(spirobifluorenyl)phenylpyridine; biphenylyl(spirobifluorenyl)phenylpyridine; biphenylyl(spirobifluorenyl)naphthylpyridine; di(terphenylyl)(spirobifluorenyl)pyridine; biphenylyl(spirobifluorenyl)phenylpyridine; biphenylyl(spirobifluorenyl)phenylpyridine; biphenylyl(spirobifluorenyl)naphthylpyridine; di(terphenylyl)(spirobifluorenyl)pyridine; biphenylyl(spirobifluorenyl)phenylpyridine; biphenylyl(spirobifluorenyl)phenylpyridine; biphenylyl(spirobifluorenyl)naphthylpyridine; biphenylyl(spirobifluorenyl)phenylpyrimidine; biphenylyl(spirobifluorenyl)phenylpyrimidine; di(biphenylyl)(spirobifluorenyl)phenylpyrimidine; biphenylyl(spirobifluorenyl)naphthylpyrimidine; terphenylyl(spirobifluorenyl)phenylpyrimidine; biphenylyl(spirobifluorenyl)phenylpyrimidine; biphenylyl(spirobifluorenyl)phenylpyrimidine; biphenylyl(spirobifluorenyl)naphthylpyrimidine; biphenylyl(spirobifluorenyl)naphthylpyrimidine; terphenylyl(spirobifluorenyl)phenylpyrimidine; biphenylyl(spirobifluorenyl)phenyltriazine; biphenylyl(spirobifluorenyl)phenyltriazine; (biphenyl-d₁)(spirobifluorenyl)phenyltriazine; (biphenyl-d₅)(spirobifluorenyl)phenyltriazine; biphenylyl(spirobifluorenyl)(phenyl-d₅)triazine; terphenylyl(spirobifluorenyl)phenyltriazine; terphenylyl(spirobifluorenyl)naphthyltriazine; biphenylyl(spirobifluorenyl)quinazoline; biphenylyl(spirobifluorenyl)quinazoline; terphenylyl(spirobifluorenyl)quinazoline; terphenylyl(spirobifluorenyl)quinazoline; (biphenyl-d₁)(spirobifluorenyl)quinazoline; terphenylyl(spirobifluorenyl)quinazoline; di(terphenylyl)diboraoxanaphthoanthracene; di(terphenylyl)diboraoxanaphthoanthracene; [(triphenylenyl)biphenylyl]diboraoxanaphthoanthracene; (quarterphenylyl)diboraoxanaphthoanthracene; (phenylquarterphenylyl)diboraoxanaphthoanthracene; di(dibenzofuranyl)diboraoxanaphthoanthracene; di(dibenzofuranyl)diboraoxanaphthoanthracene; di(biphenylyl)(dimethylfluorenyl)triazine; (terphenylyl)(biphenylyl)(dimethylfluorenyl)triazine; di(terphenylyl)(dimethylfluorenyl)triazine; (biphenylyl)(diphenylfluorenyl)phenyltriazine; (biphenylyl)(diphenylfluorenyl)phenyltriazine; bis(diphenylphosphoryl)dibenzothiophene; bis(diphenylphosphoryl)dibenzofuran; diphenyl(triphenylenylterphenylyl)amine; diphenyl(quinquephenylyl)amine; diphenyl(phenylquinquephenylyl)amine; diphenyl[(spirobifluorenyl)biphenylyl]amine; bis[(diphenylamino)phenyl]dibenzofuran; [(triphenylenyl)terphenylyl]indole; tris(indolylphenyl)benzene; (diphenylquinquephenylyl)carbazole; [(triphenylenyl)terphenylyl]carbazole; [(triphenylenyl)biphenylyl]carbazole; di(carbazolyl)quarterbenzene; (carbazolylbiphenylyl)[di(biphenylyl)]amine; terphenylylbicarbazole; quarterphenylylbicarbazole; bis(diphenylcarbazolyl)benzene; di(carbazolyl)terbenzene; di(carbazolyl)quarterbenzene; di(carbazolyl)quarterbenzene; di(carbazolyl)spirobifluorene; [(triphenylenyl)biphenylyl]carbazolyldibenzothiophene; di(carbazolyl)dibenzothiophene; di(carbazolyl)dibenzofuran; di(carbazolyl)(diphenylfluorene); di(carbazolyl)(biphenylyl)carbazole; (quarterphenylyl)bicarbazole; bis(bicarbazolyl)benzene; bis(bicarbazolyl)benzene; bis(bicarbazolyl)biphenyl; bis[di(carbazolyl)carbazolyl]benzene; bis[di(carbazolyl)carbazolyl]biphenyl; tris(carbazolyl)benzene; dimethyl(phenylquarterphenylyl)acridane; (phenylquarterphenylyl)phenoxazine; (phenylquarterphenylyl)phenothiazine; phenyl(phenylquarterphenylyl)phenazine; dimethyl[(terphenylyl)carbazolyl]acridane; dimethyl[(terphenylyl)carbazolyl]phenoxazine; dimethyl[(terphenylyl)carbazolyl]phenothiazine; phenyl(spirobifluorenyl)phenazine; bis(dimethylacridinyl)terbenzene; di(phenoxazinyl)terbenzene; di(phenoxazinyl)biphenyl; di(phenothiazinyl)terbenzene; bis(dimethylacridinyl)biphenyl; di(biphenylyl)bicarbazole; di(biphenylyl)bicarbazole; phenyl(terphenylyl)bicarbazole; di(biphenylyl)bicarbazole-d₂; phenyl(triphenylenyl)bicarbazole; biphenylyl(terphenylyl)bicarbazole; diphenyltercarbazole; phenyl(dibenzothiophenyl)bicarbazole; phenyl(dimethylfluorenyl)bicarbazole; di(biphenylyl)bicarbazole; phenyl(triphenylenyl)bicarbazole; di(biphenylyl)bicarbazole-d₂; di(biphenylyl)bicarbazole-d₂; phenyl(terphenylyl)bicarbazole; phenyl(triphenylenyl)bicarbazole; di(biphenylyl)bicarbazole; diphenyltercarbazole; phenyl(triphenylenyl)bicarbazole-d₁; di(biphenylyl)bicarbazole; phenyl(triphenylenyl)bicarbazole; di(biphenylyl)bicarbazole; phenyl(triphenylenyl)bicarbazole; phenyl(dibenzofuranyl)bicarbazole; phenyl(terphenylyl)bicarbazole-d₂; di(biphenylyl)bicarbazole; phenyl(triphenylenyl)bicarbazole; (phenylcarbazolyl)[(triphenylenyl)carbazolyl]benzene; (phenylcarbazolyl)[(biphenylyl)carbazolyl]benzene; (phenylcarbazolyl)[(biphenylyl)carbazolyl]benzene; (phenylcarbazolyl)[(terphenylyl)carbazolyl]benzene; bis(phenylcarbazolyl)biphenyl; bis[(biphenylyl)carbazolyl]biphenyl; (phenylcarbazolyl)[(triphenylenyl)carbazolyl]biphenyl; (phenylcarbazolyl)[(terphenylyl)carbazolyl]biphenyl; bis(phenylcarbazolyl)biphenyl-d₂; terphenylyl(dimethylfluorenyl)carbazole; quarterphenylyl(dimethylfluorenyl)carbazole; terphenylyl(dimethylfluorenyl)carbazole; terphenylyl(diphenylfluorenyl)carbazole; quarterphenylyl(dibenzothiophenyl)carbazole; terphenylyl(dibenzofuranyl)carbazole; biphenylyl(dibenzofuranyl)bicarbazole; terphenylyl(dibenzothiophenyl)carbazole; di(biphenylyl)indolocarbazole; di(biphenylyl)indolocarbazole; phenyl(terphenylyl)indolocarbazole-d₂; bis(phenylindolocarbazolyl)benzene; di(biphenylyl)indolocarbazole; phenyl(terphenylyl)indolocarbazole; phenyl(terphenylyl)indolocarbazole-d₁; bis(phenylindolocarbazolyl)benzene; bis(phenylindolocarbazolyl)biphenyl; phenyl(dinaphthylphenyl)indolocarbazole; phenyl(spirobifluorenyl)indolocarbazole; di(biphenylyl)indolocarbazole; bis(phenylindolocarbazolyl)biphenyl; phenyl(terphenylyl)indolocarbazole; di(biphenylyl)indolocarbazole; bis(phenylindolocarbazolyl)biphenyl; di(terphenylyl)indolocarbazole; phenyl(quarterphenylyl)indolocarbazole; phenyl(terphenylyl)indolocarbazole-d₂; bis(phenylindolocarbazolyl)benzene; (quarterphenylyl)dimethylindenocarbazole; (quarterphenylyl)dimethylindenocarbazole; [(terphenylyl)carbazolyl]dimethylindenocarbazole; (terphenylyl)oxaazaindenofluorene; bis(oxaazaindenofluorenylbiphenyl); (quarterphenylyl)oxaazaindenofluorene (quinquephenylyl)benzothienocarbazole; (terphenylyl)benzothienocarbazole; phenyl(terphenylyl)indolophenoxazine; phenyl(terphenylyl)indoloacridane; phenyl(terphenylyl)indolophenothiazine; di(biphenylyl)indolophenoxazine; di(biphenylyl)indolophenothiazine; di(biphenylyl)indoloacridane; phenyl(terphenylyl)indolophenoxazine; phenyl(terphenylyl)indolophenothiazine; phenyl(terphenylyl)indoloacridane; phenyl(terphenylyl)spiroindolo(acridinefluorene); phenyl(quarterphenylyl)indolophenothiazine; phenyl(terphenylyl)indolophenoxazine; phenyl(terphenylyl)indoloacridane; phenyl(biphenylyl)spiroindolo(phenothiazinefluorene); phenyl(terphenylyl)benzoindolocarbazole

### (Group 26A)

(phenyl)(biphenylyl)[(phenylbicarbazolyl)phenyl]triazine; di(phenyl)[(phenylbicarbazolyl)biphenylyl]triazine; di(phenyl)[(biphenylylbicarbazolyl)phenyl]triazine; di(phenyl)[(diphenylbicarbazolyl)phenyl]triazine; (phenyl)(cyanotriphenylenyl)bicarbazole; (methylphenyl)(cyanotriphenylenyl)bicarbazole; (tert-butylphenyl)(cyanotriphenylenyl)bicarbazole

### (Group 27A)

CBP(dicarbazolebiphenyl); PVK(poly(n-vinylcarbazone)); AD-N(di(naphthaleyl)anthracene); TCTA; TPBI(tris(phenylbenzimidazolyl)benzene)); Ir(pq)₂(acac); PtOEP; Ir(piq)₃; Btp₂; Ir(acac); Ir(ppy)₃; Ir(ppy)₂(acac); Ir(mpyp)₃; FIrpic; (F2ppy)₂Irtmd); Ir(dfppz)₃; mCP(dicarbazolebenzene); mCBP(di(carbazolyl)biphenyl); CBP(bis(carbazolyl)biphenyl); TPBI(tris(phenylbenzimidazolyl)benzene)); BmPyPb(tri[(pyridyl)phenyl]benzene); TSPO1(diphenylphosphineoxidetriphenylsilylphenyl); Alq3(tris(quinolinolato)aluminum; COT(substituted cyclooctatetraene); TAZ; Bphen(diphenylphenanthroline)); BCP; Balq

### (Group 28A)

tris[(methylindolocarbazolyl)phenyl]amine; tris[(azaoxaindenofluorenyl)phenyl]amine; tris[(thiaazaindenobenzofluorenyl)phenyl]amine; tris[(indenocarbazolyl)phenyl]amine; bis[(methylindolocarbazolyl)phenyl][(azaoxaindenofluorenyl)phenyl]amine; tris[(azaoxaindenobenzofluorenyl)phenyl]amine; tris[(azaselenaindenobenzofluorenyl)phenyl]amine; tris[(thiaazaindenofluorenyl)phenyl]amine; [(methylindolocarbazolyl)phenyl]bis[(azaoxaindenofluorenyl)phenyl]amine; tris[(azaoxaindenonaphthofluorenyl)phenyl]amine; tris[(azaselenaindenobenzofluorenyl)phenyl]amine; tris[(phenylindolocarbazolyl)phenyl]amine; tris[(dimethylindolophenazinyl)phenyl]amine; [(dihydroindoloanthracenyl)phenyl]bis[(indolothioxantheny)phenyl]amine; tris[(indolophenoxazinyl)phenyl]amine; tris[(indoloxanthenyl)phenyl]amine; tris[(methylindolobenzophenoxazinyl)phenyl]amine; tris[(indenoacridinyl)phenyl]amine; tris[(benzofuroacridinyl)phenyl]amine; tris[(benzothiophenothiazinyl)phenyl]amine; tris[(phenylbenzothiophenazinyl)phenyl]amine; tris[(dihydrobenzofurophenanthridinyl)phenyl]amine; tetrakis[(methylindolocarbazolyl)phenyl]silane; tetrakis[(azaoxaindenofluorenyl)phenyl]silane; tetrakis[(azaselenaindenofluorenyl)phenyl]silane; tetrakis[(azaoxaindenofluorenyl)phenyl]silane; tetrakis[(azaoxaindenofluorenyl)phenyl]silane; tetrakis[(azaoxadithiapentacenyl)phenyl]silane; tetrakis[(azaoxaindenofluorenyl)phenyl]germane; tetrakis[(methylindolocarbazolyl)phenyl]germane; tetrakis[(methyldiazaoxathiapentacenyl)phenyl]germane; bis[(benzofurophenoxazinyl)phenyl]bis[(benzothienophenoxazinyl)phenyl]germane; (phenyl)(benzofurocarbazolyl)[(benzofurocarbazolyl)phenyl]phosphineoxide; (phenyl)(benzothienocarbazolyl)[(benzothienocarbazolyl)pyridyl]phosphineoxide; (pyridyl)(methylindolocarbazolyl)[(methylindolocarbazolyl)phenyl]phosphineoxide; (phenyl)(benzothienocarbazolyl)[(benzothienocarbazolyl)phenyl]phosphineoxide; (phenyl)(benzoselenocarbazolyl)[(benzoselenocarbazolyl)phenyl]phosphineoxide; (phenyl)(azaoxaindenobenzofluorenyl)[(azaoxaindenobenzofluorenyl)phenyl]phosphineoxide; (phenyl)(dimethylindolophenazinyl)[(dimethylindolophenazinyl)phenyl]phosphineoxide; (phenyl)(indolothioxanthenyl)[(indolothioxanthenyl)pyridyl]phosphineoxide; (phenyl)(methylindolophenothiazinyl)[(methylindolophenothiazinyl)pyridyl]phosphineoxide; bis[(azaoxaindenofluorenyl)phenyl]furan; bis[(methylindolophenothiazinyl)phenyl]furan; bis[(thiaazaindenofluorenyl)phenyl]thiophene; bis[(azaselenaindenofluorenyl)pyridyl]thiophene; bis[(thiaazaindenofluorenyl)phenyl]selenophene; bis[(phenylindoloacridinyl)phenyl]selenophene; dimethylbis[(thiaazaindenofluorenyl)phenyl]cyclopentadiene; dimethylbis[(phenylindolobenzocarbazolyl)pyridyl]cyclopentadiene; bis[(benzothienophenothiazinyl)phenyl]oxazole; bis[(benzofurophenoxazinyl)phenyl]oxadiazole; bis[(benzothienophenoxazinyl)phenyl]thiadiazole

### (Group 29A)

di(phenyl)[(phenylbicarbazolyl)phenyl]triazine; di(phenyl)[(phenylbicarbazolyl)phenyl]triazine; di(phenyl)[(phenylbicarbazolyl)phenyl]triazine; di(phenyl)(biphenylylbicarbazolyl)triazine; di(phenyl)(biphenylylbicarbazolyl)triazine; di(phenyl)(biphenylylbicarbazolyl)triazine; (phenyl)(biphenylyl)(phenylbicarbazolyl)triazine; (phenyl)(biphenylyl)(phenylbicarbazolyl)triazine; (phenyl)(biphenylyl)(phenylbicarbazolyl)triazine; (phenyl)(biphenylyl)(phenylbicarbazolyl)triazine; (phenyl)(biphenylyl)(phenylbicarbazolyl)triazine; (phenyl)(biphenylyl)(phenylbicarbazolyl)triazine; di(phenyl)(biphenylylbicarbazolyl)triazine; di(phenyl)(biphenylylbicarbazolyl)triazine; di(phenyl)(biphenylylbicarbazolyl)triazine; di(phenyl)[(methylphenylbicarbazolyl)phenyl]triazine; di(phenyl)[(methylphenylbicarbazolyl)phenyl]triazine; di(phenyl)[methyl(phenylbicarbazolyl)phenyl]triazine; di(phenyl)[(fluorophenylbicarbazolyl)phenyl]triazine; di(phenyl)[fluoro(phenylbicarbazolyl)phenyl]triazine; (phenyl)(fluorophenyl)[(phenylbicarbazolyl)phenyl]triazine; di(phenyl)[(cyclohexylphenylbicarbazolyl)phenyl]triazine; di(phenyl)[(trimethylsilylphenylbicarbazolyl)phenyl]triazine; phenyl(cyanophenanthryl)bicarbazole

### (Group 30A)

dicarbazolylbenzene; dicarbazolylbiphenyl; bis[(oxodiphenylphosphino)phenyl]ether; bis[(dimethyldihydroacridinyl)phenyl]sulfone; di(carbazolyl)benzophosphone; bis(dimethoxycarbazolyl)benzophosphone

### (Group 31A)

(phenyl)(biphenylyl)(phenylindolocarbazolyl)triazine; (phenyl)(biphenylyl)(phenylindolocarbazolyl)triazine; di(phenyl)(biphenylylindolocarbazolyl)triazine; di(phenyl)(biphenylylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(phenyl)(terphenylylindolocarbazolyl)triazine; di(phenyl)(terphenylylindolocarbazolyl)triazine; di(phenyl)(terphenylylindolocarbazolyl)triazine; di(phenyl)(terphenyyllindolocarbazolyl)triazine; di(biphenylyl)(phenylindolocarbazolyl)triazine; di(biphenylyl)(phenylindolocarbazolyl)triazine; di(biphenylyl)(phenylindolocarbazolyl)triazine; (phenyl)(biphenylyl)(dibutylphenylindolocarbazoly)triazine; (phenyl)(biphenylyl)[di(tert-butyl)phenylindolocarbazolyl]triazine; (phenyl)(terphenylyl)(dibutylphenylindolocarbazolyl)triazine; (phenyl)(terphenylyl)[di(tert-butyl)phenylindolocarbazolyl]triazine; (phenyl)(biphenylyl)(dibutylphenylindolocarbazolyl)triazine; (phenyl)(biphenylyl)[di(tert-butyl)phenylindolocarbazolyl]triazine; (phenyl)(terphenylyl)[di(tert-butyl)phenylindolocarbazolyl]triazine; (phenyl)(terphenylyl)(dibutylphenylindolocarbazolyl)triazine; (biphenylyl)(biphenylyl)(dibutylphenylindolocarbazolyl)triazine; (phenyl)(biphenylyl)(phenylindolocarbazolyl)triazine; (phenyl)(biphenylyl)(phenylindolocarbazolyl)triazine; di(phenyl)(biphenylylindolocarbazolyl)triazine; di(phenyl)(biphenylylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(phenyl)(terphenylylindolocarbazolyl)triazine; di(phenyl)(terphenylylindolocarbazolyl)triazine; di(phenyl)(terphenylylindolocarbazolyl)triazine; di(biphenylyl)(phenylindolocarbazolyl)triazine; di(biphenylyl)(phenylindolocarbazolyl)triazine; di(biphenylyl)(phenylindolocarbazolyl)triazine; di(biphenylyl)(phenylindolocarbazolyl)triazine; (phenyl)(biphenylyl)(dibutylphenylindolocarbazoly)triazine; (phenyl)(biphenylyl)[di(tert-butyl)phenylindolocarbazolyl]triazine; (phenyl)(terphenylyl)(dibutylphenylindolocarbazolyl)triazine; (phenyl)(terphenylyl)[di(tert-butyl)phenylindolocarbazolyl]triazine; (phenyl)(biphenylyl)(dibutylphenylindolocarbazolyl)triazine; (phenyl)(biphenylyl)[di(tert-butyl)phenylindolocarbazolyl]triazine; (phenyl)(terphenylyl)[di(tert-butyl)phenylindolocarbazolyl]triazine; (phenyl)(terphenylyl)(dibutylphenylindolocarbazolyl)triazine; (biphenylyl)(terphenylyl)(dibutylphenylindolocarbazolyl)triazine; (phenyl)(biphenylyl)(phenylindolocarbazolyl)triazine; (phenyl)(biphenylyl)(phenylindolocarbazolyl)triazine; di(phenyl)(biphenylylindolocarbazolyl)triazine; di(phenyl)(biphenylylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(phenyl)(terphenylylindolocarbazolyl)triazine; di(phenyl)(terphenylylindolocarbazolyl)triazine; di(phenyl)(terphenylylindolocarbazolyl)triazine; di(phenyl)(terphenylylindolocarbazolyl)triazine; di(biphenylyl)(phenylindolocarbazolyl)triazine; di(biphenylyl)(phenylindolocarbazolyl)triazine; di(biphenylyl)(phenylindolocarbazolyl)triazine; (phenyl)(biphenylyl)(dibutylphenylindolocarbazolyl)triazine; (phenyl)(biphenylyl)[di(tert-butyl)phenylindolocarbazolyl]triazine; (phenyl)(terphenylyl)(dibutylphenylindolocarbazolyl)triazine; (phenyl)(terphenylyl)[di(tert-butyl)phenylindolocarbazolyl]triazine; (phenyl)(biphenylyl)(dibutylphenylindolocarbazolyl)triazine; (phenyl)(biphenylyl)[di(tert-butyl)phenylindolocarbazolyl]triazine; (phenyl)(terphenylyl)(dibutylphenylindolocarbazolyl)triazine; (phenyl)(terphenylyl)[di(tert-butyl)phenylindolocarbazolyl]triazine; (biphenylyl)(terphenylyl)[di(tert-butyl)phenylindolocarbazolyl]triazine; (phenyl)(biphenylyl)(phenylindolocarbazolyl)triazine; (phenyl)(biphenylyl)(phenylindolocarbazolyl)triazine; di(phenyl)(biphenylylindolocarbazolyl)triazine; di(phenyl)(biphenylylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(biphenylyl)(phenylindolocarbazolyl)triazine; di(biphenylyl)(phenylindolocarbazolyl)triazine; (phenyl)(biphenylyl)(phenylindolocarbazolyl)triazine; (phenyl)(biphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(biphenylyl)(phenylindolocarbazolyl)triazine; di(biphenylyl)(phenylindolocarbazolyl)triazine; (phenyl)(biphenylyl)(phenylindolocarbazolyl)triazine; (phenyl)(biphenylyl)(phenylindolocarbazolyl)triazine; di(phenyl)(biphenylylindolocarbazolyl)triazine; di(phenyl)(biphenylylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; (phenyl)(terphenylyl)(phenylindolocarbazolyl)triazine; di(biphenylyl)(phenylindolocarbazolyl)triazine; di(biphenylyl)(phenylindolocarbazolyl)triazine; di(terphenylyl)(phenylindolocarbazolyl)triazine; di(terphenylyl)(phenylindolocarbazolyl)triazine; di(terphenylyl)(phenylindolocarbazolyl)triazine; di(terphenylyl)(phenylindolocarbazolyl)triazine; (phenyl)(biphenylyl)[phenyl(dibenzofuranyl)indolocarbazolyl]triazine; (phenyl)(biphenylyl)[phenyl(dibenzothiophenyl)indolocarbazolyl]triazine; (phenyl)(terphenylyl)[phenyl(dibenzofuranyl)indolocarbazolyl]triazine; (phenyl)(terphenylyl)[phenyl(dibenzothiophenyl)indolocarbazolyl]triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(biphenylyl)(biphenylylindolocarbazolyl)triazine; (phenyl)(terphenylyl)(biphenylylindolocarbazolyl)triazine; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; di(biphenylyl)bicarbazole; (phenyl)(biphenylyl)bicarbazole; (phenyl)(biphenylyl)bicarbazole; (phenyl)(biphenylyl)bicarbazole; (phenyl)(biphenylyl)bicarbazole; (phenyl)(biphenylyl)bicarbazole; di(biphenylyl)bicarbazole; (phenyl)(terphenylyl)bicarbazole; (phenyl)(terphenylyl)bicarbazole; (biphenyl)(terphenylyl)bicarbazole; (phenyl)(terphenylyl)bicarbazole; (phenyl)(terphenylyl)bicarbazole; (biphenylyl)(terphenylyl)bicarbazole; di(biphenylyl)bicarbazole; di(biphenylyl)bicarbazole

### (Group 32A)

(phenyl)(carbazolylphenyl)(dibenzofuranyl)triazine; (biphenylyl)(carbazolylphenyl)(dibenzofuranyl)triazine; (terphenylyl)(carbazolylphenyl)(dibenzofuranyl)triazine; (biphenylyl)(carbazolylphenyl)(dibenzofuranyl)triazine; (terphenylyl)(carbazolylphenyl)(dibenzofuranyl)triazine; (phenyl)(phenylcarbazolylphenyl)(dibenzofuranyl)triazine; (terphenylyl)(carbazolylphenyl)(dibenzofuranyl)triazine; (terphenylyl)(carbazolylphenyl)(dibenzofuranyl)triazine; (phenyl)(phenylcarbazolylphenyl)(dibenzofuranyl)triazine; (phenyl)(phenylcarbazolylphenyl)(dibenzofuranyl)triazine; (phenyl)(diphenylcarbazolylphenyl)(dibenzofuranyl)triazine; (phenyl)(biphenylylcarbazolylphenyl)(dibenzofuranyl)triazine; (phenyl)(biphenylylcarbazolylphenyl)(dibenzofuranyl)triazine; (phenyl)(biphenylylcarbazolylphenyl)(dibenzofuranyl)triazine; (biphenylyl)(phenylcarbazolylphenyl)(dibenzofuranyl)triazine; (phenyl)(carbazolylbiphenylyl)(dibenzofuranyl)triazine; (phenyl)(phenylcarbazolylbiphenylyl)(dibenzofuranyl)triazine; (phenyl)(carbazolylterphenylyl)(dibenzofuranyl)triazine; (biphenylyl)(carbazolylbiphenylyl)(dibenzofuranyl)triazine; (phenyl)(phenylcarbazolylbiphenylyl)(dibenzofuranyl)triazine; (phenyl)(carbazolylbiphenylyl)(dibenzofuranyl)triazine; (biphenylyl)(carbazolylbiphenylyl)(dibenzofuranyl)triazine; (biphenylyl)(carbazolylbiphenylyl)(dibenzofuranyl)triazine; (terphenylyl)(carbazolylbiphenylyl)(dibenzofuranyl)triazine; (phenyl)(carbazolylterphenylyl)(dibenzofuranyl)triazine; (phenyl)(phenylcarbazolylbiphenylyl)(dibenzofuranyl)triazine; (phenyl)(phenylcarbazolylbiphenylyl)(dibenzofuranyl)triazine; (phenyl)(phenylcarbazolylbiphenylyl)(dibenzofuranyl)triazine; (biphenylyl)(carbazolylbiphenylyl)(dibenzofuranyl)triazine; (terphenylyl)(carbazolylbiphenylyl)(dibenzofuranyl)triazine; (phenyl)(diphenylcarbazolylbiphenylyl)(dibenzofuranyl)triazine; (phenyl)(carbazolylbiphenylyl)(dibenzofuranyl)triazine; (biphenylyl)(carbazolylbiphenylyl)(dibenzofuranyl)triazine; (phenyl)(phenylcarbazolylbiphenylyl)(dibenzofuranyl)triazine; (phenyl)(phenylcarbazolylbiphenylyl)(dibenzofuranyl)triazine; (biphenylyl)(phenylcarbazolylbiphenylyl)(dibenzofuranyl)triazine; (phenyl)(carbazolylterphenylyl)(dibenzofuranyl)triazine; (phenyl)(carbazolylterphenylyl)(dibenzofuranyl)triazine; (carbazolylphenyl)bis(dibenzofuranyl)triazine; (carbazolylbiphenylyl)bis(dibenzofuranyl)triazine; (phenyl)(carbazolylphenyl)(dibenzothiophenyl)triazine; (biphenylyl)(carbazolylphenyl)(dibenzothiophenyl)triazine; (terphenylyl)(carbazolylphenyl)(dibenzothiophenyl)triazine; (biphenylyl)(carbazolylphenyl)(dibenzothiophenyl)triazine; (terphenylyl)(carbazolylphenyl)(dibenzothiophenyl)triazine; (terphenylyl)(carbazolylphenyl)(dibenzothiophenyl)triazine; (terphenylyl)(carbazolylphenyl)(dibenzothiophenyl)triazine; (phenyl)(phenylcarbazolylphenyl)(dibenzothiophenyl)triazine; (phenyl)(phenylcarbazolylphenyl)(dibenzothiophenyl)triazine; (biphenylyl)(phenylcarbazolylphenyl)(dibenzothiophenyl)triazine; (phenyl)(diphenylcarbazolylphenyl)(dibenzothiophenyl)triazine; (phenyl)(biphenylylcarbazolylphenyl)(dibenzothiophenyl)triazine; (phenyl)(biphenylylcarbazolylphenyl)(dibenzothiophenyl)triazine; (phenyl)(biphenylylcarbazolylphenyl)(dibenzothiophenyl)triazine; (biphenylyl)(phenylcarbazolylphenyl)(dibenzothiophenyl)triazine; (phenyl)(carbazolylbiphenylyl)(dibenzothiophenyl)triazine; (biphenylyl)(carbazolylbiphenylyl)(dibenzothiophenyl)triazine; (phenyl)(carbazolylbiphenylyl)(dibenzothiophenyl)triazine; (phenyl)(carbazolylbiphenylyl)(dibenzothiophenyl)triazine; (phenyl)(carbazolylterphenylyl)(dibenzothiophenyl)triazine; (phenyl)(carbazolylbiphenylyl)(dibenzothiophenyl)triazine; (biphenylyl)(carbazolylbiphenylyl)(dibenzothiophenyl)triazine; (biphenylyl)(carbazolylbiphenylyl)(dibenzothiophenyl)triazine; (terphenylyl)(carbazolylbiphenylyl)(dibenzothiophenyl)triazine; (phenyl)(carbazolylterphenylyl)(dibenzothiophenyl)triazine; (phenyl)(phenylcarbazolylbiphenylyl)(dibenzothiophenyl)triazine; (phenyl)(carbazolylbiphenylyl)(dibenzothiophenyl)triazine; (biphenylyl)(carbazolylbiphenylyl)(dibenzothiophenyl)triazine; (terphenylyl)(carbazolylbiphenylyl)(dibenzothiophenyl)triazine; (phenyl)(carbazolylterphenylyl)(dibenzothiophenyl)triazine; (phenyl)(phenylcarbazolylbiphenylyl)(dibenzothiophenyl)triazine; (phenyl)(phenylcarbazolylbiphenylyl)(dibenzothiophenyl)triazine; (phenyl)(phenylcarbazolylbiphenylyl)(dibenzothiophenyl)triazine; (phenyl)(diphenylcarbazolylbiphenylyl)(dibenzothiophenyl)triazine; (phenyl)(carbazolylbiphenylyl)(dibenzothiophenyl)triazine; (biphenylyl)(carbazolylbiphenylyl)(dibenzothiophenyl)triazine; (terphenylyl)(carbazolylbiphenylyl)(dibenzothiophenyl)triazine; (biphenylyl)(carbazolylbiphenylyl)(dibenzothiophenyl)triazine; (phenyl)(phenylcarbazolylbiphenylyl)(dibenzothiophenyl)triazine; (phenyl)(phenylcarbazolylbiphenylyl)(dibenzothiophenyl)triazine; (biphenylyl)(phenylcarbazolylbiphenylyl)(dibenzothiophenyl)triazine; (phenyl)(carbazolylterphenylyl)(dibenzothiophenyl)triazine; (phenyl)(carbazolylterphenylyl)(dibenzothiophenyl)triazine; (carbazolylphenyl)bis(dibenzothiophenyl)triazine; (carbazolylbiphenylyl)bis(dibenzothiophenyl)triazine; (diphenylpyridyl)(phenyl)bicarbazole; (diphenylpyridyl)(phenyl)bicarbazole; (diphenylpyridyl)(biphenylyl)bicarbazole; (diphenylpyridyl)(terphenylyl)bicarbazole; (terphenylyl)(phenyl)bicarbazole; (diphenylpyridyl)(naphthyl)bicarbazole; (diphenylpyridyl)(naphthyl)bicarbazole; (diphenylpyridyl)(triphenylenyl)bicarbazole; (diphenylpyridyl)(triphenylenyl)bicarbazole; bis(diphenylpyridyl)bicarbazole; bis(diphenylpyridyl)bicarbazole; bis(diphenylpyridyl)bicarbazole; (dimethylfluorenyl)(phenyl)bicarbazole; (dimethylfluorenyl)(biphenylyl)bicarbazole; (dimethylfluorenyl)(terphenylyl)bicarbazole; (dibenzofuranyl)(phenyl)bicarbazole; (dibenzofuranyl)(biphenylyl)bicarbazole; (dibenzofuranyl)(terphenylyl)bicarbazole; (dibenzothiophenyl)(phenyl)bicarbazole; (dibenzothiophenyl)(biphenylyl)bicarbazole; (dibenzothiophenyl)(terphenyl)bicarbazole; diphenylbicarbazole; dipyridylbicarbazole; dipyrimidylbicarbazole; (triphenylenyl)(phenyl)bicarbazole; (pyridyl)(triphenylenyl)bicarbazole; (phenyl)(triphenylenyl)bicarbazole; (pyridyl)(triphenylenyl)bicarbazole; (phenyl)(triphenylenyl)bicarbazole; (pyridyl)(triphenylenyl)bicarbazole; di(biphenylyl)bicarbazole; (biphenylyl)(terphenylyl)bicarbazole; (biphenylyl)(terphenylyl)bicarbazole; (dimethylfluorenyl)(phenyl)bicarbazole; (dimethylfluorenyl)(biphenylyl)bicarbazole; (dimethylfluorenyl)(biphenylyl)bicarbazole; (dimethylfluorenyl)(terphenylyl)bicarbazole; (dibenzofuranyl)(biphenylyl)bicarbazole; (dibenzothiophenyl)(biphenylyl)bicarbazole; diphenyltercarbazole; (dibenzofuranyl)(phenyl)bicarbazole; (dibenzofuranyl)(biphenylyl)bicarbazole; (dibenzofuranyl)(terphenylyl)bicarbazole; (dibenzofuranyl)(biphenylyl)bicarbazole; (dibenzothiophenyl)(phenyl)bicarbazole; (dibenzothiophenyl)(biphenylyl)bicarbazole; (dibenzothiophenyl)(terphenylyl)bicarbazole; (dibenzothiophenyl)(biphenylyl)bicarbazole; (dimethylfluorenyl)(diphenylpyridyl)bicarbazole; (dimethylfluorenyl)(diphenylpyridyl)bicarbazole; (dimethylfluorenyl)(pyridylbiphenylyl)bicarbazole; (dimethylfluorenyl)(pyridylbiphenylyl)bicarbazole; (dimethylfluorenyl)(pyridylbiphenylyl)bicarbazole; (dibenzofuranyl)(diphenylpyridyl)bicarbazole; (dibenzofuranyl)(pyridylbiphenylyl)bicarbazole; (dibenzofuranyl)(pyridylbiphenylyl)bicarbazole; (dibenzofuranyl)(pyridylbiphenylyl)bicarbazole; (dibenzothiophenyl)(diphenylpyridyl)bicarbazole; (dibenzothiophenyl)(pyridylbiphenylyl)bicarbazole; (dibenzothiophenyl)(pyridylbiphenylyl)bicarbazole; (dibenzothiophenyl)(pyridylbiphenylyl)bicarbazole; (diphenylpyridyl)(phenyl)bicarbazole; (pyridylbiphenylyl)(phenyl)bicarbazole; (diphenylpyridyl)(phenyl)bicarbazole; (diphenylpyridyl)(biphenylyl)bicarbazole; (pyridylbiphenylyl)(biphenylyl)bicarbazole; (diphenylpyridyl)(biphenylyl)bicarbazole; (diphenylpyridyl)(biphenylyl)bicarbazole; (diphenylpyridyl)(biphenylyl)bicarbazole; (pyridylbiphenylyl)(biphenylyl)bicarbazole; (diphenylpyridyl)(phenyl)bicarbazole; (diphenylpyridyl)(phenyl)bicarbazole; (pyridylbiphenylyl)(phenyl)bicarbazole; (diphenylpyridyl)(biphenylyl)bicarbazole; (diphenylpyridyl)(biphenylyl)bicarbazole; (pyridylbiphenylyl)(biphenylyl)bicarbazole; (diphenylpyridyl)(biphenylyl)bicarbazole; (diphenylpyridyl)(biphenylyl)bicarbazole; (pyridylbiphenylyl)(biphenylyl)bicarbazole; (dibenzofuranyl)(terphenylyl)bicarbazole; (dibenzofuranyl)(biphenylyl)bicarbazole; (dibenzofuranyl)(phenyl)bicarbazole; (dibenzofuranyl)(biphenylyl)bicarbazole; (dibenzothiophenyl)(terphenylyl)bicarbazole; (dibenzothiophenyl)(biphenylyl)bicarbazole; (dibenzothiophenyl)(phenyl)bicarbazole; (dibenzothiophenyl)(biphenylyl)bicarbazole; (diphenylpyridyl)(biphenylyl)bicarbazole; (diphenylpyridyl)(biphenylyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(biphenylyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(biphenylyl)bicarbazole; (diphenylpyridyl)(phenyl)bicarbazole; di(biphenylyl)bicarbazole; di(biphenylyl)bicarbazole; (biphenylyl)(phenyl)bicarbazole; bis(phenylcarbazolyl)benzene; (phenylcarbazolyl)(biphenylylcarbazolyl)benzene; bis(biphenylylcarbazolyl)benzene; bis(phenylcarbazolyl)benzene; (phenylcarbazolyl)(terphenylylcarbazolyl)benzene; bis(biphenylylcarbazolyl)benzene; (phenylcarbazolyl)(dimethylfluorenylcarbazolyl)benzene; (dibenzofuranyl)(phenylcarbazolyl)benzene; (dibenzothiophenyl)(phenylcarbazolyl)benzene; bis(phenylcarbazolyl)biphenyl; (phenylcarbazolyl)(biphenylylcarbazolyl)benzene; (biphenylylcarbazolyl)(terphenylylcarbazolyl)benzene; bis(phenylcarbazolyl)benzene; (phenylcarbazolyl)(terphenylylcarbazolyl)benzene; bis(biphenylylcarbazolyl)benzene; (phenylcarbazolyl)(dimethylfluorenylcarbazolyl)benzene; (phenylcarbazolyl)(terphenylylcarbazolyl)benzene; (dibenzothiophenyl)(phenylcarbazolyl)benzene; (biphenylyl)(terphenylyl)bicarbazole; (biphenylyl)(quarterphenylyl)bicarbazole; (terphenylyl)(quarterphenylyl)bicarbazole; (biphenylyl)(terphenylyl)bicarbazole; (terphenylyl)(quarterphenylyl)bicarbazole; di(quarterphenylyl)bicarbazole; (biphenylyl)(quarterphenylyl)bicarbazole; (phenyl)(quarterphenylyl)bicarbazole; (phenyl)(terphenylyl)bicarbazole; di(phenyl)(biphenylyl)bicarbazole; di(phenyl)(biphenylyl)bicarbazole; tri(phenyl)bicarbazole; tri(phenyl)bicarbazole; di(phenyl)(biphenylyl)bicarbazole; di(phenyl)(biphenylyl)bicarbazole; di(phenyl)(biphenylyl)bicarbazole; (phenyl)(biphenylyl)bicarbazole; (dibenzofuranylphenyl)(phenyl)bicarbazole; (dibenzothiophenylphenyl)(phenyl)bicarbazole; diphenylindolocarbazole; (biphenylyl)(phenyl)indolocarbazole; (biphenylyl)(phenyl)indolocarbazole; di(biphenylyl)indolocarbazole; di(biphenylyl)indolocarbazole; (biphenylyl)(terphenylyl)indolocarbazole; (biphenylyl)(terphenylyl)indolocarbazole; di(terphenylyl)indolocarbazole; (terphenylyl)(phenyl)indolocarbazole; (biphenylyl)(terphenylyl)indolocarbazole; (biphenylyl)(terphenylyl)indolocarbazole; di(terphenylyl)indolocarbazole; di(biphenylyl)(phenyl)indolocarbazole; di(phenyl)(biphenylyl)indolocarbazole; di(biphenylyl)(phenyl)indolocarbazole; di(biphenylyl)(phenyl)indolocarbazole; di(biphenylyl)(phenyl)indolocarbazole; di(phenyl)(biphenylyl)indolocarbazole; di(biphenylyl)(phenyl)indolocarbazole; di(biphenylyl)(phenyl)indolocarbazole; di(naphthyl)indolocarbazole; di(naphthyl)indolocarbazole; (naphthyl)(biphenylyl)indolocarbazole; (naphthyl)(biphenylyl)indolocarbazole; (naphthyl)(terphenylyl)indolocarbazole; (naphthyl)(terphenylyl)indolocarbazole; (naphthyl)(terphenylyl)indolocarbazole; (naphthyl)(terphenylyl)indolocarbazole; (naphthylphenyl)(phenyl)indolocarbazole; (naphthylphenyl)(phenyl)indolocarbazole; (naphthylphenyl)(phenyl)indolocarbazole; (naphthylphenyl)(phenyl)indolocarbazole; (naphthylphenyl)(biphenylyl)indolocarbazole; (naphthylphenyl)(biphenylyl)indolocarbazole; (naphthylphenyl)(biphenylyl)indolocarbazole; (naphthylphenyl)(biphenylyl)indolocarbazole; (phenylnaphthyl)(biphenylyl)indolocarbazole; (phenylnaphthyl)(biphenylyl)indolocarbazole; (phenylnaphthyl)(biphenylyl)indolocarbazole; (phenylnaphthyl)(biphenylyl)indolocarbazole; di(phenyl)(phenylnaphthyl)indolocarbazole; di(phenyl)(phenylnaphthyl)indolocarbazole; di(phenyl)(phenylnaphthyl)indolocarbazole; di(phenyl)(phenylnaphthyl)indolocarbazole; di(phenyl)(naphthylphenyl)indolocarbazole; di(phenyl)(naphthylphenyl)indolocarbazole; di(phenyl)(naphthylphenyl)indolocarbazole; di(phenyl)(naphthylphenyl)indolocarbazole; (phenyl)(naphthyl)(naphthylphenyl)indolocarbazole; (phenyl)(biphenylyl)(naphthylphenyl)indolocarbazole; (phenyl)(naphthyl)(naphthylphenyl)indolocarbazole; (phenyl)(biphenylyl)(naphthylphenyl)indolocarbazole

### (Group 33A)

[bis(ditrifluoromethylphenyl)indenofluorenediylidene]bis(malononitrile); (diindenothiophenediylidene)bis(malononitrile); [bis(trifluoromethoxyphenyl)indenofluorenediylidene]bis(malononitrile); [bis(trifluoromethoxyphenyl)indenofluorenediylidene]bis(malononitrile); [bis[fluoro(trifluoromethyl)phenyl]diazaindenofluorenediylidene]bis(malononitrile); [bis(trifluoromethylphenyl)diazaindenofluorenediylidene]bis(malononitrile); [bis(trifluoromethylphenyl)diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis(pentafluorophenyl)diazaindenofluorenediylidene]bis(malononitrile); [bis(pentafluorophenyl)diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[bis(trifluoromethyl)phenyl]diazaindenofluorenediylidene]bis(malononitrile); [bis[bis(trifluoromethyl)phenyl]diazaindenofluorenediylidene]bis(aminonitrile); [bis(trifluorophenyl)diazaindenofluorenediylidene]bis(malononitrile); [bis(trifluorophenyl)diazaindenofluorenediylidene]bis(aminonitrile); [bis[(trifluoromethoxy)phenyl]diazaindenofluorenediylidene]bis(malononitrile); [bis[(trifluoromethoxy)phenyl]diazaindenofluorenediylidene]bis(aminonitrile); [bis[(trifluoroacetyl)phenyl]diazaindenofluorenediylidene]bis(malononitrile); [bis[(trifluoroacetyl)phenyl]diazaindenofluorenediylidene]bis(aminonitrile); [bis[cyano(trifluoromethyl)phenyl]diazaindenofluorenediylidene]bis(malononitrile); [bis[cyano(trifluoromethyl)phenyl]diazaindenofluorenediylidene]bis(aminonitrile); [bis(trifluoromethyl)diazaindenofluorenediylidene]bis(malononitrile); [bis(trifluoromethyl)diazaindenofluorenediylidene]bis(aminonitrile); (difluorodiazaindenofluorenediylidene)bis(malononitrile); (difluorodiazaindenofluorenediylidene)bis(aminonitrile); (hexafluorodiazaindenofluorenediylidene)bis(malononitrile); (hexafluorodiazaindenofluorenediylidene)bis(aminonitrile); (tetrafluorodiazaindenofluorenediylidene)bis(malononitrile); (tetrafluorodiazaindenofluorenediylidene)bis(aminonitrile); [bis(trifluoromethyl)azaindenofluorenediylidene]bis(malononitrile); (diphenyldiazaindenofluorenediylidene)bis(malononitrile); (difluorodiazaindenofluorenediylidene)bis[(trifluoromethyl)ethyl acrylate]; (difluorodiazaindenofluorenediylidene)bis(methyleneindanedione); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[bis(trifluoromethyl)phenyl]diazaindenofluorenediylidene]bis(malononitrile); [bis[bis(trifluoromethyl)phenyl]diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethoxy)phenyl]diazaindenofluorenediylidene]bis(malononitrile); [bis[(trifluoromethoxy)phenyl]diazaindenofluorenediylidene]bis(aminonitrile); [bis[cyano(fluoro)phenyl]diazaindenofluorenediylidene]bis(malononitrile); [bis[cyano(fluoro)phenyl]diazaindenofluorenediylidene]bis(aminonitrile); [bis(fluoropyridyl)diazaindenofluorenediylidene]bis(malononitrile); [bis(fluoropyridyl)diazaindenofluorenediylidene]bis(aminonitrile); [bis(difluoropyridyl)diazaindenofluorenediylidene]bis(malononitrile); [bis(difluoropyridyl)diazaindenofluorenediylidene]bis(aminonitrile); [bis[(trifluoromethyl)thiophenyl]diazaindenofluorenediylidene]bis(malononitrile); [bis[(trifluoromethyl)thiophenyl]diazaindenofluorenediylidene]bis(aminonitrile); (dinaphthyldiazaindenofluorenediylidene)bis(malononitrile); (dinaphthyldiazaindenofluorenediylidene)bis(aminonitrile); [bis(heptafluoronaphthyl)diazaindenofluorenediylidene]bis(malononitrile); [bis(heptafluoronaphthyl)diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [tetrakis[(trifluoromethyl)phenyl]diazaindenofluorenediylidene]bis(malononitrile); [tetrakis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]indenofluorenediylidene]bis(aminonitrile); [bis[(trifluoromethyl)phenyl]indenofluorenediylidene]bis(malononitrile); [bis[bis(trifluoromethyl)phenyl]indenofluorenediylidene]bis(aminonitrile); [bis[bis(trifluoromethyl)phenyl]indenofluorenediylidene]bis(malononitrile); [bis(trifluorophenyl)indenofluorenediylidene]bis(aminonitrile); [bis(trifluorophenyl)indenofluorenediylidene]bis(malononitrile); [bis(pentafluorophenyl)indenofluorenediylidene]bis(aminonitrile); [bis(pentafluorophenyl)indenofluorenediylidene]bis(malononitrile); [bis(cyanophenyl)indenofluorenediylidene]bis(aminonitrile); [bis(cyanophenyl)indenofluorenediylidene]bis(malononitrile); (diphenylindenofluorenediylidene)bis(aminonitrile); (diphenylindenofluorenediylidene]bis(malononitrile); (dinaphthylindenofluorenediylidene)bis(aminonitrile); (dinaphthylindenofluorenediylidene]bis(malononitrile); (difluoroindenofluorenediylidene)bis(aminonitrile); (difluoroindenofluorenediylidene]bis(malononitrile); (hexafluoroindenofluorenediylidene)bis(aminonitrile); (hexafluoroindenofluorenediylidene]bis(malononitrile); (tetrafluoroindenofluorenediylidene)bis(aminonitrile); (tetrafluoroindenofluorenediylidene]bis(malononitrile); [tetrakis(trifluoromethyl)indenofluorenediylidene]bis(aminonitrile); [tetrakis(trifluoromethyl)indenofluorenediylidene]bis(malononitrile); (phenylindenofluorenediylidene)bis(aminonitrile); [phenyl(trifluoromethyl)indenofluorenediylidene]bis(aminonitrile); (diphenylindenofluorenediylidene)bis(aminonitrile); [diphenylbis(trifluoromethyl)indenofluorenediylidene]bis(aminonitrile); [diphenyl(difluoro)indenofluorenediylidene]bis(aminonitrile); [bis(trifluoromethylphenyl)indenofluorenediylidene]bis(aminonitrile); [dimethylbis(trifluoromethyl)indenofluorenediylidene]bis(malononitrile); [bis[(trifluoromethyl)phenyl]indenofluorenediylidene]bis(malononitrile); [bis[(trifluoromethyl)phenyl]indenofluorenediylidene]bis(aminonitrile); [bis(fluoropyridyl)indenofluorenediylidene]bis(malononitrile); [bis(fluoropyridyl)indenofluorenediylidene]bis(aminonitrile); [bis(difluoropyridyl)indenofluorenediylidene]bis(malononitrile); [bis(difluoropyridyl)indenofluorenediylidene]bis(aminonitrile); [bis(cyanofluorophenyl)indenofluorenediylidene]bis(malononitrile); [bis(cyanofluorophenyl)indenofluorenediylidene]bis(aminonitrile); [bis(cyanophenyl)indenofluorenediylidene]bis(malononitrile); [bis(cyanophenyl)indenofluorenediylidene]bis(aminonitrile); [[(trifluoromethyl)phenyl]indenofluorenediylidene]bis(malononitrile); [[(trifluoromethyl)phenyl]indenofluorenediylidene]bis(aminonitrile); [fluoro[(trifluoromethyl)phenyl]indenofluorenediylidene]bis(malononitrile); [fluoro[(trifluoromethyl)phenyl]indenofluorenediylidene]bis(aminonitrile); [(cyanophenyl)indenofluorenediylidene]bis(malononitrile); [(cyanophenyl)indenofluorenediylidene]bis(aminonitrile); [fluoro(cyanophenyl)indenofluorenediylidene]bis(malononitrile); [fluoro(cyanophenyl)indenofluorenediylidene]bis(aminonitrile); [tetrafluoro[(trifluoromethyl)phenyl]indenofluorenediylidene]bis(malononitrile); [tetrafluoro[(trifluoromethyl)phenyl]indenofluorenediylidene]bis(aminonitrile); [[fluoro(trifluoromethyl)phenyl]indenofluorenediylidene]bis(malononitrile); [[fluoro(trifluoromethyl)phenyl]indenofluorenediylidene]bis(aminonitrile); [[bis(trifluoromethyl)phenyl]indenofluorenediylidene]bis(malononitrile); [[bis(trifluoromethyl)phenyl]indenofluorenediylidene]bis(aminonitrile); [biphenylyl(trifluoromethyl)indenofluorenediylidene]bis(malononitrile); [biphenylyl(trifluoromethyl)indenofluorenediylidene]bis(aminonitrile); [naphthyl(trifluoromethyl)indenofluorenediylidene]bis(malononitrile); [naphthyl(trifluoromethyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis(difluorophenyl)indenofluorenediylidene]bis(malononitrile); [bis(difluorophenyl)indenofluorenediylidene]bis(aminonitrile); [bis(difluorophenyl)indenofluorenediylidene]bis(malononitrile); [bis(difluorophenyl)indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[(trifluoromethyl)phenyl]indenofluorenediylidene]bis(malononitrile); [bis[(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[bis(trifluoromethyl)phenyl]indenofluorenediylidene]bis(malononitrile); [bis[bis(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis(trifluorophenyl)indenofluorenediylidene]bis(malononitrile); [bis(trifluorophenyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis[(trifluoromethyl)phenyl]indenofluorenediylidene]bis(malononitrile); [bis[(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[difluoro(trifluoromethyl)phenyl]indenofluorenediylidene]bis(malononitrile); [bis[difluoro(trifluoromethyl)phenyl]indenofluorenediylidene]bis(aminonitrile); [bis[difluoro(trifluoromethyl)phenyl]indenofluorenediylidene]bis(malononitrile); [bis[difluoro(trifluoromethyl)phenyl]indenofluorenediylidene]bis(aminonitrile); (dinaphthylindenofluorenediylidene)bis(malononitrile); (dinaphthylindenofluorenediylidene)bis(aminonitrile); (difluoroindenofluorenediylidene)bis(malononitrile); (difluoroindenofluorenediylidene)bis(aminonitrile); [bis(trifluoromethyl)indenofluorenediylidene]bis(malononitrile); [bis(trifluoromethyl)indenofluorenediylidene]bis(aminonitrile); (dicyanoindenofluorenediylidene)bis(malononitrile); (dicyanoindenofluorenediylidene)bis(aminonitrile); (hexafluoroindenofluorenediylidene)bis(malononitrile); (hexafluoroindenofluorenediylidene)bis(aminonitrile); [dicyanobis(trifluoromethyl)indenofluorenediylidene]bis(malononitrile); [dicyanobis(trifluoromethyl)indenofluorenediylidene]bis(aminonitrile); [tetrakis[(trifluoromethyl)phenyl]indenofluorenediylidene]bis(malononitrile); [tetrakis[(trifluoromethyl)phenyl]indenofluorenediylidene]bis(malononitrile); [tetrakis[(trifluoromethyl)phenyl]indenofluorenediylidene]bis(malononitrile); [bis[bis(trifluoromethyl)phenyl]azaindenofluorenediylidene]bis(malononitrile); [bis[bis(trifluoromethyl)phenyl]diazaindenofluorenediylidene]bis(malononitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(malononitrile); [bis[(trifluoromethyl)phenyl]indenofluorenediylidene]bis(trifluoromethylacrylonitrile); [bis(trifluoromethoxy)indenofluorenediylidene]bis(malononitrile); [fluorobis(trifluoromethoxy)indenofluorenediylidene]bis(malononitrile); [bis[(trifluoromethoxy)phenyl]indenofluorenediylidene]bis(malononitrile); [bis[fluoro(trifluoromethoxy)phenyl]indenofluorenediylidene]bis(malononitrile); [(trifluoroethoxy)bis[(trifluoromethoxy)phenyl]indenofluorenediylidene]bis(malononitrile); [bis[(pentafluoroethoxy)phenyl]indenofluorenediylidene]bis(malononitrile); [bis[(pentafluoropropoxy)phenyl]indenofluorenediylidene]bis(malononitrile); [bis[(hexafluoroisopropoxy)phenyl]indenofluorenediylidene]bis(malononitrile); [(pentafluoropropoxy)bis(trifluoromethoxy)indenofluorenediylidene]bis(malononitrile); [(trifluoromethoxy)[fluoro(trifluoromethyl)phenyl]indenofluorenediylidene]bis(malononitrile); [(trifluoromethoxy)[(trifluoromethoxy)phenyl]indenofluorenediylidene]bis(malononitrile); [fluoro[(trifluoromethoxy)phenyl]indenofluorenediylidene]bis(malononitrile); (dibenzoindenofluorenediylidene)bis(malononitrile); (azadibenzoindenofluorenediylidene)bis(malononitrile); (diazadibenzoindenofluorenediylidene)bis(malononitrile); [(trifluoromethoxy)benzoindenofluorenediylidene]bis(malononitrile); [[(trifluoromethoxy)phenyl]bis(trifluoromethoxy)indenofluorenediylidene]bis(malononitrile); [dithiophenylindenofluorenediylidene]bis(malononitrile); [bis(trifluoromethoxy)diazaindenofluorenediylidene]bis(malononitrile); [bis(trifluoromethoxy)hexaazaindenofluorenediylidene]bis(malononitrile); [tetrakis(trifluoromethoxy)indenofluorenediylidene]bis(malononitrile); [tetrakis(trifluoromethoxy)indenofluorenediylidene]bis(malononitrile); hexacyanohexaazatriphenylene; tris[cyano(cyanotetrafluorophenyl)methylene]cyclopropane; di(biphenylyl)(phenylspiroacridinefluorenyl)amine; (biphenylyl)(dimethylfluorenyl)(spiroindoloacridinefluorenyl)amine; (biphenylyl)(dibenzofuranyl)(phenylspiroacridinefluorenyl)amine; di(biphenylyl)(spirobenzoanthracenefluorenyl)amine; (biphenylyl)[(dibenzothiophenyl)phenyl](spirobenzoanthracenefluorenyl)amine; di(biphenylyl)(dibenzofuranyl)amine; (biphenylyl)(terphenylyl)(dibenzofuranyl)amine; (phenyl)(terphenylyl)(dibenzofuranyl)amine; (biphenylyl)(dibenzofuranyl)[(carbazolyl)phenyl]amine; (terphenylyl)(naphthyl)(dibenzofuranyl)amine; (phenyl)(dibenzofuranyl)[(dibenzofuranyl)phenyl]amine; (terphenylyl)(biphenylyl)(dibenzofuranyl)amine; (biphenylyl)(dibenzofuranyl)(dimethylfluorenyl)amine; (naphthyl)(biphenylyl)(dibenzofuranyl)amine; di(biphenylyl)[(phenyldibenzofuranyl)phenyl]amine; (naphthyl)(naphthylphenyl)[(phenyldibenzofuranyl)phenyl]amine; (naphthyl)(naphthylphenyl)[(phenyldibenzofuranyl)phenyl]amine; (biphenylyl)[(dimethylfluorenyl)phenyl][(dibenzofuranyl)phenyl]amine; (naphthyl)(biphenylyl)[(phenyldibenzofuranyl)biphenylyl]amine; (naphthyl)(biphenylyl)[(dibenzofuranyl)phenyl]amine; (phenyl)(naphthylphenyl)[(phenyldibenzofuranyl)phenyl]amine; (naphthylphenyl)bis[(dibenzofuranyl)phenyl]amine; di(terphenylyl)[(dibenzofuranyl)phenyl]amine; (phenyl)(biphenylyl)[(dibenzofuranyl)dimethylfluorenyl]amine; (phenyl)[(triphenylsilyl)phenyl](diphenylfluorenyl)amine; (phenyl)[(triphenylsilyl)phenyl](triphenylfluorenyl)amine; (diphenylfluorenyl)di(biphenylyl)amine; (diphenylfluorenyl)(biphenylyl)(naphthylphenyl)amine; (diphenylfluorenyl)(biphenylyl)(terphenyl)amine; (diphenylfluorenyl)(biphenylyl)(phenyldibenzofuranyl)amine; (phenyl)[(triphenylsilyl)phenyl](naphthylphenylfluorenyl)amine; (diphenylfluorenyl)(biphenylyl)(dibenzofuranyl)amine; (triphenylsilyldibenzothiophenyl)(phenyl)(diphenylfluorenyl)amine; (diphenylnaphthylsilylbiphenylyl)(phenyl)(diphenylyl)amine; (triphenylsilylphenyl)(phenyl)(naphthylphenylfluorenyl)amine; (diphenylfluorenyl)(biphenylyl)(phenyldibenzothiophenyl)amine; (diphenylfluorenyl)(biphenylyl)(dibenzothiophenyl)amine; (diphenylfluorenyl)(biphenylyl)(dibenzofuranylphenyl)amine; (diphenylfluorenyl)(biphenylyl)(phenyldibenzofuranylphenyl)amine; (diphenylfluorenyl)(biphenylyl)(phenyldibenzothiophenyl)amine; (dimethylfluorenyl)di(biphenylyl)amine; (dimethylfluorenyl)(terphenylyl)(biphenylyl)amine; (dimethylfluorenyl)(biphenylyl)(dibenzofuranylphenyl)amine; (dimethylfluorenyl)(biphenylyl)(dibenzothiophenylphenyl)amine; (dimethylfluorenyl)(biphenylyl)(phenyldibenzofuranyl)amine; (diphenylfluorenyl)bis(methylbiphenylyl)amine; (dimethylfluorenyl)di(biphenylyl)amine; (dimethylfluorenyl)di(biphenylyl)amine; (dibenzofuranylphenyl)(biphenylyl)(dimethylfluorenyl)amine; (quarterphenylyl)(dibenzofuranylphenyl)(phenylcarbazolylphenyl)amine; (quarterphenylyl)(dibenzofuranylphenyl)(phenylcarbazolylphenyl)amine; (quarterphenylyl)(dibenzofuranylphenyl)(phenylcarbazolylphenyl)amine; (quarterphenylyl)(dibenzofuranylphenyl)(phenylcarbazolylphenyl)amine; (quarterphenylyl)bis(dibenzofuranylphenyl)amine; (quarterphenylyl)bis(dibenzofuranylphenyl)amine; (quarterphenylyl)(dibenzofuranylphenyl)(phenylcarbazolylphenyl)amine; (quarterphenylyl)(dibenzofuranylphenyl)(phenylcarbazolylphenyl)amine; (quarterphenylyl)(biphenylyl)(dibenzofuranylphenyl)amine; (quarterphenylyl)(biphenylyl)(dibenzofuranylphenyl)amine; (terphenylyl)(naphthylphenyl)(dibenzofuranylbiphenylyl)amine; (terphenylyl)(phenylnaphthyl)(dibenzofuranylbiphenylyl)amine; (terphenylyl)(naphthyl)(dibenzofuranylbiphenylyl)amine; (dimethylfluorenyl)bis(spirobifluorenyl)amine; (biphenylyl)bis(spirobifluorenyl)amine; (dimethylfluorenyl)bis(spirobifluorenyl)amine; (spirobifluorenyl)(biphenylyl)(dimethylfluorenyl)amine; (spirobifluorenyl)di(biphenylyl)amine; (spirobifluorenyl)bis(dimethylfluorenyl)amine; (spirobifluorenyl)(biphenylyl)(dimethylfluorenyl)amine; (spirobifluorenyl)(terphenylyl)(dimethylfluorenyl)amine; (spirobifluorenyl)(biphenylyl)(dimethylfluorenyl)amine; (spirobifluorenyl)bis(dimethylfluorenyl)amine; (spirobifluorenyl)(biphenylyl)(dimethylfluorenyl)amine; (spirobifluorenyl)di(biphenylyl)amine; (spirobifluorenylphenyl)di(biphenylyl)amine; (spirobifluorenyl)di(biphenylyl)amine; (spirobifluorenyl)(biphenylyl)(dibenzofuranyl)amine; (spirobifluorenyl)(biphenylyl)(dibenzofuranyl)amine; (spirobifluorenyl)(dibenzofuranyl)(dimethylfluorenyl)amine; (spirobifluorenyl)(biphenylyl)(phenylcarbazolyl)amine; (spirobifluorenyl)(diphenylfluorenyl)(dibenzothiophenylphenyl)amine; (spirobifluorenyl)(dimethylfluorenyl)(dibenzothiophenyl)amine; (spirobifluorenyl)(biphenylyl)(phenylcarbazolyl)amine; (spirobifluorenyl)(biphenylyl)(diphenylfluorenyl)amine; (spirobifluorenyl)(biphenylyl)(dibenzofuranylphenyl)amine; (spirobifluorenyl)(biphenylyl)(dibenzothiophenylphenyl)amine; (spirobifluorenyl)(biphenylyl)(diphenylfluorenyl)amine; (biphenylyl)bis(dibenzofuranylphenyl)amine; (terphenylyl)bis(dibenzofuranylphenyl)amine; (dimethylfluorenyl)bis(dibenzofuranylphenyl)amine; (terphenylyl)bis(dibenzofuranylphenyl)amine; (quarterphenylyl)bis(dibenzofuranylphenyl)amine; (diphenylfluorenyl)(dibenzofuranylphenyl)(phenyl)amine; (diphenylfluorenyl)(dibenzofuranylphenyl)(biphenylyl)amine; (diphenylfluorenyl)(dibenzofuranylphenyl)(biphenylyl)amine; (diphenylfluorenyl)(dibenzofuranylphenyl)(biphenylyl)amine; (diphenylfluorenyl)(dibenzofuranylphenyl)(terphenylyl)amine; (diphenylfluorenyl)(dibenzofuranylphenyl)(terphenylyl)amine; (diphenylfluorenyl)(dibenzofuranylphenyl)(terphenylyl)amine; (diphenylfluorenyl)(dibenzofuranylphenyl)(terphenylyl)amine; (diphenylfluorenyl)(dibenzofuranylphenyl)(naphthyl)amine; (diphenylfluorenyl)(dibenzofuranylphenyl)(naphthyl)amine; (diphenylfluorenyl)(dibenzofuranylphenyl)(naphthylphenyl)amine; (diphenylfluorenyl)(dibenzofuranylphenyl)(naphthylphenyl)amine; (diphenylfluorenyl)(dibenzofuranylphenyl)(dimethylfluorenyl)amine; (diphenylfluorenyl)(dibenzofuranylphenyl)(phenylmethylfluorenyl)amine; bis(diphenylfluorenyl)(dibenzofuranylphenyl)amine; (diphenylfluorenyl)(dibenzothiophenylphenyl)(phenyl)amine; (diphenylfluorenyl)(dibenzothiophenylphenyl)(biphenylyl)amine; (diphenylfluorenyl)(dibenzothiophenylphenyl)(biphenylyl)amine; (diphenylfluorenyl)(dibenzothiophenylphenyl)(terphenylyl)amine; (diphenylfluorenyl)(dibenzothiophenylphenyl)(naphthyl)amine; (diphenylfluorenyl)(dibenzothiophenylphenyl)(naphthyl)amine; (diphenylfluorenyl)(dibenzothiophenylphenyl)(naphthylphenyl)amine; (diphenylfluorenyl)(dibenzothiophenylphenyl)(naphthylphenyl)amine; (phenyl)(diphenylfluorenyl)(dibenzofuranylphenyl)amine; (biphenylyl)(diphenylfluorenyl)(dibenzofuranylphenyl)amine; (biphenylyl)(diphenylfluorenyl)(dibenzofuranylphenyl)amine; (naphthylphenyl)(diphenylfluorenyl)(dibenzofuranylphenyl)amine; (naphthylphenyl)(diphenylfluorenyl)(dibenzofuranylphenyl)amine; (dimethylfluorenyl)(diphenylfluorenyl)(dibenzofuranylphenyl)amine; bis(diphenylfluorenyl)(dibenzofuranylphenyl)amine; (phenyl)(diphenylfluorenyl)(dibenzothiophenylphenyl)amine; (biphenylyl)(diphenylfluorenyl)(dibenzothiophenylphenyl)amine; (biphenylyl)(diphenylfluorenyl)(dibenzothiophenylphenyl)amine; (terphenylyl)(diphenylfluorenyl)(dibenzothiophenylphenyl)amine; (naphthylphenyl)(diphenylfluorenyl)(dibenzothiophenylphenyl)amine; (naphthylphenyl)(diphenylfluorenyl)(dibenzothiophenylphenyl)amine; (dimethylfluorenyl)(diphenylfluorenyl)(dibenzothiophenylphenyl)amine; (biphenylyl)(diphenylfluorenyl)(carbazolylphenyl)amine; (biphenylyl)(diphenylfluorenyl)(carbazolylphenyl)amine; (terphenylyl)(diphenylfluorenyl)(carbazolylphenyl)amine; (naphthylphenyl)(diphenylfluorenyl)(carbazolylphenyl)amine; (naphthylphenyl)(diphenylfluorenyl)(carbazolylphenyl)amine; (dimethylfluorenyl)(diphenylfluorenyl)(carbazolylphenyl)amine; (biphenylyl)(dibenzofuranyl)(diphenylfluorenyl)amine; (dibenzofuranyl)(dimethylfluorenyl)(diphenylfluorenyl)amine; (biphenylyl)(dibenzothiophenyl)(diphenylfluorenyl)amine; (dimethylfluorenyl)(dibenzothiophenyl)(diphenylfluorenyl)amine; (biphenylyl)(dibenzofuranyl)(diphenylfluorenyl)amine; (biphenylyl)(dibenzofuranyl)(diphenylfluorenyl)amine; (dimethylfluorenyl)(dibenzofuranyl)(diphenylfluorenyl)amine; (biphenylyl)(dibenzothiophenyl)(diphenylfluorenyl)amine; (biphenylyl)(dibenzothiophenyl)(diphenylfluorenyl)amine; (dimethylfluorenyl)(dibenzothiophenyl)(diphenylfluorenyl)amine; bis(dibenzofuranylphenyl)(diphenylfluorenyl)amine; bis(dibenzofuranylphenyl)(diphenylfluorenyl)amine; (dibenzofuranylphenyl)(dibenzothiophenylphenyl)(diphenylfluorenyl)amine; (dibenzofuranylphenyl)(carbazolylphenyl)(diphenylfluorenyl)amine; bis(dibenzofuranylphenyl)(diphenylfluorenyl)amine; (dibenzofuranylphenyl)(dibenzothiophenylphenyl)(diphenylfluorenyl)amine; (dibenzofuranylphenyl)(carbazolylphenyl)(diphenylfluorenyl)amine; (dibenzothiophenylphenyl)(carbazolylphenyl)(diphenylfluorenyl)amine; (methylbiphenylyl)(dibenzofuranylphenyl)(diphenylfluorenyl)amine; (tert-butylbiphenylyl)(dibenzofuranylphenyl)(diphenylfluorenyl)amine; (dimethylbiphenylyl)(dibenzofuranylphenyl)(diphenylfluorenyl)amine; (dimethylbiphenylyl)(dibenzofuranylphenyl)(diphenylfluorenyl)amine; (methylbiphenylyl)(dibenzofuranylphenyl)(diphenylfluorenyl)amine; (tert-butylbiphenylyl)(dibenzofuranylphenyl)(diphenylfluorenyl)amine; (methoxybiphenylyl)(dibenzofuranylphenyl)(diphenylfluorenyl)amine; (phenyl)(dimethylfluorenyl)(diphenylfluorenyl)amine; (biphenylyl)(dimethylfluorenyl)(diphenylfluorenyl)amine; (biphenylyl)(dimethylfluorenyl)(diphenylfluorenyl)amine; (biphenylyl)(dimethylfluorenyl)(diphenylfluorenyl)amine; (terphenylyl)(dimethylfluorenyl)(diphenylfluorenyl)amine; (terphenylyl)(dimethylfluorenyl)(diphenylfluorenyl)amine; (terphenylyl)(dimethylfluorenyl)(diphenylfluorenyl)amine; (terphenylyl)(dimethylfluorenyl)(diphenylfluorenyl)amine; (terphenylyl)(dimethylfluorenyl)(diphenylfluorenyl)amine; (naphthyl)(dimethylfluorenyl)(diphenylfluorenyl)amine; (naphthyl)(dimethylfluorenyl)(diphenylfluorenyl)amine; (naphthylphenyl)(dimethylfluorenyl)(diphenylfluorenyl)amine; (naphthylphenyl)(dimethylfluorenyl)(diphenylfluorenyl)amine; bis(dimethylfluorenyl)(diphenylfluorenyl)amine; (phenylmethylfluorenyl)(dimethylfluorenyl)(diphenylfluorenyl)amine; (dimethylfluorenyl)bis(diphenylfluorenyl)amine; (terphenylyl)(dimethylfluorenyl)(diphenylfluorenyl)amine; (terphenylyl)(dimethylfluorenyl)(diphenylfluorenyl)amine; (fluorophenyl)(dimethylfluorenyl)(diphenylfluorenyl)amine; (methylphenyl)(dimethylfluorenyl)(diphenylfluorenyl)amine; (tert-butylphenyl)(dimethylfluorenyl)(diphenylfluorenyl)amine; (methylbiphenylyl)(dimethylfluorenyl)(diphenylfluorenyl)amine; (tert-butylbiphenylyl)(dimethylfluorenyl)(diphenylfluorenyl)amine; (dimethylbiphenylyl)(dimethylfluorenyl)(diphenylfluorenyl)amine; (dimethylbiphenylyl)(dimethylfluorenyl)(diphenylfluorenyl)amine; (methylbiphenylyl)(dimethylfluorenyl)(diphenylfluorenyl)amine; (tert-butylbiphenylyl)(dimethylfluorenyl)(diphenylfluorenyl)amine; (methoxybiphenylyl)(dimethylfluorenyl)(diphenylfluorenyl)amine; (phenyl)bis(diphenylfluorenyl)amine; (biphenylyl)bis(diphenylfluorenyl)amine; (biphenylyl)bis(diphenylfluorenyl)amine; (biphenylyl)bis(diphenylfluorenyl)amine; (terphenylyl)bis(diphenylfluorenyl)amine; (terphenylyl)bis(diphenylfluorenyl)amine; (terphenylyl)bis(diphenylfluorenyl)amine; (terphenylyl)bis(diphenylfluorenyl)amine; (terphenylyl)bis(diphenylfluorenyl)amine; (terphenylyl)bis(diphenylfluorenyl)amine; (naphthyl)bis(diphenylfluorenyl)amine; (naphthyl)bis(diphenylfluorenyl)amine; (naphthylphenyl)bis(diphenylfluorenyl)amine; (naphthylphenyl)bis(diphenylfluorenyl)amine; (dimethylfluorenyl)bis(diphenylfluorenyl)amine; (phenylmethylfluorenyl)bis(diphenylfluorenyl)amine; tris(diphenylfluorenyl)amine; (terphenylyl)bis(diphenylfluorenyl)amine; (terphenylyl)bis(diphenylfluorenyl)amine; (methylbiphenylyl)bis(diphenylfluorenyl)amine; (tert-butylbiphenylyl)bis(diphenylfluorenyl)amine; (dimethylbiphenylyl)bis(diphenylfluorenyl)amine; (dimethylbiphenylyl)bis(diphenylfluorenyl)amine; (methylbiphenylyl)bis(diphenylfluorenyl)amine; (tert-butylbiphenylyl)bis(diphenylfluorenyl)amine; (methoxybiphenylyl)bis(diphenylfluorenyl)amine; (phenyl)(dimethylfluorenyl)(diphenylfluorenyl)amine; (biphenylyl)(dimethylfluorenyl)(diphenylfluorenyl)amine; (biphenylyl)(dimethylfluorenyl)(diphenylfluorenyl)amine; (phenyl)(dibenzofuranylphenyl)(diphenylfluorenyl)amine; (biphenylyl)(dibenzofuranylphenyl)(diphenylfluorenyl)amine; (biphenylyl)(dibenzofuranylphenyl)(diphenylfluorenyl)amine; (biphenylyl)(dibenzofuranylphenyl)[di(biphenylyl)fluorenyl]amine; (biphenylyl)(dimethylfluorenyl)[di(methylphenyl)fluorenyl]amine; (biphenylyl)(dimethylfluorenyl)[di(methylphenyl)fluorenyl]amine; (biphenylyl)(dimethylfluorenyl)[di(tert-butylphenyl)fluorenyl]amine; (biphenylyl)(dibenzofuranylphenyl)[di(methylphenyl)fluorenyl]amine; (biphenylyl)(dibenzofuranylphenyl)[di(methylphenyl)fluorenyl]amine; (biphenylyl)(dibenzofuranylphenyl)[di(tert-butylphenyl)fluorenyl]amine; (biphenylyl)(dimethylfluorenyl)(methyldiphenylfluorenyl)amine; (biphenylyl)(dimethylfluorenyl)(methyldiphenylfluorenyl)amine; (biphenylyl)(dimethylfluorenyl)(tert-butyldiphenylfluorenyl)amine; (biphenylyl)(dimethylfluorenyl)(tert-butyldiphenylfluorenyl)amine; (biphenylyl)(dibenzofuranylphenyl)(methyldiphenylfluorenyl)amine; (biphenylyl)(dibenzofuranylphenyl)(methyldiphenylfluorenyl)amine; (biphenylyl)(dibenzofuranylphenyl)(tert-butyldiphenylfluorenyl)amine; (biphenylyl)(dibenzofuranylphenyl)(tert-butyldiphenylfluorenyl)amine; (biphenylyl)(dimethylfluorenyl)(triphenylfluorenyl)amine; (biphenylyl)(dimethylfluorenyl)(triphenylfluorenyl)amine; (biphenylyl)(dibenzofuranylphenyl)(triphenylfluorenyl)amine; (biphenylyl)(dibenzofuranylphenyl)(triphenylfluorenyl)amine; (biphenylyl)(methyldibenzofuranylphenyl)(diphenylfluorenyl)amine; (biphenylyl)(methyldibenzofuranylphenyl)(diphenylfluorenyl)amine; (biphenylyl)(phenyldibenzofuranylphenyl)(diphenylfluorenyl)amine; (biphenylyl)(phenyldibenzofuranylphenyl)(diphenylfluorenyl)amine; (biphenylyl)(methyldibenzofuranyl)(diphenylfluorenyl)amine; (biphenylyl)(methyldibenzofuranyl)(diphenylfluorenyl)amine; (biphenylyl)(phenyldibenzofuranyl)(diphenylfluorenyl)amine; (biphenylyl)(phenyldibenzofuranyl)(diphenylfluorenyl)amine; (dibenzofuranyl)bis(diphenylfluorenyl)amine; (dibenzothiophenyl)bis(diphenylfluorenyl)amine; (dibenzofuranylphenyl)bis(diphenylfluorenyl)amine; (dibenzothiophenylphenyl)bis(diphenylfluorenyl)amine; (dibenzofuranyl)bis(diphenylfluorenyl)amine; (dibenzothiophenyl)bis(diphenylfluorenyl)amine; (dibenzofuranylphenyl)bis(diphenylfluorenyl)amine; (dibenzothiophenylphenyl)bis(diphenylfluorenyl)amine; (dibenzothiophenyl)bis(diphenylfluorenyl)amine; (quarterphenylyl)bis(diphenylfluorenyl)amine; (dibenzothiophenylphenyl)(dimethylfluorenyl)(diphenylfluorenyl)amine; (quarterphenylyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(biphenylyl)(diphenylfluorenyl)amine; (dibenzothiophenylphenyl)(biphenylyl)(diphenylfluorenyl)amine; (dibenzofuranylphenyl)(terphenylyl)(diphenylfluorenyl)amine; (dibenzothiophenylphenyl)(terphenylyl)(diphenylfluorenyl)amine; (dibenzothiophenylphenyl)(terphenylyl)(diphenylfluorenyl)amine; (dibenzofuranylphenyl)(terphenylyl)(diphenylfluorenyl)amine; (dibenzothiophenylphenyl)(terphenylyl)(diphenylfluorenyl)amine; (dibenzofuranylphenyl)(terphenylyl)(diphenylfluorenyl)amine; (dibenzothiophenylphenyl)(terphenylyl)(diphenylfluorenyl)amine; (phenyl)(dibenzofuranyl)(diphenylfluorenyl)amine; (phenyl)(dibenzothiophenyl)(diphenylfluorenyl)amine; (phenyl)(dibenzofuranyl)(diphenylfluorenyl)amine; (phenyl)(dibenzothiophenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; bis(dibenzofuranyl)(diphenylfluorenyl)amine; bis(dibenzothiophenyl)(diphenylfluorenyl)amine; (biphenylyldimethylfluorenyl)(phenyl)(diphenylfluorenyl)amine; (naphthyldimethylfluorenyl)(phenyl)(diphenylfluorenyl)amine; (naphthyldimethylfluorenyl)(phenyl)(diphenylfluorenyl)amine; (biphenylyldimethylfluorenyl)(biphenylyl)(diphenylfluorenyl)amine; (naphthyldimethylfluorenyl)(biphenylyl)(diphenylfluorenyl)amine; (naphthyldimethylfluorenyl)(biphenylyl)(diphenylfluorenyl)amine; (naphthyldimethylfluorenyl)(biphenylyl)(diphenylfluorenyl)amine; (phenyl)(dimethylfluorenylphenyl)(diphenylfluorenyl)amine; (phenyl)(dimethylfluorenylphenyl)(diphenylfluorenyl)amine; (biphenylyl)(dimethylfluorenylphenyl)(diphenylfluorenyl)amine; (biphenylyl)(dimethylfluorenylphenyl)(diphenylfluorenyl)amine; (biphenylyl)(dimethylfluorenylphenyl)(diphenylfluorenyl)amine; (biphenylyl)(dimethylfluorenylphenyl)(diphenylfluorenyl)amine; (biphenylyl)(dimethylfluorenylphenyl)(diphenylfluorenyl)amine; (biphenylyl)(dimethylfluorenylphenyl)(diphenylfluorenyl)amine; (dimethylfluorenylphenyl)bis(diphenylfluorenyl)amine; (dimethylfluorenylphenyl)bis(diphenylfluorenyl)amine; di(biphenylyl)(diphenylfluorenyl)amine; (biphenylyl)(methylbiphenylyl)(diphenylfluorenyl)amine; (methylphenyl)(biphenylyl)(diphenylfluorenyl)amine; di(biphenylyl)(diphenylfluorenyl)amine; bis(dimethylphenyl)(diphenylfluorenyl)amine; (biphenylyl)(terphenylyl)(diphenylfluorenyl)amine; bis(methylbiphenylyl)(diphenylfluorenyl)amine; (biphenylyl)(dimethylbiphenylyl)(diphenylfluorenyl)amine; (phenyl)(dibenzofuranylphenyl)(spirobifluorenyl)amine; (biphenylyl)(dibenzofuranylphenyl)(spirobifluorenyl)amine; (biphenylyl)(dibenzofuranylphenyl)(spirobifluorenyl)amine; (biphenylyl)(dibenzofuranylphenyl)(spirobifluorenyl)amine; (terphenylyl)(dibenzofuranylphenyl)(spirobifluorenyl)amine; (terphenylyl)(dibenzofuranylphenyl)(spirobifluorenyl)amine; (terphenylyl)(dibenzofuranylphenyl)(spirobifluorenyl)amine; (terphenylyl)(dibenzofuranylphenyl)(spirobifluorenyl)amine; (terphenylyl)(dibenzofuranylphenyl)(spirobifluorenyl)amine; (naphthyl)(dibenzofuranylphenyl)(spirobifluorenyl)amine; (naphthyl)(dibenzofuranylphenyl)(spirobifluorenyl)amine; (naphthylphenyl)(dibenzofuranylphenyl)(spirobifluorenyl)amine; (naphthylphenyl)(dibenzofuranylphenyl)(spirobifluorenyl)amine; (dimethylfluorenyl)(dibenzofuranylphenyl)(spirobifluorenyl)amine; (phenylmethylfluorenyl)(dibenzofuranylphenyl)(spirobifluorenyl)amine; (dibenzofuranylphenyl)(diphenylfluorenyl)(spirobifluorenyl)amine; (phenyl)(dibenzothiophenylphenyl)(spirobifluorenyl)amine; (biphenylyl)(dibenzothiophenylphenyl)(spirobifluorenyl)amine; (biphenylyl)(dibenzothiophenylphenyl)(spirobifluorenyl)amine; (terphenylyl)(dibenzothiophenylphenyl)(spirobifluorenyl)amine; (naphthyl)(dibenzothiophenylphenyl)(spirobifluorenyl)amine; (naphthyl)(dibenzothiophenylphenyl)(spirobifluorenyl)amine; (naphthylphenyl)(dibenzothiophenylphenyl)(spirobifluorenyl)amine; (naphthylphenyl)(dibenzothiophenylphenyl)(spirobifluorenyl)amine; (phenyl)(dibenzofuranylphenyl)(spirobifluorenyl)amine; (biphenylyl)(dibenzofuranylphenyl)(spirobifluorenyl)amine; (biphenylyl)(dibenzofuranylphenyl)(spirobifluorenyl)amine; (dibenzofuranylphenyl)(diphenylfluorenyl)(spirobifluorenyl)amine; (biphenylyl)(dibenzothiophenylphenyl)(spirobifluorenyl)amine; (biphenylyl)(dibenzothiophenylphenyl)(spirobifluorenyl)amine; (biphenylyl)(carbazolylphenyl)(spirobifluorenyl)amine; (biphenylyl)(carbazolylphenyl)(spirobifluorenyl)amine; (biphenylyl)(dibenzofuranyl)(spirobifluorenyl)amine; (biphenylyl)(dibenzofuranyl)(spirobifluorenyl)amine; (biphenylyl)(dibenzofuranyl)(spirobifluorenyl)amine; (dimethylfluorenyl)(dibenzofuranyl)(spirobifluorenyl)amine; (biphenylyl)(dibenzothiophenyl)(spirobifluorenyl)amine; (biphenylyl)(dibenzothiophenyl)(spirobifluorenyl)amine; (biphenylyl)(dibenzothiophenyl)(spirobifluorenyl)amine; (dimethylfluorenyl)(dibenzothiophenyl)(spirobifluorenyl)amine; (biphenylyl)(dibenzofuranyl)(spirobifluorenyl)amine; (biphenylyl)(dibenzofuranyl)(spirobifluorenyl)amine; (biphenylyl)(dibenzofuranyl)(spirobifluorenyl)amine; (dimethylfluorenyl)(dibenzofuranyl)(spirobifluorenyl)amine; (biphenylyl)(dibenzothiophenyl)(spirobifluorenyl)amine; (biphenylyl)(dibenzothiophenyl)(spirobifluorenyl)amine; (biphenylyl)(dibenzothiophenyl)(spirobifluorenyl)amine; (dimethylfluorenyl)(dibenzothiophenyl)(spirobifluorenyl)amine; bis(dibenzofuranylphenyl)(spirobifluorenyl)amine; (dibenzofuranylphenyl)(carbazolylphenyl)(spirobifluorenyl)amine; bis(dibenzofuranylphenyl)(spirobifluorenyl)amine; (dibenzofuranylphenyl)(carbazolylphenyl)(spirobifluorenyl)amine; (methylphenyl)(dibenzofuranylphenyl)(spirobifluorenyl)amine; (tert-butylphenyl)(dibenzofuranylphenyl)(spirobifluorenyl)amine; (methylbiphenylyl)(dibenzofuranylphenyl)(spirobifluorenyl)amine; (tert-butylbiphenylyl)(dibenzofuranylphenyl)(spirobifluorenyl)amine; (dimethylbiphenylyl)(dibenzofuranylphenyl)(spirobifluorenyl)amine; (dimethylbiphenylyl)(dibenzofuranylphenyl)(spirobifluorenyl)amine; (methylbiphenylyl)(dibenzofuranylphenyl)(spirobifluorenyl)amine; (tert-butylbiphenylyl)(dibenzofuranylphenyl)(spirobifluorenyl)amine; (phenyl)(dimethylfluorenyl)(spirobifluorenyl)amine; (biphenylyl)(dimethylfluorenyl)(spirobifluorenyl)amine; (biphenylyl)(dimethylfluorenyl)(spirobifluorenyl)amine; (biphenylyl)(dimethylfluorenyl)(spirobifluorenyl)amine; (terphenylyl)(dimethylfluorenyl)(spirobifluorenyl)amine; (terphenylyl)(dimethylfluorenyl)(spirobifluorenyl)amine; (terphenylyl)(dimethylfluorenyl)(spirobifluorenyl)amine; (terphenylyl)(dimethylfluorenyl)(spirobifluorenyl)amine; (terphenylyl)(dimethylfluorenyl)(spirobifluorenyl)amine; (naphthyl)(dimethylfluorenyl)(spirobifluorenyl)amine; (naphthyl)(dimethylfluorenyl)(spirobifluorenyl)amine; (naphthylphenyl)(dimethylfluorenyl)(spirobifluorenyl)amine; (naphthylphenyl)(dimethylfluorenyl)(spirobifluorenyl)amine; bis(dimethylfluorenyl)(spirobifluorenyl)amine; (phenylmethylfluorenyl)(dimethylfluorenyl)(spirobifluorenyl)amine; (diphenylfluorenyl)(dimethylfluorenyl)(spirobifluorenyl)amine; (terphenylyl)(dimethylfluorenyl)(spirobifluorenyl)amine; (terphenylyl)(dimethylfluorenyl)(spirobifluorenyl)amine; (methylphenyl)(dimethylfluorenyl)(spirobifluorenyl)amine; (tert-butylphenyl)(dimethylfluorenyl)(spirobifluorenyl)amine; (methylbiphenylyl)(dimethylfluorenyl)(spirobifluorenyl)amine; (tert-butylbiphenylyl)(dimethylfluorenyl)(spirobifluorenyl)amine; (dimethylbiphenylyl)(dimethylfluorenyl)(spirobifluorenyl)amine; (dimethylbiphenylyl)(dimethylfluorenyl)(spirobifluorenyl)amine; (methylbiphenylyl)(dimethylfluorenyl)(spirobifluorenyl)amine; (tert-butylbiphenylyl)(dimethylfluorenyl)(spirobifluorenyl)amine; (phenyl)(diphenylfluorenyl)(spirobifluorenyl)amine; (biphenylyl)(diphenylfluorenyl)(spirobifluorenyl)amine; (biphenylyl)(diphenylfluorenyl)(spirobifluorenyl)amine; (biphenylyl)(diphenylfluorenyl)(spirobifluorenyl)amine; (terphenylyl)(diphenylfluorenyl)(spirobifluorenyl)amine; (terphenylyl)(diphenylfluorenyl)(spirobifluorenyl)amine; (terphenylyl)(diphenylfluorenyl)(spirobifluorenyl)amine; (naphthyl)(diphenylfluorenyl)(spirobifluorenyl)amine; (naphthyl)(diphenylfluorenyl)(spirobifluorenyl)amine; (naphthylphenyl)(diphenylfluorenyl)(spirobifluorenyl)amine; (naphthylphenyl)(diphenylfluorenyl)(spirobifluorenyl)amine; (dimethylfluorenyl)(diphenylfluorenyl)(spirobifluorenyl)amine; (methylphenylfluorenyl)(diphenylfluorenyl)(spirobifluorenyl)amine; bis(diphenylfluorenyl)(spirobifluorenyl)amine; (terphenylyl)(diphenylfluorenyl)(spirobifluorenyl)amine; (terphenylyl)(diphenylfluorenyl)(spirobifluorenyl)amine; (methylphenyl)(diphenylfluorenyl)(spirobifluorenyl)amine; (tert-butylphenyl)(diphenylfluorenyl)(spirobifluorenyl)amine; (methylbiphenylyl)(diphenylfluorenyl)(spirobifluorenyl)amine; (tert-butylbiphenylyl)(diphenylfluorenyl)(spirobifluorenyl)amine; (dimethylbiphenylyl)(diphenylfluorenyl)(spirobifluorenyl)amine; (dimethylbiphenylyl)(diphenylfluorenyl)(spirobifluorenyl)amine; (methylbiphenylyl)(diphenylfluorenyl)(spirobifluorenyl)amine; (tert-butylbiphenylyl)(diphenylfluorenyl)(spirobifluorenyl)amine; (phenyl)(dimethylfluorenyl)(spirobifluorenyl)amine; (biphenylyl)(dimethylfluorenyl)(spirobifluorenyl)amine; (biphenylyl)(dimethylfluorenyl)(spirobifluorenyl)amine; (phenyl)(dibenzofuranylphenyl)(spirobifluorenyl)amine; (biphenylyl)(dibenzofuranylphenyl)(spirobifluorenyl)amine; (biphenylyl)(dibenzofuranylphenyl)(spirobifluorenyl)amine; (phenyl)(dimethylfluorenyl)(spirobifluorenyl)amine; (biphenylyl)(dimethylfluorenyl)(spirobifluorenyl)amine; (biphenylyl)(dimethylfluorenyl)(spirobifluorenyl)amine; (phenyl)(dimethylfluorenyl)(phenylspirobifluorenyl)amine; (biphenylyl)(dimethylfluorenyl)(phenylspirobifluorenyl)amine; (biphenylyl)(dimethylfluorenyl)(phenylspirobifluorenyl)amine; (biphenylyl)(dimethylfluorenyl)(phenylspirobifluorenyl)amine; (biphenylyl)(dimethylfluorenyl)(methylspirobifluorenyl)amine; (biphenylyl)(dimethylfluorenyl)(methylspirobifluorenyl)amine; (biphenylyl)(dimethylfluorenyl)(tert-butylspirobifluorenyl)amine; (biphenylyl)(dimethylfluorenyl)(tert-butylspirobifluorenyl)amine; (biphenylyl)(dimethylfluorenyl)(methylspirobifluorenyl)amine; (biphenylyl)(dimethylfluorenyl)(tert-butylspirobifluorenyl)amine; (biphenylyl)(dimethylfluorenyl)(methylspirobifluorenyl)amine; (biphenylyl)(dimethylfluorenyl)(methylspirobifluorenyl)amine; (biphenylyl)(dimethylfluorenyl)(tert-butylspirobifluorenyl)amine; (biphenylyl)(dimethylfluorenyl)(tert-butylspirobifluorenyl)amine; (biphenylyl)(dibenzofuranylphenyl)(methylspirobifluorenyl)amine; (biphenylyl)(dibenzofuranylphenyl)(methylspirobifluorenyl)amine; (biphenylyl)(dibenzofuranylphenyl)(tert-butylspirobifluorenyl)amine; (biphenylyl)(dibenzofuranylphenyl)(tert-butylspirobifluorenyl)amine; (biphenylyl)(dimethylfluorenyl)(phenylspirobifluorenyl)amine; (biphenylyl)(dimethylfluorenyl)(phenylspirobifluorenyl)amine; (biphenylyl)(dibenzofuranylphenyl)(phenylspirobifluorenyl)amine; (biphenylyl)(dibenzofuranylphenyl)(phenylspirobifluorenyl)amine; (biphenylyl)(methyldibenzofuranylphenyl)(spirobifluorenyl)amine; (biphenylyl)(methyldibenzofuranylphenyl)(spirobifluorenyl)amine; (biphenylyl)(phenyldibenzofuranylphenyl)(spirobifluorenyl)amine; (biphenylyl)(phenyldibenzofuranylphenyl)(spirobifluorenyl)amine; (biphenylyl)(methyldibenzofuranyl)(spirobifluorenyl)amine; (biphenylyl)(methyldibenzofuranyl)(spirobifluorenyl)amine; (biphenylyl)(phenyldibenzofuranyl)(spirobifluorenyl)amine; (biphenylyl)(phenyldibenzofuranyl)(spirobifluorenyl)amine; (dibenzofuranylphenyl)bis(spirobifluorenyl)amine; (dibenzothiophenylphenyl)bis(spirobifluorenyl)amine; (dibenzofuranyl)bis(spirobifluorenyl)amine; (dibenzothiophenyl)bis(spirobifluorenyl)amine; (dibenzofuranylphenyl)bis(spirobifluorenyl)amine; (dibenzothiophenylphenyl)bis(spirobifluorenyl)amine; (dibenzofuranylphenyl)bis(spirobifluorenyl)amine; (dibenzothiophenylphenyl)bis(spirobifluorenyl)amine; (dibenzofuranylphenyl)bis(spirobifluorenyl)amine; (dibenzothiophenylphenyl)bis(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(biphenylyl)(spirobifluorenyl)amine; (dibenzothiophenylphenyl)(biphenylyl)(spirobifluorenyl)amine; (dibenzofuranylphenyl)(biphenylyl)(spirobifluorenyl)amine; (dibenzothiophenylphenyl)(biphenylyl)(spirobifluorenyl)amine; (dibenzofuranylphenyl)(biphenylyl)(spirobifluorenyl)amine; (dibenzothiophenylphenyl)(biphenylyl)(spirobifluorenyl)amine; (dibenzofuranylphenyl)(phenyl)(spirobifluorenyl)amine; (dibenzothiophenylphenyl)(phenyl)(spirobifluorenyl)amine; bis(dibenzofuranyl)(spirobifluorenyl)amine; bis(dibenzothiophenyl)(spirobifluorenyl)amine; (phenyl)(biphenylyldimethylfluorenyl)(spirobifluorenyl)amine; (phenyl)(naphthyldimethylfluorenyl)(spirobifluorenyl)amine; (phenyl)(naphthyldimethylfluorenyl)(spirobifluorenyl)amine; (biphenylyl)(biphenylyldimethylfluorenyl)(spirobifluorenyl)amine; (biphenylyl)(naphthyldimethylfluorenyl)(spirobifluorenyl)amine; (biphenylyl)(biphenylyldimethylfluorenyl)(spirobifluorenyl)amine; (biphenylyl)(naphthyldimethylfluorenyl)(spirobifluorenyl)amine; (dimethylfluorenyl)(biphenylyldimethylfluorenyl)(spirobifluorenyl)amine; (dimethylfluorenyl)(naphthyldimethylfluorenyl)(spirobifluorenyl)amine; (dimethylfluorenyl)(naphthyldimethylfluorenyl)(spirobifluorenyl)amine; (phenyl)(dimethylfluorenylphenyl)(spirobifluorenyl)amine; (biphenylyl)(dimethylfluorenylphenyl)(spirobifluorenyl)amine; (biphenylyl)(dimethylfluorenylphenyl)(spirobifluorenyl)amine; (biphenylyl)(dimethylfluorenylphenyl)(spirobifluorenyl)amine; (biphenylyl)(dimethylfluorenylphenyl)(spirobifluorenyl)amine; (terphenylyl)(dimethylfluorenylphenyl)(spirobifluorenyl)amine; (terphenylyl)(dimethylfluorenylphenyl)(spirobifluorenyl)amine; (dimethylfluorenyl)(dimethylfluorenylphenyl)(spirobifluorenyl)amine; (dimethylfluorenyl)(dimethylfluorenylphenyl)(spirobifluorenyl)amine; di(biphenylyl)(spirobifluorenyl)amine; (biphenylyl)(methylbiphenylyl)(spirobifluorenyl)amine; (methylphenyl)(biphenylyl)(spirobifluorenyl)amine; di(biphenylyl)(spirobifluorenyl)amine; (biphenylyl)(terphenylyl)(spirobifluorenyl)amine; bis(methylbiphenylyl)(spirobifluorenyl)amine; (biphenylyl)(dimethylbiphenylyl)(spirobifluorenyl)amine; (phenyl)(naphthyl)(biphenylyldimethylfluorenyl)amine; (phenyl)(naphthyl)(biphenylyldimethylfluorenyl)amine; (phenyl)(phenanthrenyl)(biphenylyldimethylfluorenyl)amine; (phenyl)(biphenylyl)(biphenylyldimethylfluorenyl)amine; (phenyl)(naphthylphenyl)(biphenylyldimethylfluorenyl)amine; (phenyl)(naphthylphenyl)(biphenylyldimethylfluorenyl)amine; (phenyl)(terphenylyl)(biphenylyldimethylfluorenyl)amine; (phenyl)(terphenylyl)(biphenylyldimethylfluorenyl)amine; bis(methylphenyl)(biphenylyldimethylfluorenyl)amine; bis(methylphenyl)(biphenylyldimethylfluorenyl)amine; (naphthyl)(methylphenyl)(biphenylyldimethylfluorenyl)amine; (naphthyl)(methylphenyl)(biphenylyldimethylfluorenyl)amine; (phenanthrenyl)(methylphenyl)(biphenylyldimethylfluorenyl)amine; (biphenylyl)(methylphenyl)(biphenylyldimethylfluorenyl)amine; (naphthylphenyl)(methylphenyl)(biphenylyldimethylfluorenyl)amine; bis(methylphenyl)(biphenylyldimethylfluorenyl)amine; (naphthyl)(methylphenyl)(biphenylyldimethylfluorenyl)amine; (naphthyl)(methylphenyl)(biphenylyldimethylfluorenyl)amine; (phenanthrenyl)(methylphenyl)(biphenylyldimethylfluorenyl)amine; (biphenylyl)(methylphenyl)(biphenylyldimethylfluorenyl)amine; (naphthylphenyl)(methylphenyl)(biphenylyldimethylfluorenyl)amine; di(naphthyl)(biphenylyldimethylfluorenyl)amine; di(naphthyl)(biphenylyldimethylfluorenyl)amine; (naphthyl)(phenanthrenyl)(biphenylyldimethylfluorenyl)amine; (naphthyl)(biphenylyl)(biphenylyldimethylfluorenyl)amine; (naphthyl)(naphthylphenyl)(biphenylyldimethylfluorenyl)amine; (naphthyl)(naphthylphenyl)(biphenylyldimethylfluorenyl)amine; (naphthyl)(terphenylyl)(biphenylyldimethylfluorenyl)amine; (naphthyl)(terphenylyl)(biphenylyldimethylfluorenyl)amine; di(naphthyl)(biphenylyldimethylfluorenyl)amine; (naphthyl)(phenanthrenyl)(biphenylyldimethylfluorenyl)amine; (naphthyl)(biphenylyl)(biphenylyldimethylfluorenyl)amine; (naphthyl)(naphthylphenyl)(biphenylyldimethylfluorenyl)amine; (naphthyl)(naphthylphenyl)(biphenylyldimethylfluorenyl)amine; (naphthyl)(terphenylyl)(biphenylyldimethylfluorenyl)amine; (naphthyl)(terphenylyl)(biphenylyldimethylfluorenyl)amine; di(phenanthrenyl)(biphenylyldimethylfluorenyl)amine; (biphenylyl)(phenanthrenyl)(biphenylyldimethylfluorenyl)amine; (naphthylphenyl)(phenanthrenyl)(biphenylyldimethylfluorenyl)amine; (naphthylphenyl)(phenanthrenyl)(biphenylyldimethylfluorenyl)amine; (terphenylyl)(phenanthrenyl)(biphenylyldimethylfluorenyl)amine; (terphenylyl)(phenanthrenyl)(biphenylyldimethylfluorenyl)amine; di(biphenylyl)(biphenylyldimethylfluorenyl)amine; (phenyl)(dimethylfluorenyl)(biphenylyldimethylfluorenyl)amine; (methylphenyl)(dimethylfluorenyl)(biphenylyldimethylfluorenyl)amine; (methylphenyl)(dimethylfluorenyl)(biphenylyldimethylfluorenyl)amine; (naphthyl)(dimethylfluorenyl)(biphenylyldimethylfluorenyl)amine; (naphthyl)(dimethylfluorenyl)(biphenylyldimethylfluorenyl)amine; (phenanthrenyl)(dimethylfluorenyl)(biphenylyldimethylfluorenyl)amine; (biphenylyl)(dimethylfluorenyl)(biphenylyldimethylfluorenyl)amine; (naphthylphenyl)(dimethylfluorenyl)(biphenylyldimethylfluorenyl)amine; (naphthylphenyl)(dimethylfluorenyl)(biphenylyldimethylfluorenyl)amine; bis(dimethylfluorenyl)(biphenylyldimethylfluorenyl)amine; di(biphenylyl)(biphenylyldimethylbenzofluorenyl)amine; di(biphenylyl)(biphenylyldimethylbenzofluorenyl)amine; di(biphenylyl)(biphenylyldimethyldibenzofluorenyl)amine; di(biphenylyl)(biphenylyldiphenylfluorenyl)amine; di(biphenylyl)(biphenylylphenylmethylfluorenyl)amine; (phenyl)(naphthyl)(biphenylylspirobifluorenyl)amine; (phenyl)(biphenylyl)(biphenylylspirobifluorenyl)amine; di(biphenylyl)(biphenylylspirobifluorenyl)amine; di(phenyl)(biphenylylspirobifluorenyl)amine; (phenyl)(methylphenyl)(biphenylylspirobifluorenyl)amine; di(methylphenyl)(biphenylylspirobifluorenyl)amine; (phenyl)(triphenylenyl)(biphenylyldimethylfluorenyl)amine; (naphthyl)(triphenylenyl)(biphenylyldimethylfluorenyl)amine; (phenyl)(naphthyl)(terphenylyldimethylfluorenyl)amine; (phenyl)(naphthyl)(terphenylyldimethylfluorenyl)amine; (phenyl)(biphenylyl)(terphenylyldimethylfluorenyl)amine; (phenyl)(naphthylphenyl)(terphenylyldimethylfluorenyl)amine; (phenyl)(naphthylphenyl)(terphenylyldimethylfluorenyl)amine; di(phenyl)bis(phenylthiophenylphenyl)biphenyldiamine; di(biphenylyl)bis(phenylthiophenylphenyl)biphenyldiamine; di(phenyl)bis(phenylthiophenylbiphenylyl)biphenyldiamine; di(phenyl)bis(phenylthiophenyldimethylfluorenyl)biphenyldiamine; di(phenyl)bis(phenylthiophenylphenyl)terphenyldiamine; di(phenyl)bis(phenylthiophenylphenyl)dimethylfluorenyldiamine; bis(dimethylfluorenyl)bis(phenylthiophenylphenyl)biphenyldiamine; di(naphthyl)bis(phenylthiophenylphenyl)biphenyldiamine; di(phenyl)bis(naphthylthiophenylphenyl)biphenyldiamine; di(phenyl)bis(phenylthiophenylnaphthyl)biphenyldiamine; tri(biphenylyl)(phenylthiophenylphenyl)biphenyldiamine; (phenyl)di(biphenylyl)(phenylthiophenylphenyl)biphenyldiamine; di(biphenylyl)(naphthyl)(phenylthiophenylphenyl)biphenyldiamine; di(biphenylyl)bis(phenylthiophenylphenyl)biphenyldiamine; (phenylthiophenylphenyl)bis(diphenylaminobiphenylyl)amine; (phenylthiophenylphenyl)bis(diphenylaminoterphenylyl)amine; (phenylthiophenylphenyl)bis(diphenylaminodimethylfluorenyl)amine; (terphenylyl)bis[phenyl(phenylthiophenylphenyl)aminobiphenylyl]amine; (phenylthiophenylphenyl)bis(phenylnaphthylaminobiphenylyl)amine; (phenyl)bis(diphenylaminophenyl)(phenylthiophenylphenyl)biphenyldiamine; bis(phenylthiophenylphenyl)bis(diphenylaminophenyl)biphenyldiamine; di(phenyl)bis[phenyl(phenylthiophenylphenyl)aminophenyl]biphenyldiamine; di(phenyl)bis[phenyl(phenylthiophenylphenyl)aminophenyl]terphenyldiamine; bis(phenylthiophenylphenyl)bis(diphenylaminobiphenylyl)biphenyldiamine; tris[phenyl(phenylthiophenylphenyl)aminobiphenylyl]amine; tris[phenyl(phenylthiophenylphenyl)aminophenyl]amine; (phenyl)bis(diphenylaminophenyl)(phenylthiophenylphenyl)biphenyldiamine; (phenyl)(naphthyl)[(phenylcarbazolyl)dimethylfluorenyl]amine; (phenyl)(naphthyl)[(phenylcarbazolyl)biphenylyl]amine; (phenyl)(naphthyl)[(phenylcarbazolyl)phenyl]amine; di(biphenylyl)[(phenylcarbazolyl)dimethylfluorenyl]amine; (phenyl)(naphthyl)[(diphenylcarbazolyl)dimethylfluorenyl]amine; di(biphenylyl)[(phenylcarbazolyl)phenyl]amine; (biphenylyl)(diphenylaminophenyl)[(phenylcarbazolyl)phenyl]amine; bis(diphenylaminophenyl)[(phenylcarbazolyl)phenyl]amine; (phenyl)(biphenylyl)[(phenylcarbazolyl)biphenylyl]amine; (phenyl)(naphthyl)[(phenylcarbazolyl)terphenylyl]amine; di(phenyl)[(phenylcarbazolyl)phenanthrenyl]amine; di(phenyl)[(phenylcarbazolyl)biphenylyl]amine; di(biphenylyl)[(phenylcarbazolyl)naphthyl]amine; bis(naphthylphenyl)[(phenylcarbazolyl)phenyl]amine; (phenyl)(biphenylyl)[(diphenylcarbazolyl)phenyl]amine; di(biphenylyl)[(phenylcarbazolyl)thiophenylphenyl]amine; di(biphenylyl)[(phenylcarbazolyl)dibenzothiophenylphenyl]amine; di(biphenylyl)[(phenylcarbazolyl)furanylphenyl]amine; (biphenylyl)(phenanthrenyl)[(phenylcarbazolyl)phenyl]amine; di(biphenylyl)[(naphthylmethylcarbazolyl)phenyl]amine; (phenyl)(biphenylyl)[(phenylcarbazolyl)dibenzofuranylphenyl]amine; di(biphenylyl)[(phenylbiphenylylcarbazolyl)phenyl]amine; (phenyl)(terphenylyl)[(phenylbiphenylylcarbazolyl)phenyl]amine; (phenyl)(terphenylyl)[(phenylbiphenylylcarbazolyl)phenyl]amine; bis(methylbiphenylyl)[(tert-butylphenylcarbazolyl)phenyl]amine; (biphenylyl)(diphenylaminobiphenylyl)[(phenylcarbazolyl)phenyl]amine; (phenyl)(phenyldimethylfluorenylaminobiphenylyl)[(phenylcarbazolyl)phenyl]amine; (phenyl)(phenylbiphenylylaminobiphenylyl)[(phenylcarbazolyl)biphenylyl]amine; (phenyl)[phenyl(diphenylaminophenyl)aminobiphenylyl][(phenylcarbazolyl)phenyl]amine; (diphenylaminophenyl)(diphenylaminobiphenylyl)[(phenylcarbazolyl)phenyl]amine; (diphenylaminophenyl)[phenyl(dimethylfluorenyl)aminophenyl][(phenylcarbazolyl)phenyl]amine; bis(dibenzofuranylphenyl)[(phenylcarbazolyl)phenyl]amine; bis(phenylthiophenylphenyl)[(diphenylcarbazolyl)phenyl]amine; bis(dibenzothiophenylphenyl)[(phenylcarbazolyl)phenyl]amine; bis(dibenzothiophenylphenyl)[(biphenylylcarbazolyl)phenyl]amine; di(terphenylyl)[(phenylcarbazolyl)phenyl]amine; di(biphenylyl)[(biphenylylcarbazolyl)phenyl]amine; di(biphenylyl)[(naphthylcarbazolyl)phenyl]amine; (naphthyl)(biphenylyl)[(phenylcarbazolyl)phenyl]amine; tri(phenyl)[(phenylcarbazolyl)phenyl]biphenyldiamine; (phenyl)bis[(phenylcarbazolyl)phenyl]amine; (biphenylyl)bis[(phenylcarbazolyl)phenyl]amine; (naphthyl)bis[(phenylcarbazolyl)phenyl]amine; di(biphenylyl)[(phenylcarbazolyl)biphenylyl]amine; di(phenyl)(carbazolylbiphenylyl)amine; (phenyl)(biphenylyl)(carbazolylbiphenylyl)amine; (phenyl)(biphenylyl)(carbazolylbiphenylyl)amine; (phenyl)(biphenylyl)(carbazolylbiphenylyl)amine; di(biphenylyl)(carbazolylbiphenylyl)amine; (phenyl)(naphthyl)(carbazolylbiphenylyl)amine; (naphthyl)(biphenylyl)(carbazolylbiphenylyl)amine; (phenyl)(naphthyl)(diphenylcarbazolylbiphenylyl)amine; di(biphenylyl)(carbazolyldimethylfluorenyl)amine; (phenyl)(naphthyl)(carbazolyldimethylfluorenyl)amine; (phenyl)(phenanthrenyl)(carbazolyldimethylfluorenyl)amine; (biphenylyl)(naphthyl)(carbazolyldimethylfluorenyl)amine; (phenyl)(naphthyl)(carbazolyldimethylfluorenyl)amine; di(naphthyl)(carbazolyldimethylfluorenyl)amine; (phenyl)(naphthyl)(diphenylcarbazolyldimethylfluorenyl)amine; (phenyl)(biphenylyl)(carbazolyldimethylfluorenyl)amine; (phenyl)(biphenylyl)(carbazolylbiphenylyl)amine; (phenyl)(biphenylyl)(carbazolylbiphenylyl)amine; (phenyl)(biphenylyl)(carbazolylbiphenylyl)amine; di(biphenylyl)(carbazolylbiphenylyl)amine; di(biphenylyl)(carbazolylbiphenylyl)amine; di(biphenylyl)(carbazolylbiphenylyl)amine; (phenyl)bis(carbazolylbiphenylyl)amine; (phenyl)bis(carbazolyldimethylfluorenyl)amine; phenylbis[(diphenylamino)phenyl]carbazole; phenylbis[(phenyl(naphthyl)amino)phenyl]carbazole; di(terphenylyl)(carbazolyldimethylfluorenyl)amine; bis(naphthylphenyl)(carbazolyldimethylfluorenyl)amine; di(biphenylyl)(diphenylcarbazolyldimethylfluorenyl)amine; (phenyl)(biphenylyl)(carbazolyldimethylfluorenyl)amine; (phenyl)(dimethylfluorenyl)(carbazolyldimethylfluorenyl)amine; (biphenylyl)(dimethylfluorenyl)(carbazolyldimethylfluorenyl)amine; bis(dimethylfluorenyl)(carbazolyldimethylfluorenyl)amine; (naphthyl)(dimethylfluorenyl)(carbazolyldimethylfluorenyl)amine; di(biphenylyl)(carbazolylphenyl)amine; di(biphenylyl)(carbazolylphenyl)amine; di(naphthyl)(carbazolylphenyl)amine; (phenyl)(naphthyl)(carbazolylbiphenylyl)amine; di(biphenylyl)(carbazolyldimethylbiphenylyl)amine; (phenyl)(naphthyl)(carbazolylterphenylyl)amine; (phenyl)(naphthyl)(carbazolylterphenylyl)amine; tetra(biphenylyl)biphenyldiamine; di(phenyl)di(naphthyl)biphenyldiamine; di(naphthyl)di(biphenylyl)biphenyldiamine; (phenyl)(biphenylyl)di(naphthyl)biphenyldiamine; (phenyl)(naphthyl)di(biphenylyl)biphenyldiamine; di(biphenylyl)di(terphenylyl)biphenyldiamine; di(biphenylyl)di(terphenylyl)biphenyldiamine; di(phenyl)di(terphenylyl)biphenyldiamine; di(phenyl)di(terphenylyl)biphenyldiamine; (phenyl)di(biphenylyl)(terphenylyl)biphenyldiamine; tri(biphenylyl)(terphenylyl)biphenyldiamine; (phenyl)di(biphenylyl)(terphenylyl)biphenyldiamine; tri(biphenylyl)(terphenylyl)biphenyldiamine; di(biphenylyl)bis(naphthylphenyl)biphenyldiamine; tri(biphenylyl)(naphthylphenyl)biphenyldiamine; di(biphenylyl)bis(naphthylphenyl)biphenyldiamine; tri(biphenylyl)(naphthylphenyl)biphenyldiamine; di(biphenylyl)bis(dimethylfluorenyl)biphenyldiamine; tetrakis(dimethylfluorenyl)biphenyldiamine; tetrakis(dimethylfluorenyl)dimethylfluorenyldiamine; di(phenyl)bis(dimethylfluorenyl)biphenyldiamine; di(phenyl)di(naphthyl)dimethylfluorenyldiamine; (phenyl)bis(diphenylaminobiphenylyl)amine; (phenyl)bis[phenyl(biphenylyl)aminobiphenylyl]amine; (phenyl)bis[phenyl(naphthyl)aminobiphenylyl]amine; (biphenylyl)bis[diphenylaminobiphenylyl]amine; (biphenylyl)bis[diphenylaminoterphenylyl]amine; di(phenyl)bis(diphenylaminobiphenylyl)biphenyldiamine; di(phenyl)bis[phenyl(naphthyl)aminophenyl]biphenyldiamine; di(naphthyl)bis(diphenylaminobiphenylyl)biphenyldiamine; di(phenyl)bis(phenylthiophenylphenyl)biphenyldiamine; (biphenylyl)(dimethylfluorenyl)(phenylcarbazolylphenyl)amine; (phenyl)(diphenylfluorenyl)(phenylcarbazolylphenyl)amine; (phenyl)(dimethylfluorenyl)(phenylcarbazolylbiphenylyl)amine; (phenyl)(terphenylyl)(biphenylyldimethylfluorenyl)amine; di(biphenylyl)(biphenylyldimethylfluorenyl)amine; di(biphenylyl)(naphthyldimethylfluorenyl)amine; (biphenylyl)(dimethylfluorenyl)(phenylcarbazolylphenyl)amine; di(biphenylyl)(phenylcarbazolylphenyl)amine; (biphenylyl)(terphenylyl)(phenylcarbazolylphenyl)amine; (naphthyl)(dimethylfluorenyl)(phenylcarbazolylbiphenylyl)amine; (biphenylyl)(dibenzothiophenyl)(phenylcarbazolylbiphenylyl)amine; bis(naphthylphenyl)(phenanthrenylphenyl)amine; (biphenylyl)(phenylnaphthylphenyl)(naphthylphenyl)amine; (biphenylyl)(dibenzofuranylbiphenylyl)(naphthylphenyl)amine; di(biphenylyl)(dibenzofuranylbiphenylyl)amine; di(biphenylyl)(dibenzothiophenylbiphenylyl)amine; di(biphenylyl)(triphenylsilylbiphenylyl)amine; di(biphenylyl)(triphenylsilylbiphenylyl)amine; (phenyl)(diphenylfluorenyl)(triphenylsilylbiphenylyl)amine; (biphenylyl)bis(naphthylphenyl)amine; tris(naphthylphenyl)amine; (phenyl)bis(carbazolylbiphenylyl)amine; bis(dibenzofuranylphenyl)(carbazolylbiphenylyl)amine; (biphenylyl)(dibenzofuranylphenyl)(carbazolylbiphenylyl)amine; (terphenylyl)(dibenzofuranylphenyl)(carbazolylbiphenylyl)amine; (biphenylyl)(dibenzofuranylphenyl)(carbazolylbiphenylyl)amine; (biphenylyl)(dimethylfluorenyl)(carbazolylbiphenylyl)amine; (biphenylyl)(dibenzofuranyl)(carbazolylbiphenylyl)amine; (phenyl)(biphenylyl)(carbazolylbiphenylyl)amine; di(biphenylyl)(carbazolylbiphenylyl)amine; (phenyl)(diphenylfluorenyl)(triphenylsilylbiphenylyl)amine; (dimethylfluorenyl)(biphenylyl)(carbazolylphenyl)amine; (biphenylyl)bis(diphenylfluorenyl)amine; (biphenylyl)bis(spirobifluorenyl)amine

In one embodiment, one or more compounds selected from each of the following groups (Group 1B) to (Group 33B) may also be independently used as the first organic compound and the second organic compound. Note that the first organic compound and the second organic compound in this specification are not limited to one or more compounds independently selected from each of the following groups (Group 1B) to (Group 33B), and may not be one or more compounds independently selected from each of the following groups (Group 1B) to (Group 33B).

### (Group 1B)

9,10-di(2-naphthyl)anthracene (ADN); 2-tert-butyl-9,10-di(2-naphthyl)anthracene (TBADN); 5,6,11,12-tetraphenyltetracene (rubrene); 2,5,8,11-tetra-tert-butylperylene (TBP)

### (Group 2B)

4,4′-bis[(1-naphthyl)-N-phenylamino]biphenyl(NBP); 5,6,11,12-tetraphenyltetracene (rubrene); 9,10-bis[N-(1-phenylamino)biphenyl]; 2,5,8,11-tetra-tert-butylperylene (TBP); tris(8-quinolinato-N1,O8)aluminium (Alq₃); coumarin 545T

### (Group 3B)

N,N′-di(1-naphthyl)-N,N′-diphenyl-(1,1′-biphenyl)-4,4′-diamine (NPD); Alq3; 10-(2-benzothiazolyl)-1,1,7,7-tetramethyl-2,3,6,7-tetrahydro-1H,5H,11H-[1]benzopyrano[6,7,8-ij]quinolizine-11-one (C545T); rubrene (5,6,11,12-tetraphenyltetracene); 4,4′-bis(2,2-diphenylvinyl)biphenyl (DPVBi)

### (Group 4B)

TBADN; TBP

### (Group 5B)

TBADN; Alq3; TBP; 5,6,11,12-tetraphenyltetracene (rubrene); 4-(dicyanomethylene)-2-tert-butyl-6-(1,1,7,7-tetramethyljulolidin-4-yl-vinyl)-4H-pyran (DCJTB)

### (Group 6B)

tetracene; tetrafluoro-tetracyano-quinodimethane (F4-TCNQ); 4,4′,4″-tris[phenyl(m-tolyl)amino]triphenylamine; naphthalene tetracarboxylic Dianhydride (NTCDA); Leuco-Crystal Violet (LCV); N,N′-bis(3-methylphenyl)-N,N′-bis(phenyl)-benzidine (TPD)

### (Group 9B)

1-(2,2′-binaphthalene-6-yl)-3-(phenanthrene-9-yl)benzene (hereinafter also referred to as “compound 9-1”); iridium(III)bis(2-phenylquinolyl-N,C²′)acetylacetonate (hereinafter also referred to as “compound 9-2”); 9-{3-[6-phenyl-2-phenylpyrimidine-4-yl]-5-(9H-carbazole-9-yl)phenyl}-9H-carbazole (hereinafter also referred to as “compound 9-3”); tris[2-phenylpyridinato-C²,N]iridium(III) (hereinafter also referred to as “compound 9-4”)

### (Group 10B)

1,3-di(9H-carbazole-9-yl)benzene (hereinafter also referred to as “compound 10-1”); [2,2′-bis(2′,4′-difluoro-2,3′-bipyridinato-2-yl)propane-C,N,N,C]platinum(II) (hereinafter also referred to as “compound 10-2”); 4,4′,4″-tris[2-naphthyl(phenyl)amino]triphenylamine (2-TNATA); 2,3,5,6-tetrafluoro-7,7,8,8-tetracyano-quinodimethane (F4-TCNQ); 3,3′-di(9H-carbazole-9-yl)-1,1′-biphenyl(hereinafter also referred to as “compound 10-5”); [2-(2′,4′-difluoro-2,3′-bipyridinato-2-yl)-2-{6-(5-trifluoromethyl-1H-pyrazole-1-yl)pyridinato-2-yl-C,N,N,C}propane-C,N,N,C]platinum(II) (hereinafter also referred to as “compound 10-6”); [2,2′-bis(2,3′-bipyridinato-2-yl)propane-C,N,N,C]platinum(II) (hereinafter also referred to as “compound 10-7”); iridium(III)bis(2-phenylquinolyl-N,C²′)acetylacetonate (hereinafter also referred to as “compound 10-8”); 9,10-di(2-naphthy)anthracene (hereinafter also referred to as “compound 10-9”); 2,5,8,11-tetra-tert-butylperylene (hereinafter also referred to as “compound 10-10”); 10-(2-benzothiazolyl)-1,1,7,7-tetramethyl-11-oxo-1,2,3,5,6,7-hexahydro-11H-[1]benzopyrano[6,7,8-ij]quinolizine-9-yde (hereinafter also referred to as “compound 10-11”); 2-[6-[2-[(2,3,6,7-tetrahydro-1H,5H-benzo[ij]quinolizine)-9-yl]ethenyl]-2-methyl-4H-pyran-4-ilidene]propane dinitrile (hereinafter also referred to as “compound 10-12”)

### (Group 12B)

2-{4′-triphenylenyl-[1,1′-biphenyl]-3-yl}-4,6-diphenyl-1,3,5-triazine (hereinafter also referred to as “compound 12-1”); 9-[4,6-diphenyl-2-pyridyl]-9′-phenyl-3,3′-bis[9H-carbazole] (hereinafter also referred to as “compound 12-2”); 9-(1,1′-biphenyl-3-yl)-9′-(1,1′-biphenyl-4-yl)-3,3′-bis[9H-carbazole] (hereinafter also referred to as “compound 12-3”)

### (Group 13B)

9-[3′-(triphenylene-2-yl)-1,1′-biphenyl]-9H-carbazole (hereinafter also referred to as “compound 13-1”); 11-(4,6-diphenyl-1,3,5-triazine-2-yl)-12-(4′-phenyl-1,1′-biphenyl-4-yl)-11H,12H-indolo[2,3-a]carbazole (hereinafter also referred to as “compound 13-2”)

### (Group 14B)

2-(1-(1,1′-biphenyl-4-yl)-9H-carbazole-9-yl)-4,6-diphenyl-1,3,5-triazine (hereinafter also referred to as “compound 14-1”); iridium(III)bis(2-(3,5-dimethylphenyl)-5-(2-methylpropyl)quinolyl-N,C²′)acetylacetonate (hereinafter also referred to as “compound 14-2”); 2-(1-(9,9′-dimethylfluorene-2-yl)-9H-carbazole-9-yl)-4,6-diphenyl-1,3,5-triazine (hereinafter also referred to as “compound 14-3”); iridium(III)bis(2-(3,5-dimethylphenyl)quinolyl-N,C²′)acetylacetonate (hereinafter also referred to as “compound 14-4”); 2-(1-phenyl-9H-carbazole-9-yl)-4-(9,9′-dimethylfluorene-2-yl)-6-phenyl-1,3,5-triazine (hereinafter also referred to as “compound 14-5”); iridium(III)bis(2-(3,5-dimethylphenyl)quinolyl-N,C²′)2,2,8,8-tetramethyl-4,6-nonanedionate (hereinafter also referred to as “compound 14-6”); 2-(1-(1,1′-biphenyl-4-yl)-9H-carbazole-9-yl)-4,6-diphenyl-1,3,5-triazine (hereinafter also referred to as “compound 14-7”); iridium(III)bis(2-(3,5-dimethylphenyl)-7-(2-methylpropyl)quinolyl-N,C²′)acetylacetonate (hereinafter also referred to as “compound 14-8”); 2-(1-phenyl-9H-carbazole-9-yl)-4-(9,9′-dimethylfluorene-2-yl)-6-phenyl-1,3,5-triazine (hereinafter also referred to as “compound 14-9”); iridium(III)bis(2-(3,5-dimethylphenyl)-5-cyclopentylquinolyl-N,C²′)acetylacetonate (hereinafter also referred to as “compound 14-10”); 2-(1-(1,1′-biphenyl-3-yl)-9H-carbazole-9-yl)-4,6-diphenyl-1,3,5-triazine (hereinafter also referred to as “compound 14-11”); iridium(III)bis(2-(3,5-dimethylphenyl)-6-(2-methylpropyl)quinolyl-N,C²′)acetylacetonate (hereinafter also referred to as “compound 14-12”); 11-(1,1′-biphenyl-4-yl)-12-(4,6-diphenyl-1,3,5-triazine-2-yl)-11H,12H-indolo[2,3-a]carbazole (hereinafter also referred to as “compound 14-13”); iridium(III)bis(2-phenylpyridyl-N,C²′) (4-methyl-5-(4-fluorophenyl)-2-phenylpyridyl-N,C₂′) (hereinafter also referred to as “compound 14-14”); 11-phenyl-12-(4-(1,1′-biphenyl-4-yl)-6-phenyl-1,3,5-triazine-2-yl)-11H,12H-indolo[2,3-a]carbazole (hereinafter also referred to as “compound 14-15”); iridium(III)bis(2-phenylpyridyl-N,C²′) (2,5-diphenylpyridyl-N,C₂′) (hereinafter also referred to as “compound 14-16”); 12-(4,6-diphenyl-1,3,5-triazine-2-yl)-12H-[1]benzothieno[2,3-a]carbazole (hereinafter also referred to as “compound 14-17”); iridium(III)bis(2-phenylpyridyl-N,C²′) (4-isopropyl-2,5-diphenylpyridyl-N,C₂′) (hereinafter also referred to as “compound 14-18”); 11-phenyl-12-(4-(9,9-dimethylfluorene-2-yl)-6-phenyl-1,3,5-triazine-2-yl)-11H,12H-indolo[2,3-a]carbazole (hereinafter also referred to as “compound 14-19”); iridium(III)bis(2-phenylpyridyl-N,C²′) (5-(4-fluorophenyl)-2-phenylpyridyl-N,C₂′) (hereinafter also referred to as “compound 14-20”); 5-phenyl-11-(4,6-diphenyl-1,3,5-triazine-2-yl)-5H,11H-indolo[3,2-b]carbazole (hereinafter also referred to as “compound 14-21”); iridium(III)bis(2-phenylpyridyl-N,C²′) (4-methyl-2,5-diphenylpyridyl-N,C₂′) (hereinafter also referred to as “compound 14-22”); iridium(III)bis(2-phenylpyridyl-N,C²′) (4-(methyl-d₃)-2,5-diphenylpyridyl-N,C₂′) (hereinafter also referred to as “compound 14-23”); 5-phenyl-11-(4-(9,9-dimethylfluorene-2-yl)-6-phenyl-1,3,5-triazine-2-yl)-5H,11H-indolo[3,2-b]carbazole (hereinafter also referred to as “compound 14-24”); iridium(III)bis(2-phenylpyridyl-N,C²′) (4-(4-methylphenyl)-2-phenylpyridyl-N,C₂′) (hereinafter also referred to as “compound 14-25”); 2-(7,7-dimethylindeno[2,1-b]carbazole-5-yl)-4-(1,1′-biphenyl-4-yl)-6-phenyl-1,3,5-triazine (hereinafter also referred to as “compound 14-26”); iridium(III)bis(2-phenylpyridyl-N,C²′) (4-(4-fluorophenyl)-2-phenylpyridyl-N,C₂′) (hereinafter also referred to as “compound 14-27”); 5-phenyl-12-(4,6-diphenyl-1,3,5-triazine-2-yl)-5H,12H-indolo[3,2-a]carbazole (hereinafter also referred to as “compound 14-28”); iridium(III)bis(5-methyl-2-phenylpyridyl-N,C²′) (4-methyl-2,5-diphenylpyridyl-N,C₂′) (hereinafter also referred to as “compound 14-29”); iridium(III)bis(5-(methyl-d₃)-2-phenylpyridyl-N,C²′) (4-(methyl-d₃)-5-phenyl-2-phenylpyridyl-N,C₂′) (hereinafter also referred to as “compound 14-30”)

### (Group 15B)

4-[3-(triphenylene-2-yl)phenyl]-6-phenyldibenzothiophene (hereinafter also referred to as “compound 15-1”); 2-(6-(1,1′-biphenyl-4-yl)-dibenzothiophene-4-yl)-4,6-diphenyl-1,3,5-triazine (hereinafter also referred to as “compound 15-2”); iridium(III)bis(2-phenylpyridyl-N,C²′) (4-methyl-2,5-diphenylpyridyl-N,C₂′) (hereinafter also referred to as “compound 15-3”); 2-(6-(4′-phenyl-1,1′-biphenyl-3-yl)-dibenzothiophene-4-yl)-4,6-diphenyl-1,3,5-triazine (hereinafter also referred to as “compound 15-4”); 2-{3-(6-(4′-phenyl-1,1′-biphenyl-3-yl)-dibenzothiophene-4-yl)phenyl}-4,6-diphenyl-1,3,5-triazine (hereinafter also referred to as “compound 15-5”); 2-{3-(6-(1,1′-biphenyl-3-yl)-dibenzothiophene-4-yl)phenyl}-4,6-diphenyl-1,3,5-triazine (hereinafter also referred to as “compound 15-6”); 2-{3-(dibenzothiophene-4-yl)phenyl}-4,6-diphenyl-1,3,5-triazine (hereinafter also referred to as “compound 15-7”); 2-{3-(dibenzothiophene-4-yl)-5-(1,1′-biphenyl-4-yl)-phenyl}-4,6-diphenyl-1,3,5-triazine (hereinafter also referred to as “compound 15-8”); 2-{3-(dibenzothiophene-4-yl)-5-(9,9-dimethylfluorene-2-yl)-phenyl}-4,6-diphenyl-1,3,5-triazine (hereinafter also referred to as “compound 15-9”); 2-{3-(6-(1,1′-biphenyl-4-yl)-dibenzothiophene-4-yl)phenyl}-4,6-diphenyl-1,3,5-triazine (hereinafter also referred to as “compound 15-10”); 2,4,6-tri(1,1′-biphenyl-4-yl)-1,3,5-triazine (hereinafter also referred to as “compound 15-11”); 2,4-bis(terphenyl-4-yl)-6-phenyl-1,3,5-triazine (hereinafter also referred to as “compound 15-12”); 2-(3-(3-pyridyl)-5-(phenanthrene-9-yl)-phenyl)-4,6-diphenyl-1,3,5-triazine (hereinafter also referred to as “compound 15-13”); 2-(9,9-dimethylfluorene-2-yl)-4,6-bis(1,1′-biphenyl-3-yl)-1,3,5-triazine (hereinafter also referred to as “compound 15-14”); 2-(3-(dibenzothiophene-4-yl)-phenyl)-4,6-bis(1,1′-biphenyl-3-yl)-1,3,5-triazine (hereinafter also referred to as “compound 15-15”); 2-(3-(9-(2-pyridyl)-9H-carbazole-3-yl)-5-(dibenzothiophene-4-yl)-phenyl)-4,6-diphenyl-1,3,5-triazine (hereinafter also referred to as “compound 15-16”); 2-(9H-carbazole-9-yl)-4-phenyl-6-(triphenylene-2-yl)-1,3,5-triazine (hereinafter also referred to as “compound 15-17”); 2-{5-(6-phenyl-dibenzofuran-4-yl)-1,1′-biphenyl-3-yl}-4,6-diphenyl-1,3,5-triazine (hereinafter also referred to as “compound 15-18”); 2-{5-(6-phenyldibenzothiophene-4-yl)-1,1′-biphenyl-3-yl}-4,6-diphenyl-1,3,5-triazine (hereinafter also referred to as “compound 15-19”); 2-{5-(6-(1,1′-biphenyl-4-yl)-dibenzothiophene-4-yl)-1,1′-biphenyl-3-yl}-4,6-diphenyl-1,3,5-triazine (hereinafter also referred to as “compound 15-20”); 2-{5-(6-(1,1′-biphenyl-3-yl)-dibenzothiophene-4-yl)-1,1′-biphenyl-3-yl}-4,6-diphenyl-1,3,5-triazine (hereinafter also referred to as “compound 15-21”); 2-(5-(dibenzothiophene-4-yl)-1,1′-biphenyl-3-yl)-4-(1,1′-biphenyl-4-yl)-6-phenyl-1,3,5-triazine (hereinafter also referred to as “compound 15-22”); 2-(5-(dibenzothiophene-4-yl)-1,1′-biphenyl-3-yl)-4-(9,9-dimethylfluorene-2-yl)-6-phenyl-1,3,5-triazine (hereinafter also referred to as “compound 15-23”); 2-(5-(6-phenyldibenzothiophene-4-yl)-1,1′-biphenyl-3-yl)-4-(9,9-dimethylfluorene-2-yl)-6-phenyl-1,3,5-triazine (hereinafter also referred to as “compound 15-24”); 2-{3′-phenyl-5′-(dibenzothiophene-4-yl)-1,1′-biphenyl-3-yl}-4,6-diphenyl-1,3,5-triazine (hereinafter also referred to as “compound 15-25”); 2-{5-phenyl-5′-(dibenzothiophene-4-yl)-1,1′-biphenyl-3-yl}-4,6-diphenyl-1,3,5-triazine (hereinafter also referred to as “compound 15-26”); 2-{5-(9,9-dimethylfluorene-2-yl)-4′-phenyl-1,1′-biphenyl-3-yl}-4,6-diphenyl-1,3,5-triazine (hereinafter also referred to as “compound 15-27”); 2-{3,5-bis(9,9-dimethylfluorene-2-yl)-phenyl}-4,6-diphenyl-1,3,5-triazine (hereinafter also referred to as “compound 15-28”); 2-(3-(6-phenyldibenzothiophene-4-yl)-phenyl)-4-(1,1′-biphenyl-3-yl)-6-phenyl-1,3,5-triazine (hereinafter also referred to as “compound 15-29”); 2-{4-(6-phenyldibenzothiophene-4-yl)-phenyl}-4,6-diphenyl-1,3,5-triazine (hereinafter also referred to as “compound 15-30”); 2-{3′-(6-phenyldibenzothiophene-4-yl)-1,1′-biphenyl-4-yl}-4,6-diphenyl-1,3,5-triazine (hereinafter also referred to as “compound 15-31”); 2-{4′-(6-phenyldibenzothiophene-4-yl)-1,1′-biphenyl-3-yl}-4,6-diphenyl-1,3,5-triazine (hereinafter also referred to as “compound 15-32”); 2-(6-(1,1′-biphenyl-4-yl)-dibenzothiophene-4-yl)-4-(1,1′-biphenyl-3-yl)-6-phenyl-1,3,5-triazine (hereinafter also referred to as “compound 15-33”); 2-{4-(6-(1,1′-biphenyl-4-yl)-dibenzothiophene-4-yl)-phenyl}-4,6-diphenyl-1,3,5-triazine (hereinafter also referred to as “compound 15-34”); 2-{4-(6-(1,1′-biphenyl-3-yl)-dibenzothiophene-4-yl)-phenyl}-4,6-diphenyl-1,3,5-triazine (hereinafter also referred to as “compound 15-35”); 2-(6-phenyldibenzothiophene-4-yl)-4-(9,9-dimethylfluorene-2-yl)-6-phenyl-1,3,5-triazine (hereinafter also referred to as “compound 15-36”); 2-{(6-(1,1′-biphenyl-4-yl)-dibenzothiophene-4-yl}-4-(9,9-dimethylfluorene-2-yl)-6-phenyl-1,3,5-triazine (hereinafter also referred to as “compound 15-37”); 2-{3-(6-(1,1′-biphenyl-4-yl)-dibenzothiophene-4-yl)-phenyl}-4-(9,9-dimethylfluorene-2-yl)-6-phenyl-1,3,5-triazine (hereinafter also referred to as “compound 15-38”); 2-{3-(2,7-diphenyldibenzothiophene-4-yl)-phenyl}-4,6-diphenyl-1,3,5-triazine (hereinafter also referred to as “compound 15-39”); 2-{4′-(6-(1,1′-biphenyl-4-yl)-dibenzothiophene-4-yl)-1,1′-biphenyl-3-yl}-4,6-diphenyl-1,3,5-triazine (hereinafter also referred to as “compound 15-40”); 2-(9,9-dimethylfluorene-2-yl)-4,6-bis(4′-phenyl-1,1′-biphenyl-3-yl)-1,3,5-triazine (hereinafter also referred to as “compound 15-41”); 2-(dibenzothiophene-4-yl)-4-(9,9-dimethylfluorene-2-yl)-6-(4′-phenyl-1,1′-biphenyl-3-yl)-1,3,5-triazine (hereinafter also referred to as “compound 15-42”); 2-[3′-(triphenylene-2-yl)-1,1′-biphenyl-4-yl]-4,6-diphenyl-1,3,5-triazine (hereinafter also referred to as “compound 15-43”); 2-[4′-(dibenzofuran-4-yl)-1,1′-biphenyl-3-yl]-4,6-diphenyl-1,3,5-triazine (hereinafter also referred to as “compound 15-44”); 4-(triphenylene-2-yl)-dibenzofuran (hereinafter also referred to as “compound 15-45”); 4-(triphenylene-2-yl)-dibenzothiophene (hereinafter also referred to as “compound 15-46”); 4-(3-(triphenylene-2-yl)phenyl)-dibenzothiophene (hereinafter also referred to as “compound 15-47”); 4-(3-phenyl-5-(triphenylene-2-yl)phenyl)-dibenzothiophene (hereinafter also referred to as “compound 15-48”); 4-(1,1′-biphenyl-4-yl)-5-(triphenylene-2-yl)-dibenzothiophene (hereinafter also referred to as “compound 15-49”); 4-(9H-carbazole-9-yl)-5-(triphenylene-2-yl)-dibenzofuran (hereinafter also referred to as “compound 15-50”); 4-(9H-carbazole-9-yl)-5-(triphenylene-2-yl)-dibenzothiophene (hereinafter also referred to as “compound 15-51”); 9-(3′-(triphenylene-2-yl)-1,1′-biphenyl-3-yl)-9H-carbazole (hereinafter also referred to as “compound 15-52”); 9-(3′-(triphenylene-2-yl)-1,1′-biphenyl-4-yl)-9H-carbazole (hereinafter also referred to as “compound 15-53”); [2-{3-(triphenylene-2-yl)phenyl}pyridine-3-yl]-9H-carbazole (hereinafter also referred to as “compound 15-54”); 2-(6-phenyldibenzofuran-4-yl)-4,6-diphenyl-1,3,5-triazine (hereinafter also referred to as “compound 15-55”); 2-(6-phenyldibenzothiophene-4-yl)-4,6-diphenyl-1,3,5-triazine (hereinafter also referred to as “compound 15-56”); 2-(6-(1,1′-biphenyl-4-yl)dibenzothiophene-4-yl)-4,6-diphenyl-1,3,5-triazine (hereinafter also referred to as “compound 15-57”); 2-[3-(6-(1,1′-biphenyl-4-yl)dibenzofuran-4-yl)phenyl]-4,6-diphenyl-1,3,5-triazine (hereinafter also referred to as “compound 15-58”); 2-(6-phenyldibenzothiophene-4-yl)-4,6-bis(1,1′-biphenyl-3-yl)-1,3,5-triazine (hereinafter also referred to as “compound 15-59”); 2-[3-(6-(1,1′-biphenyl-4-yl)dibenzofuran-4-yl)phenyl]-4,6-bis(phenyl-d₅)-1,3,5-triazine (hereinafter also referred to as “compound 15-60”); 2-{3-(dibenzothiophene-4-yl)-5-(1,1′-biphenyl-4-yl)phenyl}-4,6-diphenyl-1,3,5-triazine (hereinafter also referred to as “compound 15-61”); 9-[3-(9-(4′-phenyl-1,1′-biphenyl-3-yl)-9H-carbazole-3-yl)phenyl]-9H-carbazole (hereinafter also referred to as “compound 15-62”); 9-[3-(9-(4′-phenyl-1,1′-biphenyl-3-yl)-9H-carbazole-2-yl)phenyl]-9H-carbazole (hereinafter also referred to as “compound 15-63”); 9-[3-(9-(triphenylene-2-yl)-9H-carbazole-3-yl)phenyl]-9H-carbazole (hereinafter also referred to as “compound 15-64”); 9-[3-(9-(triphenylene-2-yl)-9H-carbazole-2-yl)phenyl]-9H-carbazole (hereinafter also referred to as “compound 15-65”); 9-[3-(9-(dibenzothiophene-4-yl)-9H-carbazole-3-yl)phenyl]-9H-carbazole (hereinafter also referred to as “compound 15-66”); 2-(dibenzofuran-4-yl)-4-(1,1′-biphenyl-4-yl)-6-(4′-phenyl-1,1′-biphenyl-3-yl)-1,3,5-triazine (hereinafter also referred to as “compound 15-67”); 2-(dibenzothiophene-4-yl)-4-(1,1′-biphenyl-4-yl)-6-(4′-phenyl-1,1′-biphenyl-3-yl)-1,3,5-triazine (hereinafter also referred to as “compound 15-68”); 2-(dibenzothiophene-4-yl)-4-(9,9-dimethylfluorene-2-yl)-6-(4′-phenyl-1,1′-biphenyl-3-yl)-1,3,5-triazine (hereinafter also referred to as “compound 15-69”); 2-(biphenylene-3-yl)-4-(9,9-dimethylfluorene-2-yl)-6-(4′-phenyl-1,1′-biphenyl-3-yl)-1,3,5-triazine (hereinafter also referred to as “compound 15-70”)

### (Group 16B)

11-(4-(1,1′-biphenyl-4-yl)-6-phenyl-1,3,5-triazine-2-yl)-12-phenyl-11H,12H-indolo[2,3-a]carbazole (hereinafter also referred to as “compound 16-1”); 5-phenyl-12-(6-(9H-carbazole-9-yl)pyridine-2-yl)-5H,12H-indolo[3,2-a]carbazole (hereinafter also referred to as “compound 16-2”); 5-(9-phenylcarbazole-3-yl)-12-phenyl-5H,12H-indolo[3,2-a]carbazole (hereinafter also referred to as “compound 16-3”); 2-(3-(triphenylene-2-yl)phenyl)-dibenzothiophene (hereinafter also referred to as “compound 16-4”); 5,11-bis(2-phenyl-pyridine-6-yl)-5H,11H-indolo[3,2-b]carbazole (hereinafter also referred to as “compound 16-5”); 3,3′-di(9H-carbazole-9-yl)-1,1′-biphenyl(hereinafter also referred to as “compound 16-6”)

### (Group 17B)

9-(dibenzothiophene-4-yl)-9′-phenyl-3,3′-bi[9H-carbazole] (hereinafter also referred to as “compound 17-1”); 2-[3-(6-(1,1′-biphenyl-4-yl)dibenzofuran-4-yl)phenyl]-4,6-diphenyl-1,3,5-triazine (hereinafter also referred to as “compound 17-2”); 2-[3-(6-(1,1′-biphenyl-4-yl)dibenzofuran-4-yl)phenyl]-4,6-bis(phenyl-d₅)-1,3,5-triazine (hereinafter also referred to as “compound 17-3”)

### (Group 18B)

5-(1,1′-biphenyl-4-yl)-8-(4′-phenyl-1,1′-biphenyl-4-yl)-5H,8H-indolo[2,3-c]carbazole (hereinafter also referred to as “compound 18-1”); iridium(III)bis(2-phenylpyridyl-N,C²′) (4-methyl-2,5-diphenylpyridyl-N,C₂′) (hereinafter also referred to as “compound 18-2”); 5,8-bis(1,1′-biphenyl-4-yl)-5H,8H-indolo[2,3-c]carbazole (hereinafter also referred to as “compound 18-3”); 5-(4′-phenyl-1,1′-biphenyl-3-yl)-12-(9,9-dimethylfluorene-2-yl)-5H,12H-indolo[3,2-a]carbazole (hereinafter also referred to as “compound 18-4”); 5-(1,1′-biphenyl-4-yl)-12-(9,9-dimethylfluorene-2-yl)-5H,12H-indolo[3,2-a]carbazole (hereinafter also referred to as “compound 18-5”); 2-{3-(dibenzothiophene-4-yl)-5-(1,1′-biphenyl-4-yl)-phenyl}-4,6-diphenyl-1,3,5-triazine (hereinafter also referred to as “compound 18-6”); 5-(1,1′-biphenyl-4-yl)-8-(4′-phenyl-1,1′-biphenyl-3-yl)-5H,8H-indolo[2,3-c]carbazole (hereinafter also referred to as “compound 18-7”); 5-(4′-phenyl-1,1′-biphenyl-4-yl)-8-(1,1′-biphenyl-3-yl)-5H,8H-indolo[2,3-c]carbazole (hereinafter also referred to as “compound 18-8”); 2-{5-(6-phenyldibenzothiophene-4-yl)-1,1′-biphenyl-3-yl}-4,6-diphenyl-1,3,5-triazine (hereinafter also referred to as “compound 18-9”); 5-(4′-phenyl-1,1′-biphenyl-4-yl)-12-(1,1′-biphenyl-4-yl)-5H,12H-indolo[3,2-a]carbazole (hereinafter also referred to as “compound 18-10”); 5-(4′-phenyl-1,1′-biphenyl-3-yl)-8-(dibenzothiophene-4-yl)-5H,8H-indolo[2,3-c]carbazole (hereinafter also referred to as “compound 18-11”); 2-{5-(6-(1,1′-biphenyl-4-yl)dibenzothiophene-4-yl)-1,1′-biphenyl-3-yl}-4,6-diphenyl-1,3,5-triazine (hereinafter also referred to as “compound 18-12”); 5-(4′-phenyl-1,1′-biphenyl-4-yl)-8-(triphenylene-2-yl)-5H,8H-indolo[2,3-c]carbazole (hereinafter also referred to as “compound 18-13”); 5-(4′-phenyl-1,1′-biphenyl-4-yl)-8-(3-(dibenzothiophene-4-yl)phenyl)-5H,8H-indolo[2,3-c]carbazole (hereinafter also referred to as “compound 18-14”); 5-(4′-phenyl-1,1′-biphenyl-3-yl)-8-(3-(9H-carbazole-9-yl)phenyl)-5H,8H-indolo[2,3-c]carbazole (hereinafter also referred to as “compound 18-15”); 5-(4′-phenyl-1,1′-biphenyl-4-yl)-8-(dibenzofuran-2-yl)-5H,8H-indolo[2,3-c]carbazole (hereinafter also referred to as “compound 18-16”); 5-(4′-phenyl-1,1′-biphenyl-4-yl)-12-(4′-phenyl-1,1′-biphenyl-3-yl)-5H,12H-indolo[3,2-a]carbazole (hereinafter also referred to as “compound 18-17”); 2-{3-(6-(1,1′-biphenyl-4-yl)dibenzothiophene-4-yl)phenyl}-4,6-diphenyl-1,3,5-triazine (hereinafter also referred to as “compound 18-18”); 5-(4′-(phenyl-d₅)-1,1′-biphenyl-4-yl)-8-(phenyl-d₅)-5H,8H-indolo[2,3-c]carbazole (hereinafter also referred to as “compound 18-19”); 5-(4′-phenyl-1,1′-biphenyl-3-yl)-12-phenyl-5H,12H-indolo[3,2-a]carbazole (hereinafter also referred to as “compound 18-20”); 2-{4-(6-(1,1′-biphenyl-4-yl)dibenzothiophene-4-yl)phenyl}-4,6-diphenyl-1,3,5-triazine (hereinafter also referred to as “compound 18-21”); 2-{3-(6-(1,1′-biphenyl-4-yl)dibenzothiophene-4-yl)phenyl}-4,6-bis(phenyl-d₅)-1,3,5-triazine (hereinafter also referred to as “compound 18-22”); 5-(3′-(phenyl-d₅)-1,1′-biphenyl-4-yl)-8-(phenyl-d₅)-5H,8H-indolo[2,3-c]carbazole (hereinafter also referred to as “compound 18-23”); 2-{3-(6-(9,9-dimethylfluorene-2-yl)dibenzothiophene-4-yl)phenyl}-4,6-diphenyl-1,3,5-triazine (hereinafter also referred to as “compound 18-24”); 5-(4′-phenyl-1,1′-biphenyl-4-yl)-12-phenyl-5H,12H-indolo[3,2-a]carbazole (hereinafter also referred to as “compound 18-25”); 2-{5-(6-(9,9-dimethylfluorene-2-yl)dibenzothiophene-4-yl)-1,1′-biphenyl-3-yl}-4,6-diphenyl-1,3,5-triazine (hereinafter also referred to as “compound 18-26”); 5-(4′-phenyl-1,1′-biphenyl-3-yl)-12-(triphenylene-2-yl)-5H,12H-indolo[3,2-a]carbazole (hereinafter also referred to as “compound 18-27”)

### (Group 19B)

11-(4-(1,1′-biphenyl-4-yl)-6-phenyl-1,3,5-triazine-2-yl)-12-phenyl-11H,12H-indolo[2,3-a]carbazole (hereinafter also referred to as “compound 19-1”); 9-(2-naphthyl)-9′-phenyl-3,3′-bis[9H-carbazole] (hereinafter also referred to as “compound 19-2”); 11-(4,6,-bis(1,1′-biphenyl-4-yl)-1,3,5-triazine-2-yl)-12-phenyl-11H,12H-indolo[2,3-a]carbazole (hereinafter also referred to as “compound 19-3”); 9-(9-phenanthrenyl)-9′-phenyl-3,3′-bis[9H-carbazole](hereinafter also referred to as “compound 19-4”)

### (Group 20B)

2-{5-(dibenzothiophene-4-yl)-4′-phenyl-1,1′-biphenyl-3-yl}-4,6-diphenyl-1,3,5-triazine (hereinafter also referred to as “compound 20-1”); 2-{5-(6-phenyldibenzothiophene-4-yl)-1,1′-biphenyl-3-yl}-4,6-diphenyl-1,3,5-triazine (hereinafter also referred to as “compound 20-2”); 2-{5-(6-(1,1′-biphenyl-4-yl)dibenzothiophene-4-yl)-1,1′-biphenyl-3-yl}-4,6-diphenyl-1,3,5-triazine (hereinafter also referred to as “compound 20-3”); 2-{5-(6-(1,1′-biphenyl-3-yl)dibenzothiophene-4-yl)-1,1′-biphenyl-3-yl}-4,6-diphenyl-1,3,5-triazine (hereinafter also referred to as “compound 20-4”); 2-{3-(6-(1,1′-biphenyl-4-yl)dibenzothiophene-4-yl)phenyl}-4,6-diphenyl-1,3,5-triazine (hereinafter also referred to as “compound 20-5”); 2-{4-(6-(1,1′-biphenyl-4-yl)dibenzothiophene-4-yl)phenyl}-4,6-diphenyl-1,3,5-triazine (hereinafter also referred to as “compound 20-6”); 2-{3-(6-(1,1′-biphenyl-4-yl)dibenzothiophene-4-yl)phenyl}-4,6-bis(phenyl-d₅)-1,3,5-triazine (hereinafter also referred to as “compound 20-7”); 2-{3-(6-(9,9-dimethylfluorene-2-yl)dibenzothiophene-4-yl)phenyl}-4,6-diphenyl-1,3,5-triazine (hereinafter also referred to as “compound 20-8”); 2-{5-(6-(9,9-dimethylfluorene-2-yl)dibenzothiophene-4-yl)-1,1′-biphenyl-3-yl}-4,6-diphenyl-1,3,5-triazine (hereinafter also referred to as “compound 20-9”); 6,6′,9,9′-tetraphenyl-3,3′-bis[9H-carbazole] (hereinafter also referred to as “compound 20-10”); 9-(9,9-dimethylfluorene-2-yl)-9′-phenyl-3,3′-bis[9H-carbazole] (hereinafter also referred to as “compound 20-11”); 9-(1,1′-biphenyl-4-yl)-9′-phenyl-3,3′-bis[9H-carbazole] (hereinafter also referred to as “compound 20-12”); 9-phenyl-9′-(triphenylene-2-yl)-3,3′-bis[9H-carbazole] (hereinafter also referred to as “compound 20-13”); 9-(1,1′-biphenyl-4-yl)-9′-(dibenzothiophene-2-yl)-3,3′-bis[9H-carbazole] (hereinafter also referred to as “compound 20-14”); 9-(dibenzothiophene-2-yl)-9′-(9,9-dimethylfluorene-2-yl)-3,3′-bis[9H-carbazole] (hereinafter also referred to as “compound 20-15”); 9,9′-bis(1,1′-biphenyl-4-yl)-3,3′-bis[9H-carbazole] (hereinafter also referred to as “compound 20-16”); 9-(dibenzothiophene-2-yl)-9′-phenyl-3,3′-bis[9H-carbazole] (hereinafter also referred to as “compound 20-17”); 9-(dibenzothiophene-4-yl)-9′-phenyl-3,3′-bis[9H-carbazole] (hereinafter also referred to as “compound 20-18”); 9-(dibenzothiophene-4-yl)-9′-phenyl-3,4′-bis[9H-carbazole] (hereinafter also referred to as “compound 20-19”)

### (Group 21B)

4-{3-(1,1′-biphenyl-4-yl)phenyl}-6-phenyl-dibenzothiophene (hereinafter also referred to as “compound 21-1”); 2-{3-(6-(1,1′-biphenyl-4-yl)dibenzothiophene-4-yl)phenyl}-4,6-diphenyl-1,3,5-triazine (hereinafter also referred to as “compound 21-2”); 4-(triphenylene-2-yl)-6-(1,1′-biphenyl-4-yl)-dibenzothiophene (hereinafter also referred to as “compound 21-3”); 4-{3-(1,1′-biphenyl-4-yl)phenyl}-dibenzothiophene (hereinafter also referred to as “compound 21-4”); 1,6-bis(9H-carbazole-9-yl)-[1]benzothieno[2,3-c]pyridine (hereinafter also referred to as “compound 21-5”); iridium(III)bis(2-phenylpyridyl-N,C2) (4-ethyl-2,5-diphenylpyridyl-N,C₂′) (hereinafter also referred to as “compound 21-6”)

### (Group 22B)

2-{5-(dibenzothiophene-4-yl)-1,1′-biphenyl-3-yl}-4,6-diphenyl-1,3,5-triazine (hereinafter also referred to as “compound 22-1”); 2-{5-(6-phenyldibenzothiophene-4-yl)-1,1′-biphenyl-3-yl}-4,6-diphenyl-1,3,5-triazine (hereinafter also referred to as “compound 22-2”); 2-{5-(6-(1,1′-biphenyl-4-yl)dibenzothiophene-4-yl)-1,1′-biphenyl-3-yl}-4,6-diphenyl-1,3,5-triazine (hereinafter also referred to as “compound 22-3”); 2-{5-(6-(1,1′-biphenyl-3-yl)dibenzothiophene-4-yl)-1,1′-biphenyl-3-yl}-4,6-diphenyl-1,3,5-triazine (hereinafter also referred to as “compound 22-4”); 2-{5-(dibenzothiophene-3-yl)-1,1′-biphenyl-3-yl}-4,6-diphenyl-1,3,5-triazine (hereinafter also referred to as “compound 22-5”); 2-{5-(dibenzothiophene-3-yl)-4′-phenyl-1,1′-biphenyl-3-yl}-4,6-diphenyl-1,3,5-triazine (hereinafter also referred to as “compound 22-6”); 2-{3-(6-(1,1′-biphenyl-4-yl)dibenzothiophene-4-yl)phenyl}-4,6-bis(phenyl-d₅)-1,3,5-triazine (hereinafter also referred to as “compound 22-7”); 2-{3-(6-(9,9-dimethylfluorene-2-yl)dibenzothiophene-4-yl)phenyl}-4,6-diphenyl-1,3,5-triazine (hereinafter also referred to as “compound 22-8”); 2-{5-(6-(9,9-dimethylfluorene-2-yl)dibenzothiophene-4-yl)-1,1′-biphenyl-3-yl}-4,6-diphenyl-1,3,5-triazine (hereinafter also referred to as “compound 22-9”); 2-{3′-triphenylenyl-[1,1′-biphenyl]-3-yl}-4,6-diphenyl-1,3,5-triazine (hereinafter also referred to as “compound 22-10”); 2-(6-(4′-phenyl-1,1′-biphenyl-4-yl)dibenzothiophene-4-yl)-4-(1,1′-biphenyl-3-yl)-6-phenyl-1,3,5-triazine (hereinafter also referred to as “compound 22-11”); 5-{4-(4,6-diphenyl-1,3,5-triazine-2-yl)phenyl}-8-phenyl-5H,8H-indolo[2,3-c]carbazole (hereinafter also referred to as “compound 22-12”); 5-(1,1′-biphenyl-4-yl)-8-(4′-phenyl-1,1′-biphenyl-3-yl)-5H,8H-indolo[2,3-c]carbazole (hereinafter also referred to as “compound 22-13”); 5-(1,1′-biphenyl-3-yl)-8-(4′-phenyl-1,1′-biphenyl-4-yl)-5H,8H-indolo[2,3-c]carbazole (hereinafter also referred to as “compound 22-14”); 5-(4′-phenyl-1,1′-biphenyl-4-yl)-12-(1,1′-biphenyl-4-yl)-5H,12H-indolo[3,2-a]carbazole (hereinafter also referred to as “compound 22-15”); 5-(dibenzothiophene-4-yl)-8-(4′-phenyl-1,1′-biphenyl-3-yl)-5H,8H-indolo[2,3-c]carbazole (hereinafter also referred to as “compound 22-16”); 5-(triphenylene-2-yl)-8-(4′-phenyl-1,1′-biphenyl-4-yl)-5H,8H-indolo[2,3-c]carbazole (hereinafter also referred to as “compound 22-17”); 5-{3-(dibenzothiophene-4-yl)phenyl}-8-(4′-phenyl-1,1′-biphenyl-4-yl)-5H,8H-indolo[2,3-c]carbazole (hereinafter also referred to as “compound 22-18”); 5-{3-(9H-carbazole-9-yl)phenyl}-8-(4′-phenyl-1,1′-biphenyl-3-yl)-5H,8H-indolo[2,3-c]carbazole (hereinafter also referred to as “compound 22-19”); 5-(4′-phenyl-1,1′-biphenyl-4-yl)-12-(4′-phenyl-1,1′-biphenyl-3-yl)-5H,12H-indolo[3,2-a]carbazole (hereinafter also referred to as “compound 22-20”); 5-(4′-(phenyl-d₅)-1,1′-biphenyl-4-yl)-8-(phenyl-d₅)-5H,8H-indolo[2,3-c]carbazole (hereinafter also referred to as “compound 22-21”); 5-(4′-phenyl-1,1′-biphenyl-3-yl)-12-phenyl-5H,12H-indolo[3,2-a]carbazole (hereinafter also referred to as “compound 22-22”); 5-(3′-(phenyl-d₅)-1,1′-biphenyl-4-yl)-8-(phenyl-d₅)-5H,8H-indolo[2,3-c]carbazole (hereinafter also referred to as “compound 22-23”); 5-(4′-phenyl-1,1′-biphenyl-4-yl)-12-phenyl-5H,12H-indolo[3,2-a]carbazole (hereinafter also referred to as “compound 22-24”); 5-(4′-phenyl-1,1′-biphenyl-3-yl)-12-(triphenylene-2-yl)-5H,12H-indolo[3,2-a]carbazole (hereinafter also referred to as “compound 22-25”); 5-{3-phenyl(1,1′-biphenyl-3-yl)}-8-(4′-phenyl-1,1′-biphenyl-3-yl)-5H,8H-indolo[2,3-c]carbazole (hereinafter also referred to as “compound 22-26”)

### (Group 23B)

2,4-bis(1,1′-biphenyl-3-yl)-6-(10H-[1]benzothieno[3,2-b]indole-10-yl)-1,3,5-triazine (hereinafter also referred to as “compound 23-1”); 3-(10-phenyl-5,10-dimethyl-5,10-dihydroindolo[3,2-b]indole-5-yl)phenyl-1,3,5-triazine (hereinafter also referred to as “compound 23-2”); 2-(1,1′-biphenyl-3-yl)-4-(10H-benzofuro[3,2-b]indole-10-yl)-6-phenyl-1,3,5-triazine (hereinafter also referred to as “compound 23-3”); 9-(2-naphthyl)-9′-phenyl-3,3′-bis[9H-carbazole] (hereinafter also referred to as “compound 23-4”); 9-(1,1′-biphenyl-3-yl)-9′-phenyl-3,3′-bis[9H-carbazole] (hereinafter also referred to as “compound 23-5”); 3-(dibenzofuran-2-yl)-9-(5-phenyl(1,1′-biphenyl-3-yl))-9H-carbazole (hereinafter also referred to as “compound 23-6”); 3-(dibenzothiophene-2-yl)-9-(2-naphthylbenzene-3-yl)-9H-carbazole (hereinafter also referred to as “compound 23-7”); 11-(4,6-diphenyl-1,3,5-triazine-2-yl)-12-phenyl-11H,12H-indolo[2,3-a]carbazole (hereinafter also referred to as “compound 23-8”); 9,9′-diphenyl-3,3′-bis[9H-carbazole] (hereinafter also referred to as “compound 23-9”)

### (Group 24B)

11-(4-(1,1′:3′,1″-terbenzene-3-yl)-6-phenyl-1,3,5-triazine-2-yl)-12-phenyl-11H,12H-indolo[2,3-a]carbazole (hereinafter also referred to as “compound 24-1”); 11-(4-(1,1′-biphenyl-3-yl)-6-phenyl-1,3,5-triazine-2-yl)-12-phenyl-11H,12H-indolo[2,3-a]carbazole (hereinafter also referred to as “compound 24-2”); 11-(4-(1,1′-biphenyl-4-yl)-6-phenyl-1,3,5-triazine-2-yl)-12-phenyl-11H,12H-indolo[2,3-a]carbazole (hereinafter also referred to as “compound 24-3”); 9-(1,1′-biphenyl-2-yl)-9′-(1,1′-biphenyl-3-yl)-3,3′-bis[9H-carbazole] (hereinafter also referred to as “compound 24-4”); 9,9′-bis(1,1′-biphenyl-2-yl)-3,3′-bis[9H-carbazole] (hereinafter also referred to as “compound 24-5”)

### (Group 25B)

2-(1,1′-biphenyl-4-yl)-4-phenyl-6-(9,9′-spirobifluorene-4-yl)-1,3,5-triazine (hereinafter also referred to as “compound 25-1”); 9-(1,1′-biphenyl-3-yl)-9′-(1,1′-biphenyl-4-yl)-3,3′-bis[9H-carbazole] (hereinafter also referred to as “compound 25-2”); 9-phenyl-9′-(triphenylene-2-yl)-3,3′-bis[9H-carbazole] (hereinafter also referred to as “compound 25-3”); 2-(1,1′-biphenyl-3-yl)-4-phenyl-6-(9,9′-spirobifluorene-4-yl)-1,3,5-triazine (hereinafter also referred to as “compound 25-4”); 2,4,6-tri(1,1′-biphenyl-3-yl)-1,3,5-triazine (hereinafter also referred to as “compound 25-5”); N,N′-diphenyl-N,N′-bis(1-naphthyl)benzidine (hereinafter also referred to as “compound 25-6”); 4,7-diphenyl-1,10-phenanthroline (hereinafter also referred to as “compound 25-7”); (9,9-dimethylfluorene-3-yl) (9-phenyl-9H-carbazole-3-yl) (1,1′:3′,1″-terbenzene-5′-yl)amine (hereinafter also referred to as “compound 25-8”)

### (Group 26B)

9-(7-cyanotriphenylene-2-yl)-9′-phenyl-3,3′-bis[9H-carbazole] (hereinafter also referred to as “compound 26-1”); 9-(4′-cyano-1,1′-biphenyl-4-yl)-9′-phenyl-3,3′-bis[9H-carbazole] (hereinafter also referred to as “compound 26-2”); 9-(5-(4,6-diphenyl-1,3,5-triazine-2-yl)-1,1′-biphenyl-3-yl)-9′-phenyl-2,3′-bis[9H-carbazole] (hereinafter also referred to as “compound 26-3”); 9-(3-(4-(1,1′-biphenyl-3-yl)-6-phenyl-1,3,5-triazine-2-yl)phenyl)-9′-phenyl-2,3′-bis[9H-carbazole] (hereinafter also referred to as “compound 26-4”); 9-(3′-(4,6-diphenyl-1,3,5-triazine-2-yl)-1,1′-biphenyl-3-yl)-9′-phenyl-2,3′-bis[9H-carbazole] (hereinafter also referred to as “compound 26-5”); 9-(3-(4,6-diphenyl-1,3,5-triazine-2-yl)phenyl)-9′-phenyl-2,3′-bis[9H-carbazole] (hereinafter also referred to as “compound 26-6”)

### (Group 28B)

tris(4-(6H-6-aza-12-oxaindeno[1,2-b]fluorene-6-yl)phenyl)amine (hereinafter also referred to as “compound 28-1”); 5-methyl-8-((4-(5-methyl-5H,8H-indolo[2,3-c]carbazole-8-yl)-phenyl) (2-pyridyl)phosphoryl)-5H,8H-indolo[2,3-c]carbazole (hereinafter also referred to as “compound 28-2”); tetrakis (4-(6H-6-aza-8-oxaindeno[2,3-b]fluorene-6-yl)-phenyl)silane (hereinafter also referred to as “compound 28-3”); 2,5-bis(4-(6H-6-aza-12-oxaindeno[1,2-b]fluorene-6-yl)phenyl)furan (hereinafter also referred to as “compound 28-4”); tetrakis (4-(6H-6-aza-8-oxaindeno[2,3-b]fluorene-6-yl)-phenyl)germane (hereinafter also referred to as “compound 28-5”); 1,4-bis(4-(7-aza-7H-12-thiaindeno[1,2-a]fluorene-7-yl)phenyl)-5,5-dimethyl-1,3-cyclopentadiene (hereinafter also referred to as “compound 28-6”)

### (Group 29B)

9-(7-cyanotriphenylene-2-yl)-9′-phenyl-3,3′-bis[9H-carbazole] (hereinafter also referred to as “compound 29-1”); 9-(3-(4,6-diphenyl-1,3,5-triazine-2-yl)phenyl)-9′-phenyl-2,3′-bis[9H-carbazole] (hereinafter also referred to as “compound 29-2”); 9-(4′-cyano-1,1′-biphenyl-4-yl)-9′-phenyl-3,3′-bis[9H-carbazole] (hereinafter also referred to as “compound 29-3”)

### (Group 30B)

1,3-bis(9H-carbazole-9-yl)benzene (hereinafter also referred to as “compound 30-1”); bis[4-[9,9-dimethylacridine-10 (9H)-yl]phenyl]sulfone (hereinafter also referred to as “compound 30-2”); 4,4′-bis(9-carbazolyl)-1,1′-biphenyl(hereinafter also referred to as “compound 30-3”); 4,4′-bis(9-carbazolyl)-1,1′-benzophenone (hereinafter also referred to as “compound 30-4”); bis(2-((oxo)diphenylphosphino)phenyl)ether (hereinafter also referred to as “compound 30-5”); 4,4′-bis(9-dimethoxycarbazole)-1,1′-benzophenone (hereinafter also referred to as “compound 30-6”)

### (Group 31B)

11-(4-(1,1′-biphenyl-4-yl)-6-phenyl-1,3,5-triazine-2-yl)-12-phenyl-11H,12H-indolo[2,3-a]carbazole (hereinafter also referred to as “compound 31-1”); 11-(4-(3′-phenyl-1,1′-biphenyl-3-yl)-6-phenyl-1,3,5-triazine-2-yl)-12-phenyl-11H,12H-indolo[2,3-a]carbazole (hereinafter also referred to as “compound 31-2”); 11-(4-(3′-phenyl-1,1′-biphenyl-4-yl)-6-phenyl-1,3,5-triazine-2-yl)-12-phenyl-11H,12H-indolo[2,3-a]carbazole (hereinafter also referred to as “compound 31-3”); 11-(4,6-diphenyl-1,3,5-triazine-2-yl)-12-(4′-phenyl-1,1′-biphenyl-4-yl)-11H,12H-indolo[2,3-a]carbazole (hereinafter also referred to as “compound 31-4”); 11-(4,6-bis(1,1′-biphenyl-4-yl)-1,3,5-triazine-2-yl)-12-phenyl-11H,12H-indolo[2,3-a]carbazole (hereinafter also referred to as “compound 31-5”); 11-(4-(1,1′-biphenyl-4-yl)-6-phenyl-1,3,5-triazine-2-yl)-12-(1,1′-biphenyl-3-yl)-11H,12H-indolo[2,3-a]carbazole (hereinafter also referred to as “compound 31-6”); 9-(1,1′-biphenyl-3-yl)-9′-phenyl-3,3′-bis[9H-carbazole] (hereinafter also referred to as “compound 31-7”); 9-(1,1′-biphenyl-4-yl)-9′-phenyl-3,3′-bis[9H-carbazole] (hereinafter also referred to as “compound 31-8”); 9-(1,1′-biphenyl-3-yl)-9′-(1,1′-biphenyl-4-yl)-3,3′-bis[9H-carbazole] (hereinafter also referred to as “compound 31-9”)

### (Group 32B)

2-(1,1′-biphenyl-3-yl)-4-[3-(9H-carbazole-9-yl)phenyl]-6-(dibenzofuran-3-yl)-1,3,5-triazine (hereinafter also referred to as “compound 32-1”); iridium(III)tris(5′-phenyl-2-phenylpyridyl-N,C₂′) (hereinafter also referred to as “compound 32-2”); 8-(4-(4,6-di(naphthalene-2-yl)-1,3,5-triazine-2-yl)phenyl)quinoline (hereinafter also referred to as “compound 32-3”); Liq (hereinafter also referred to as “compound 32-4”); 2-(1,1′-biphenyl-3-yl)-4-[3-(9H-carbazole-9-yl)phenyl]-6-(dibenzofuran-4-yl)-1,3,5-triazine (hereinafter also referred to as “compound 32-5”); 2-[3′-(9H-carbazole-9-yl)-1,1′-biphenyl-4-yl]-4-(dibenzofuran-3-yl)-6-phenyl-1,3,5-triazine (hereinafter also referred to as “compound 32-6”); 2-[4′-(9H-carbazole-9-yl)-1,1′-biphenyl-3-yl]-4-(dibenzofuran-3-yl)-6-phenyl-1,3,5-triazine (hereinafter also referred to as “compound 32-7”); 2-(1,1′-biphenyl-4-yl)-4-[3-(9H-carbazole-9-yl)phenyl]-6-(dibenzofuran-3-yl)-1,3,5-triazine (hereinafter also referred to as “compound 32-8”); 2-(1,1′-biphenyl-4-yl)-4-[4-(9H-carbazole-9-yl)phenyl]-6-(dibenzofuran-3-yl)-1,3,5-triazine (hereinafter also referred to as “compound 32-9”); 2-[3-(9H-carbazole-9-yl)phenyl]-4-(dibenzofuran-3-yl)-6-phenyl-1,3,5-triazine (hereinafter also referred to as “compound 32-10”); 2-[4-(9H-carbazole-9-yl)phenyl]-4-(dibenzofuran-3-yl)-6-phenyl-1,3,5-triazine (hereinafter also referred to as “compound 32-11”); 2-[3-(3-phenyl-9H-carbazole-9-yl)phenyl]-4-(dibenzofuran-3-yl)-6-phenyl-1,3,5-triazine (hereinafter also referred to as “compound 32-12”); 2-[4-(3-phenyl-9H-carbazole-9-yl)phenyl]-4-(dibenzofuran-3-yl)-6-phenyl-1,3,5-triazine (hereinafter also referred to as “compound 32-13”); 9,9′-bis(1,1′-biphenyl-4-yl)-3,3′-bis[9H-carbazole] (hereinafter also referred to as “compound 32-14”); 5,8-bis(1,1′-biphenyl-4-yl)-5H,8H-indolo[2,3-c]carbazole (hereinafter also referred to as “compound 32-15”); 2-(3-phenyl-9H-carbazole-9-yl)-4-(dibenzofuran-3-yl)-6-phenyl-1,3,5-triazine (hereinafter also referred to as “compound 32-16”); 2-[3-(9H-carbazole-9-yl)phenyl]-4-phenyl-6-(dibenzofuran-3-yl)-pyrimidine (hereinafter also referred to as “compound 32-17”)

### (Group 33B)

2,8-bis(trifluoromethoxy)-10,12-bis(dicyanomethylene)-10,12-dihydroindeno[2,1-b]fluorene (hereinafter also referred to as “compound 33-1”); N-phenyl-N-(1,1′:4′,1″-terphenyl-4-yl)-N′,N′-bis(1,1′-biphenyl-4-yl)-1,1′-biphenyl-4,4′-diamine (hereinafter also referred to as “compound 33-2”); N,N-bis(4-(dibenzofuran-4-yl)phenyl)[1,1′:4′,1″-terphenyl]-4-amine (hereinafter also referred to as “compound 33-3”); biphenyl-2-yl-bis(9,9′-spirobi[9H-fluorene]-2-yl)amine (hereinafter also referred to as “compound 33-4”); 2,8-bis(3,5-bis(trifluoromethyl)phenyl)-10,12-bis(dicyanomethylene)-10,12-dihydroindeno[1,2-b]fluorene (hereinafter also referred to as “compound 33-5”); N-(naphthalene-1-yl)-N-phenyl-N′,N′-bis(1,1′-biphenyl-4-yl)-1,1′-biphenyl-4,4′-diamine (hereinafter also referred to as “compound 33-6”); N,N-bis(1,1′-biphenyl-4-yl)-4-(9-phenyl-9H-carbazole-3-yl)aniline; (hereinafter also referred to as “compound 33-7”); N,N-bis(biphenyl-4-yl)-3′-(9H-carbazole-9-yl)-1,1′-biphenyl-4-amine (hereinafter also referred to as “compound 33-8”); N-biphenyl-2-yl-N-9,9-dimethylfluorene-2-yl-(9,9′-spirobi[9H-fluorene]-2-yl)amine (hereinafter also referred to as “compound 33-9”); 6,12-bis(dicyanomethylene)-2,8-bis(3-trifluoromethyl-4-fluorophenyl)-5,11-diazaindeno[1,2-b]fluorene (hereinafter also referred to as “compound 33-10”); biphenyl-2-yl-bis(9,9′-diphenyl-9H-fluorene-2-yl)amine (hereinafter also referred to as “compound 33-11”); N-(1,1′-biphenyl-4-yl)-N-(9,9-dimethylfluorene-2-yl)-4-(9-phenyl-9H-carbazole-3-yl)aniline (hereinafter also referred to as “compound 33-12”)

In one embodiment, one or more combinations of the first organic compound and the second organic compound selected from the following may also be used. “(AA; BB)” below means a combination of a compound AA and a compound BB. The combination of the first organic compound and the second organic compound in this specification may not be independently one or more combinations selected from the following.
(ADN; TBADN; TBP)
(TBADN; TBP)
(TBADN; 5,6,11,12-tetraphenyltetracene)
(NBP; 5,6,11,12-tetraphenyltetracene)
(9,10-bis[N-(1-phenylamino)biphenyl]; TBP)
(TBADN; TBP)
(Alq; coumarin 545T)
(NPD; Alq3)
(NPD; Alq3; C545T)
(NPD; Alq3; 5,6,11,12-tetraphenyltetracene)
(NPD; DPVBi)
(NPD; 5,6,11,12-tetraphenyltetracene; DPVBi)
(NPD; C545T; 5,6,11,12-tetraphenyltetracene; DPVBi)
(TBADN; TBP)
(TBADN; TBP)
(TBADN; Alq3)
(5,6,11,12-tetraphenyltetracene; DCJTB)
(tetracene; F4-TCNQ)
(NTCDA; LCV)
(F4-TCNQ; 4,4′,4″-tris[phenyl(m-tolyl)amino]triphenylamine)
(F4-TCNQ; TPD)
(compound 9-1; compound 9-2)
(compound 9-3; compound 9-4)
(compound 10-1; compound 10-2)
(2-TNATA; F4-TCNQ)
(compound 10-5; compound 10-6; compound 10-7; compound 10-8)
(compound 10-9; compound 10-10; compound 10-11; compound 10-12)
(compound 12-1; compound 12-2)
(compound 12-1; compound 12-3)
(compound 13-1; compound 13-2)
(compound 14-1; compound 14-2)
(compound 14-3; compound 14-4)
(compound 14-5; compound 14-6)
(compound 14-7; compound 14-8)
(compound 14-9; compound 14-10)
(compound 14-11; compound 14-12)
(compound 14-13; compound 14-14)
(compound 14-15; compound 14-16)
(compound 14-17; compound 14-18)
(compound 14-19; compound 14-20)
(compound 14-21; compound 14-22)
(compound 14-21; compound 14-23)
(compound 14-24; compound 14-25)
(compound 14-26; compound 14-27)
(compound 14-28; compound 14-29)
(compound 14-28; compound 14-30)
(compound 15-1; compound 15-2; compound 15-3)
(compound 15-1; compound 15-4; compound 15-3)
(compound 15-3; compound 15-5)
(compound 15-3; compound 15-6)
(compound 15-1; compound 15-7; compound 15-3)
(compound 15-1; compound 15-8; compound 15-3)
(compound 15-1; compound 15-9; compound 15-3)
(compound 15-1; compound 15-10; compound 15-3)
(compound 15-11; compound 15-3)
(compound 15-42; compound 15-3)
(compound 15-1; compound 15-43; compound 15-3)
(compound 15-1; compound 15-44; compound 15-3)
(compound 16-1; compound 16-2)
(compound 16-1; compound 16-3)
(compound 16-4; compound 16-5)
(compound 16-1; compound 16-6)
(compound 17-1; compound 17-2)
(compound 17-1; compound 17-3)
(compound 18-1; compound 18-2)
(compound 18-3; compound 18-2)
(compound 18-4; compound 18-2)
(compound 18-5; compound 18-2)
(compound 18-6; compound 18-7)
(compound 18-6; compound 18-8)
(compound 18-9; compound 18-10)
(compound 18-9; compound 18-11)
(compound 18-12; compound 18-13)
(compound 18-12; compound 18-14)
(compound 18-12; compound 18-15)
(compound 18-16; compound 18-8)
(compound 18-16; compound 18-7)
(compound 18-16; compound 18-17)
(compound 18-18; compound 18-19)
(compound 18-18; compound 18-20)
(compound 18-21; compound 18-7)
(compound 18-21; compound 18-8)
(compound 18-22; compound 18-23)
(compound 18-24; compound 18-25)
(compound 18-26; compound 18-27)
(compound 19-1; compound 19-2)
(compound 19-3; compound 19-4)
(compound 19-1; compound 19-4)
(compound 20-1; compound 20-10)
(compound 20-2; compound 20-11)
(compound 20-2; compound 20-12)
(compound 20-3; compound 20-13)
(compound 20-3; compound 20-14)
(compound 20-3; compound 20-15)
(compound 20-3; compound 20-16)
(compound 20-4; compound 20-17)
(compound 20-4; compound 20-16)
(compound 20-4; compound 20-10)
(compound 20-5; compound 20-18)
(compound 20-5; compound 20-19)
(compound 20-6; compound 20-17)
(compound 20-6; compound 20-10)
(compound 20-7; compound 20-18)
(compound 20-8; compound 20-18)
(compound 20-9; compound 20-16)
(compound 21-1; compound 21-2)
(compound 21-3; compound 21-2)
(compound 21-4; compound 21-5)
(compound 21-4; compound 21-5; compound 21-6)
(compound 22-1; compound 22-13)
(compound 22-1; compound 22-13)
(compound 22-2; compound 22-15)
(compound 22-2; compound 22-16)
(compound 22-3; compound 22-17)
(compound 22-3; compound 22-18)
(compound 22-3; compound 22-19)
(compound 22-4; compound 22-14)
(compound 22-4; compound 22-13)
(compound 22-4; compound 22-20)
(compound 22-5; compound 22-21)
(compound 22-5; compound 22-22)
(compound 22-6; compound 22-13)
(compound 22-6; compound 22-14)
(compound 22-7; compound 22-23)
(compound 22-8; compound 22-24)
(compound 22-9; compound 22-25)
(compound 22-10; compound 22-13)
(compound 22-11; compound 22-26)
(compound 22-12; compound 22-13)
(compound 23-1; compound 23-4)
(compound 23-1; compound 23-5)
(compound 23-1; compound 23-6)
(compound 23-1; compound 23-7)
(compound 23-2; compound 23-4)
(compound 23-2; compound 23-5)
(compound 23-2; compound 23-6)
(compound 23-3; compound 23-4)
(compound 23-3; compound 23-5)
(compound 23-8; compound 23-9)
(compound 24-1; compound 24-4)
(compound 24-2; compound 24-5)
(compound 24-3; compound 24-5)
(compound 25-1; compound 25-2)
(compound 25-1; compound 25-3)
(compound 25-4; compound 25-2)
(compound 25-4; compound 25-3)
(compound 25-5; compound 25-6)
(compound 25-7; compound 25-8)
(compound 26-1; compound 26-3)
(compound 26-1; compound 26-4)
(compound 26-1; compound 26-5)
(compound 26-2; compound 26-6)
(compound 28-1; compound 28-2)
(compound 28-3; compound 28-4)
(compound 28-5; compound 28-6)
(compound 29-1; compound 29-2)
(compound 29-3; compound 29-2)
(compound 30-1; compound 30-2)
(compound 30-3; compound 30-4)
(compound 30-5; compound 30-6)
(compound 31-1; compound 31-7)
(compound 31-2; compound 31-8)
(compound 31-3; compound 31-8)
(compound 31-3; compound 31-9)
(compound 31-4; compound 31-8)
(compound 31-5; compound 31-9)
(compound 31-6; compound 31-8)
(compound 32-1; compound 32-2)
(compound 32-3; compound 32-4)
(compound 32-5; compound 32-2)
(compound 32-6; compound 32-2)
(compound 32-7; compound 32-2)
(compound 32-8; compound 32-2)
(compound 32-9; compound 32-2)
(compound 32-10; compound 32-2)
(compound 32-11; compound 32-2)
(compound 32-12; compound 32-2)
(compound 32-13; compound 32-2)
(compound 32-8; compound 32-14; compound 32-2)
(compound 32-9; compound 32-14; compound 32-2)
(compound 32-12; compound 32-14; compound 32-2)
(compound 32-13; compound 32-14; compound 32-2)
(compound 32-6; compound 32-14; compound 32-2)
(compound 32-7; compound 32-14; compound 32-2)
(compound 32-12; compound 32-15; compound 32-2)
(compound 32-16; compound 32-15; compound 32-2)
(compound 32-10; compound 32-14; compound 32-2)
(compound 32-17; compound 32-14; compound 32-2)
(compound 33-1; compound 33-2)
(compound 33-1; compound 33-3)
(compound 33-1; compound 33-4)
(compound 33-5; compound 33-2)
(compound 33-5; compound 33-6)
(compound 33-5; compound 33-3)
(compound 33-5; compound 33-7)
(compound 33-5; compound 33-8)
(compound 33-5; compound 33-9)
(compound 33-10; compound 33-6)
(compound 33-5; compound 33-11)
(compound 33-10; compound 33-6)
(compound 33-10; compound 33-3)
(compound 33-10; compound 33-11)
(compound 33-10; compound 33-7)
(compound 33-5; compound 33-12)

### (Other Components, etc.)

In one embodiment, the mixed powder may or may not contain a component other than the first organic compound.

In one embodiment, the mixed powder does not contain a phosphorescent emitting compound.

In one embodiment, the mixed powder does not contain a heavy metal complex.

In one embodiment, the mixed powder consists of the first component and the second component, or consists essentially of the first component and the second component. In the latter case, the mixed powder may contain inevitable impurities.

In one embodiment, the mixed powder contains the first component and the second component in an amount of 80% by mass or more, 90% by mass or more, 95% by mass or more, 99% by mass or more, 99.5% by mass or more, 99.9% by mass or more, 99.99% by mass or more, or 100% by mass.

### (Method of Producing Powder, Etc.)

The mixed powder may be composed of particles containing the first organic compound and the second organic compound in one particle, or may be a mixture composed of a powder of the first organic compound and a powder of the second organic compound.

As a method of producing a powder, for example, a method wherein the first organic compound and the second organic compound is pulverized and mixed using a mortar or the like, or a method wherein the first organic compound and the second organic compound is placed in a container or the like, heated and melted in a chemically inert environment, followed by cooling to an ambient temperature, and the obtained mixture may be pulverized by a mixer or the like to obtain a powder may be given. By the latter method, the first organic compound and the second organic compound can be mixed at the molecular level. As a result, the ratio of sublimation areas of both the compounds can be easily controlled to a desired range, and more uniform vapor deposition can be performed. In addition, it is possible to prevent a problem such as uneven mixing that may occur during conveyance of the mixed powder.

The mixed powder may be formed into pellets by compression molding.

### <Method of Vapor-Depositing and Conditions for Vapor Deposition>

In the method of vapor-depositing according to one aspect of the invention, the other conditions are not particularly limited, a general vapor deposition equipment and general conditions for vapor deposition may be employed, as long as the method includes a step of vaporizing the above-mentioned mixed powder from a single vapor deposition source to form a film on a surface to be vapor-deposited of an opposing base material located above the vapor deposition source.

Vapor deposition is usually carried out under vacuum (under a pressure lower than atmospheric pressure). The pressure inside the apparatus during the vapor deposition is preferably 5.0 Pa or lower, more preferably 1.0 Pa or lower. The heating temperature during the vapor deposition is usually 150° C. to 400° C., and preferably 200° C. to 350° C.

In the method of vapor-depositing according to one aspect of the invention, a mixed powder which is obtained by melt-mixing a powder of a first organic compound and a powder of a second organic compound to obtain a solidified material, and pulverizing the solidified material, may be used to the vapor deposition. By the use of the mixed powder obtained as described above, the ratio of sublimation areas of both the compounds can be easily adjusted to a desired range.

Alternatively, as described above, the mixed powder may be compressed in advance to form pellets, and the pellets may be put into a vapor deposition source to perform the vapor deposition.

In the method of vapor-depositing according to one aspect of the invention, the distance between the opening of a vapor deposition source and a base material (the distance between a vapor deposition source and a substrate, the distance between S—S) is, for example, 20 to 600 mm.

### <Applicable Technical Field>

The method of vapor-depositing according to one aspect of the invention can be applied to any technical field including vapor deposition of an organic compound to form a film, and can be applied to, for example, fabrication of organic semiconductor devices such as an organic EL device, an organic transistor, an organic solar cell, and the like. As an example, a method of fabricating an organic EL device using the method of vapor-depositing according to one aspect of the invention will be described below.

### [Method of Fabrication of Organic EL Device]

A method of fabricating an organic EL device according to one aspect of the invention is a method of fabricating an organic EL device including a cathode, an anode, and one or more organic layers including an emitting layer disposed between the cathode and the anode, which includes a step of vaporizing a mixed powder from a vapor deposition source to deposit at least one layer of the one or two or more organic layers, wherein

the mixed powder includes a first organic compound and a second organic compound, and the following formula (1) is satisfied for the mixed powder:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

The mixed powder and the method of vapor-depositing in the above method of fabrication are as described above in the method of vapor-depositing in one aspect of the invention. As the mixed powder, a first organic compound and a second organic compound which are materials for an organic EL device are used.

As the device configuration of the organic EL device, the structures obtained by stacking structures represented by each of the following (1) to (4) on a substrate are exemplified.

(1) anode/emitting layer/cathode
(2) anode/hole-transporting zone/emitting layer/cathode
(3) anode/emitting layer/electron-transporting zone/cathode
(4) anode/hole-transporting zone/emitting layer/electron-transporting zone/cathode

“/” indicates that the layers are stacked directly adjacent to each other.

The electron-transporting zone is a region composed of one, or two or more organic layers containing an electron-transporting compound (also referred to as an “electron-transport layer” and/or an “electron-injecting layer”), and the hole-transporting zone is a region composed of one, or two or more organic layers containing a hole-transporting compound (also referred to as a “hole-transporting layer” and/or a “hole-injecting layer”).

In the method of fabricating an organic EL device according to one aspect of the invention, at least one layer in the organic layers of the organic EL device is formed by a vapor deposition process using the mixed powder. The layer to be formed by the use of the mixed powder is not particularly limited, and may be any organic layer. Two or more layers of the organic layers may be formed by a vapor deposition process using the mixed powder.

Examples of the combinations of a first organic compound and a second organic compound [first organic compound, second organic compound] in the mixed powder used for the film formation of an organic layer include, but are not limited to, [a host material for an emitting layer, and a host material for an emitting layer], [a host material for an emitting layer, and a dopant material for an emitting layer], [a host material for an emitting layer, and a material for a hole-transporting layer], [a material for a hole-transporting layer, and a material for a hole-transporting layer], [a material for an electron-transporting layer, and a material for an electron-transporting layer], [a host material for an emitting layer, and a material for an electron-transporting layer], and the like. As the above-described host material for an emitting layer, a blue emitting host material for an emitting layer can be used, for example.

Note that the method of forming each layer other than the layer to be formed by the vapor deposition of the above-mentioned mixed powder is not particularly limited, and a method of film formation by a vacuum deposition process using a single material, a spin coating process, or the like can be used.

Each layer of the organic EL device will be described below.

### (Substrate)

A substrate is used as a support of an emitting device. As the material for the substrate, glass, quartz, plastics or the like can be used, for example. Further, a flexible substrate may be used. The “flexible substrate” means a bendable (flexible) substrate, and specific examples thereof include plastic substrates formed each of polycarbonate, polyvinyl chloride, and the like.

### (Anode)

For the anode formed on the substrate, metals, alloys, electrically conductive compounds, mixtures thereof, and the like, which have a large work function (specifically 4.0 eV or larger) are preferably used. Specific examples include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition thereto, gold (Au), platinum (Pt), a nitride of a metallic material (for example, titanium nitride), and the like may be given.

### (Hole-Injecting Layer)

The hole-injecting layer is a layer containing a substance having a high hole-injecting property. As such a substance having a high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, or a polymer compound (oligomers, dendrimers, polymers, etc.) can be given.

### (Hole-Transporting Layer)

The hole-transporting layer is a layer containing a substance having a high hole-transporting property. For the hole-transporting layer, an aromatic amine compound, a carbazole derivative, an anthracene derivative, or the like can be used. A polymer compound such as poly(N-vinylcarbazole) (abbreviation: PVK) and poly(4-vinyltriphenylamine) (abbreviation: PVTPA) can also be used. However, substances other than the above-described substances may be used as long as they have a hole-transporting property higher than an electron-transporting property. It should be noted that the layer containing the material having a high hole-transporting property may be formed into not only a monolayer, but also a stacked layer in which two or more layers formed each of the above-described materials are stacked.

### (Guest (Dopant) Material for Emitting Layer)

The emitting layer is a layer containing a substance having a high emitting property, and can be formed of varioussubstances. For example, as the substance having a high emitting property, a fluorescent compound which emits fluorescence and a phosphorescent compound which emits phosphorescence can be used. The fluorescent compound is a compound which can emit from a singlet excited state, and the phosphorescent compound is a compound which can emit from a triplet excited state.

As a blue fluorescent emitting material which can be used for an emitting layer, pyrene derivatives, styrylamine derivatives, chrysene derivatives, fluoranthene derivatives, fluorene derivatives, diamine derivatives, triarylamine derivatives, and the like may be given. As a green fluorescent emitting material which can be used for an emitting layer, aromatic amine derivatives and the like may be given. As a red fluorescent emitting material which can be used for an emitting layer, tetracene derivatives, diamine derivatives and the like may be given.

As a blue phosphorescent emitting material which can be used for an emitting layer, metal complexes such as iridium complexes, osmium complexes, platinum complexes and the like may be given. As a green phosphorescent emitting material which can be used for an emitting layer, iridium complexes and the like may be given. As a red phosphorescent emitting material which can be used for an emitting layer, metal complexes such as iridium complexes, platinum complexes, terbium complexes, europium complexes and the like may be given.

### (Host Material for Emitting Layer)

The emitting layer may have a constitution in which the above-mentioned substance having a high emitting property (guest material) is dispersed in another substance (host material). As a substance for dispersing the substance having a high emitting property, a variety of substances can be used, and it is preferable to use a substance which has a lowest unoccupied orbital level (LUMO level) higher than that of the substance having a high emitting property, and a highest occupied orbital level (HOMO level) lower than the substance having a high emitting property.

As a substance (host material) for dispersing a substance having a high emitting property, 1) metal complexes such as aluminum complexes, beryllium complexes, and zinc complexes, 2) heterocyclic compounds such as oxadiazole derivatives, benzimidazole derivatives, and phenanthroline derivatives, 3) fused aromatic compounds such as carbazole derivatives, anthracene derivatives, phenanthrene derivatives, pyrene derivatives, and chrysene derivatives, and 4) aromatic amine compounds such as triarylamine derivatives and condensed polycyclic aromatic amine derivatives are used.

### (Electron-Transporting Layer)

An electron-transporting layer is a layer containing a substance having high electron-transporting property. For the electron-transporting layer, 1) metal complexes such as aluminum complexes, beryllium complexes, zinc complexes, or the like; 2) heteroaromatic complexes such as imidazole derivatives, benzimidazole derivatives, azine derivatives, carbazole derivatives, phenanthroline derivatives, or the like; and 3) polymer compounds can be used.

In one embodiment of the invention, the electron-transporting layer may or may not contain other substances described above in addition to the first organic compound and the second organic compound described above.

### (Electron-Injecting Layer)

An electron-injecting layer is a layer containing a substance having a high electron-injecting property. For the electron-injecting layer, lithium (Li), ytterbium (Yb), lithium fluoride (LiF), cesium fluoride (CsF), calcium fluoride (CaF₂), metal complex compounds such as 8-hydroxyquinolinolato-lithium (Liq); alkali metal, alkaline earth metals and a compound thereof such as lithium oxide (LiOₓ) can be used.

### (Cathode)

For the cathode, metals, alloys, electrically conductive compounds, mixtures thereof, and the like which have a small work function (specifically, 3.8 eV or smaller) are preferably used. Specific examples of the cathode material include elements belonging to Group 1 or Group 2 of the Periodic Table of the Elements, i.e., alkali metals such as lithium (Li) and cesium (Cs), alkaline earth metals such as magnesium (Mg), calcium (Ca) and strontium (Sr), and alloys containing these metals (e.g., MgAg and AlLi); rare earth metals such as europium (Eu) and ytterbium (Yb), and alloys containing these metals.

The cathode is usually formed by a vacuum vapor deposition process or a sputtering method. Further, in the case of using a silver paste or the like, a coating method, an inkjet method, or the like can be employed.

Moreover, when the electron-injecting layer is provided, the cathode may be formed of a material selected from various electrically conductive materials such as aluminum, silver, ITO, graphene, indium oxide-tin oxide containing silicon or silicon oxide, regardless of large or small of the work function.

The thickness of each layer is not particularly limited, but is generally preferable that the thickness be in the range of several nm to 1 μm, in order to suppress defects such as pinholes, to decrease applied voltage to be low, and to increase luminous efficiency.

### [Mixed Powder]

The mixed powder according to one aspect of the invention is a mixed powder containing a first organic compound and a second organic compound, wherein the following formula (1) is satisfied:

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

Each condition in the above mixed powder is as described in the method of depositing according to one aspect of the invention described above.

The mixed powder according to one aspect of the invention can be used for a vapor deposition process, and can be applied to any technical field including film formation by vapor deposition of an organic compound.

In one embodiment, the mixed powder is an organic semiconductor material, e.g., a material for an organic EL device, a material for an organic transistor, or a material for an organic solar cell.

In one embodiment, the first organic compound and the second organic compound are both organic semiconductor materials, e.g., materials for an organic EL device, materials for an organic transistor, or materials for an organic solar cell.

As described in the method of depositing according to one aspect of the invention, the first organic compound and the second organic compound are different compounds from each other.

The expression “the first organic compound and the second organic compound are different compounds from each other” includes a case in which their chemical structural formulas (skeletons) are different from each other, and a case in which their chemical structural formulas (skeletons) are the same but contain a different isotope. The “isotope” means an atom having the same in their atomic number but different in the number of neutrons. For example, benzene (C₆H₆) and deuterated benzene (C₆D₆) are different components from each other.

In the case where their chemical structural formulas (skeletons) are the same but contain a different isotope, the compounds are also different in a case where just the number or position of the isotope is different from each other. For example, even in deuterated benzene, C₆H₅D₁ and C₆D₆ are compounds different from each other because the number of isotopes is different. For example, even among compounds represented by C₆H₄D₂, a compound having deuterium atoms at positions 1 and 2 of a benzene ring and a compound having deuterium atoms at positions 1 and 3 of a benzene ring are compounds different from each other because the position of isotopes is different.

### [Method of Selecting Organic Compounds]

The method of selecting an organic compound according to one aspect of the invention is a method of selecting a first organic compound and a second organic compound contained in a mixed powder, including selecting the first organic compound and the second organic compound so as to satisfy the following formula (1):

|θ₁−θ₂|≥10° (1)

where

θ₁: a spread angle of a vapor deposition trajectory when a powder consisting of the first organic compound is vapor-deposited on a base material from a vapor deposition source, and

θ₂: a spread angle of a vapor deposition trajectory when a powder consisting of the second organic compound is vapor-deposited on a base material from a vapor deposition source.

Each condition in the above method of selecting is as described in the method of depositing and the mixed powder according to each of an aspect of the invention described above.

### EXAMPLES

Now, Examples according to the invention will be described. The invention is not limited in any way by these Examples.

Compounds used in Examples and Comparative Examples are shown below.

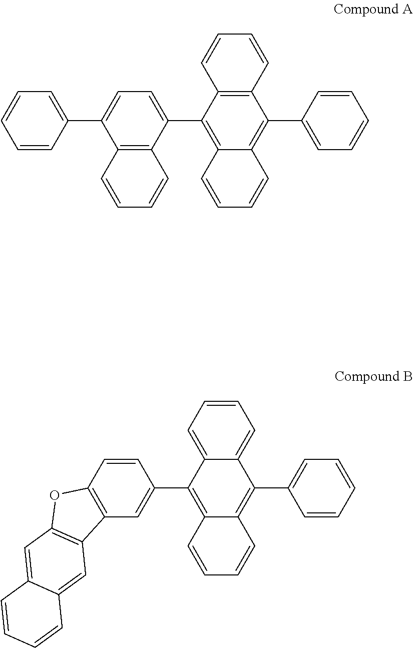

Conditions for the method of measuring a spread angle θ of a vapor deposition trajectory is as follows. Conditions not described below are as described above.
Vapor deposition equipment: “EBX-8C” manufactured by ULVAC, Inc. was used with a partial setting change for this measurement.
Crucible: a crucible having cylindrical shape with one end closed (the hollow part is cylindrical, the inner diameter of the hollow part is 10 mm, the total length of the hollow part is 77 mm, and made of aluminum nitride)
Vacuum degree: 2×10⁻⁴ Pa or less made by evacuating the chamber with a scroll pump and a cryopump
Substrate: an alkali-free glass substrate
Method of measuring film thickness: vapor deposition was carried out after placing a mask to form steps for measuring the film thickness on the surface of the substrate to be vapor-deposited. After completion of vapor deposition, the mask was removed, and by using the step film thickness meter (surface roughness measuring instrument (SURFCORDER), manufactured by Kosaka Laboratory Ltd.), the height of the steps (film thickness) formed by the mask was measured from the center of the substrate toward the longitudinal direction. FIG. 3 is a schematic diagram of masks 201 placed on the surface of the substrate 102 to be vapor-deposited. In FIG. 3, the length of M1 is 10 mm, the length of M2 is 1 mm, and the length of M3 is 2 mm. Note that the scale in FIG. 3 is not accurate.

### Example 1

Vapor deposition was performed using a mixed powder obtained by mixing a powder of the compound A with a powder of the compound B whose spread of the vapor deposition trajectory is smaller than that of the compound A, and it was confirmed that the spread of the vapor deposition trajectory of the mixed powder was smaller than that of the compound A.

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group” is a “ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

“Substituted or Unsubstituted Aryl Group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group” is an “aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group GIB1 and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

Unsubstituted Aryl Group (Specific Example Group G1A):

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a m-terphenyl-3-yl group,

a m-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenalenyl group,

a pyrenyl group,

a chrysenyl group,

a benzochrysenyl group,

a triphenylenyl group,

a benzotriphenylenyl group,

a tetracenyl group,

a pentacenyl group,

a fluorenyl group,

a 9,9′-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by any of the following general formulas (TEMP-1) to (TEMP-15).

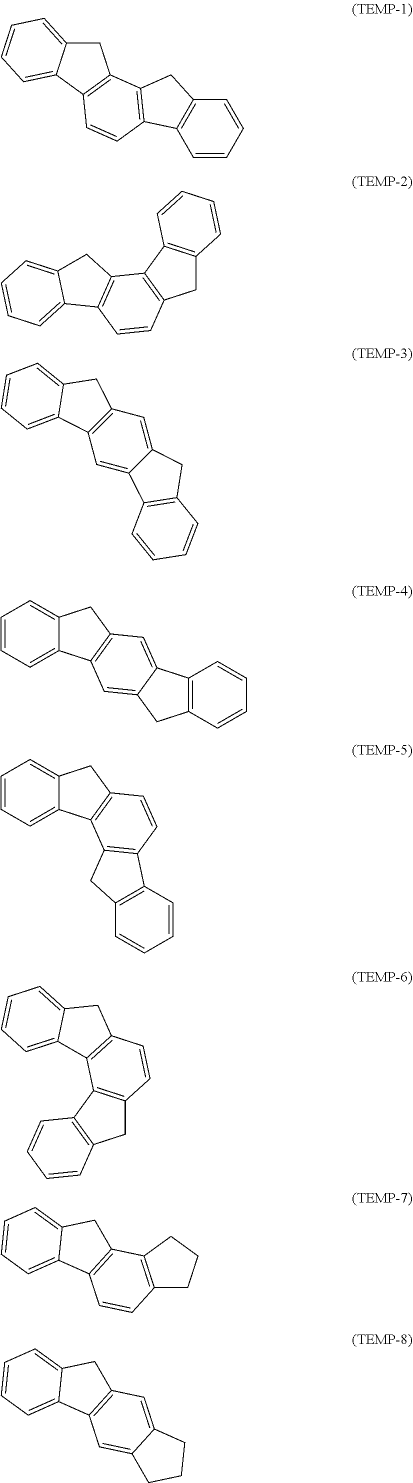

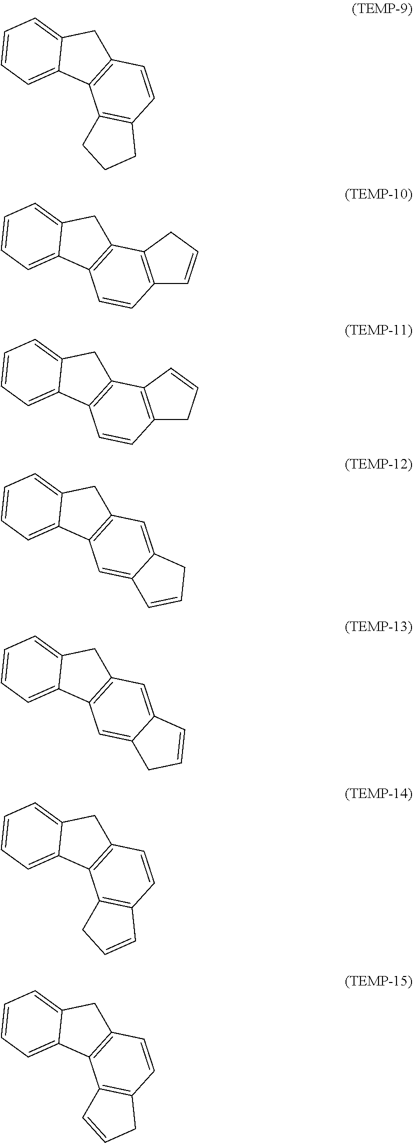

Substituted Aryl Group (Specific Example Group G1B):

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by any of the general formulas (TEMP-1) to (TEMP-15) are substituted by a substituent.

“Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group” is a “heterocyclic group unsubstituted by a substituent”, and the substituted heterocyclic group refers to the case where the “substituted or unsubstituted heterocyclic group” is a “heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).

Unsubstituted Heterocyclic Group Containing a Nitrogen Atom (Specific Example Group G2A1):

a pyrrolyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadiazolyl group,

a pyridyl group,

a pyridazinyl group,

a pyrimidinyl group,

a pyrazinyl group,

a triazinyl group,

an indolyl group,

an isoindolyl group,

an indolizinyl group,

a quinolizinyl group,

a quinolyl group,

an isoquinolyl group,

a cinnolyl group,

a phthalazinyl group,

a quinazolinyl group,

a quinoxalinyl group,

a benzimidazolyl group,

an indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazolyl group, and

a diazacarbazolyl group.

Unsubstituted Heterocyclic Group Containing an Oxygen Atom (Specific Example Group G2A2):

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.

Unsubstituted Heterocyclic Group Containing a Sulfur Atom (Specific Example Group G2A3):

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).

Monovalent Heterocyclic Group Derived by Removing One Hydrogen Atom from the Ring Structures Represented by any of the Following General Formulas (TEMP-16) to (TEMP-33) (Specific Example Group G2A4):

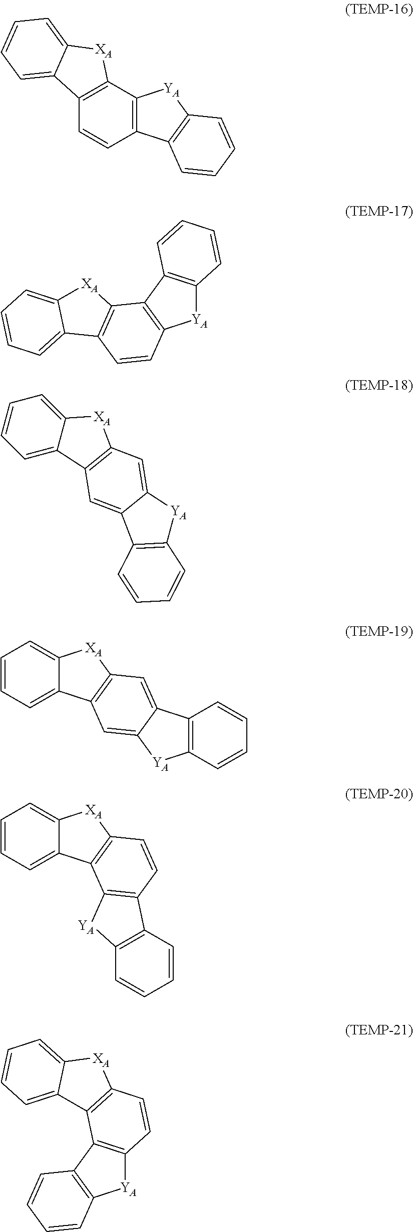

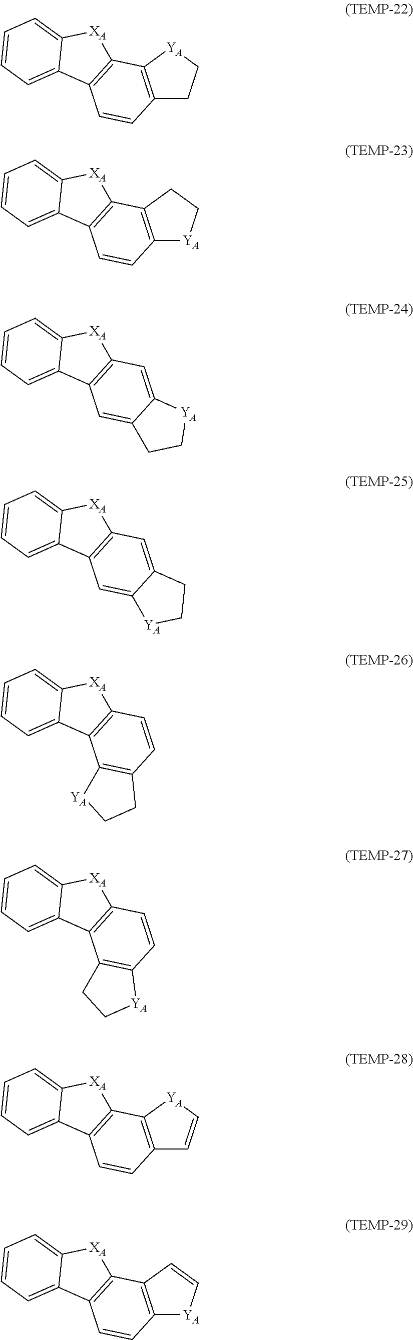

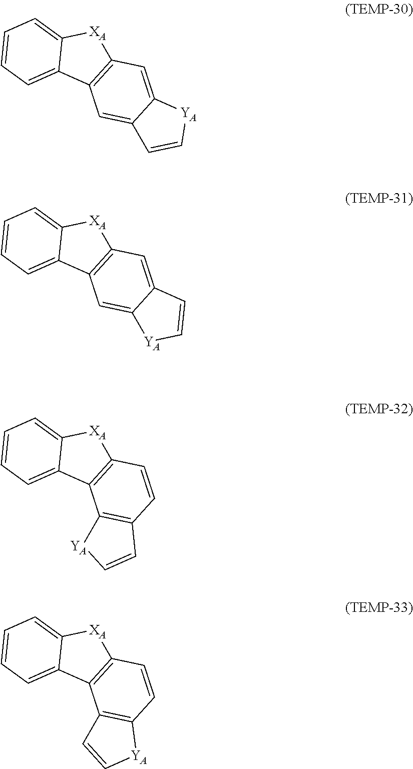

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by any of the general formulas (TEMP-16) to (TEMP-33) includes a monovalent group derived by removing one hydrogen atom from these NH or CH₂.

Substituted Heterocyclic Group Containing a Nitrogen Atom (Specific Example Group G2B1):

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.

Substituted Heterocyclic Group Containing an Oxygen Atom (Specific Example Group G2B2):

a phenyldibenzofuranyl group,

a methyldibenzofuranyl group,

a t-butyldibenzofuranyl group, and

a monovalent residue of spiro[9H-xanthene-9,9′-[9H]fluorene].

Substituted heterocyclic group containing a sulfur atom (specific example group G2B3):

a phenyldibenzothiophenyl group,

a methyldibenzothiophenyl group,

a t-butyldibenzothiophenyl group, and

a monovalent residue of spiro[9H-thioxanthene-9,9′-[9H]fluorene].

Group in which One or More Hydrogen Atoms of the Monovalent Heterocyclic Group Derived from the Ring Structures Represented by any of the Following General Formulas (TEMP-16) to (TEMP-33) are Substituted by a Substituent (Specific Example Group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

“Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group” is an “alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

Unsubstituted Alkyl Group (Specific Example Group G3A):

a methyl group,

an ethyl group,

a n-propyl group,

an isopropyl group,

a n-butyl group,

an isobutyl group,

a s-butyl group, and

a t-butyl group.

Substituted alkyl group (specific example group G3B):

a heptafluoropropyl group (including isomers),

a pentafluoroethyl group,

a 2,2,2-trifluoroethyl group, and

a trifluoromethyl group.

“Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

Unsubstituted Alkenyl Group (Specific Example Group G4A):

a vinyl group,

an allyl group,

a 1-butenyl group,

a 2-butenyl group, and

a 3-butenyl group.

Substituted Alkenyl Group (Specific Example Group G4B):

a 1,3-butanedienyl group,

a 1-methylvinyl group,

a 1-methylallyl group,

a 1,1-dimethylallylgroup,

a 2-methylally group, and

a 1,2-dimethylallylgroup.

“Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

Unsubstituted Alkynyl Group (Specific Example Group G5A):

an ethynyl group.

“Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group” is a “cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent.

Unsubstituted Cycloalkyl Group (Specific Example Group G6A):

a cyclopropyl group,

a cyclobutyl group,

a cyclopentyl group,

a cyclohexyl group,

a 1-adamantyl group,

a 2-adamantyl group,

a 1-norbornyl group, and

a 2-norbornyl group.

Substituted Cycloalkyl Group (Specific Example Group G6B):

a 4-methylcyclohexyl group.

“Group Represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same as or different from each other.

Plural G2's in —Si(G1)(G2)(G2) are the same as or different from each other.

Plural G1's in —Si(G1)(G1)(G2) are the same as or different from each other.

Plural G2's in —Si(G2)(G2)(G2) are be the same as or different from each other.

Plural G3's in —Si(G3)(G3)(G3) are the same as or different from each other.

Plural G6's in —Si(G6)(G6)(G6) are be the same as or different from each other.

“Group Represented by —O—(R₉₀₄)”

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group Represented by —S—(R₉₀₅)”

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group Represented by —N(R₉₀₆)(R₉₀₇)”

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same as or different from each other.

Plural G2's in —N(G2)(G2) are the same as or different from each other.

Plural G3's in —N(G3)(G3) are the same as or different from each other.

Plural G6's in —N(G6)(G6) are the same as or different from each other.

“Halogen Atom”

Specific examples of the “halogen atom” described in this specification (specific example group G11) include a fluorine atom, a chlorine atom, a bromine atom, an iodine atom, and the like.

“Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

“Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

“Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

“Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

“Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

“Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

“Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same as or different from each other. The number of carbon atoms in each alkyl group of the “trialkylsilyl group” is 1 to 50, preferably 1 to 20, more preferably 1 to 6, unless otherwise specified in this specification.

“Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

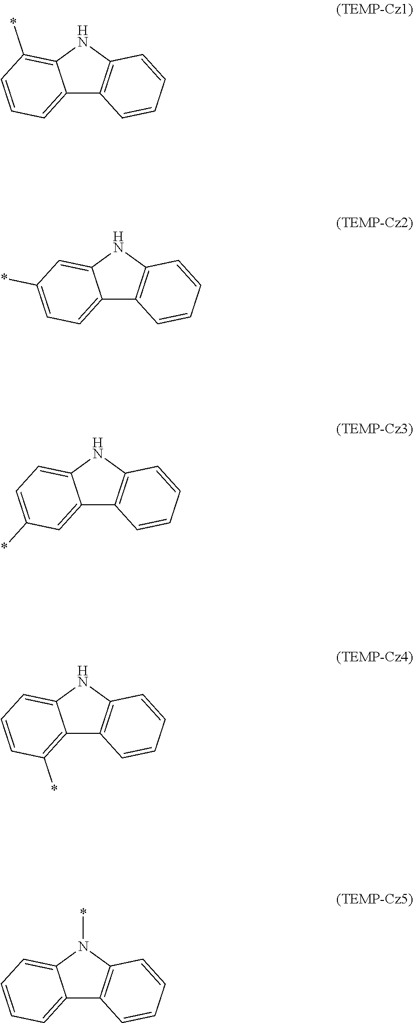 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

In this specification, the (9-phenyl)carbazolyl group is specifically any of the following groups, unless otherwise specified in this specification.

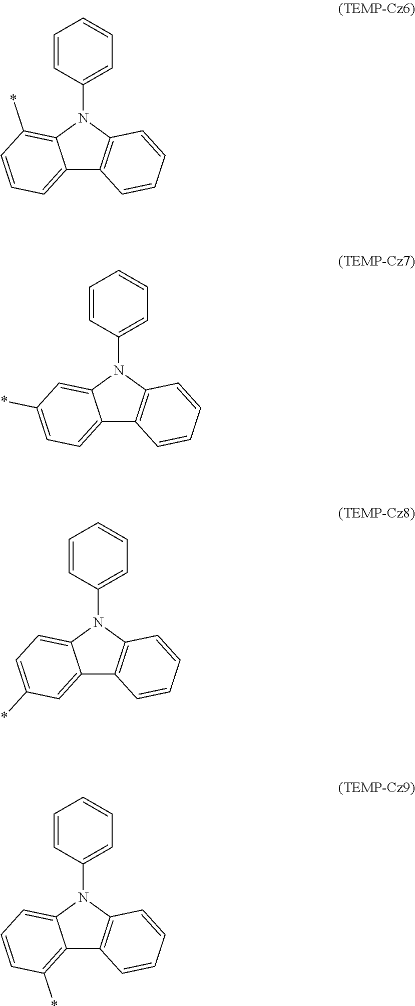 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

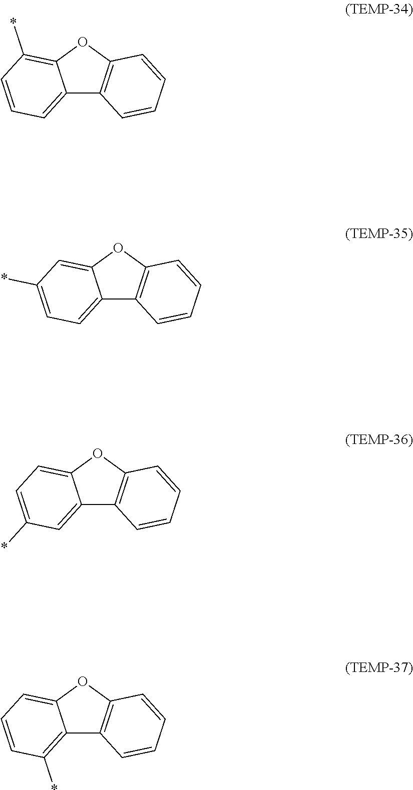 [SMILES: *c1cccc2c1oc1ccccc12 ; *c1ccc2c(c1)oc1ccccc12 ; *c1ccc2oc3ccccc3c2c1 ; *c1cccc2oc3ccccc3c12]

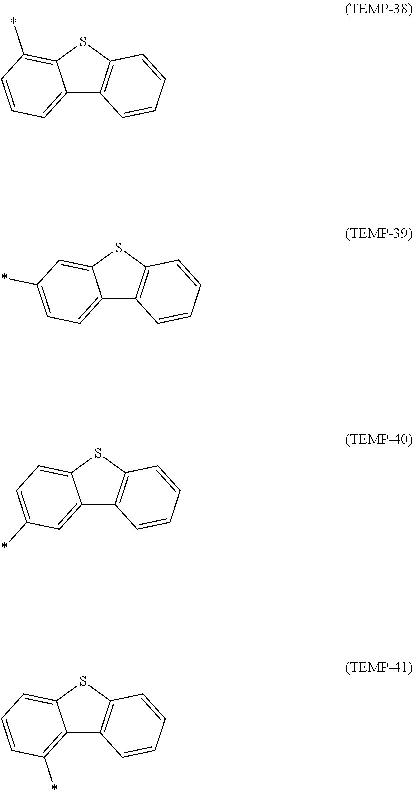 [SMILES: *c1cccc2c1sc1ccccc12 ; *c1ccc2c(c1)sc1ccccc12 ; *c1ccc2sc3ccccc3c2c1 ; *c1cccc2sc3ccccc3c12]

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

“Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

“Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

“Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

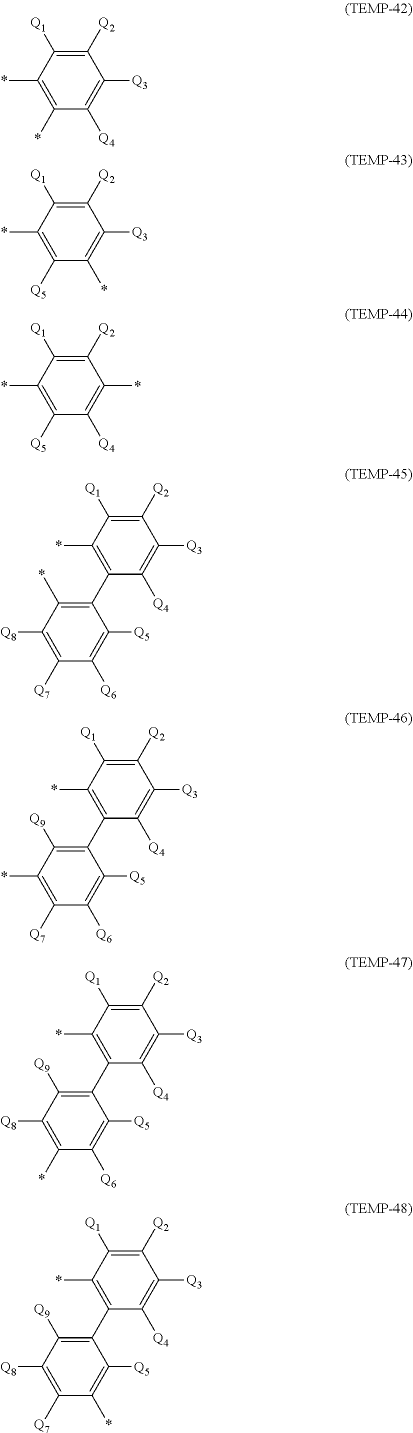

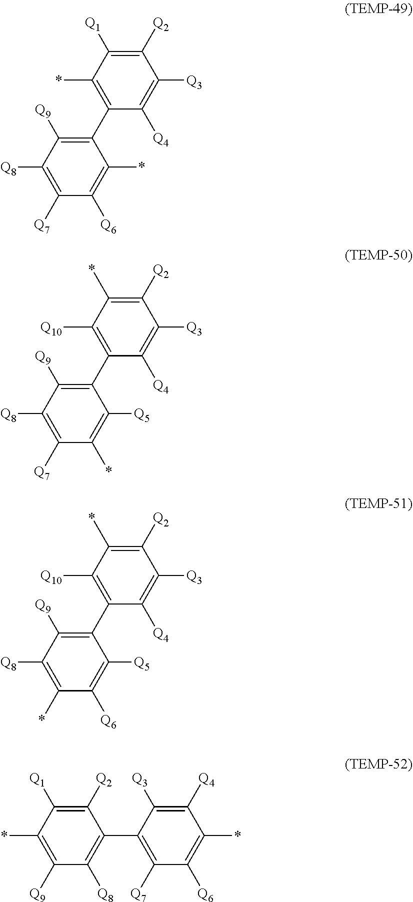

In the general formulas (TEMP-42) to (TEMP-52), Q₁ to Q₁₀ are independently a hydrogen atom or a substituent.

In the general formulas (TEMP-42) to (TEMP-52), * represents a bonding site.

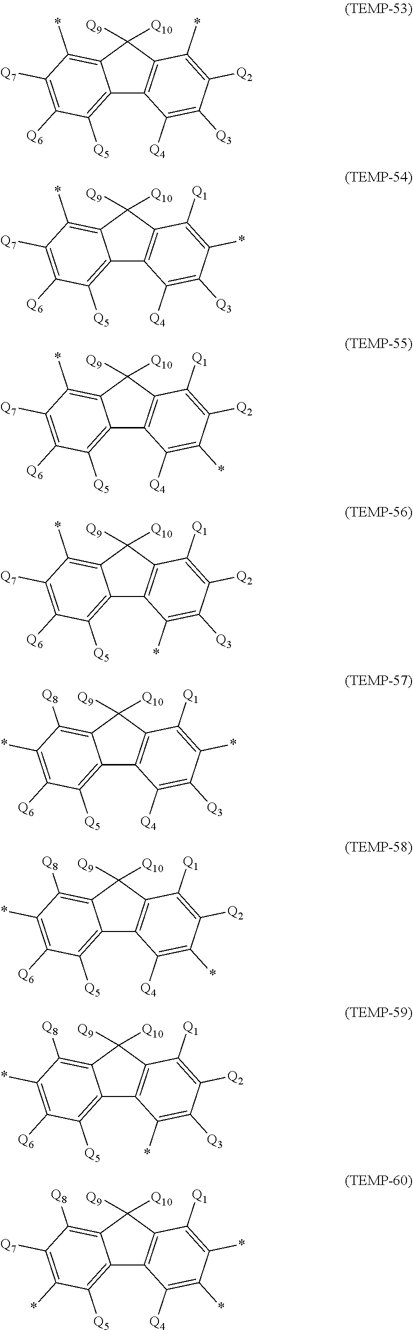

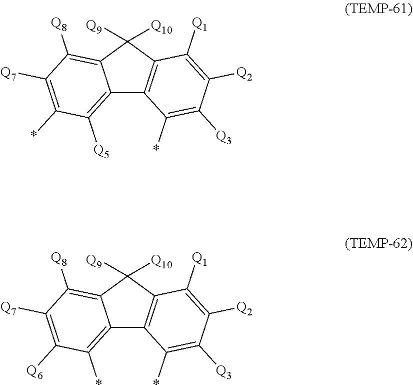

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

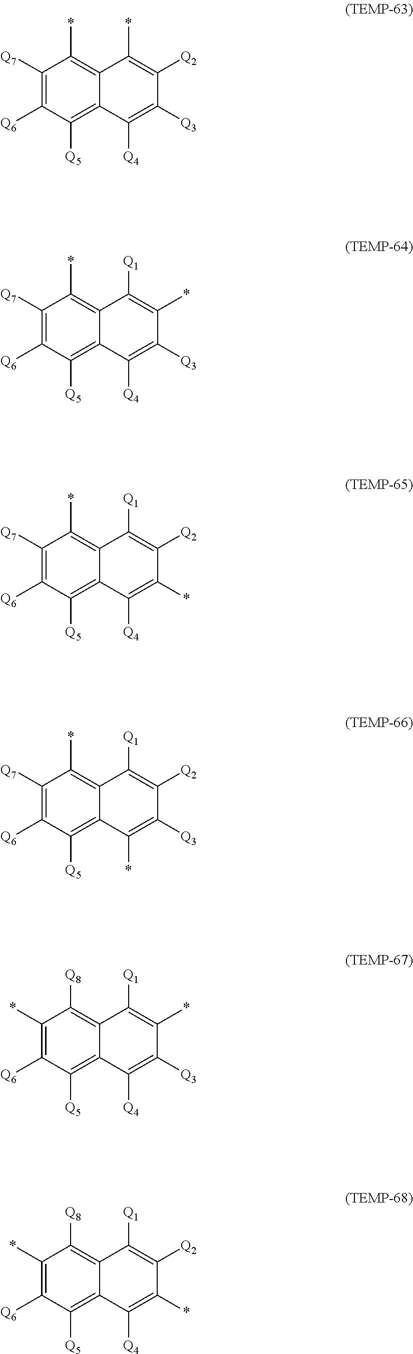

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

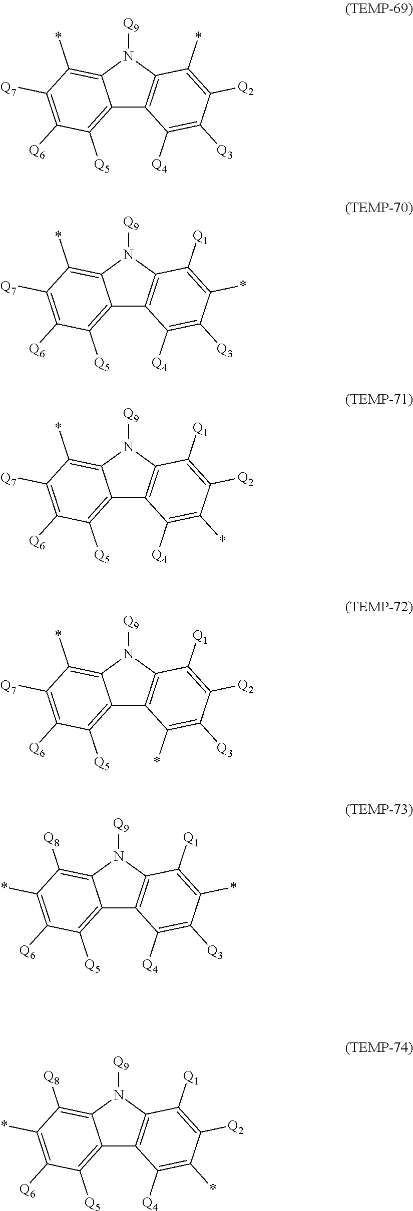

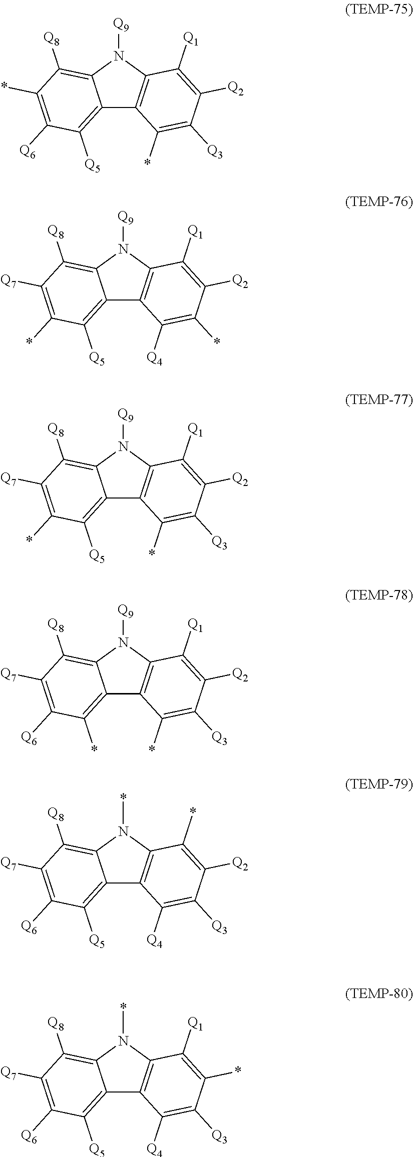

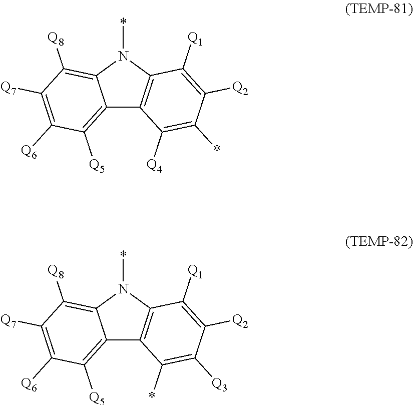

In the general formulas (TEMP-69) to (TEMP-82), Q₁ to Q₉ are independently a hydrogen atom or a substituent.

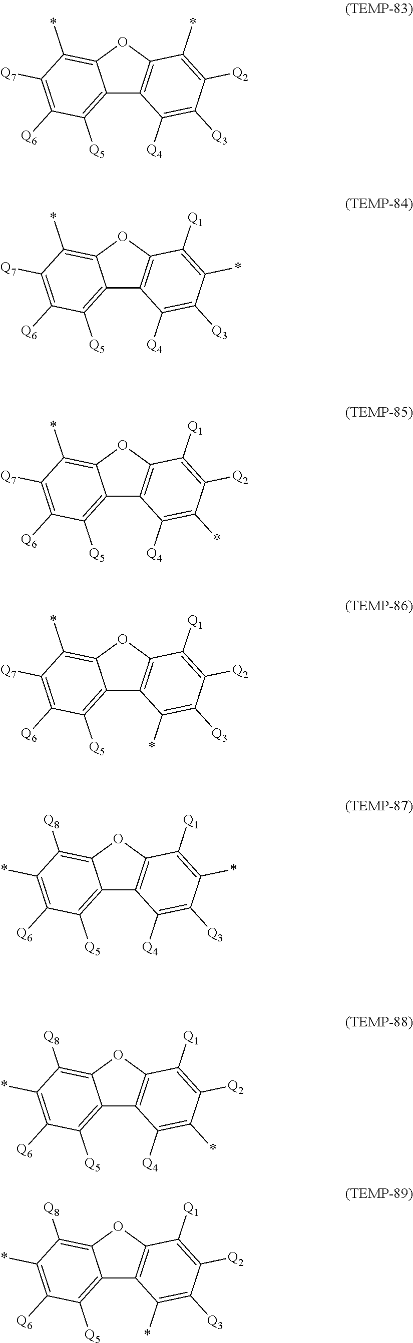

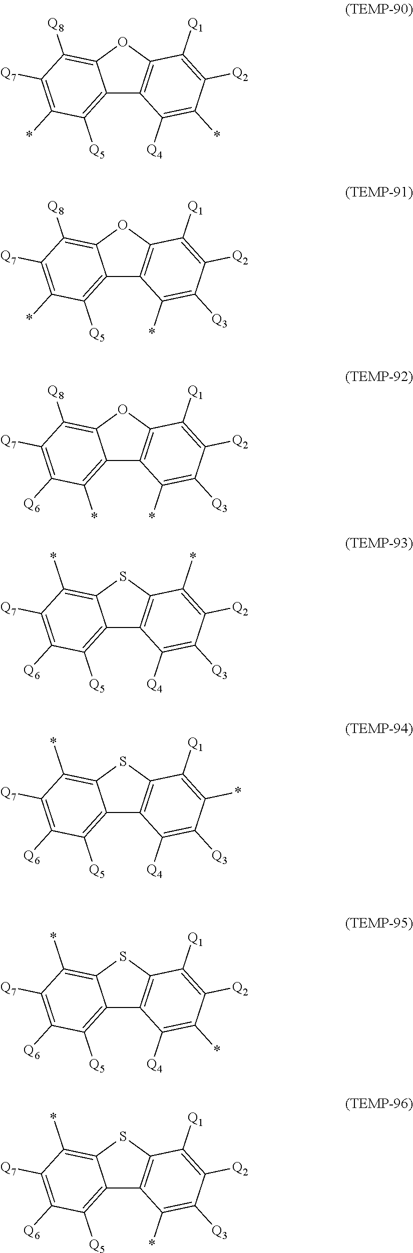

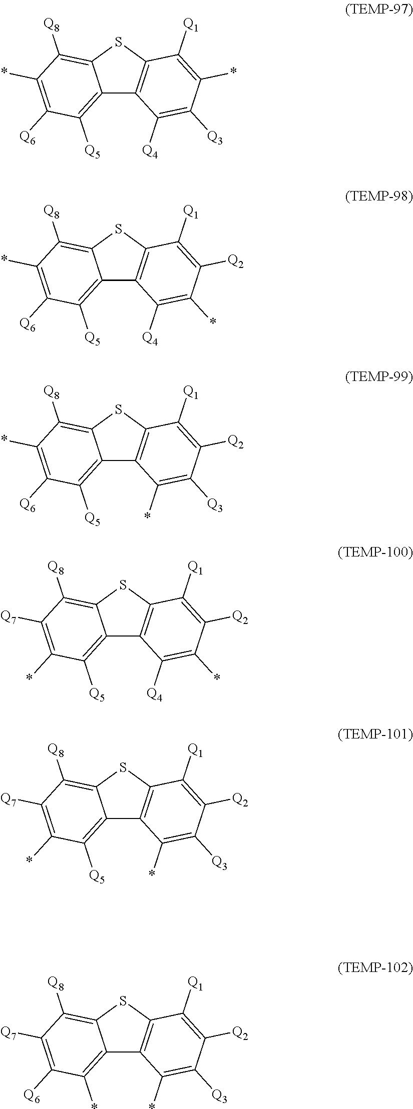

In the general formulas (TEMP-83) to (TEMP-102), Q₁ to Q₈ are independently a hydrogen atom or a substituent.

The above is the explanation of the “Substituent described in this specification.”

“The Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

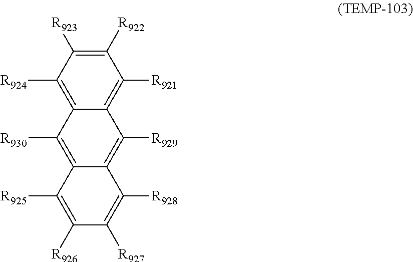

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

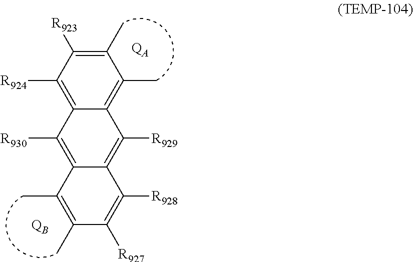

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

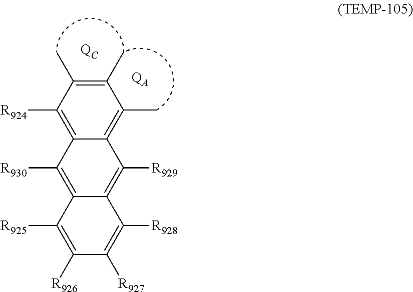

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TEMP-104) is a benzene ring, the ring Q_{A} is a monocycle. When the ring Q_{A} of the general formula (TEMP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without an unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same as or different from each other.

When two or more R₉₀₂'s are present, the two or more R₉₀₂'s may be the same as or different from each other.

When two or more R₉₀₃'s are present, the two or more R₉₀₃'s may be the same as or different from each other.

When two or more R₉₀₄'s are present, the two or more R₉₀₄'s may be the same as or different from each other.

When two or more R₉₀₅'s are present, the two or more R₉₀₅'s may be the same as or different from each other.

When two or more R₉₀₆'s are present, the two or more R₉₀₆'s may be the same as or different from each other.

When two or more R₉₀₇'s are present, the two or more R₉₀₇'s may be the same as or different from each other.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

In this specification, the numerical range represented by “AA≥BB” means that the numerical value AA is equal to or greater than the numerical value BB, and “AA≤BB” that the numerical value AA is equal to or less than the numerical value BB.

Several embodiments and/or examples of the present invention have been described in detail above. However, without substantially departing from novel teachings and effects of the present invention, the person skilled in the art can readily make a number of modifications to the embodiments and/or examples which are exemplifications of these teachings and effects. Thus, these modifications are included in the scope of the present invention.

The documents described in this specification and the contents of the application that serves as the basis of priority claim under Paris convention are incorporated herein by reference in its entirety.

1. A mixed powder usable for a vapor deposition process,
comprising a first organic compound and a second organic compound, wherein the following formula (1) is satisfied:

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source, wherein the mixed powder does not contain a green fluorescent emitting material.

2. The mixed powder according to claim 1, wherein the first organic compound and the second organic compound are organic semiconductor materials.

3. The mixed powder according to claim 1, wherein the first organic compound and the second organic compound are materials for an organic electroluminescence device.

4. The mixed powder according to claim 1, wherein the following formula (1-1) is satisfied:

|θ₁−θ₂|≥15° (1-1)
where θ₁ and θ₂ are as defined in the formula (1).

5. The mixed powder according to claim 1, wherein the following formula (1-2) is satisfied:

|θ₁−θ₂|≥20° (1-2)
where θ₁ and θ₂ are as defined in the formula (1).

6. The mixed powder according to claim 1, obtained by melt-mixing a powder of the first organic compound and a powder of the second organic compound.

7. A compressed pellet obtained by compressing the mixed powder according to claim 1.

8. A method of vapor-depositing an organic compound comprising:
vaporizing a mixed powder comprising a first organic compound and a second organic compound from a vapor deposition source, to form a film on a base material opposite to the vapor deposition source, wherein the following formula (1) is satisfied for the mixed powder:

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source.

9. The method of vapor-depositing an organic compound according to claim 8, wherein the following formula (1-1) is satisfied:

|θ₁−θ₂|≥15° (1-1)
where θ₁ and θ₂ are as defined in the formula (1).

10. The method of vapor-depositing an organic compound according to claim 8, wherein the following formula (1-2) is satisfied:

|θ₁−θ₂|≥20° (1-2)
where θ₁ and θ₂ are as defined in the formula (1).

11. The method of vapor-depositing an organic compound according to claim 8, wherein the pressure inside a vapor deposition equipment at the time of vapor deposition of the mixed powder is 5.0 Pa or lower.

12. The method of vapor-depositing an organic compound according to claim 8, wherein the heating temperature at the time of vapor deposition of the mixed powder is 150° C. to 400° C.

13. A method of fabricating an organic electroluminescence device comprising a cathode, an anode, and one or two or more organic layers disposed between the cathode and the anode, the organic layers comprising an emitting layer; comprising:
vaporizing a mixed powder from a vapor deposition source to deposit at least one layer of the one or two or more organic layers, wherein
the mixed powder comprises a first organic compound and a second organic compound, and the following formula (1) is satisfied for the mixed powder:

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source.

14. The method of fabricating an organic electroluminescence according to claim 13, wherein the following formula (1-1) is satisfied:

|θ₁−θ₂|≥15° (1-1)
where θ₁ and θ₂ are as defined in the formula (1).

15. The method of fabricating an organic electroluminescence according to claim 13, wherein the following formula (1-2) is satisfied:

|θ₁−θ₂|≥20° (1-2)
where θ₁ and θ₂ are as defined in the formula (1).

16. The method of fabricating an organic electroluminescence according to claim 13, wherein the pressure inside a vapor deposition equipment at the time of vapor deposition of the mixed powder is 5.0 Pa or lower.

17. The method of fabricating an organic electroluminescence according to claim 13, wherein the heating temperature at the time of vapor deposition of the mixed powder is 150° C. to 400° C.

18. The method of fabricating an organic electroluminescence according to claim 13, comprising forming a hole-transporting layer or a hole-injecting layer by using the mixed powder.

19. The method of fabricating an organic electroluminescence according to claim 13, comprising forming the emitting layer by using the mixed powder.

20. The method of fabricating an organic electroluminescence according to claim 13, comprising forming an electron-transporting layer or an electron-injecting layer by using the mixed powder.

21. A method of selecting a first organic compound and a second organic compound comprised in a mixed powder usable for a vapor deposition process, comprising:
selecting the first organic compound and the second organic compound so as to satisfy the following formula (1):

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source.

22. The method of selecting a first organic compound and a second organic compound according to claim 21, comprising selecting the first organic compound and the second organic compound so as to satisfy the following formula (1-1):

|θ₁−θ₂|≥15° (1-1)
where θ₁ and θ₂ are as defined in the formula (1).

23. The method of selecting a first organic compound and a second organic compound according to claim 21, comprising selecting the first organic compound and the second organic compound so as to satisfy the following formula (1-2):

|θ₁−θ₂|≥20° (1-2)
where θ₁ and θ₂ are as defined in the formula (1).

24. The method of vapor-depositing of claim 8, further comprising:
when vapor-depositing a first organic compound from a vapor deposition source to a base material, adjusting a spread angle of a vapor deposition trajectory of the first organic compound by adding a second organic compound having a larger or smaller spread angle of a vapor deposition trajectory at the time of a vapor deposition than that of the first organic compound.

25. The mixed powder according to claim 1, wherein the mixed powder does not contain the following Combination (1):

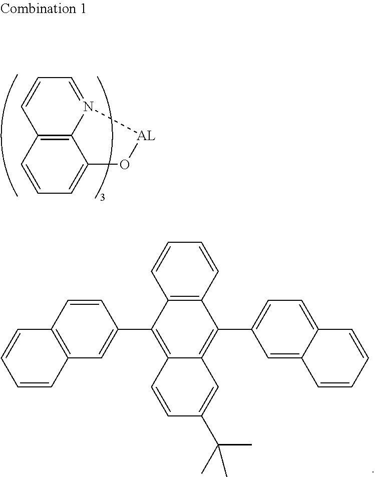

26. A mixed powder usable for a vapor deposition process, comprising a first organic compound and a second organic compound, wherein the following formula (1) is satisfied, provided that a mixed powder comprising a combination of compounds represented by the following Combination 1 is excluded:

|θ₁−θ₂|≥10° (1)
where
θ₁: a spread angle of a vapor deposition trajectory when a powder consisting of the first organic compound is vapor-deposited on a base material from a vapor deposition source, and
θ₂: a spread angle of a vapor deposition trajectory when a powder consisting of the second organic compound is vapor-deposited on a base material from a vapor deposition source. [chemical structure]
